(19) United States
(12) Patent Application Publication
(10) Pub. No.: US 2023/0133575 A1
(43) Pub. Date: May 4, 2023

(54) LIGHT-EMITTING DEVICE INCLUDING ORGANOMETALLIC COMPOUND, ELECTRONIC APPARATUS INCLUDING THE LIGHT-EMITTING DEVICE, AND THE ORGANOMETALLIC COMPOUND

(71) Applicant: Samsung Display Co., Ltd., Yongin-si (KR)

(72) Inventors: Hyunjung Lee, Yongin-si (KR); Iljoon Kang, Yongin-si (KR); Sujin Shin, Yongin-si (KR); Mina Jeon, Yongin-si (KR); Jinhee Ju, Yongin-si (KR); Junghoon Han, Yongin-si (KR)

(21) Appl. No.: 17/956,739

(22) Filed: Sep. 29, 2022

(30) Foreign Application Priority Data
Sep. 30, 2021 (KR) 10-2021-0130284

(51) Int. Cl. H01L 51/00; C09K 11/06; C07F 15/00

(52) U.S. Cl. CPC H01L 51/0087; C09K 11/06; C07F 15/0086; H01L 51/5016

(57) ABSTRACT

A light-emitting device may include: a first electrode; a second electrode facing the first electrode; and an interlayer between the first electrode and the second electrode, the interlayer including an emission layer, wherein the emission layer comprises an organometallic compound represented by Formula 1. Also provided is an electronic apparatus including the light-emitting device including the organometallic compound represented by Formula 1:

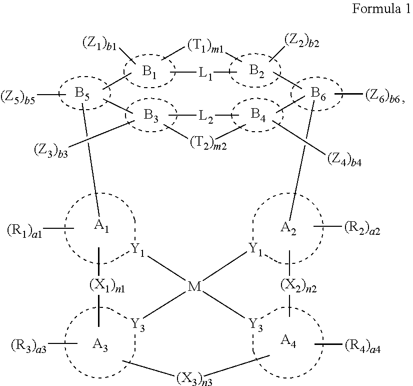

wherein Formula 1 is the same as described in the present specification.

### CROSS-REFERENCE TO RELATED APPLICATION

This application claims priority to and the benefit of Korean Patent Application No. 10-2021-0130284, filed on Sep. 30, 2021, in the Korean Intellectual Property Office, the entire content of which is incorporated herein by reference.

### BACKGROUND

### 1. Field

One or more aspects of embodiments of the present disclosure relate to a light-emitting device including an organometallic compound, an electronic apparatus including the light-emitting device, and the organometallic compound.

### 2. Description of the Related Art

Self-emissive devices among light-emitting devices have wide viewing angles, high contrast ratios, short response times, and excellent or suitable characteristics in terms of luminance, driving voltage, and/or response speed.

In a light-emitting device, a first electrode is arranged on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as holes and electrons, recombine in such an emission layer region to produce excitons. These excitons transition from an excited state to a ground state to thereby generate light.

### SUMMARY

One or more aspects of embodiments of the present disclosure are directed toward a light-emitting device including an organometallic compound, an electronic apparatus including the light-emitting device, and the organometallic compound.

Additional aspects will be set forth in part in the description, which follows and, in part, will be apparent from the description, or may be learned by practice of the presented embodiments of the disclosure.

According to one or more embodiments, provided is a light-emitting device including:

a first electrode,

a second electrode facing the first electrode, and

an interlayer arranged between the first electrode and the second electrode and including an emission layer,

wherein the emission layer includes an organometallic compound represented by Formula 1:

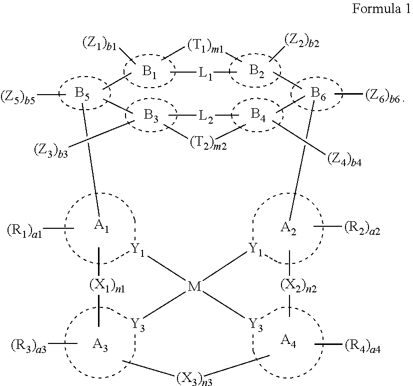

In Formula 1,

M may be iridium (Ir), platinum (Pt), palladium (Pd), copper (Cu), silver (Ag), gold (Au), rhodium (Rh), ruthenium (Ru), rhenium (Re), osmium (Os), titanium (Ti), zirconium (Zr), hafnium (Hf), europium (Eu), terbium (Tb), or thulium (Tm),

X₁ to X₃ may each independently be a single bond, *—C(R₅)(R₆)—*′, *—C(R₅)═*′, *═C(R₅)—*′, *—C(R₅)═C(R₆)—*′, *—C(═O)—*′, *—C(═S)—*′, *—C≡C—*′, *—B(R₅)—*′, *—N(R₅)—*′, *—O—*′, *—P(R₅)—*′, *—Si(R₅)(R₆)—*′, *—P(═O)(R₅)—*′, *—S—*′, *—S(═O)—*′, *—S(═O)₂—*′, or *—Ge(R₅)(R₆)*′,

n1 to n3 may each independently be 1, 2, or 3,

L₁ and L₂ may each independently be a single bond, a C₁-C₂₀ alkylene group unsubstituted or substituted with at least one R₁₀ₐ, a C₂-C₆₀ alkenylene group unsubstituted or substituted with at least one R₁₀ₐ, or a C₂-C₆₀ alkynylene group unsubstituted or substituted with at least one R₁₀ₐ,

T₁ may be *—C(Z₇)(Z₈)—*′, *—C(Z₇)═*′, *═C(Z₇)—*′, *—C(Z₇)═C(Z₈)—*′, *—C(═O)—*′, *—C(═S)—*′, *—C≡C—*′, *—B(Z₇)—*′, *—N(Z₇)—*′, *—O—*′, *—P(Z₇)—*′, *—Si(Z₇)(Z₈)*′, *—P(═O)(Z₇)—*′, *—S—*′, *—S(═O)—*′, *—S(═O)₂*′, or *—Ge(Z₇)(Z₈)*′,

T₂ may be *—C(Z₉)(Z₁₀)—*′, *—C(Z₉)═*′, *═C(Z₉)—*′, *—C(Z₉)═C(Z₁₀)—*′, *—C(═O)—*′, *—C(═S)—*′, *—C≡C—*′, *—B(Z₉)—*′, *—N(Z₉)—*′, *—O—*′, *—P(Z₉)—*′, *—Si(Z₉)(Z₁₀)—*′, *—P(═O)(Z₉)—*′, *—S—*′, *—S(═O)—*′, *—S(═O)₂*′, or *—Ge(Z₉)(Z₁₀)—*′,

m1 and m2 may each independently be 0, 1, 2, or 3, and i) when m1 is 0, T₁ may not be present, and ii) when m2 is 0, T₂ may not be present,

Y₁ to Y₄ may each independently be C or N,

ring A₁ to ring A₄ and ring B₁ to ring B₆ may each independently be a C₃-C₆₀ carbocyclic group or a C₁-C₆₀ heterocyclic group,

R₁ to R₆ and Z₁ to Z₁₀ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkoxy group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

two or more of R₁ to R₆ and Z₁ to Z₁₀ may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

a1 to a4 may each independently be an integer from 0 to 10,

b1 to b6 may each independently be an integer from 0 to 10,

* and *′ each indicate a binding site to a neighboring atom,

R₁₀ₐ may be:

deuterium, —F, —Cl, —Br, —I, a hydroxyl group, a cyano group, or a nitro group,

a C₁-C₆₀ alkyl group, a C₂-C₆₀ alkenyl group, a C₂-C₆₀ alkynyl group, or a C₁-C₆₀ alkoxy group, each independently unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each independently unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁ to Q₃, Q₁₁ to Q₁₃, Q₂₁ to Q₂₃, and Q₃₁ to Q₃₃ may each independently be hydrogen, deuterium, —F, —Cl, —Br, —I, a hydroxyl group, a cyano group, a nitro group, or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each independently unsubstituted or substituted with deuterium, —F, a cyano group, a C₁-C₆₀ alkyl group, a C₁-C₆₀ alkoxy group, a phenyl group, a biphenyl group, or any combination thereof.

According to one or more embodiments, provided is an electronic apparatus including the light-emitting device.

According to one or more embodiments, provided is the organometallic compound represented by Formula 1.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 shows a schematic view of a light-emitting device according to one or more embodiments;

FIG. 2 shows a schematic view of an electronic apparatus according to one or more embodiments; and

FIG. 3 shows a schematic view of an electronic apparatus according to one or more other embodiments.

### DETAILED DESCRIPTION

Reference will now be made in more detail to embodiments, examples of which are illustrated in the accompanying drawings, wherein like reference numerals refer to like elements throughout the specification, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. As used herein, the term “and/or” includes any and all combinations of one or more of the same associated listed items. Expressions such as “at least one of”, “one of”, and “selected from”, when preceding a list of elements, modify the entire list of elements and do not modify the individual elements of the list. For example, throughout the disclosure, the expressions “at least one of a, b or c”, “at least one of a, b and c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof. Further, the use of “may” when describing embodiments of the present disclosure refers to “one or more embodiments of the present disclosure.”

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

One or more embodiments of the present disclosure provide a light-emitting device including: a first electrode; a second electrode facing the first electrode; an interlayer arranged between the first electrode and the second electrode and including an emission layer; and an organometallic compound represented by Formula 1:

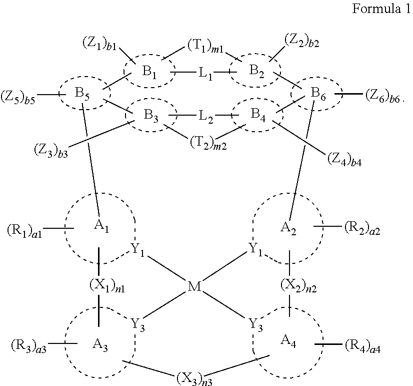

In Formula 1, M may be iridium (Ir), platinum (Pt), palladium (Pd), copper (Cu), silver (Ag), gold (Au), rhodium (Rh), ruthenium (Ru), rhenium (Re), osmium (Os), titanium (Ti), zirconium (Zr), hafnium (Hf), europium (Eu), terbium (Tb), or thulium (Tm).

In one or more embodiments, M may be Pt, Pd, or Au.

In Formula 1,

X₁ to X₃ may each independently be a single bond, *—C(R₅)(R₆)—*′, *—C(R₅)═*′, *═C(R₅)—*′, *—C(R₅)═C(R₆)—*′, *—C(═O)—*′, *—C(═S)—*′, *—C≡C—*′, *—B(R₅)—*′, *—N(R₅)—*′, *—O—*′, *—P(R₅)—*′, *—Si(R₅)(R₆)—*′, *—P(═O)(R₅)—*′, *—S—*′, *—S(═O)—*′, *—S(═O)₂—*′, or *—Ge(R₅)(R₆)*′.

In one or more embodiments, X₁ and X₂ may each independently be a single bond, *—C(R₅)(R₆)—*′, *—B(R₅)—*′, *—N(R₅)—*′, *—O—*′, *—P(R)—*′, *—Si(R₅)(R₆)*′, or *—S—*′, and

X₃ may be *—C(R₅)(R₆)—*′, *—B(R₅)*′, *—N(R₅)—*′, *—O—*′, *—P(R₅)—*′, *—Si(R₅)(R₆)—*′, or *—S*′

In one or more embodiments, X₁ and X₂ may be identical to each other.

R₅ and R₆ may respectively be the same as described herein.

In Formula 1, n1 to n3 may each independently be 1, 2, or 3.

In one or more embodiments, n1 to n3 may each be 1.

In one or more embodiments, n1 and n2 may be identical to each other.

In Formula 1,

L₁ and L₂ may each independently be a single bond, a C₁-C₂₀ alkylene group unsubstituted or substituted with at least one R₁₀ₐ, a C₂-C₆₀ alkenylene group unsubstituted or substituted with at least one R₁₀ₐ, or a C₂-C₆₀ alkynylene group unsubstituted or substituted with at least one R₁₀ₐ.

In one or more embodiments, L₁ and L₂ may each independently be a single bond, a C₁-C₅ alkylene group unsubstituted or substituted with at least one R₁₀ₐ, a C₂-C₅ alkenylene group unsubstituted or substituted with at least one R₁₀ₐ, or a C₂-C₅ alkynylene group unsubstituted or substituted with at least one R₁₀ₐ.

In one or more embodiments, L₁ and L₂ may be identical to each other.

In Formula 1,

T₁ may be *—C(Z₇)(Z₈)—*′, *—C(Z₇)═*′, *═C(Z₇)—*′, *—C(Z₇)═C(Z₈)—*′, *—C(═O)—*′, *—C(═S)—*′, *—C≡C—*′, *—B(Z₇)—*′, *—N(Z₇)—*′, *—0*′, *—P(Z₇)—*′, *—Si(Z₇)(Z₈)*′, *—P(═O)(Z₇)—*′, *—S—*′, *—S(═O)*′, *—S(═O)₂*′, or *—Ge(Z₇)(Z₈)*′, and

T₂ may be *—C(Z₉)(Z₁₀)—*′, *—C(Z₉)═*′, *═C(Z₉)—*′, *—C(Z₉)═C(Z₁₀)—*′, *—C(═O)—*′, *—C(═S)—*′, *—C≡C—*′, *—B(Z₉)—*′, *—N(Z₉)—*′, *—O—*′, *—P(Z₉)—*′, *—Si(Z₉)(Z₁₀)—*′, *—P(═O)(Z₉)—*′, *—S—*′, *—S(═O)—*′, *—S(═O)₂*′, or *—Ge(Z₉)(Z₁₀)—*′.

In one or more embodiments, T₁ may be *—C(Z₇)(Z₈)—*′, *—B(Z₇)—*′, *—N(Z₇)—*′, *—O—*′, *—Si(Z₇)(Z₈)—*′, or *—S—*′, and T₂ may be *—C(Z₉)(Z₁₀)—*′, *—B(Z₉)—*′, *—N(Z₉)—*′, *—O—*′, *—Si(Z₉)(Z₁₀)—*′, or *—S—*′.

In one or more embodiments, T₁ may be *—C(Z₇)(Z₈)—*′, *—N(Z₇)—*′, or *—O—*′, and T₂ may be *—C(Z₉)(Z₁₀)*′, *—N(Z₉)*′, or *—O—*′.

In one or more embodiments, T₁ and T₂ may be identical to each other.

In Formula 1,

m1 and m2 may each independently be 0, 1, 2, or 3, and i) when m1 is 0, T₁ may not be present, and ii) when m2 is 0, T₂ may not be present.

For example, i) when m1 is 0, T₁ may not be present, and ring B₁ and ring B₂ in Formula 1 may be linked via L₁.

For example, i) when m2 is 0, T₂ may not be present, and ring B₃ and ring B₄ in Formula 1 may be linked via L₂.

In one or more embodiments, m1 and m2 may each independently be 0 or 1. For example, both (e.g., simultaneously) m1 and m2 may be 0, or both (e.g., simultaneously) m1 and m2 may be 1.

In one or more embodiments, m1 and m2 may be identical to each other.

In Formula 1, Y₁ to Y₄ may each independently be C or N.

In one or more embodiments, Y₁ and Y₂ may each be C.

In one or more embodiments, Y₁ to Y₄ may each be C.

In one or more embodiments, Y₁ and Y₂ may be identical to each other, and Y₃ and Y₄ may be identical to each other.

In one or more embodiments, a bond between Y₁ and M and a bond between Y₂ and M may each be a coordinate bond, and a bond between Y₃ and M and a bond between Y₄ and M may each be a covalent bond.

In one or more embodiments, Y₁ and Y₂ may each be C, a bond between Y₁ and M and a bond between Y₂ and M may each be a coordinate bond, and a bond between Y₃ and M and a bond between Y₄ and M may each be a covalent bond.

In one or more embodiments, Y₁ to Y₄ may each be C, a bond between Y₁ and M and a bond between Y₂ and M may each be a coordinate bond, and a bond between Y₃ and M and a bond between Y₄ and M may each be a covalent bond.

For example, when Y₁ and Y₂ are each C, Y₁ and Y₂ may each have a carbene structure so that a coordinate bond with M may be formed.

In Formula 1,

ring A₁ to ring A₄ and ring B₁ to ring B₆ may each independently be a C₃-C₆₀ carbocyclic group or a C₁-C₆₀ heterocyclic group.

In one or more embodiments,

ring A₁ and ring A₂ may each independently be:

a pyrazole group, an imidazole group, a triazole group, an oxazole group, an isoxazole group, an oxadiazole group, a thiazole group, an isothiazole group, or a thiadiazole group; or

a pyrazole group, an imidazole group, a triazole group, an oxazole group, an isoxazole group, an oxadiazole group, a thiazole group, an isothiazole group, or a thiadiazole group, to each of which a benzene group, a pyridine group, a pyrimidine group, a pyrazine group, a pyridazine group, or any combination thereof may be condensed (e.g., each independently condensed with a benzene group, a pyridine group, a pyrimidine group, a pyrazine group, a pyridazine group, or any combination thereof).

For example, ring A₁ and ring A₂ may be identical to each other.

In one or more embodiments,

ring A₃, ring A₄, and ring B₁ to ring B₆ may each independently be:

a benzene group, a pyridine group, a pyrimidine group, a pyrazine group, a pyridazine group, or a triazine group; or

a benzene group, a pyridine group, a pyrimidine group, a pyrazine group, a pyridazine group, or a triazine group, to each of which a benzene group, a pyridine group, a pyrimidine group, a pyrazine group, a pyridazine group, a cyclohexane group, a cyclohexene group, an adamantane group, norbornane group, or any combination thereof may be condensed (e.g., each independently condensed with a benzene group, a pyridine group, a pyrimidine group, a pyrazine group, a pyridazine group, a cyclohexane group, a cyclohexene group, an adamantane group, norbornane group, or any combination thereof).

For example, ring A₃ and ring A₄ may be identical to each other.

For example, ring B₁ to ring B₆ may be identical to each other.

In one or more embodiments, the organometallic compound represented by Formula 1 may satisfy at least one of Condition 1 to Condition 4:

### Condition 1

a group represented by

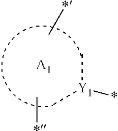

in Formula 1 is represented by one of Formulae A₁-1 to A₁-8:

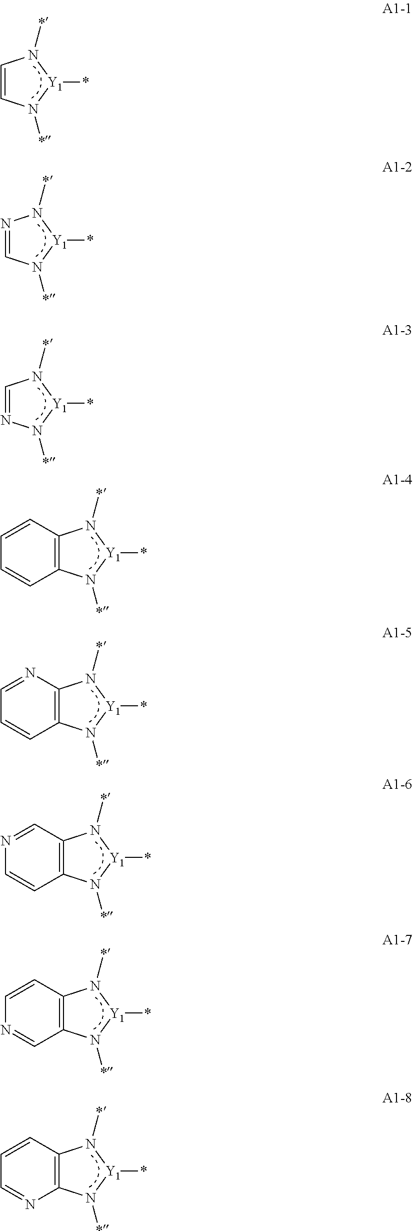

wherein, in Formulae A₁-1 to A₁-8,

Y₁ may be C,

*′ indicates a binding site to ring B₅,

* indicates a binding site to M in Formula 1, and

*″ indicates a binding site to X₁ in Formula 1;

### Condition 2

a group represented by

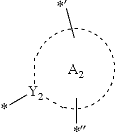

in Formula 1 is represented by one of Formulae A₂-1 to A₂-8:

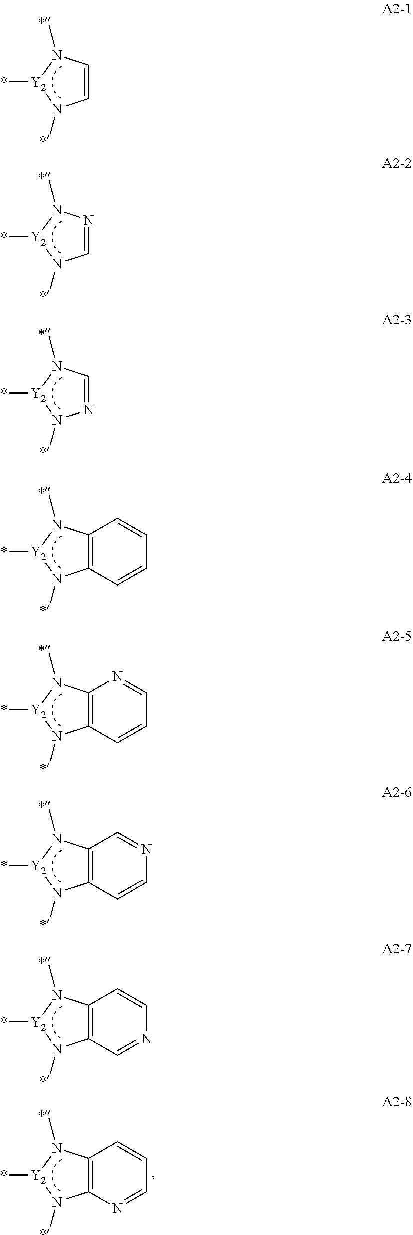

wherein, in Formulae A₂-1 to A₂-8,

Y₂ may be C,

*″ indicates a binding site to ring B₆,

* indicates a binding site to M in Formula 1, and

* indicates a binding site to X₂ in Formula 1;

### Condition 3

a group represented by

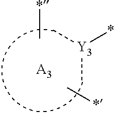

in Formula 1 is represented by one of Formulae A₃-1 to A₃-6:

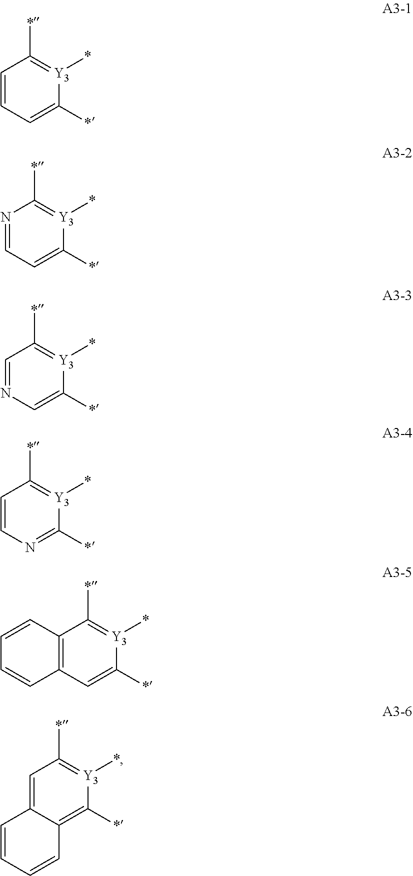

wherein, in Formulae A₃-1 to A₃-6,

Y₃ may be C,

*″ indicates a binding site to X₁ in Formula 1,

* indicates a binding site to M in Formula 1, and

*′ is a binding site to X₃ in Formula 1; and

### Condition 4

a group represented by

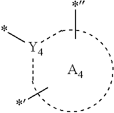

in Formula 1 is represented by one of Formulae A₄-1 to A₄-6:

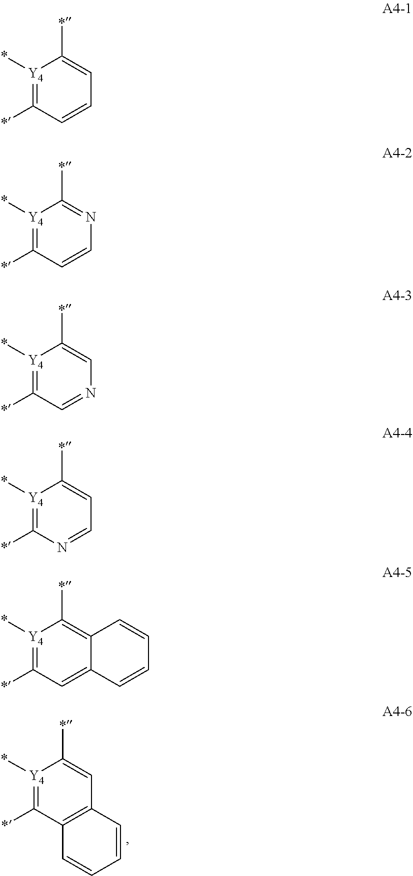

wherein, in Formulae A₄-1 to A₄-6,

Y₄ is C,

*″ indicates a binding site to X₂ in Formula 1,

* indicates a binding site to M in Formula 1, and

*′ is a binding site to X₃ in Formula 1.

For example, the organometallic compound represented by Formula 1 may satisfy Condition 1, and a bond between Y₁ and M may be a coordinate bond. Here, ring A₁ may be represented by Formula A₁-4.

For example, the organometallic compound represented by Formula 1 may satisfy Condition 2, and a bond between Y₂ and M may be a coordinate bond. Here, ring A₂ may be represented by Formula A₂-4.

For example, the organometallic compound represented by Formula 1 may satisfy Condition 3, and a bond between Y₃ and M may be a coordinate bond. Here, ring A₃ may be represented by A₃-1.

For example, the organometallic compound represented by Formula 1 may satisfy Condition 4, and a bond between Y₄ and M may be a coordinate bond. Here, ring A₄ may be represented by A₄-1.

For example, the organometallic compound represented by Formula 1 may satisfy Condition 1 and Condition 2.

For example, the organometallic compound represented by Formula 1 may satisfy Condition 3 and Condition 4.

In one or more embodiments

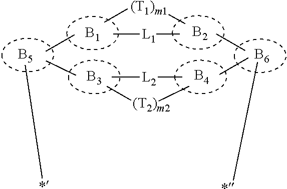

a group represented by in Formula 1 may be a group represented by one of Formulae B1-1 to B1-3:

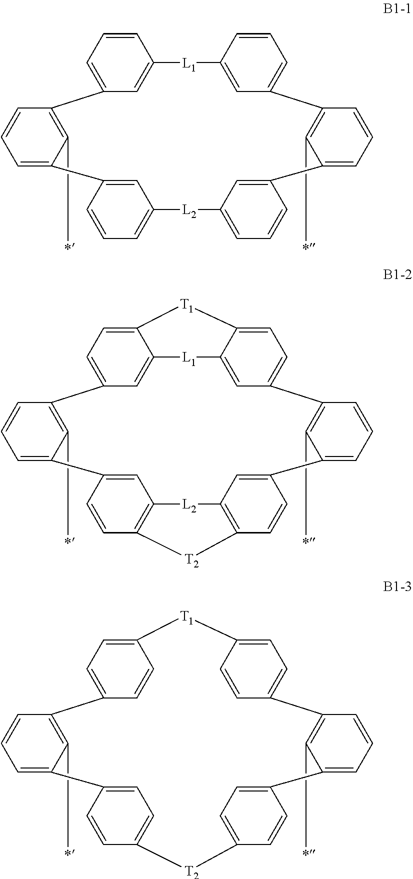

In Formulae B1-1 to B1-3,

L₁, L₂, T₁, and T₂ may respectively be the same as described herein,

*′ indicates a binding site to ring A₁ in Formula 1, and

*″ indicates a binding site to ring A₂ in Formula 1.

For example, L₁ and L₂ in Formula B1-1 may each independently be a single bond or a C₂-C₅ alkynylene group unsubstituted or substituted with at least one R₁₀ₐ.

For example, in Formula B1-2, L₁ and L₂ may each independently be a single bond, T₁ may be *—C(Z₇)(Z₈)—*′, *—N(Z₇)—*′, or *—O—*′, and T₂ may be *—C(Z₉)(Z₁₀)—*′, *—N(Z₉)—*′, or *—O—*′.

For example, L₁ and L₂ in Formula B1-3 may each independently be a C₁-C₅ alkylene group unsubstituted or substituted with at least one R₁₀ₐ or a C₂-C₅ alkenylene group unsubstituted or substituted with at least one R₁₀ₐ.

In Formula 1,

R₁ to R₆ and Z₁ to Z₁₀ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkoxy group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

two or more of R₁ to R₆ and Z₁ to Z₁₀ may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ.

In one or more embodiments,

R₁ to R₆ may each independently be hydrogen, deuterium, —F, a hydroxyl group, a cyano group, a nitro group, a C₁-C₂₀ alkyl group unsubstituted or substituted with at least one R₁₀ₐ, a C₃-C₂₀ carbocyclic group unsubstituted or substituted with at least one R₁₀ₐ, or a C₁-C₂₀ heterocyclic group unsubstituted or substituted with at least one R₁₀ₐ.

In one or more embodiments,

R₁ to R₆ may each independently be:

hydrogen, deuterium, —F, a hydroxyl group, a cyano group, or a nitro group;

a C₁-C₂₀ alkyl group unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkoxy group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, an indenyl group, a fluorenyl group, a pyrrolyl group, a thiophenyl group, a furanyl group, an indolyl group, a benzoindolyl group, a naphthoindolyl group, an isoindolyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzoxazolyl group, a benzothiazolyl group, a benzoxadiazolyl group, or a benzothiadiazolyl group, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a C₁-C₂₀ alkoxy group, a cyclopropyl group, a cyclobutyl group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, an indenyl group, a fluorenyl group, a pyrrolyl group, a thiophenyl group, a furanyl group, an indolyl group, a benzoindolyl group, a naphthoindolyl group, an isoindolyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzoxazolyl group, a benzothiazolyl group, a benzoxadiazolyl group, a benzothiadiazolyl group, —Si(Q₃₁)(Q₃₂)(Q₃₃), —B(Q₃₁)(Q₃₂), or any combination thereof; or

—Si(Q₁)(Q₂)(Q₃), —N(Q₁)(Q₂), or —B(Q₁)(Q₂), and

Q₁ to Q₃ and Q₃₁ to Q₃₃ may respectively be the same as described herein.

In one or more embodiments, Z₁ to Z₁₀ may each independently be hydrogen, deuterium, —F, a hydroxyl group, a cyano group, a nitro group, a C₁-C₂₀ alkyl group unsubstituted or substituted with at least one R₁₀ₐ, a C₃-C₂₀ carbocyclic group unsubstituted or substituted with at least one R₁₀ₐ, or a C₁-C₂₀ heterocyclic group unsubstituted or substituted with at least one R₁₀ₐ.

In one or more embodiments, Z₁ to Z₁₀ may each independently be:

hydrogen, deuterium, —F, a hydroxyl group, a cyano group, or a nitro group;

a C₁-C₂₀ alkyl group or a C₁-C₂₀ alkoxy group, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkoxy group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, an indenyl group, a fluorenyl group, a pyrrolyl group, a thiophenyl group, a furanyl group, an indolyl group, a benzoindolyl group, a naphthoindolyl group, an isoindolyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzoxazolyl group, a benzothiazolyl group, a benzoxadiazolyl group, or a benzothiadiazolyl group, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a C₁-C₂₀ alkoxy group, —Si(Q₃₁)(Q₃₂)(Q₃₃), —B(Q₃₁)(Q₃₂), or any combination thereof; or

—Si(Q₁)(Q₂)(Q₃), —N(Q₁)(Q₂), or —B(Q₁)(Q₂), and

Q₁ to Q₃ and Q₃₁ to Q₃₃ may respectively be the same as described herein.

For example, Z₅ and Z₆ may each independently be:

hydrogen, deuterium, —F, a hydroxyl group, a cyano group, or a nitro group;

a C₁-C₂₀ alkyl group unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkoxy group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a biphenyl group, a naphthyl group, a pyridinyl group, a pyrimidinyl group, or any combination thereof; or

a phenyl group unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a C₁-C₂₀ alkoxy group, —Si(Q₃₁)(Q₃₂)(Q₃₃), —B(Q₃₁)(Q₃₂), or any combination thereof.

In Formula 1, a1 to a4 may each independently be an integer from 0 to 10.

In one or more embodiments, a1 to a4 may each independently be an integer from 0 to 5.

In one or more embodiments, a1 and a2 may be identical to each other.

In Formula 1, b1 to b6 may each independently be an integer from 0 to 10.

In one or more embodiments, b1 to b6 may each independently be an integer from 0 to 5.

In one or more embodiments, b5 and b6 may be identical to each other.

In Formula 1, * and *′ each indicate a binding site to a neighboring atom.

In Formula 1, R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each independently unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each independently unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each independently unsubstituted or substituted with deuterium, —F, a cyano group, a C₁-C₆₀ alkyl group, a C₁-C₆₀ alkoxy group, a phenyl group, a biphenyl group, or any combination thereof.

The organometallic compound represented by Formula 1 may be one of Compounds 1 to 50:

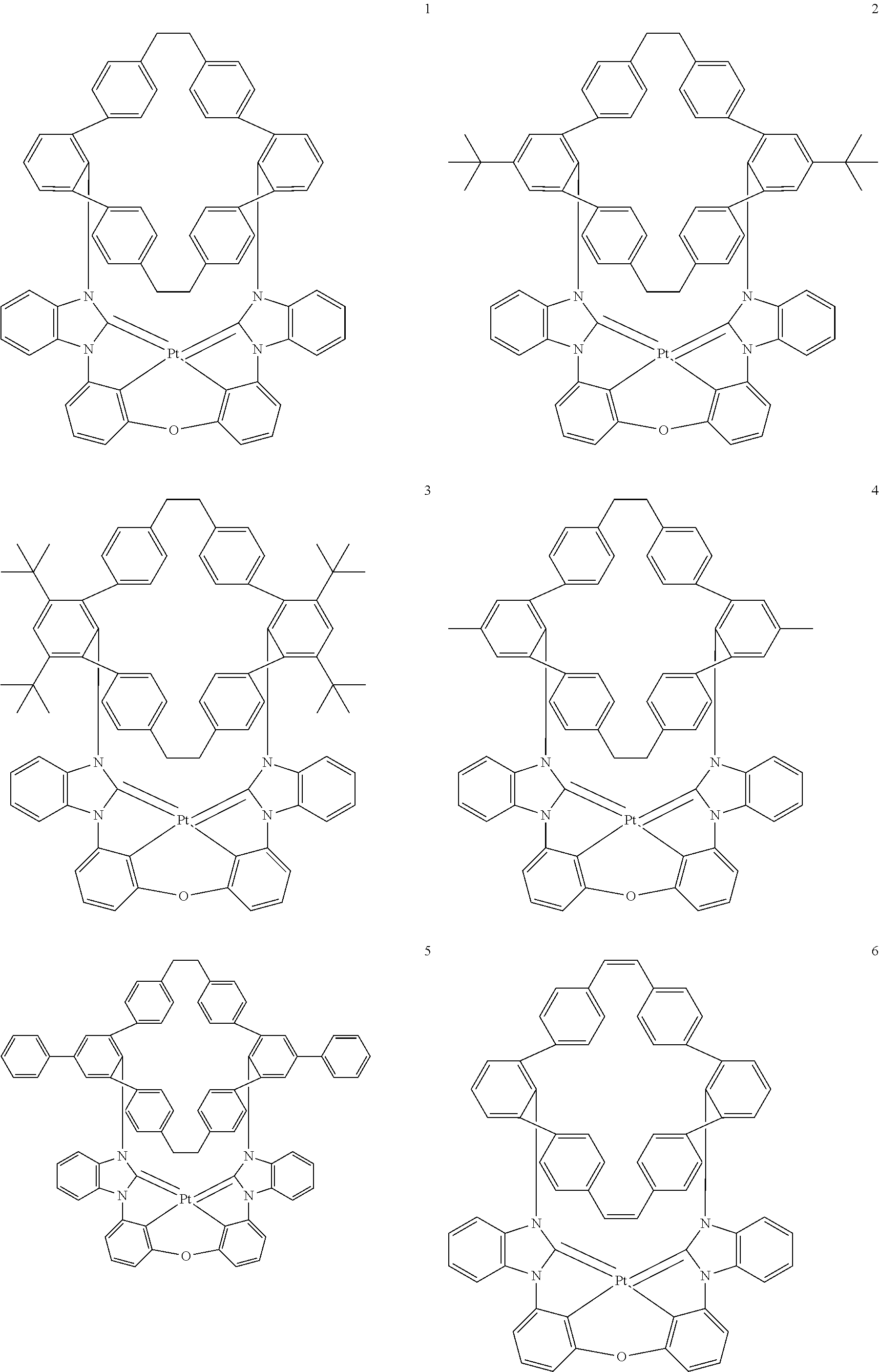

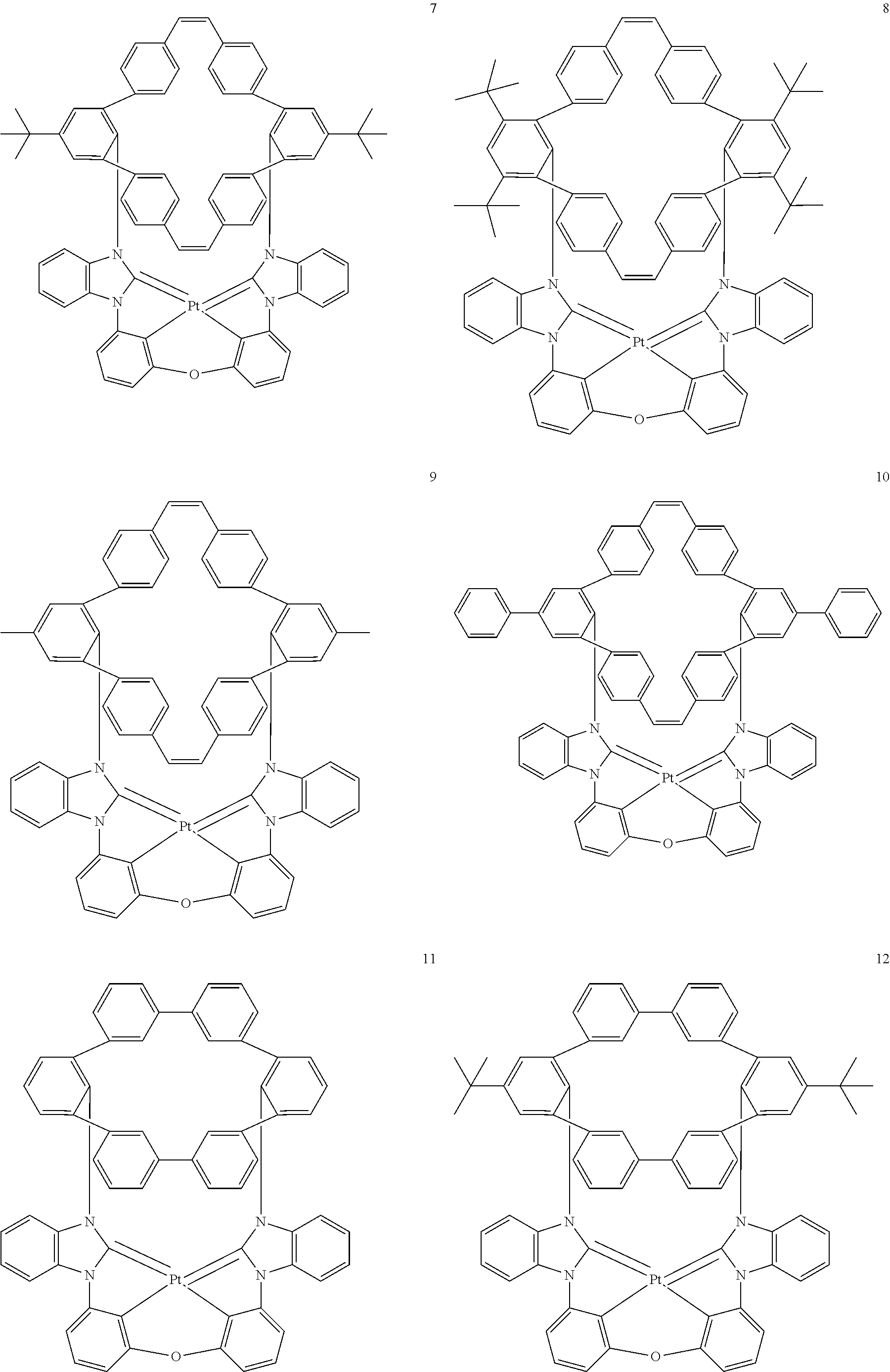

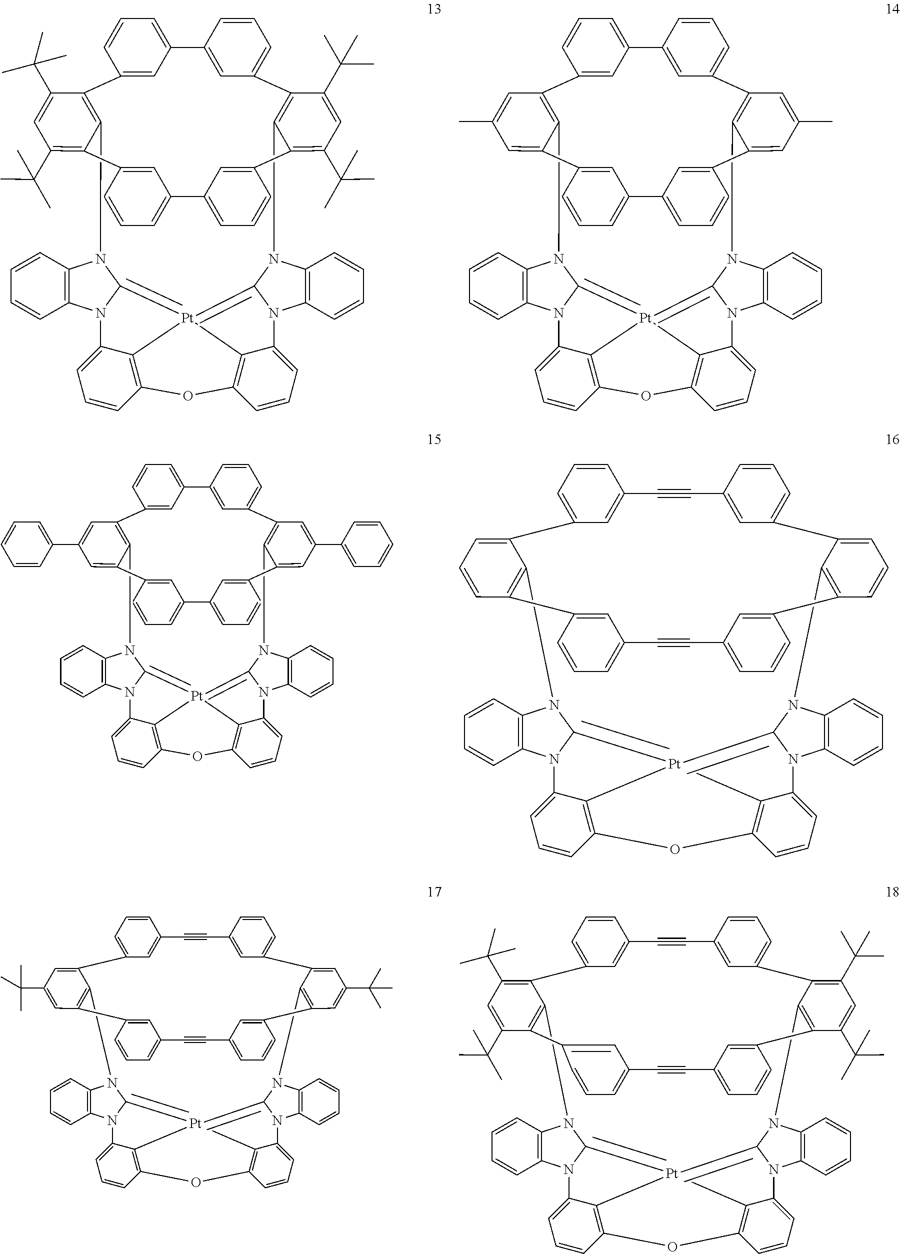

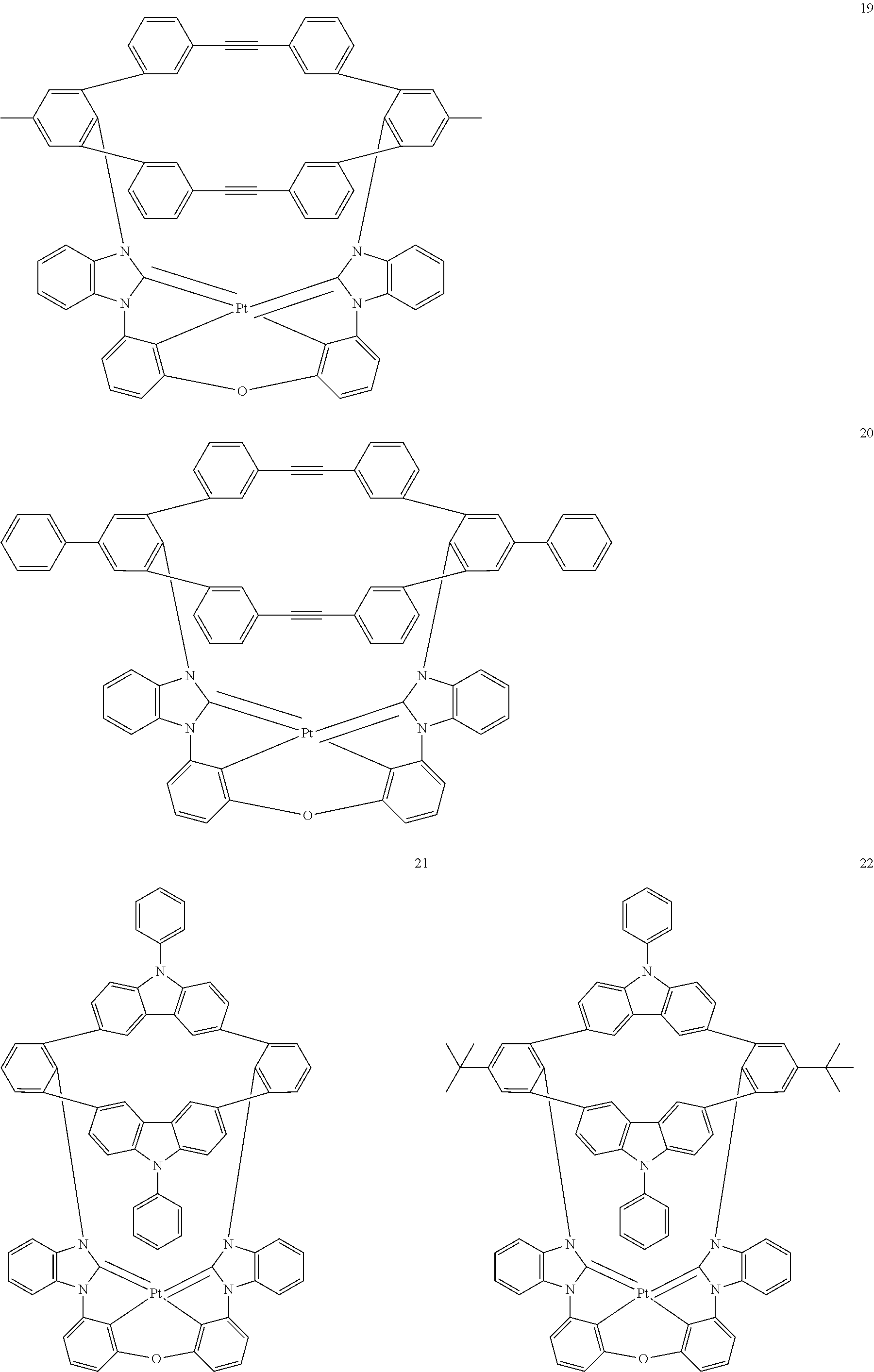

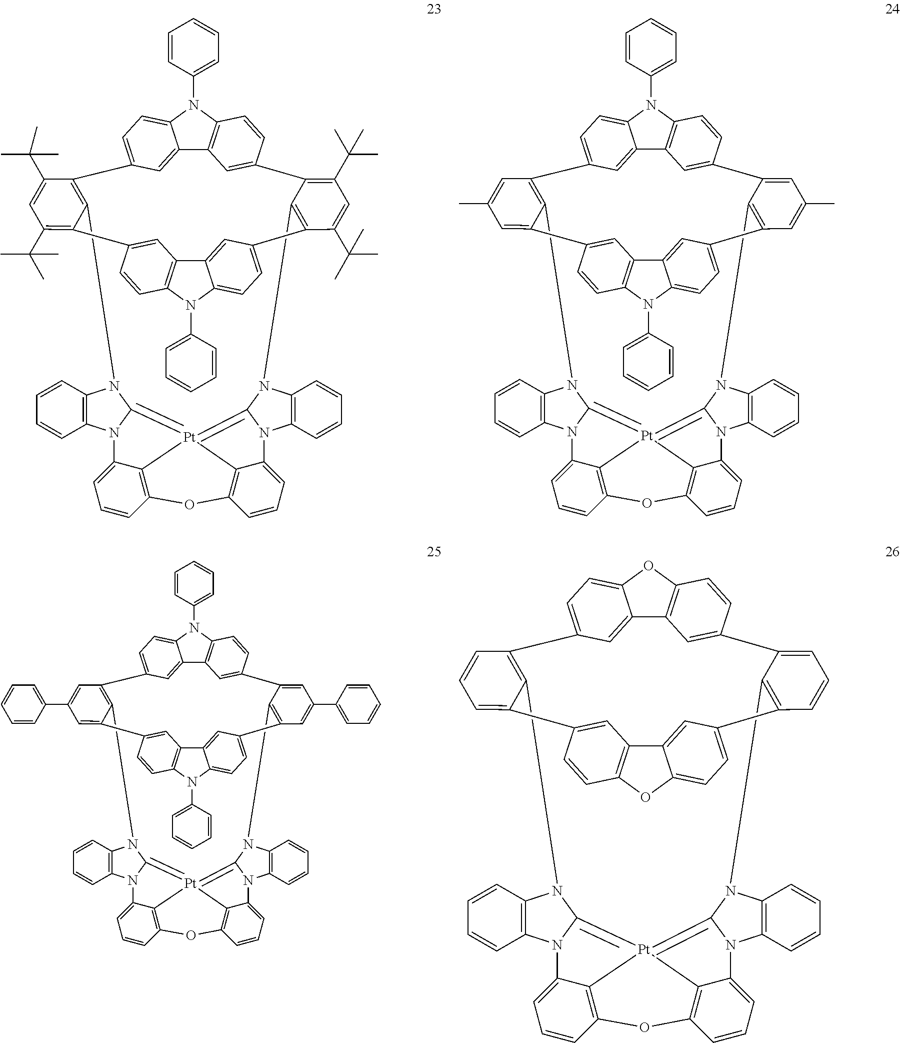

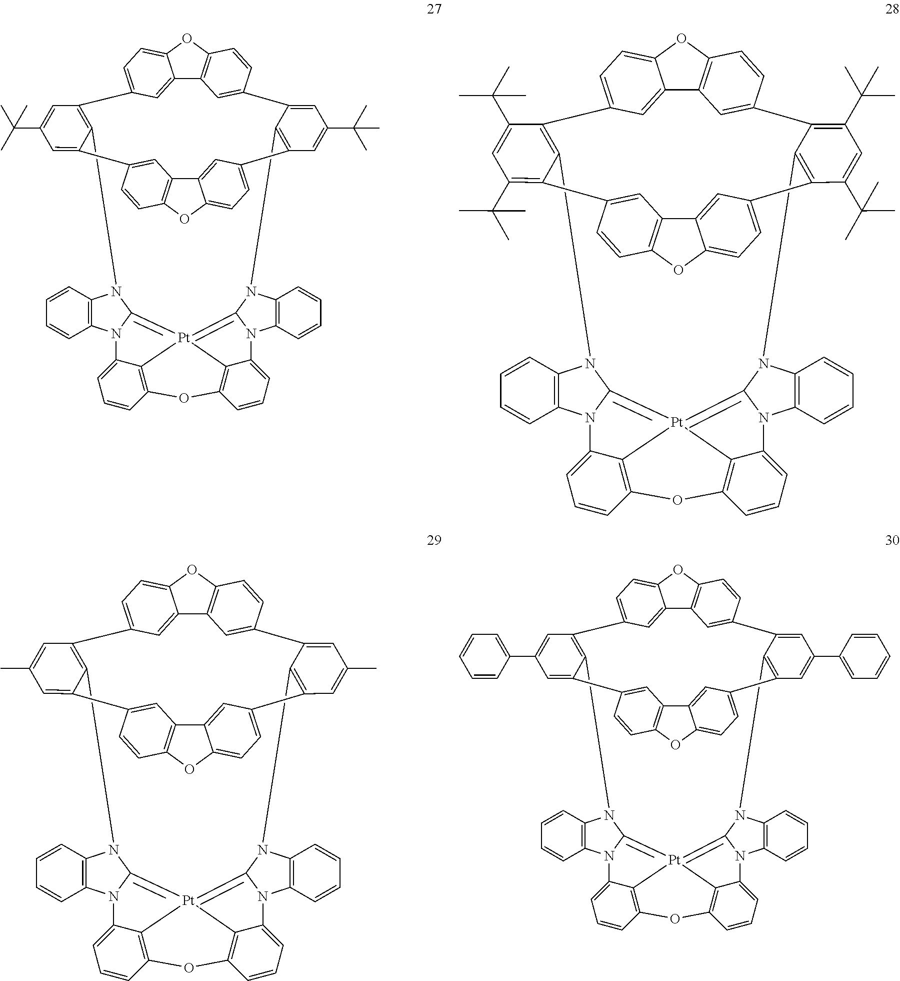

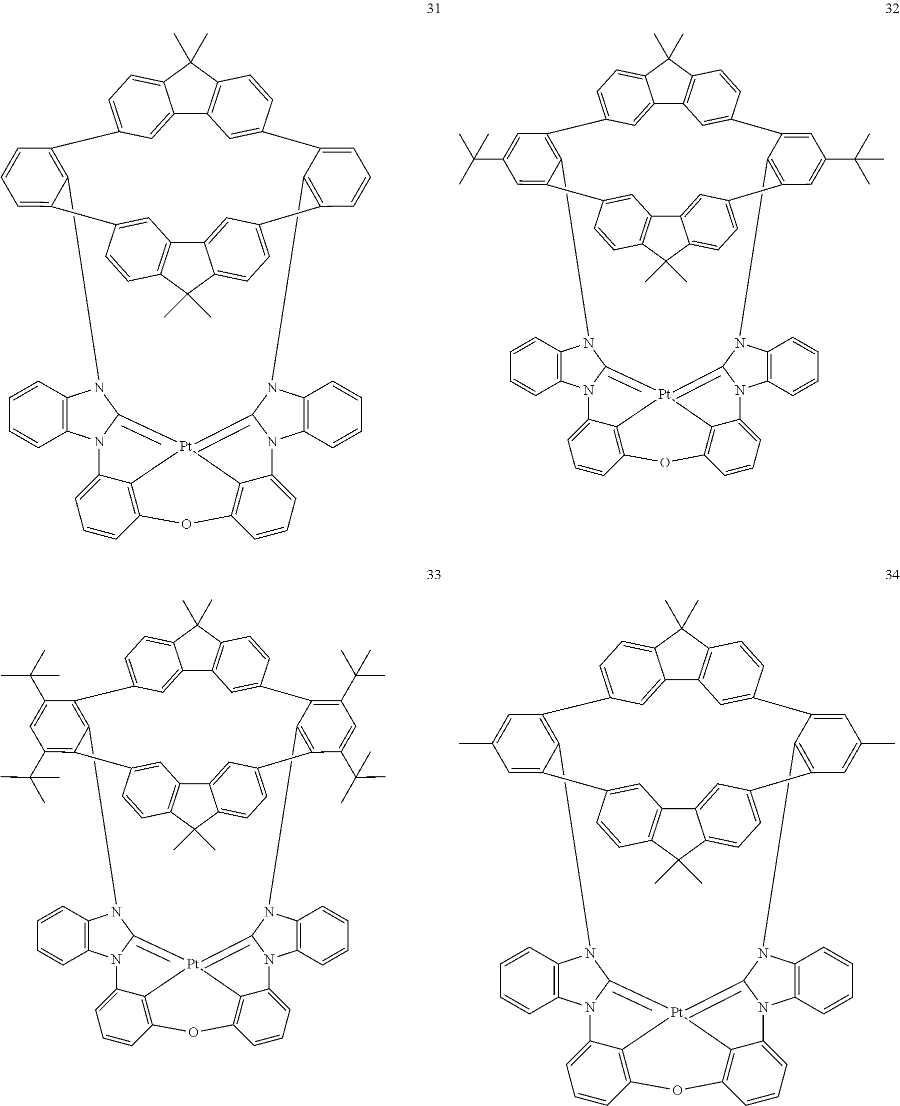

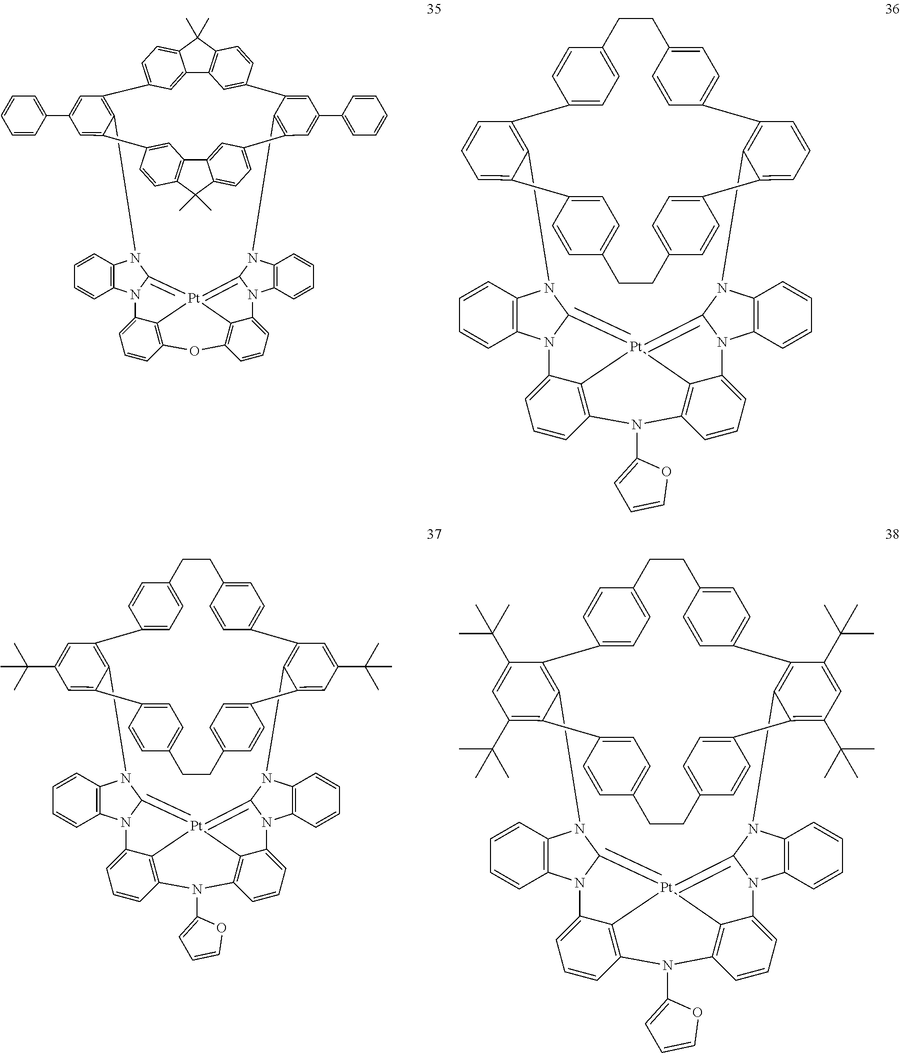

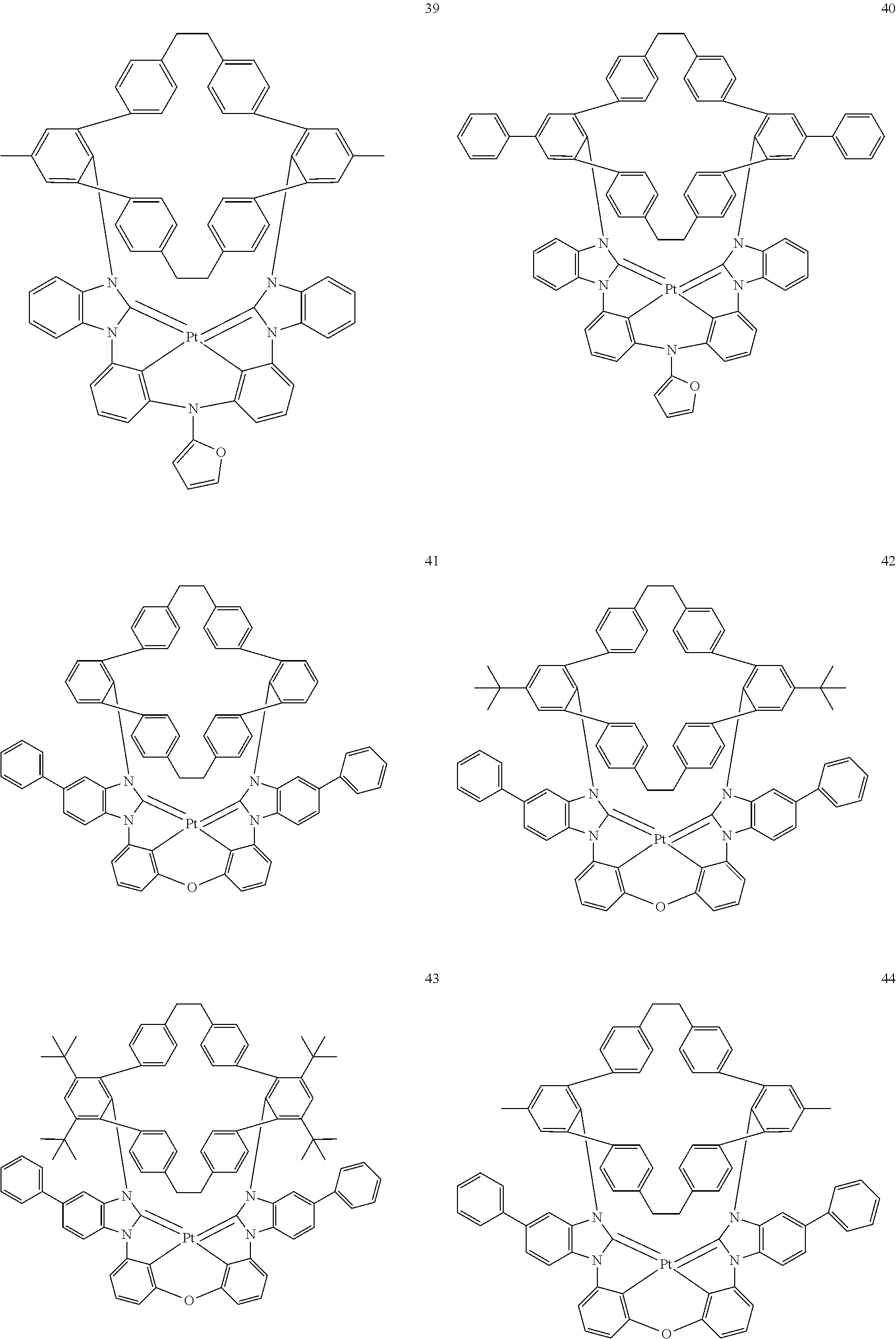

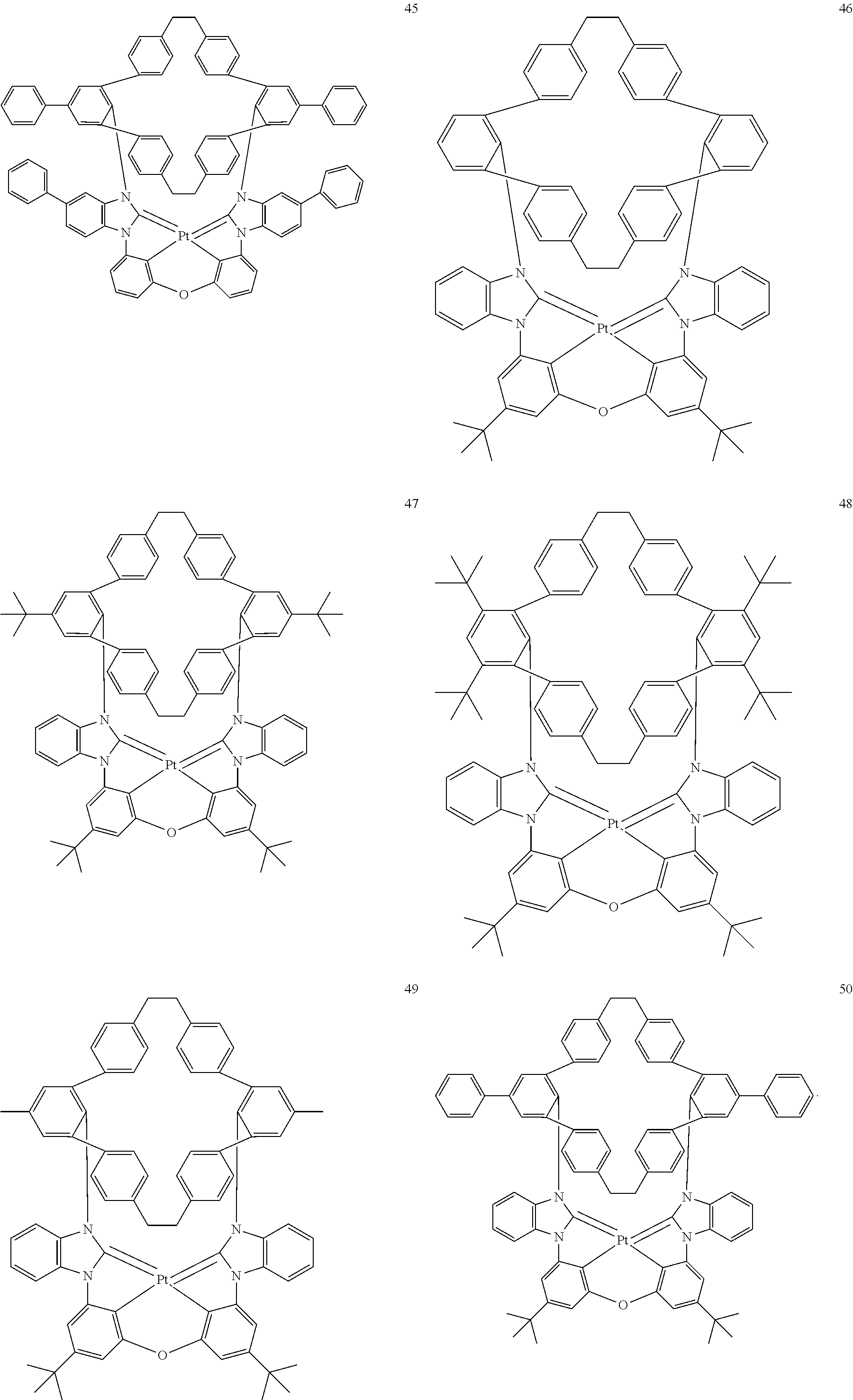

The organometallic compound represented by Formula 1 may be to emit (e.g., may be configured to emit) blue light having a maximum emission wavelength of about 430 nm or more and about 500 nm or less.

The organometallic compound represented by Formula 1 has a structure in which ring B₁ to ring B₆ in Formula 1 are linked to each other to form one ring and are also concurrently (e.g., simultaneously) linked to two ligands of a tetradentate metal complex. Accordingly, the organometallic compound represented by Formula 1 may have increased structural rigidity, and due to such structural characteristics, energy in a ³MC state may be increased, thereby improving the compound stability in an excited state.

Thus, when the organometallic compound represented by Formula 1 is utilized, an electronic device (for example, an organic light-emitting device) including the organometallic compound represented by Formula 1 may, without a significant increase in driving voltage, achieve excellent or suitable luminescence efficiency, improved color conversion efficiency, and/or long lifespan characteristics.

Synthesis methods of the organometallic compound represented by Formula 1 may be recognizable by one of ordinary skill in the art by referring to Synthesis Examples and/or Examples provided.

In one or more embodiments,

the first electrode of the light-emitting device may be an anode,

the second electrode of the light-emitting device may be a cathode,

the interlayer may further include a hole transport region arranged between the first electrode and the emission layer, and an electron transport region arranged between the emission layer and the second electrode,

the hole transport region may include a hole injection layer, a hole transport layer, an emission auxiliary layer, an electron blocking layer, or any combination thereof, and

the electron transport region may include a buffer layer, a hole blocking layer, an electron control layer, an electron transport layer, an electron injection layer, or any combination thereof.

In one or more embodiments, the interlayer of the light-emitting device may include the organometallic compound represented by Formula 1.

In one or more embodiments, the emission layer of the light-emitting device may include the organometallic compound represented by Formula 1.

In one or more embodiments, the emission layer may be to emit (e.g., may be configured to emit) red light, green light, blue light, and/or white light. For example, the emission layer may be to emit (e.g., may be configured to emit) blue light. The blue light may have a maximum emission wavelength in a range of about 410 nm to about 500 nm, about 420 nm to about 490 nm, about 430 nm to 480 nm, or about 430 nm to about 470 nm.

In one or more embodiments, the emission layer of the light-emitting device may include a dopant and a host, and the dopant may include the organometallic compound represented by Formula 1. For example, the organometallic compound may act as a dopant. The emission layer may be to emit (e.g., may be configured to emit), for example, blue light. The blue light may have a maximum emission wavelength in a range of, for example, about 430 nm to about 500 nm.

In one or more embodiments, the electron transport region of the light-emitting device may include a hole blocking layer, and the hole blocking layer may include a phosphine oxide-containing compound, a silicon-containing compound, or any combination thereof. For example, the hole blocking layer may be in direct contact with the emission layer.

In one or more embodiments, the light-emitting device may further include at least one of a first capping layer arranged outside the first electrode or a second capping layer arranged outside the second electrode, and the at least one of the first capping layer or the second capping layer may include the organometallic compound represented by Formula 1. The first capping layer and the second capping layer may respectively be the same as described herein.

In one or more embodiments, the light-emitting device may include:

a first capping layer arranged outside the first electrode and including the organometallic compound represented by Formula 1;

a second capping layer arranged outside the second electrode and including the organometallic compound represented by Formula 1; or

the first capping layer and the second capping layer.

The wording “(interlayer and/or capping layer) includes an organometallic compound” as used herein may be understood as “(interlayer and/or capping layer) may include one kind of organometallic compound represented by Formula 1 or two or more different kinds of organometallic compounds, each represented by Formula 1.”

In one or more embodiments, the interlayer and/or the capping layer may include, as the organometallic compound, Compound 1 only. In this regard, Compound 1 may be included in the emission layer of the light-emitting device. In one or more embodiments, the interlayer may include, as the organometallic compound, Compound 1 and Compound 2. In this regard, Compound 1 and Compound 2 may be included in the same layer (for example, Compound 1 and Compound 2 may both be included in the emission layer), or may be included in different layers (for example, Compound 1 may be included in the emission layer, and Compound 2 may be included in the electron transport region).

The term “interlayer” as used herein refers to a single layer and/or a plurality of layers between a first electrode and a second electrode of a light-emitting device.

In one or more embodiments,

the interlayer of the light-emitting device may include:

i) a first compound which is the organometallic compound represented by Formula 1; and

ii) a second compound including at least one π electron-deficient nitrogen-containing C₁-C₆₀ cyclic group, a third compound including a group represented by Formula 3, a fourth compound which may be to emit (e.g., may be configured to emit) delayed fluorescence, or any combination thereof,

wherein the first compound, the second compound, the third compound, and the fourth compound may be different from each other:

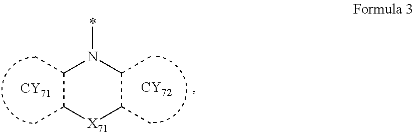

wherein, in Formula 3, ring CY71 and ring CY72 may each independently be a π electron-rich C₃-C₆₀ cyclic group or a pyridine group,

X₇₁ in Formula 3 may be a single bond or a linking group including O, S, N, B, C, Si, or any combination thereof,

* in Formula 3 indicates a binding site to an adjacent atom in the third compound, and

the following compounds may be excluded from the third compound:

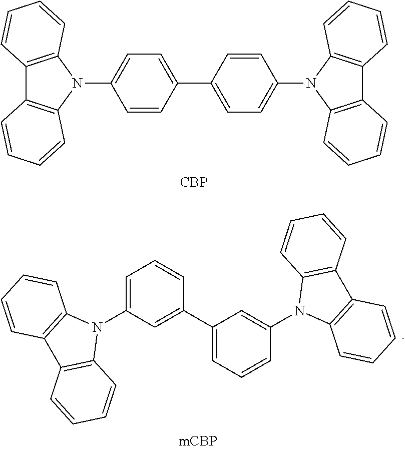 [SMILES: c1ccc2c(c1)c1ccccc1n2-c1ccc(-c2ccc(-n3c4ccccc4c4ccccc43)cc2)cc1 ; "CBP" ; c1cc(-c2cccc(-n3c4ccccc4c4ccccc43)c2)cc(-n2c3ccccc3c3ccccc32)c1]

In one or more embodiments, in the light-emitting device,

the emission layer may include: i) the first compound; and ii) the second compound, the third compound, the fourth compound, or any combination thereof,

wherein the emission layer may be to emit (e.g., may be configured to emit) phosphorescence or fluorescence emitted from the first compound.

### Descriptions of Second Compound, Third Compound, and Fourth Compound

The second compound may include a pyridine group, a pyrimidine group, a pyrazine group, a pyridazine group, a triazine group, or any combination thereof.

In one or more embodiments, the light-emitting device may further include, in addition to the first compound, at least one of the second compound or the third compound.

In one or more embodiments, the light-emitting device may further include, in addition to the first compound, the fourth compound.

In one or more embodiments, the light-emitting device may include the first compound, the second compound, the third compound, and the fourth compound.

In one or more embodiments, the interlayer may include the second compound. The interlayer may further include, in addition to the first compound and the second compound, the third compound, the fourth compound, or any combination thereof.

In one or more embodiments, a difference between a triplet energy level (eV) of the fourth compound and a singlet energy level (eV) of the fourth compound may be about 0 eV or higher and about 0.5 eV or lower (or, about 0 eV or higher and about 0.3 eV or lower).

In one or more embodiments, the fourth compound may be a compound including at least one cyclic group including boron (B) and nitrogen (N) as ring-forming atoms.

In one or more embodiments, the fourth compound may be a C₈-C₆₀ polycyclic group-containing compound including at least two condensed cyclic groups that share a boron atom (B).

In one or more embodiments, the fourth compound may include a condensed ring in which at least one third ring may be condensed with at least one fourth ring,

the third ring may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and

the fourth ring may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group.

In one or more embodiments, the interlayer may include the fourth compound. The interlayer may include, in addition to the first compound and the fourth compound, the second compound, the third compound, or any combination thereof.

In one or more embodiments, the interlayer may include the third compound. For example, the third compound may not include (e.g., may exclude) compounds represented by CBP and mCBP.

In one or more embodiments, the emission layer in the interlayer may include: i) the first compound; and ii) the second compound, the third compound, the fourth compound, or any combination thereof.

The emission layer may be to emit (e.g., may be configured to emit) phosphorescence or fluorescence emitted from the first compound. For example, the phosphorescence or the fluorescence emitted from the first compound may be blue light.

In one or more embodiments, the emission layer in the light-emitting device may include the first compound and the second compound, and the first compound and the second compound may form an exciplex.

In one or more embodiments, the emission layer in the light-emitting device may include the first compound, the second compound, and the third compound, and the first compound and the second compound may form an exciplex.

In one or more embodiments, the emission layer in the light-emitting device may include the first compound and the fourth compound, and the fourth compound may serve to improve color purity, luminescence efficiency, and/or lifespan characteristics of the light-emitting device.

In one or more embodiments, the second compound may include a compound represented by Formula 2:

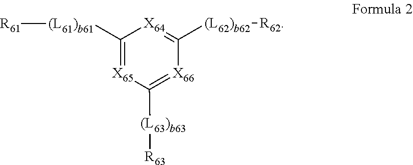

In Formula 2,

L₆₁ to L₆₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,

b61 to b63 may each independently be an integer from 1 to 5,

X₆₄ may be N or C(R₆₄), X₆₅ may be N or C(R₆₅), and X₆₆ may be N or C(R₆₆), wherein at least one of X₆₄ to X₆₆ may be N,

R₆₁ to R₆₆ may respectively be the same as described herein, and

R₁₀ₐ may be the same as described herein.

In one or more embodiments, the third compound may include a compound represented by Formula 3-1, a compound represented by Formula 3-2, a compound represented by Formula 3-3, a compound represented by Formula 3-4, a compound represented by Formula 3-5, or any combination thereof:

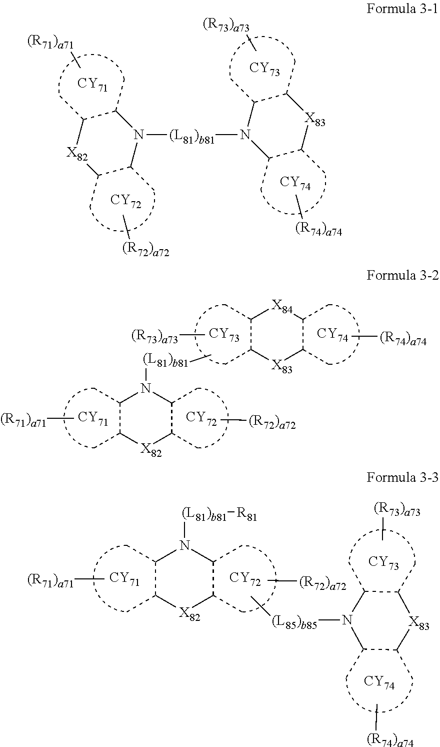

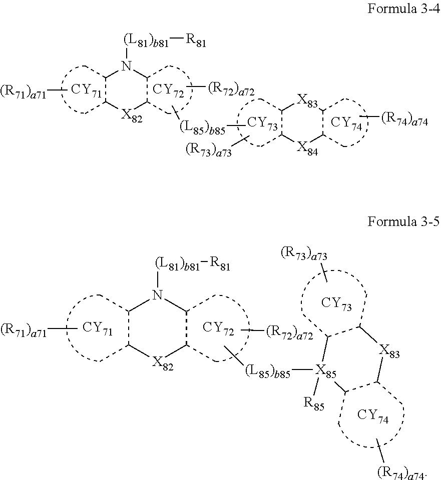

In Formulae 3-1 to 3-5,

ring CY71 to ring CY74 may each independently be a π electron-rich C₃-C₆₀ cyclic group or a pyridine group,

X₈₂ may be a single bond, O, S, N-[(L₈₂)_{b82}-R₈₂], C(R₈₂ₐ)(R_{82b}), or Si(R₈₂ₐ)(R_{82b}),

X₈₃ may be a single bond, O, S, N-[(L₈₃)_{b83}-R₈₃], C(R₈₃ₐ)(R_{83b}), or Si(R₈₃ₐ)(R_{83b}),

X₈₄ may be O, S, N-[(L₈₄)_{b84}-R₈₄], C(R₈₄ₐ)(R_{84b}), or Si(R₈₄ₐ)(R_{84b}),

X₈₅ may be C or Si,

L₈₁ to L₈₅ may each independently be a single bond, *—C(Q₄)(Q₅)-*′, *—Si(Q₄)(Q₅)-*′, a π electron-rich C₃-C₆₀ cyclic group unsubstituted or substituted with at least one R₁₀ₐ, or a pyridine group unsubstituted or substituted with at least one R₁₀ₐ, wherein Q₄ and Q₅ are respectively the same as described in connection with Q₁ in the present specification,

b81 to b85 may each independently be an integer from 1 to 5,

R₇₁ to R₇₄, R₈₁ to R₈₅, R₈₂ₐ, R_{82b}, R₈₃ₐ, R_{83b}, R₈₄ₐ, and R_{84b} may respectively be the same as described herein,

a71 to a74 may each independently be an integer from 0 to 20, and

R₁₀ₐ may be the same as described herein.

In one or more embodiments, the fourth compound may be a compound represented by Formula 502, a compound represented by Formula 503, or any combination thereof:

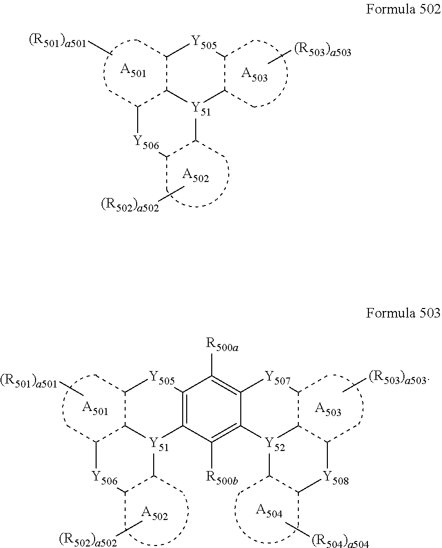

In Formulae 502 and 503,

ring A₅₀₁ to ring A₅₀₄ may each independently be a C₃-C₆₀ carbocyclic group or a C₁-C₆₀ heterocyclic group,

Y₅₀₅ may be O, S, N(R₅₀₅), B(R₅₀₅), C(R₅₀₅ₐ)(R_{505b}), or Si(R₅₀₅ₐ)(R_{505b}),

Y₅₀₆ may be O, S, N(R₅₀₆), B(R₅₀₆), C(R₅₀₆ₐ)(R_{506b}), or Si(R₅₀₆ₐ)(R_{506b}),

Y₅₀₇ may be O, S, N(R₅₀₇), B(R₅₀₇), C(R₅₀₇ₐ)(R_{507b}), or Si(R₅₀₇ₐ)(R_{507b}),

Y₅₀₈ may be O, S, N(R₅₀₈), B(R₅₀₈), C(R₅₀₈ₐ)(R_{508b}), or Si(R₅₀₈ₐ)(R_{508b}),

Y₅₁ and Y₅₂ may each independently be B, P(═O), or S(═O),

R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may respectively be the same as described herein,

a501 to a504 may each independently be an integer from 0 to 20, and

R₁₀ₐ may be the same as described herein.

### Description of Formulae 2 to 4

In Formula 2, b61 to b63 may respectively indicate the number of L₆₁(s) to the number of L₆₃(s), and b61 to b63 may each independently be an integer from 1 to 5. When b61 is 2 or greater, two or more of L₆₁ may be identical to or different from each other, when b62 is 2 or greater, two or more of L₆₂ may be identical to or different from each other, and when b63 is 2 or greater, two or more of L₆₃ may be identical to or different from each other. In one or more embodiments, b61 to b63 may each independently be 1 or 2.

In Formula 2, L₆₁ to L₆₃ may each independently be:

a single bond; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxacilline group, a dibenzothiacilline group, a dibenzodihydroazacilline group, a dibenzodihydrodicilline group, a dibenzodihydrocilline group, a dibenzodioxane group, a dibenzooxathiene group, a dibenzooxazine group, a dibenzopyran group, a dibenzodithiine group, a dibenzothiazine group, a dibenzothiopyran group, a dibenzocyclohexadiene group, a dibenzodihydropyridine group, or a dibenzodihydropyrazine group, each independently unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof, and

Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, in Formula 2, a bond between L₆₁ and R₆₁, a bond between L₆₂ and R₆₂, a bond between L₆₃ and R₆₃, a bond between two or more L₆₁(s), a bond between two or more L₆₂(s), a bond between two or more L₆₃(s), a bond between L₆₁ and carbon between X₆₄ and X₆₅ in Formula 2, a bond between L₆₂ and carbon between X₆₄ and X₆₆ in Formula 2, and a bond between L₆₃ and carbon between X₆₅ and X₆₆ in Formula 2 may each be a “carbon-carbon single bond”.

In Formula 2, X₆₄ may be N or C(R₆₄), X₆₅ may be N or C(R₆₅), and X₆₆ may be N or C(R₆₆), wherein at least one of X₆₄ to X₆₆ may be N. R₆₄ to R₆₆ may respectively be the same as described herein. In one or more embodiments, two or three of X₆₄ to X₆₆ may each be N.

R₆₁ to R₆₆, R₇₁ to R₇₄, R₈₁ to R₈₅, R₈₂ₐ, R_{82b}, R₈₃ₐ, R_{83b}, R₈₄ₐ and R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). Q₁ to Q₃ may respectively be the same as described herein.

In one or more embodiments, in Formulae 2, 3-1 to 3-5, 502, and 503, i) R₆₁ to R₆₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} and ii) R₁₀ₐ may each independently be:

hydrogen, deuterium, —F, —Cl, —Br, —I, a hydroxyl group, a cyano group, a nitro group, a C₁-C₂₀ alkyl group, or a C₁-C₂₀ alkoxy group;

a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or

—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

Q₁ to Q₃ and Q₃₁ to Q₃₃ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each independently unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof:

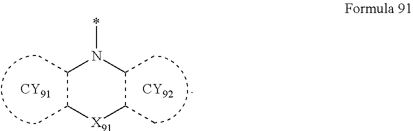

In Formula 91,

ring CY91 and ring CY92 may each independently be a C₅-C₃₀ carbocyclic group unsubstituted or substituted with at least one R₁₀ₐ or a C₁-C₃₀ heterocyclic group unsubstituted or substituted with at least one R₁₀ₐ,

X₉₁ may be a single bond, O, S, N(R₉₁), B(R₉₁), C(R₉₁ₐ)(R_{91b}), or Si(R₉₁ₐ)(R_{91b}),

R₉₁, R₉₁ₐ, and R_{91b} may respectively be the same as described in connection with R₈₂, R₈₂ₐ, and R_{82b},

R₁₀ₐ may be the same as described in connection with R₁₀ₐ, and

* indicates a binding site to a neighboring atom.

For example, in Formula 91,

ring CY91 and ring CY92 may each independently be a benzene group, a pyridine group, a pyrimidine group, a pyrazine group, a pyridazine group, or a triazine group, each independently unsubstituted or substituted with at least one R₁₀ₐ,

R₉₁, R₉₁ₐ, and R_{91b} may each independently be:

hydrogen or a C₁-C₁₀ alkyl group; or

a phenyl group, a pyridinyl group, a pyrimidinyl group, a pyridazinyl group, a pyrazinyl group, or a triazinyl group, each independently unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof.

In one or more embodiments, i) R₆₁ to R₆₆, R₇₁ to R₇₄, R₈₁ to R₈₅, R₈₂ₐ, R_{82b}, R₈₃ₐ, R_{83b}, R₈₄ₐ and R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in Formulae 2, 3-1 to 3-5, 502, and 503 and ii) R₁₀ₐ may each independently be

hydrogen, deuterium, —F, a cyano group, a nitro group, —CH₃, —CD₃, —CD₂H, —CDH₂, —CF₃, —CF₂H, —CFH₂, a group represented by one of Formulae 9-1 to 9-19, a group represented by one of Formulae 10-1 to 10-249, —C(Q₁)(Q₂)(Q₃), —Si(Q₁)(Q₂)(Q₃), —N(Q₁)(Q₂), or —P(═O)(Q₁)(Q₂) (wherein Q₁ to Q₃ may each be the same as described herein):

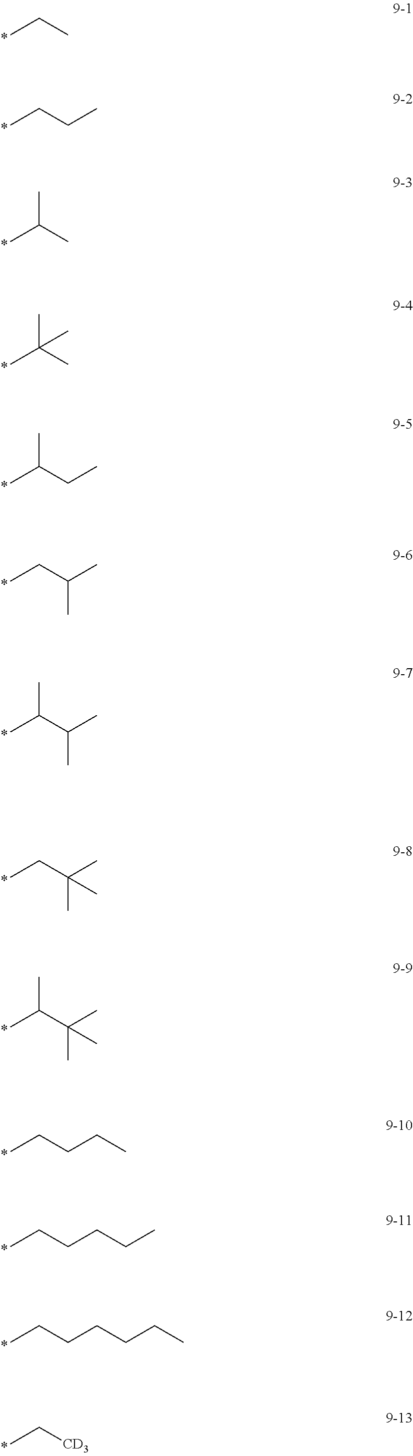

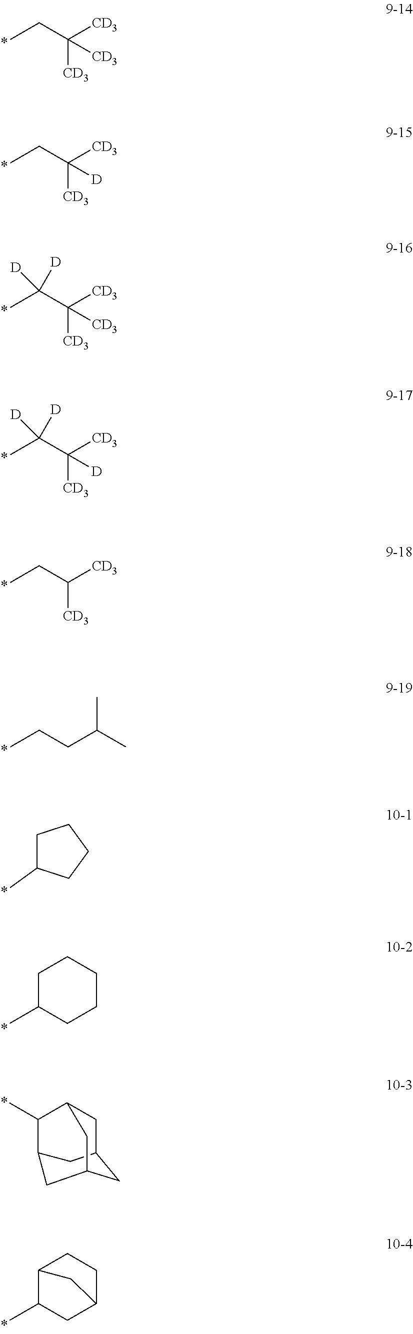

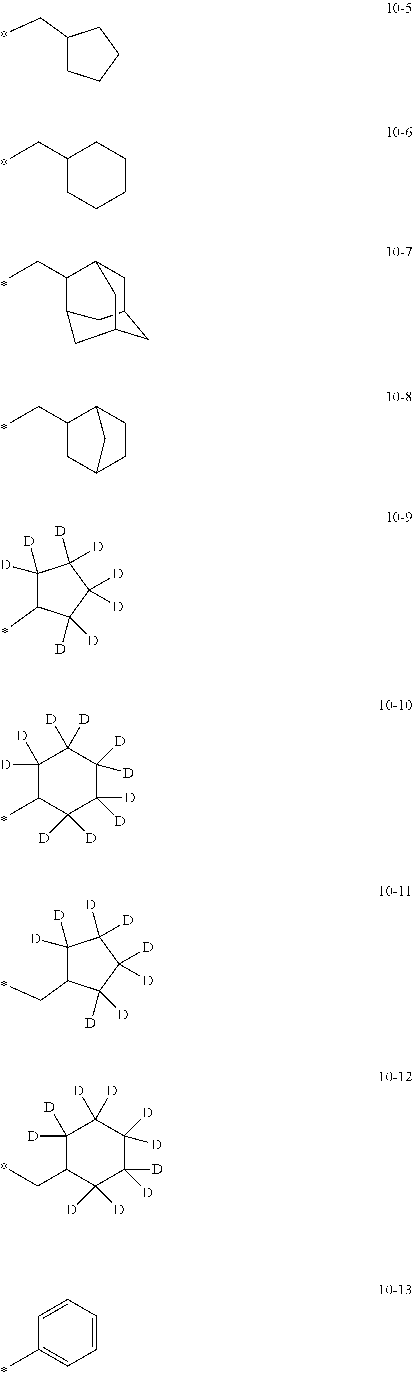

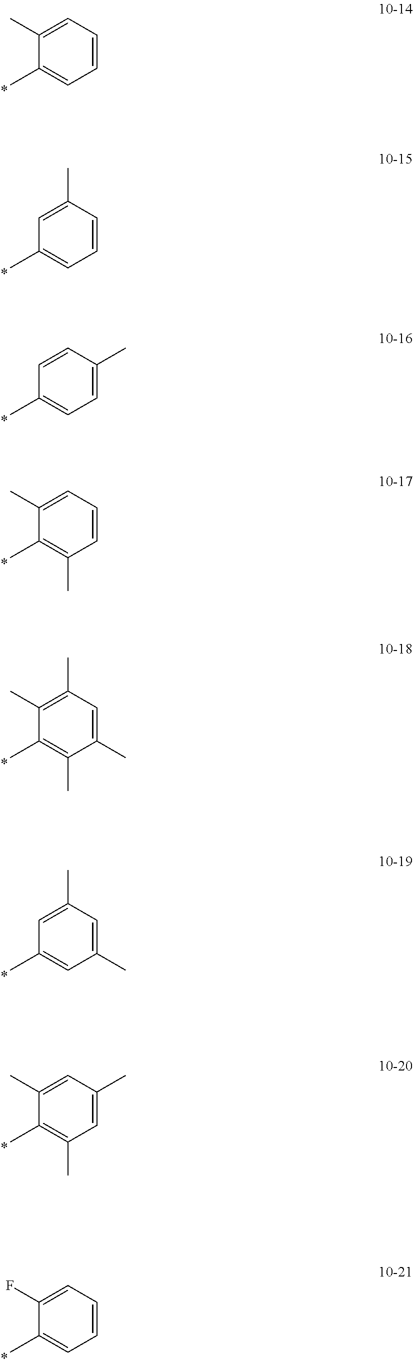

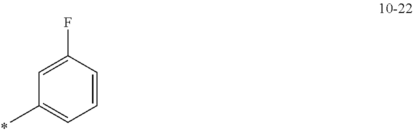

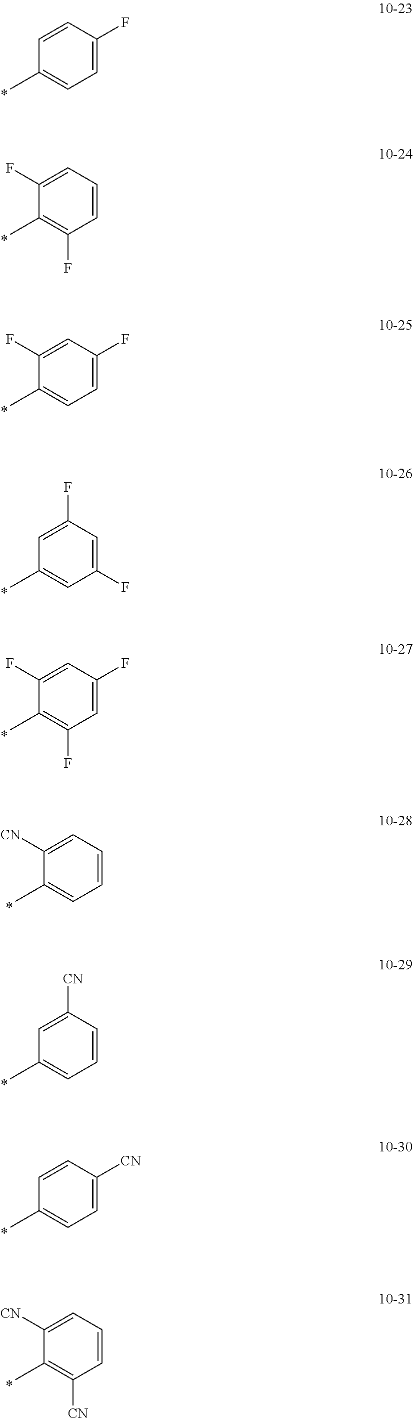

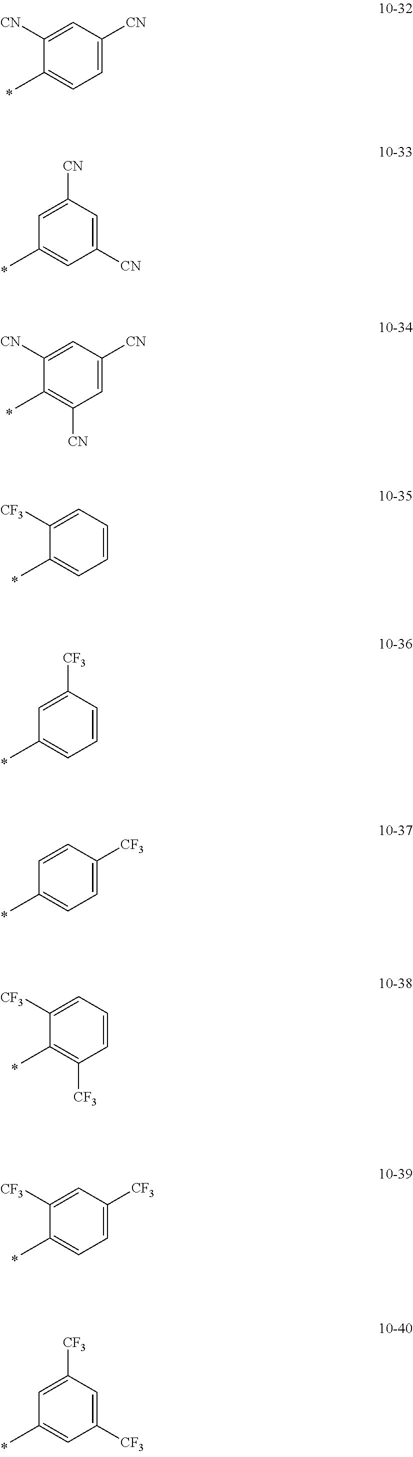

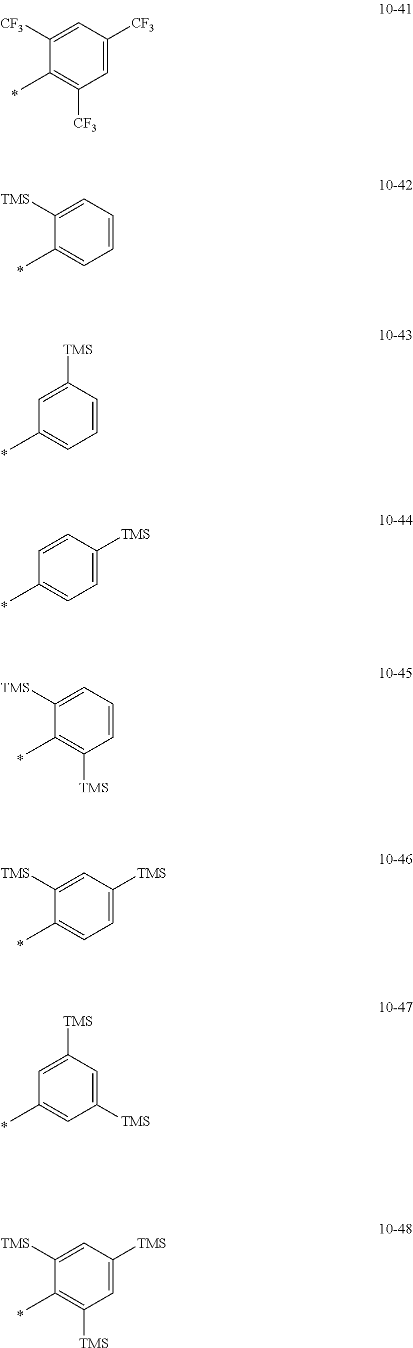

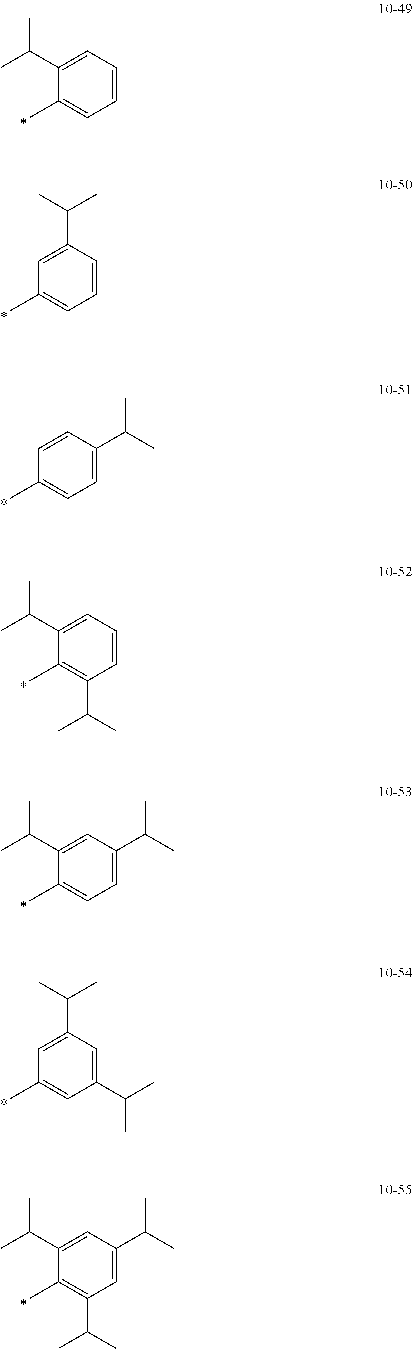

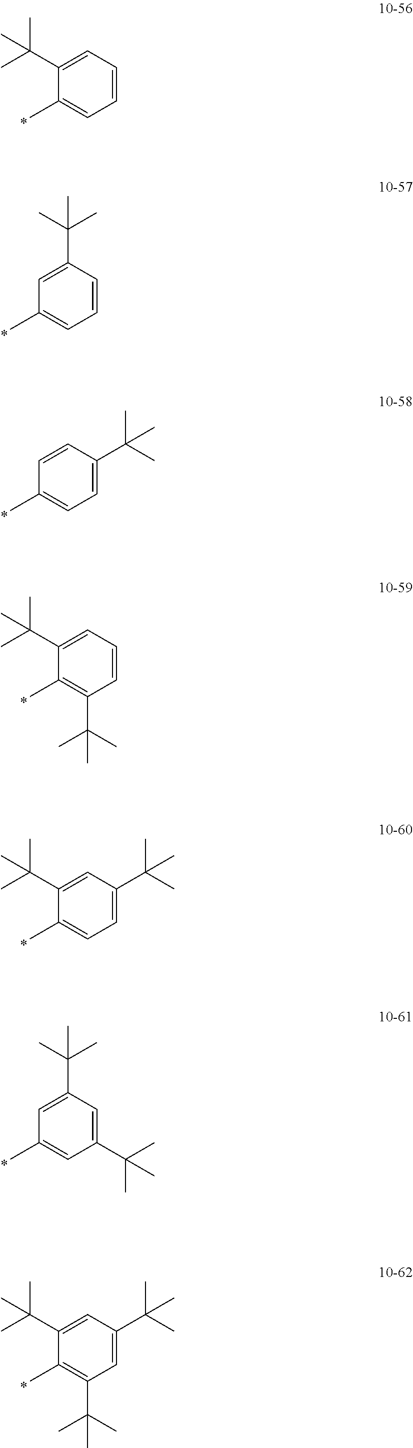

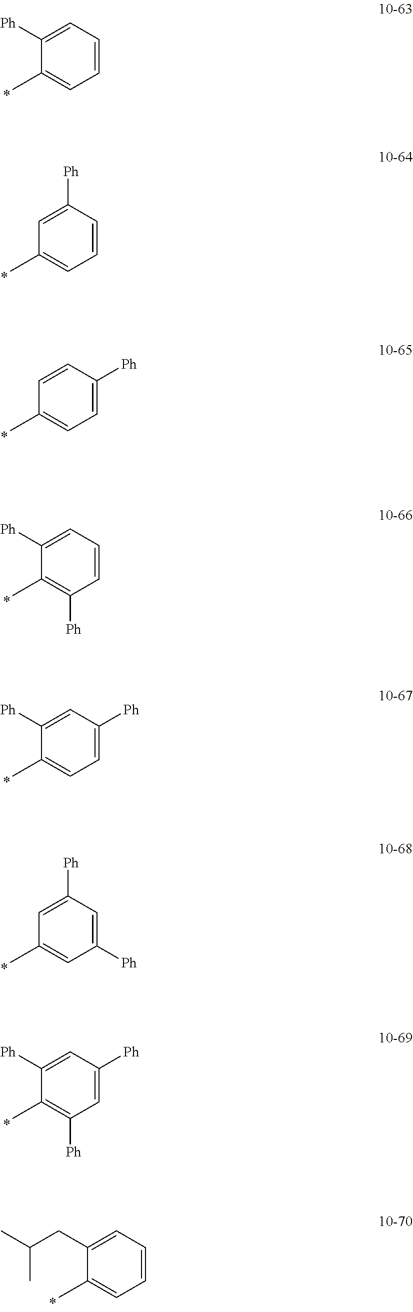

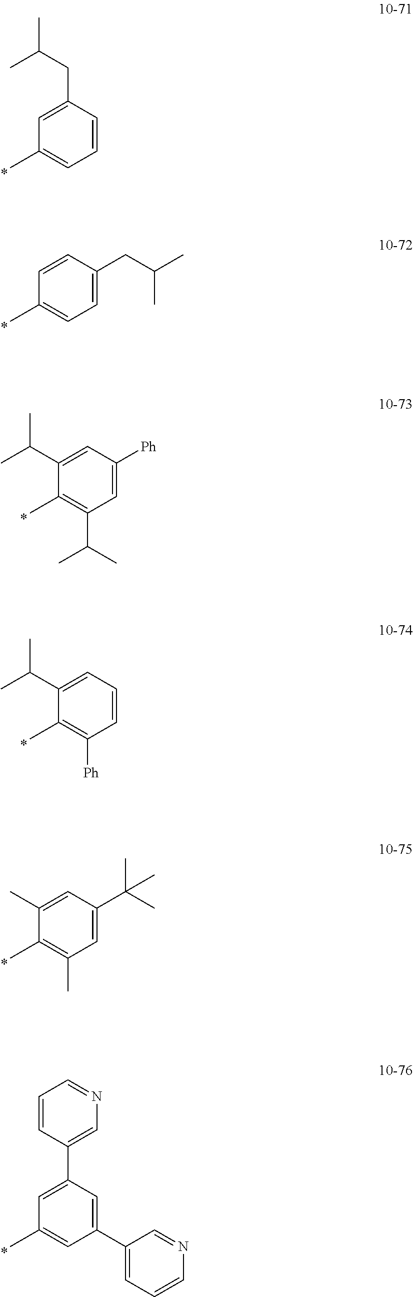

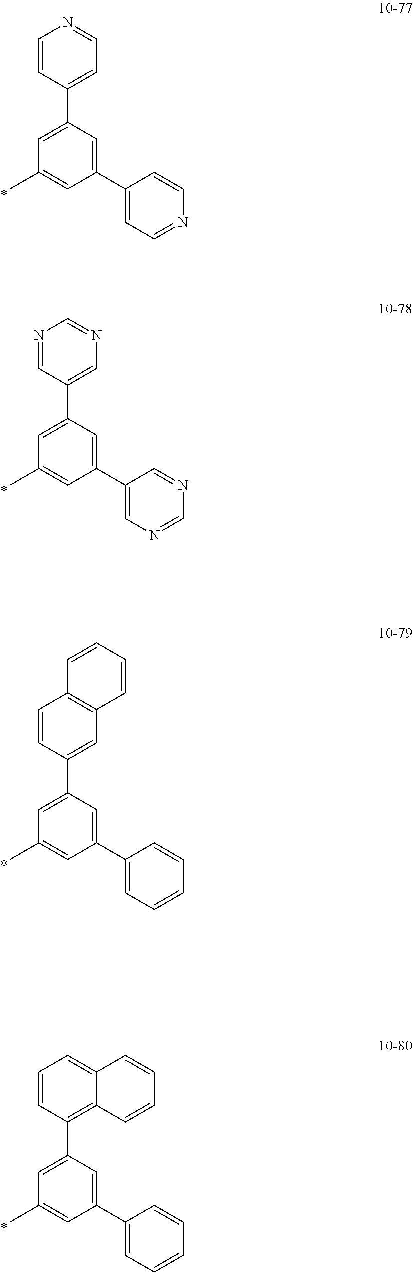

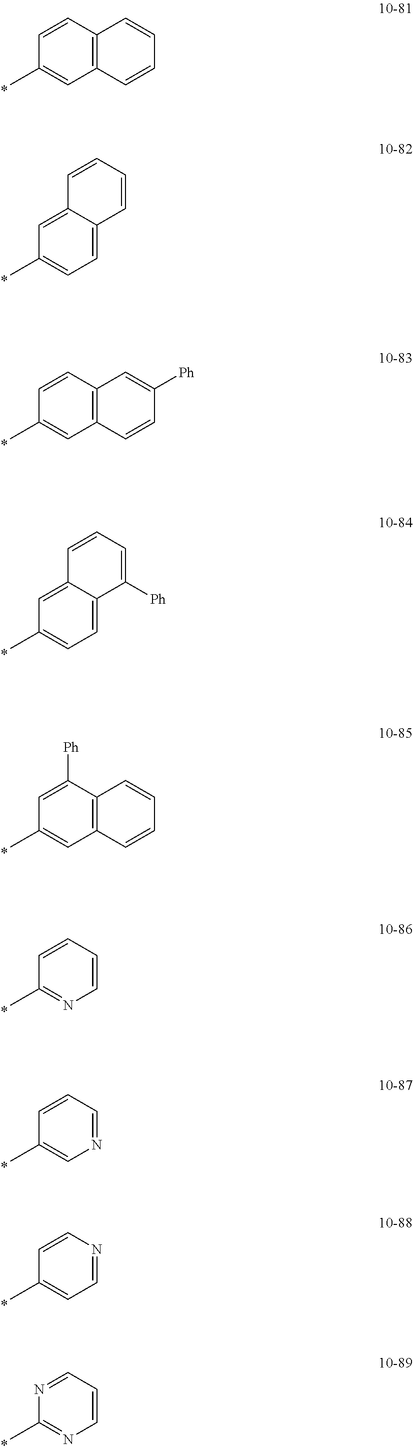

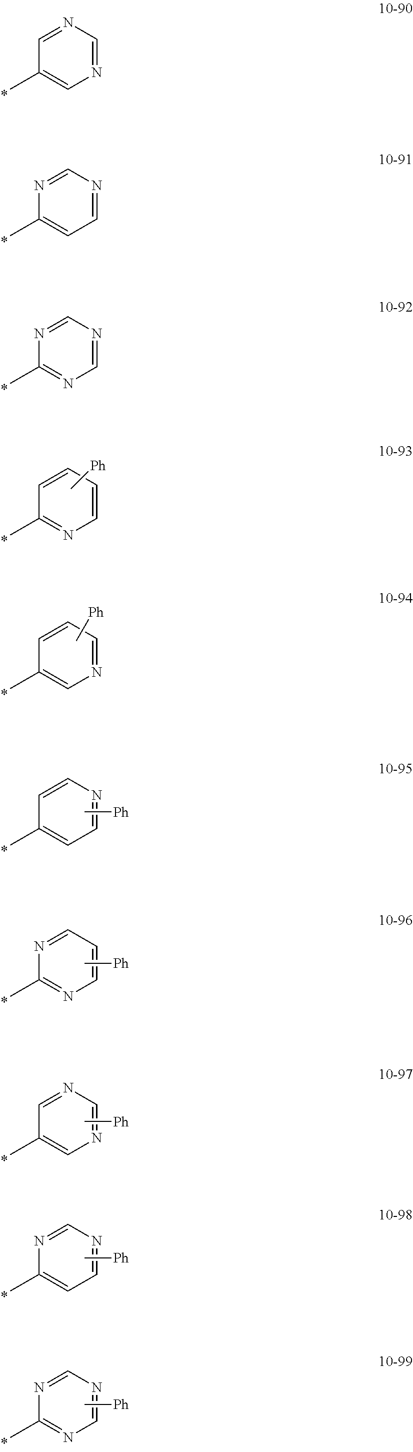

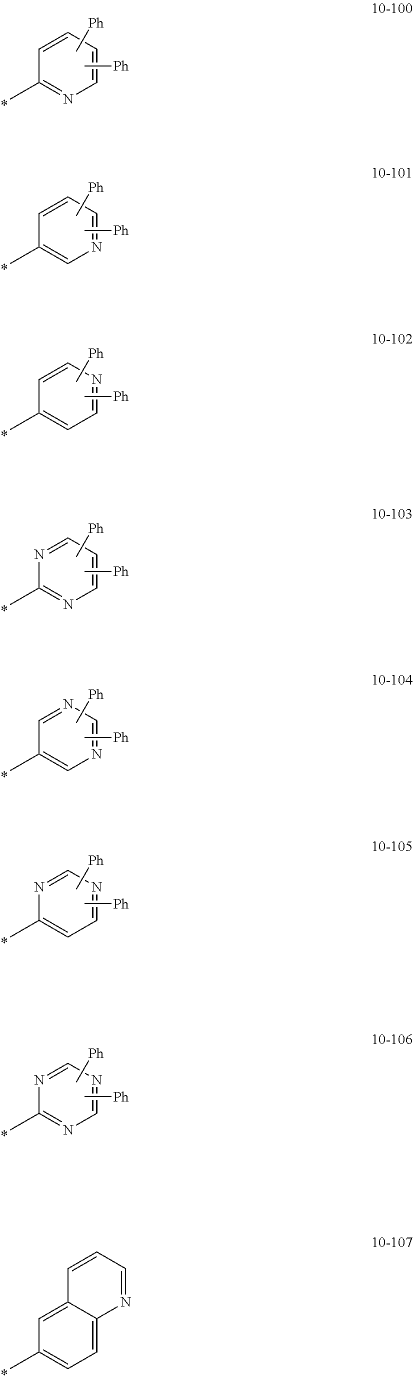

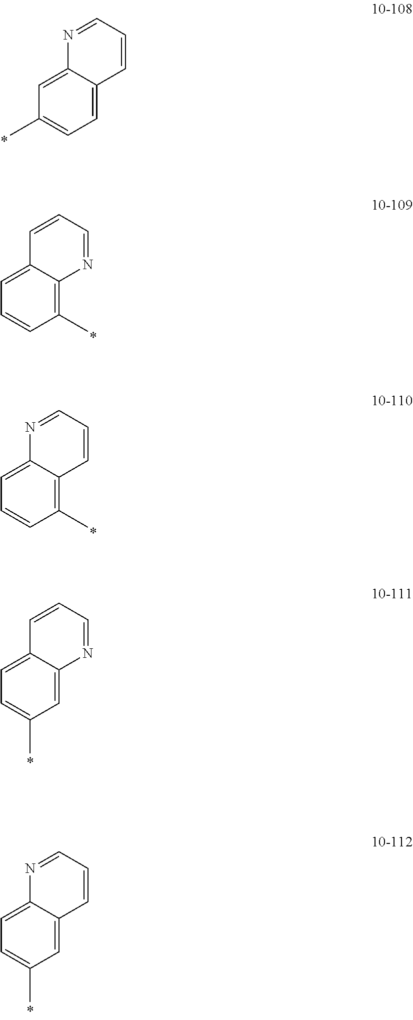

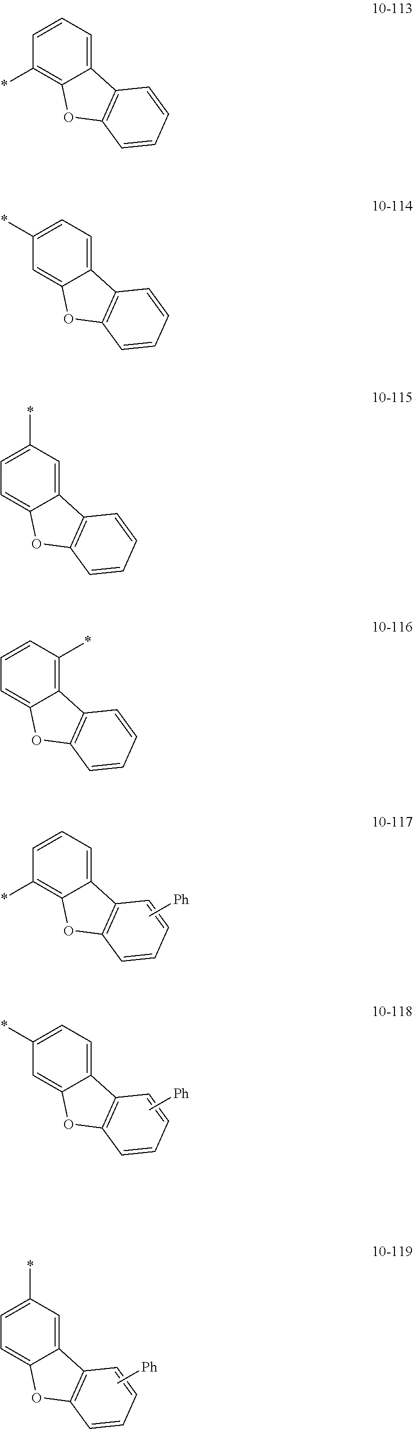

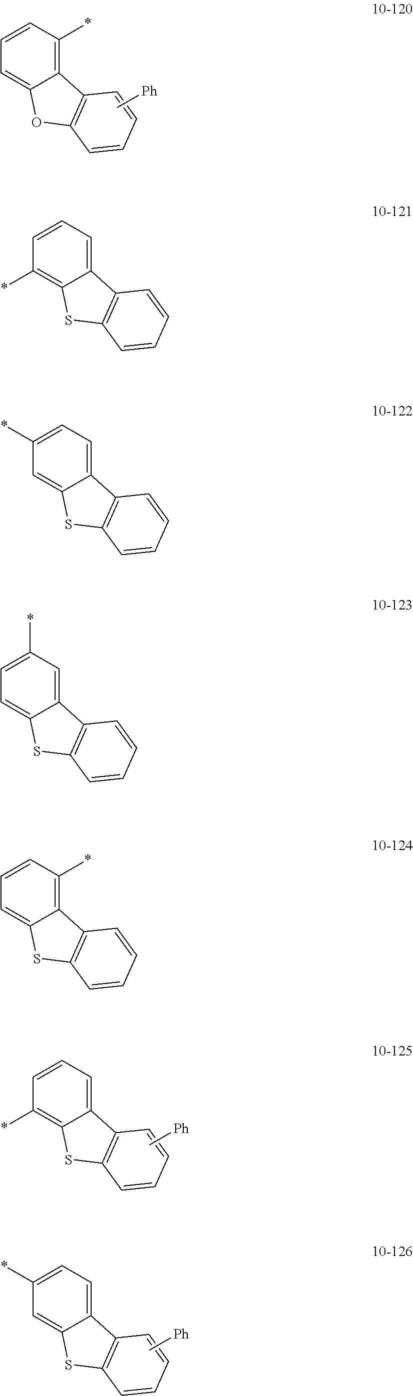

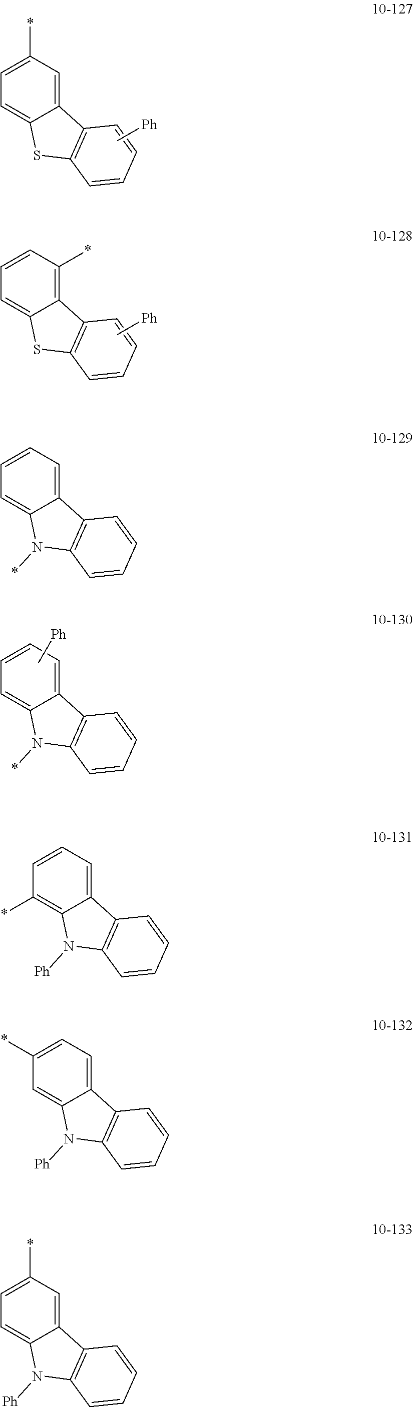

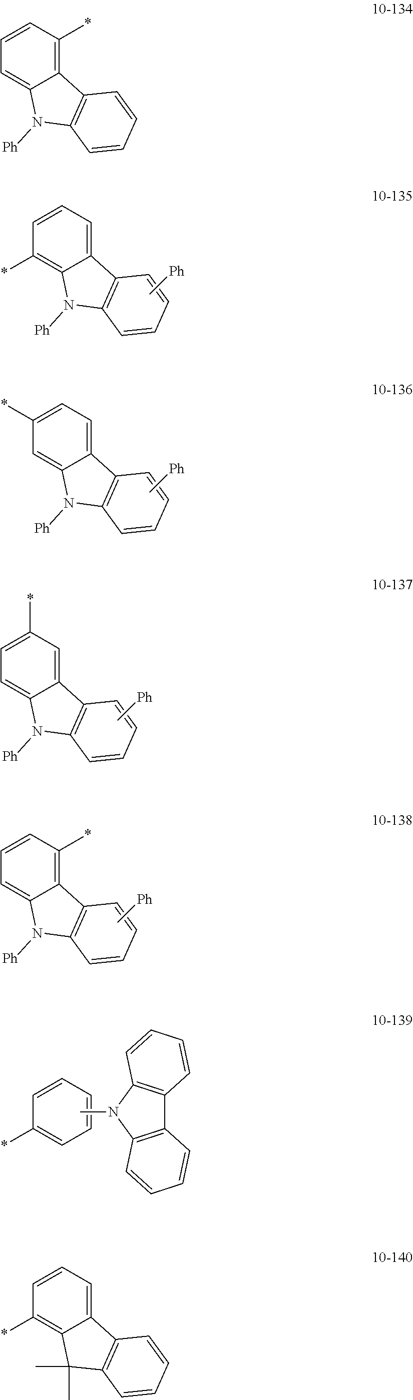

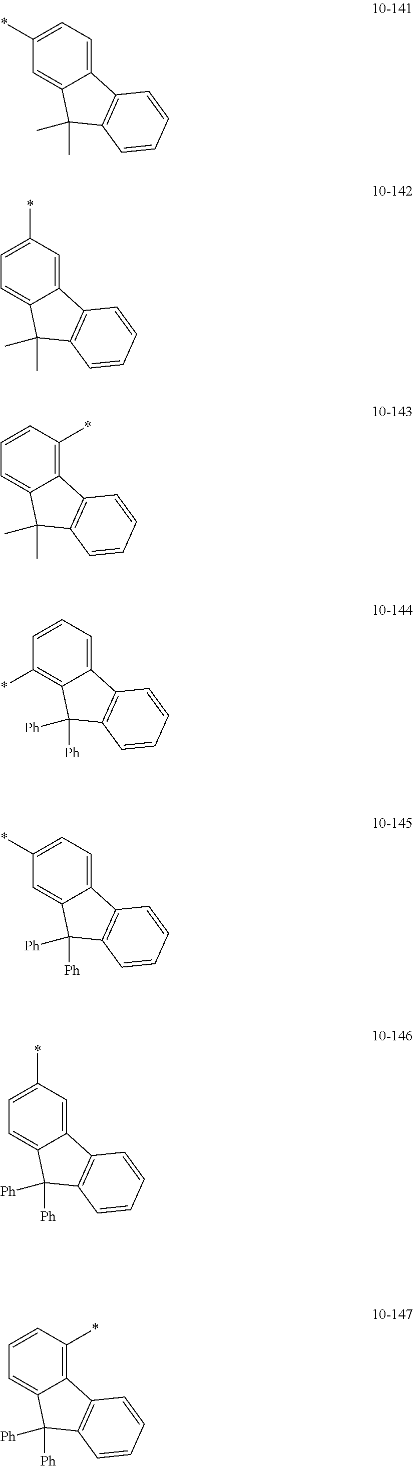

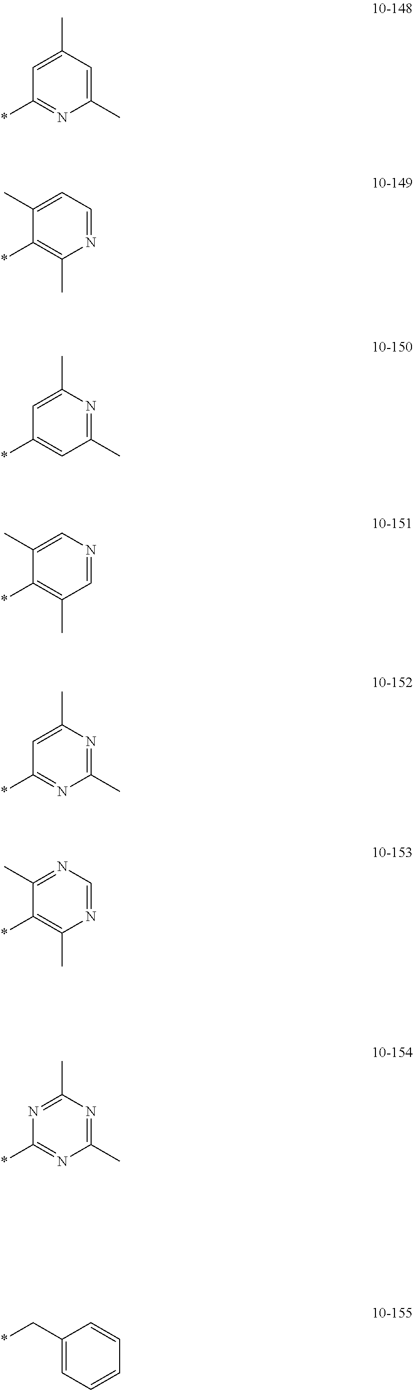

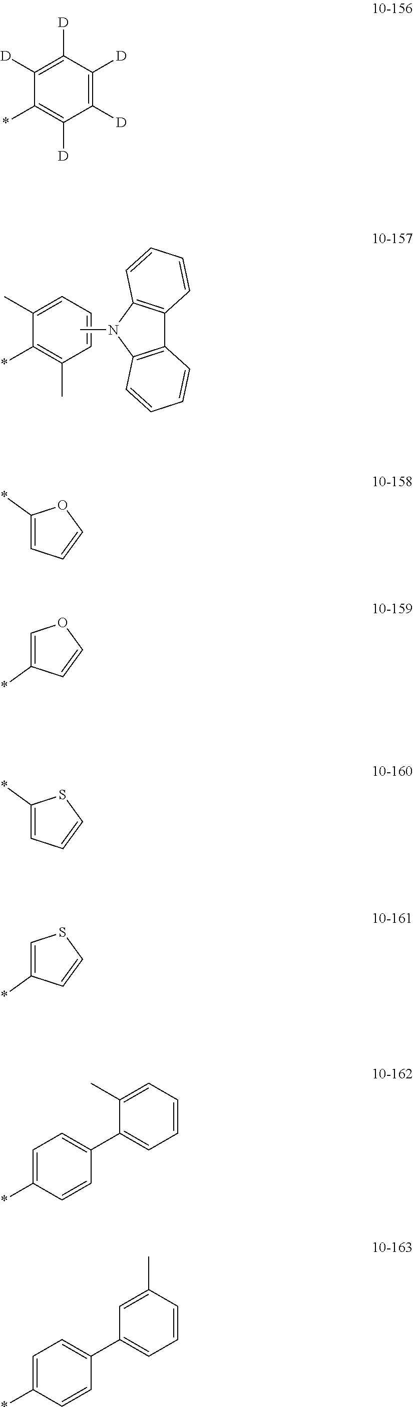

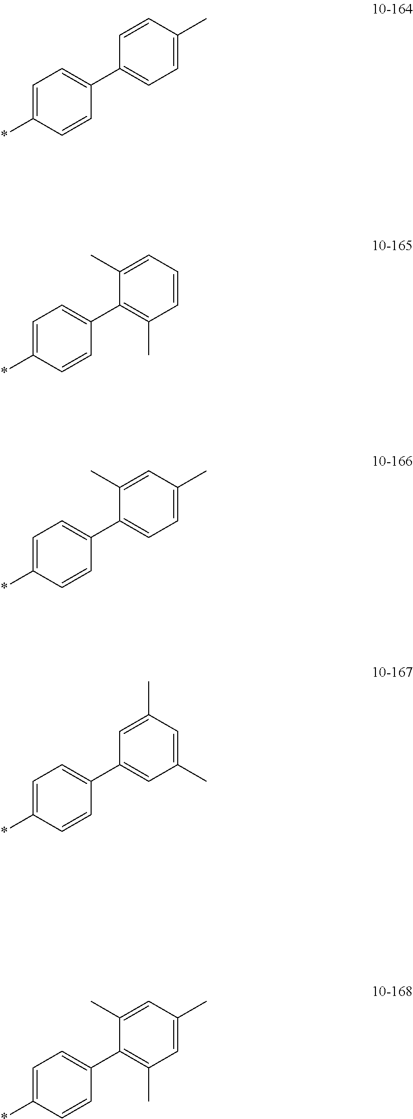 [SMILES: *c1ccc(-c2ccc(C)cc2)cc1 ; *c1ccc(-c2c(C)cccc2C)cc1 ; *c1ccc(-c2ccc(C)cc2C)cc1 ; *c1ccc(-c2cc(C)cc(C)c2)cc1 ; *c1ccc(-c2c(C)cc(C)cc2C)cc1]

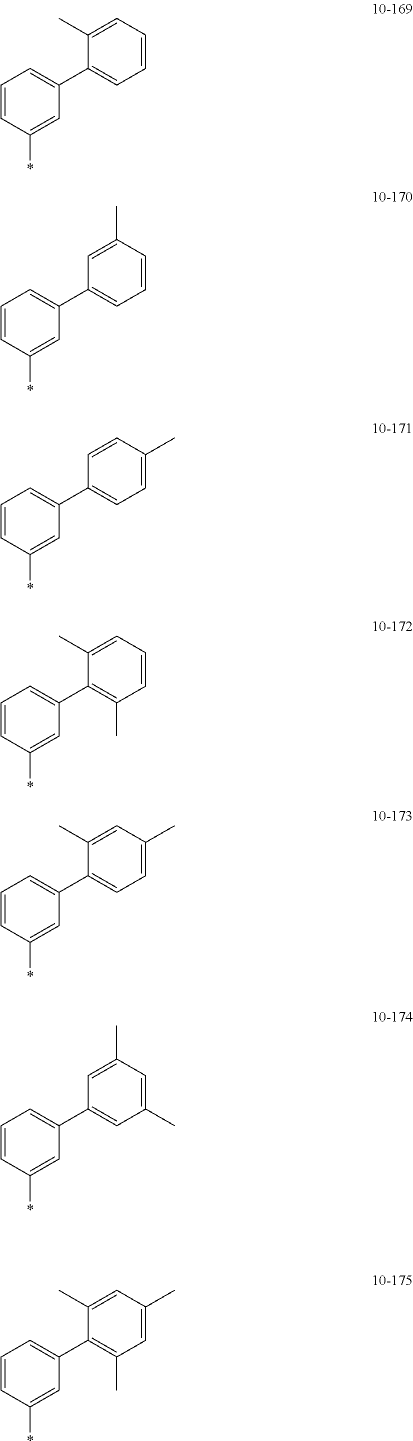

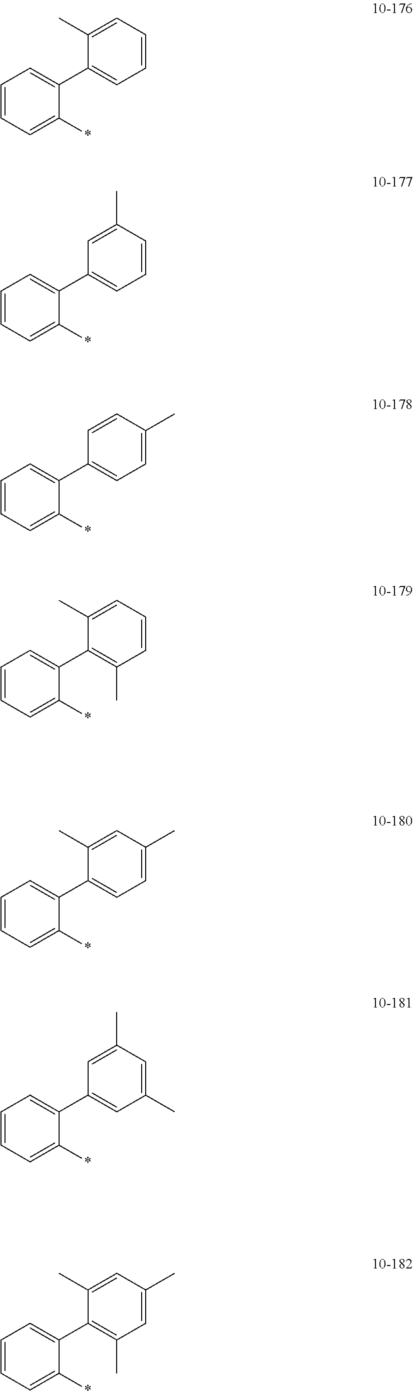

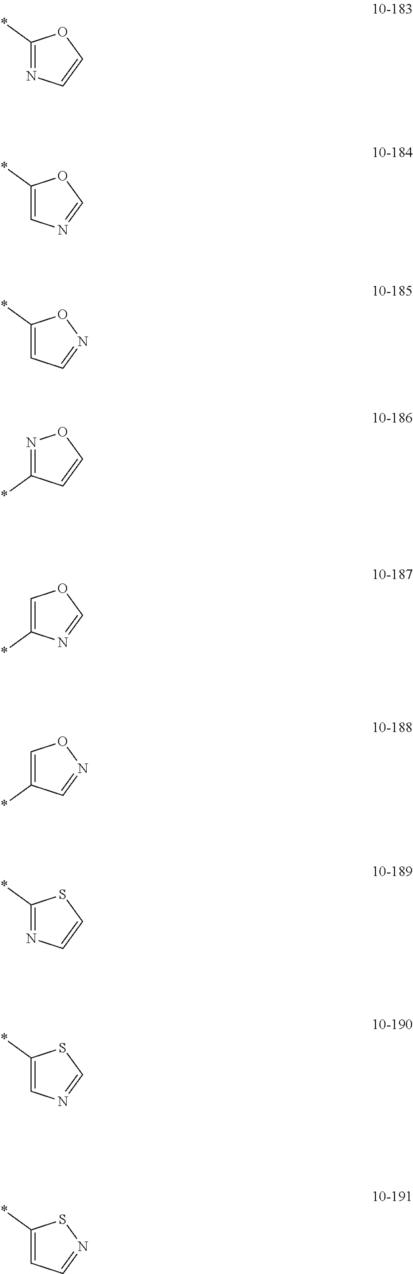

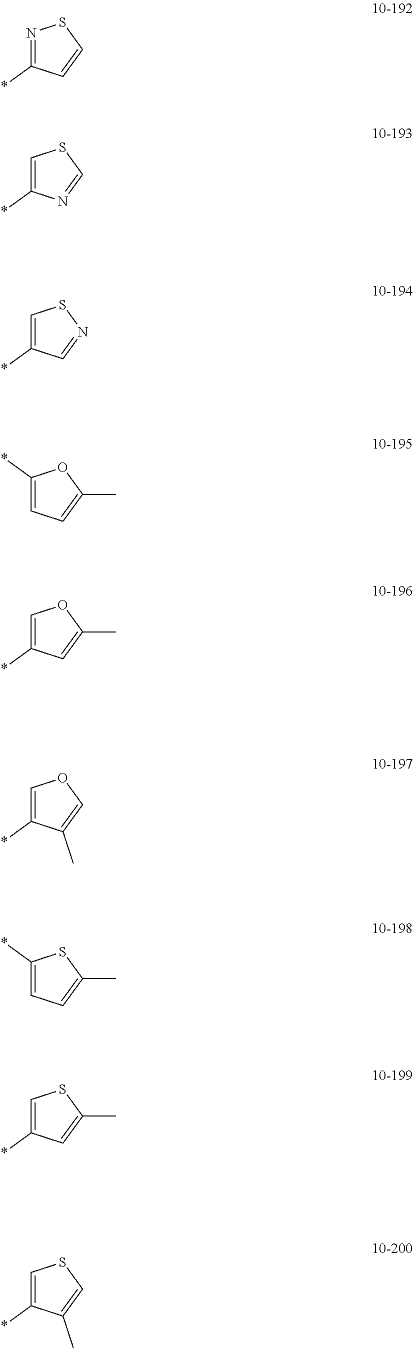

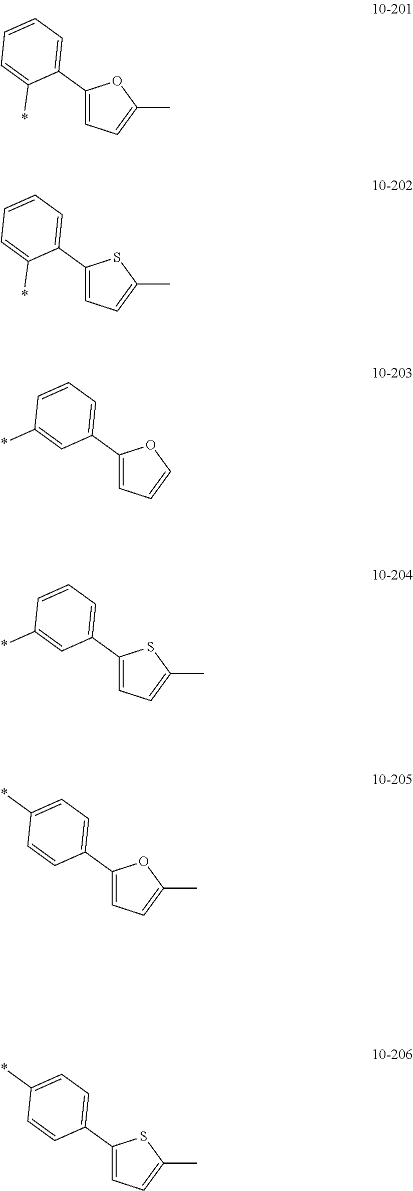 [SMILES: *c1ccccc1-c1ccc(C)o1 ; *c1ccccc1-c1ccc(C)s1 ; *c1cccc(-c2ccco2)c1 ; *c1cccc(-c2ccc(C)s2)c1 ; *c1ccc(-c2ccc(C)o2)cc1 ; *c1ccc(-c2ccc(C)s2)cc1]

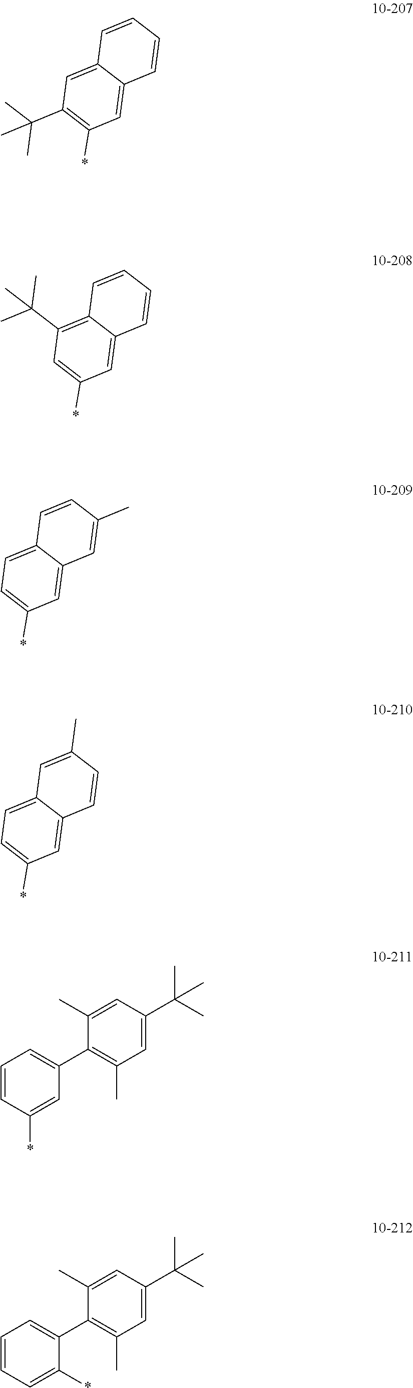 [SMILES: *c1cc2ccccc2cc1C(C)(C)C ; *c1cc(C(C)(C)C)c2ccccc2c1 ; *c1ccc2ccc(C)cc2c1 ; *c1ccc2cc(C)ccc2c1 ; *c1cccc(-c2c(C)cc(C(C)(C)C)cc2C)c1 ; *c1ccccc1-c1c(C)cc(C(C)(C)C)cc1C]

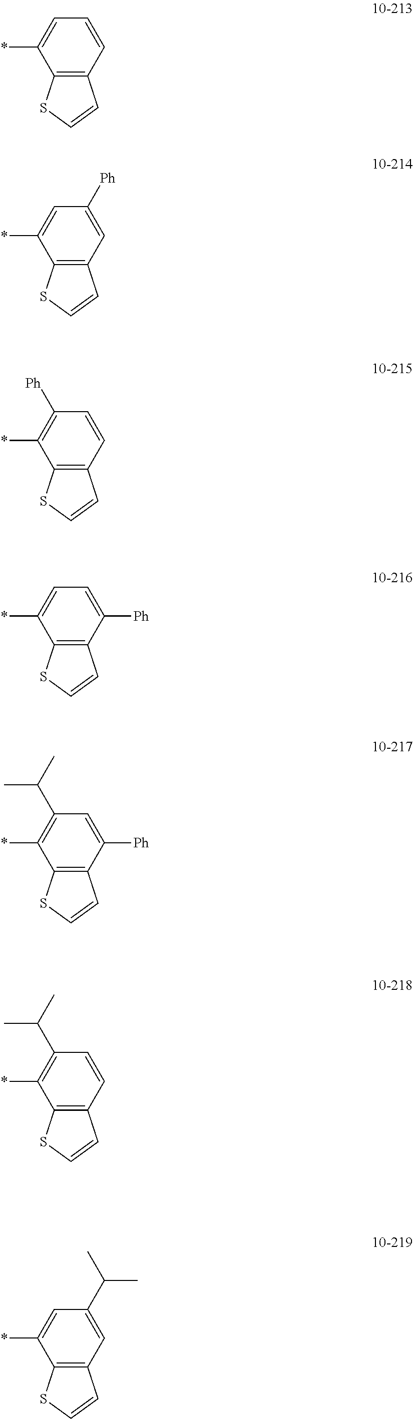

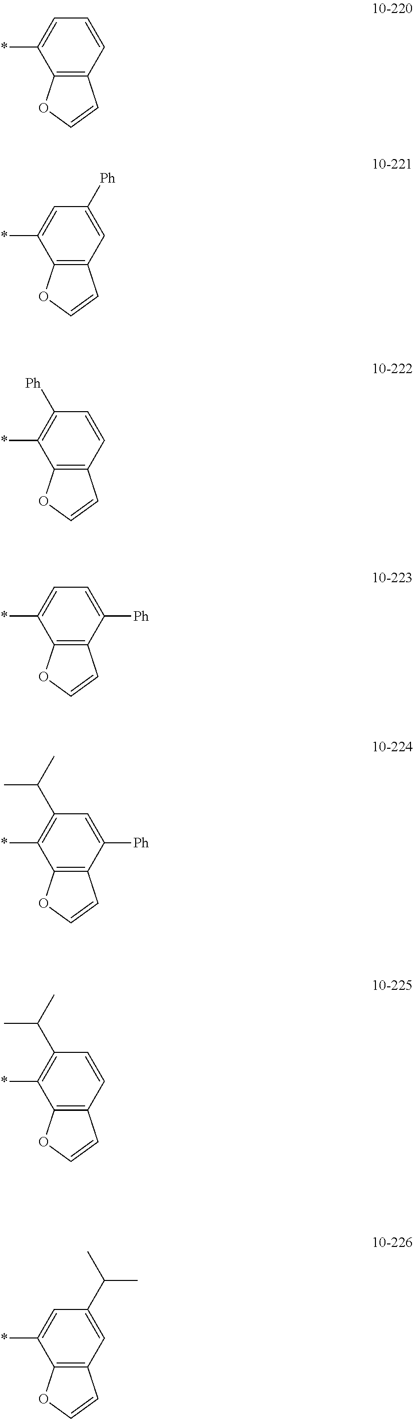

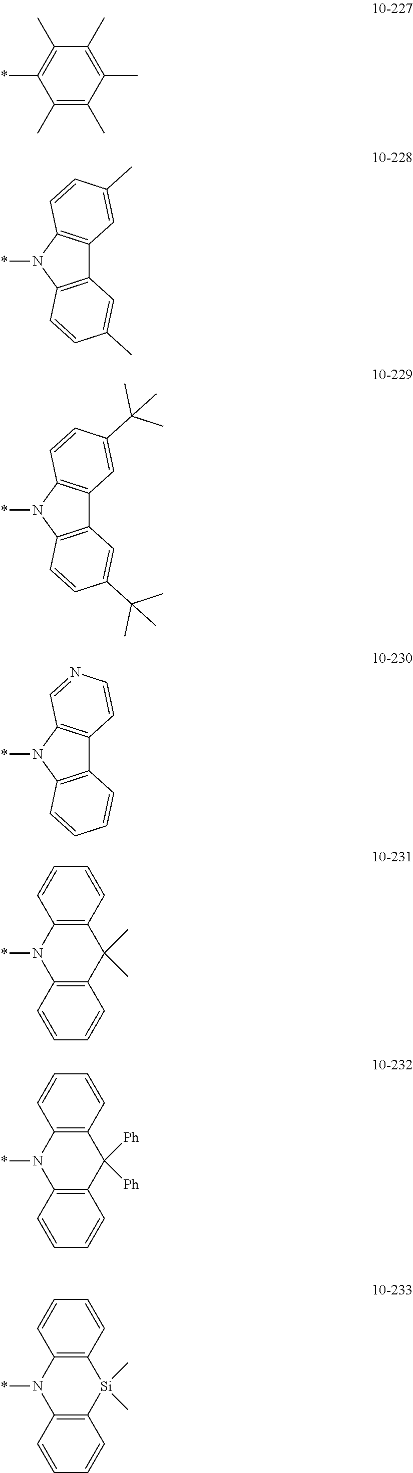

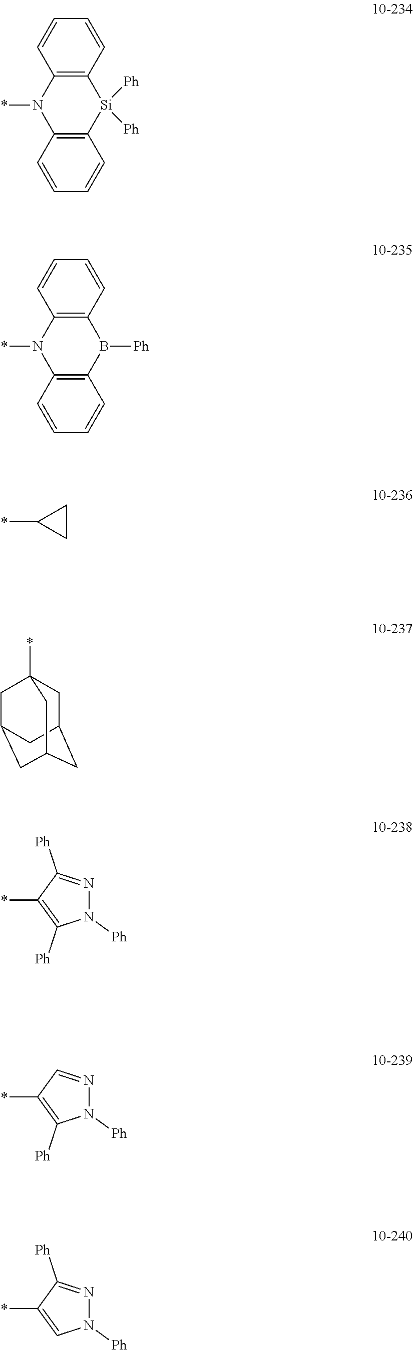

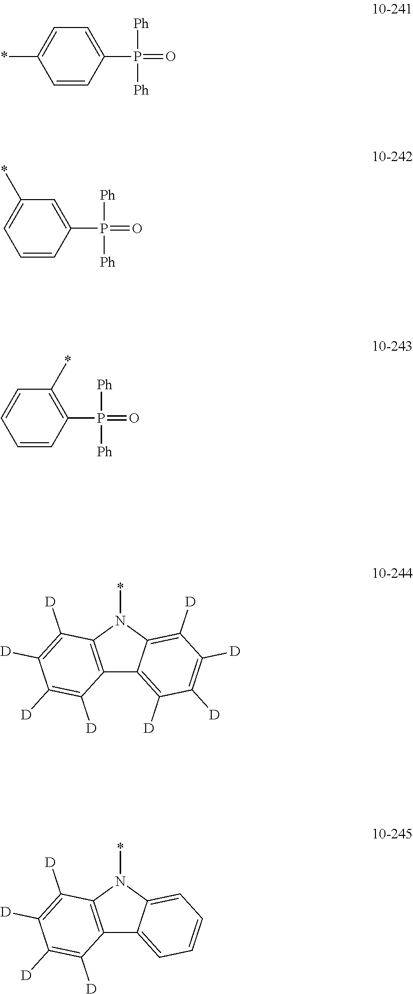 [SMILES: *c1ccc(P(=O)(c2ccccc2)c2ccccc2)cc1 ; *c1cccc(P(=O)(c2ccccc2)c2ccccc2)c1 ; *c1ccccc1P(=O)(c1ccccc1)c1ccccc1 ; *n1c2c([2H])c([2H])c([2H])c([2H])c2c2c([2H])c([2H])c([2H])c([2H])c21 ; *n1c2ccccc2c2c([2H])c([2H])c([2H])c([2H])c21]

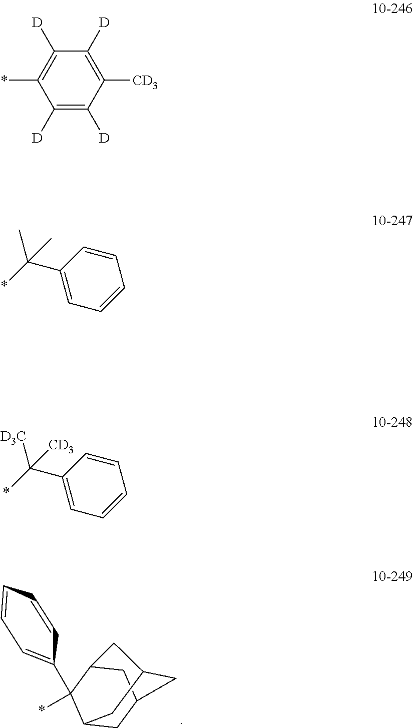

In Formulae 9-1 to 9-19 and 10-1 to 10-249, * indicates a binding site to a neighboring atom, Ph is a phenyl group, TMS is a trimethylsilyl group, and D is deuterium.

In Formulae 3-1 to 3-5, 502, and 503, a71 to a74 and a501 to a504 may respectively indicate the number of R₇₁(s) to the number of R₇₄(s) and the number of R₅₀₁(s) to the number of R₅₀₄(s), and may each independently be an integer from 0 to 20. When a71 is 2 or greater, two or more of R₇₁ may be identical to or different from each other, when a72 is 2 or greater, two or more of R₇₂ may be identical to or different from each other, when a73 is 2 or greater, two or more of R₇₃ may be identical to or different from each other, when a74 is 2 or greater, two or more of R₇₄ may be identical to or different from each other, when a 1 is 2 or greater, two or more of R₅₀ may be identical to or different from each other, when a502 is 2 or greater, two or more of R₅₀₂ may be identical to or different from each other, when a503 is 2 or greater, two or more of R₅₀₃ may be identical to or different from each other, and when a504 is 2 or greater, two or more of R₅₀₄ may be identical to or different from each other. a71 to a74 and a501 to a504 may each independently be an integer from 0 to 8.

In one or more embodiments, in Formula 2, a group represented by *-(L₆₁)_{b61}-R₆₁ and a group represented by *-(L₆₂)_{b62}-R₆₂ may each not be a phenyl group.

In one or more embodiments, in Formula 2, a group represented by *-(L₆₁)_{b61}-R₆₁ and a group represented by *-(L₆₂)_{b62}-R₆₂ may be identical to each other.

In one or more embodiments, in Formula 2, a group represented by *-(L₆₁)_{b61}-R₆₁ and a group represented by *-(L₆₂)_{b62}-R₆₂ may be different from each other.

In one or more embodiments, in Formula 2, b61 and b62 may each be 1, 2, or 3, and L₆₁ and L₆₂ may each independently be a benzene group, a pyridine group, a pyrimidine group, a pyridazine group, a pyrazine group, or a triazine group, each independently unsubstituted or substituted with at least one R₁₀ₐ.

In one or more embodiments, in Formula 2, R₆₁ and R₆₂ may each independently be a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), or —Si(Q₁)(Q₂)(Q₃), and

Q₁ to Q₃ may each independently be a C₃-C₆₀ carbocyclic group or a C₁-C₆₀ heterocyclic group, each independently unsubstituted or substituted with deuterium, —F, a cyano group, a C₁-C₆₀ alkyl group, a C₁-C₆₀ alkoxy group, a phenyl group, a biphenyl group, or any combination thereof.

In one or more embodiments,

in Formula 2, a group represented by *-(L₆₁)_{b61}-R₆₁ may be a group represented by one of Formulae CY51-1 to CY51-26, and/or

in Formula 2, the group represented by *-(L₆₂)_{b62}-R₆₂ may be a group represented by one of Formulae CY52-1 to CY52-26, and/or

in Formula 2, the group represented by *-(L₆₃)_{b63}-R₆₃ may be a group represented by one of Formulae CY53-1 to CY53-27, —C(Q₁)(Q₂)(Q₃), or —Si(Q₁)(Q₂)(Q₃):

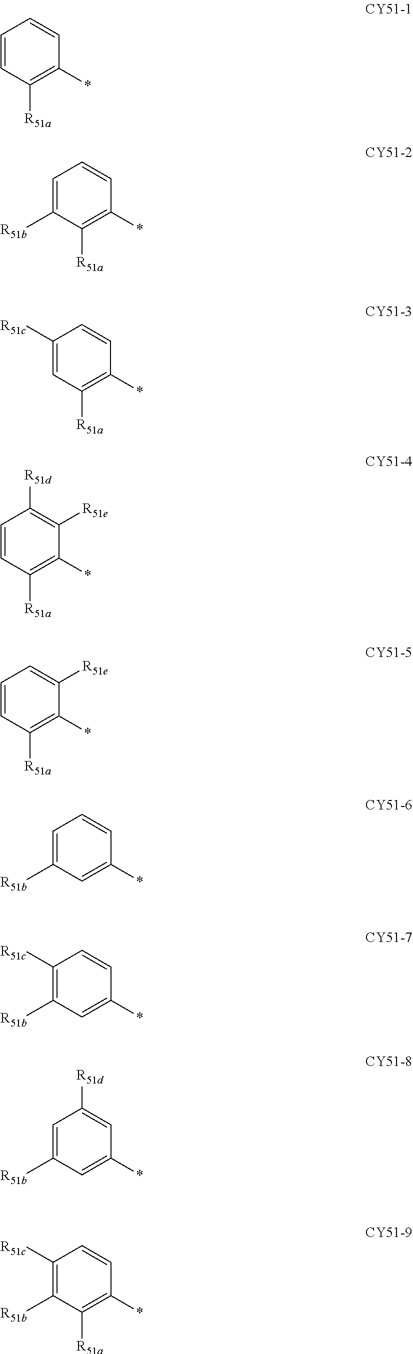

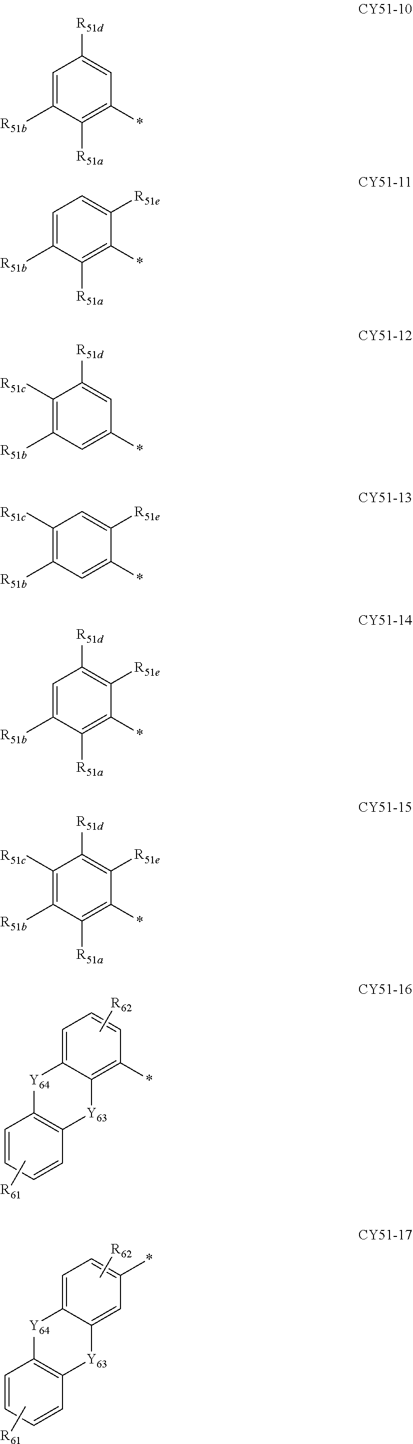

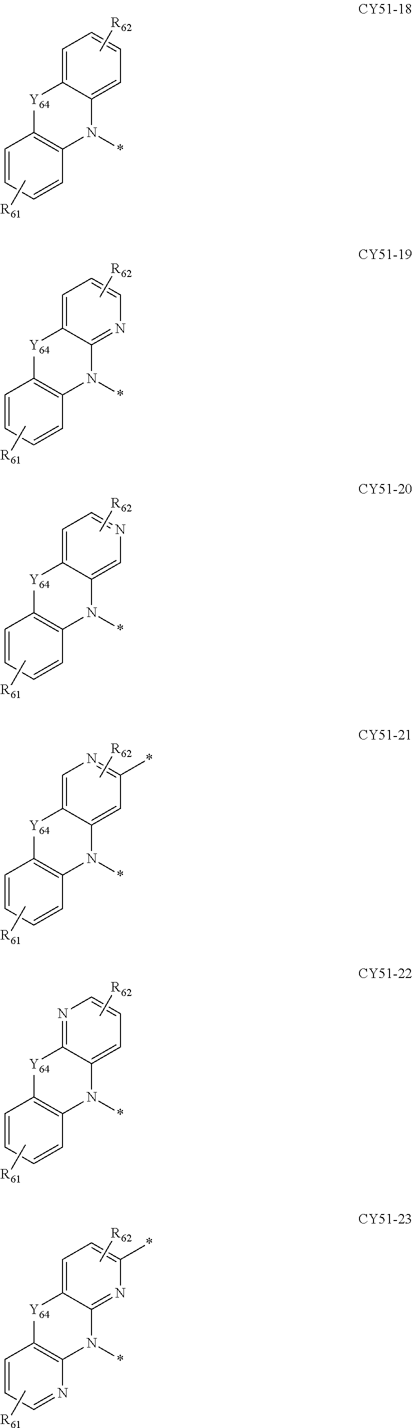

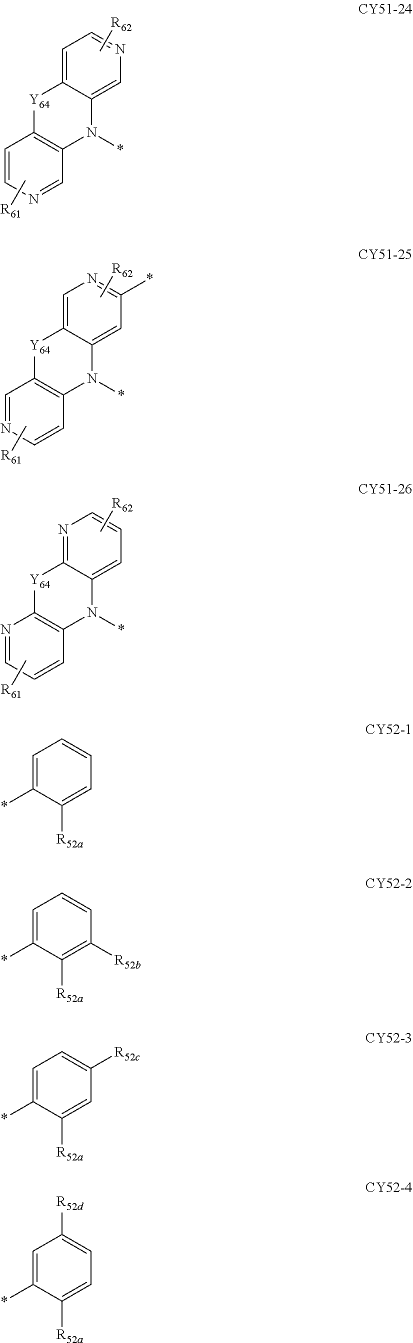

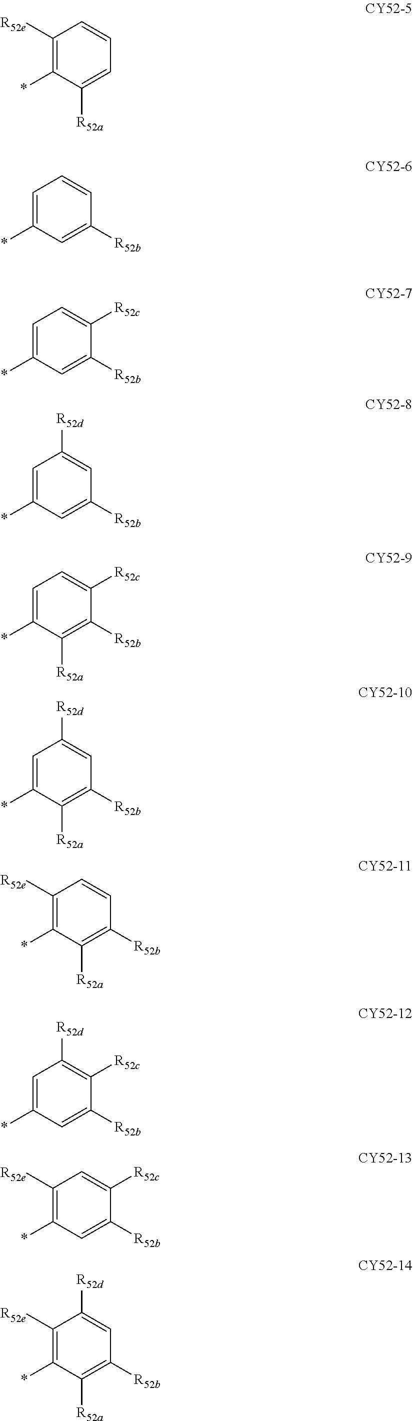

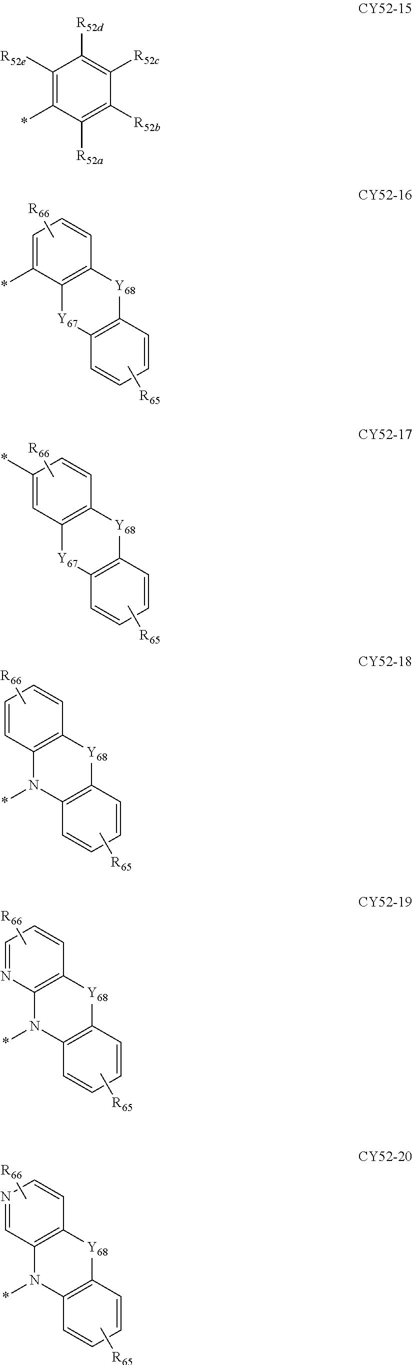

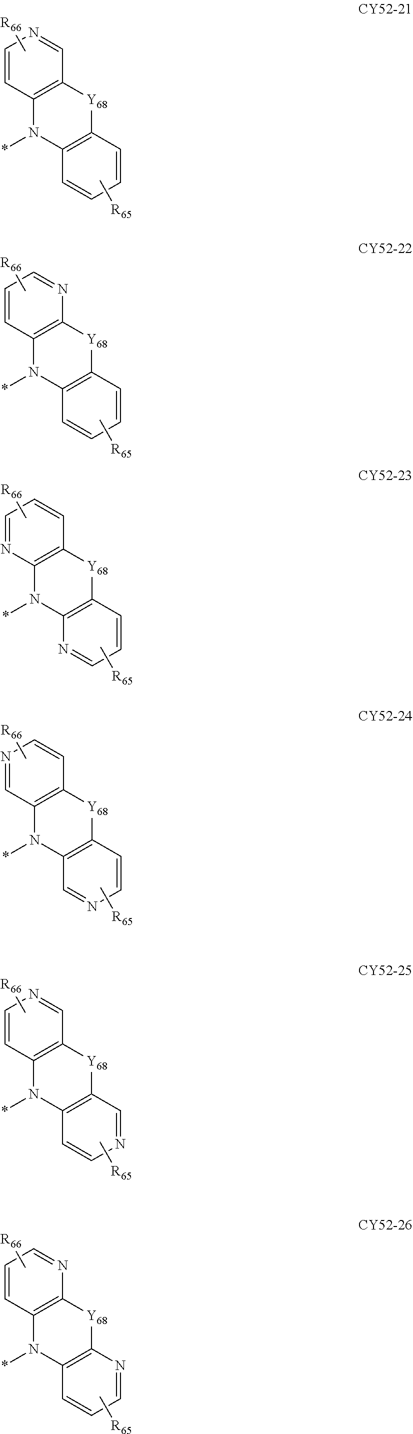

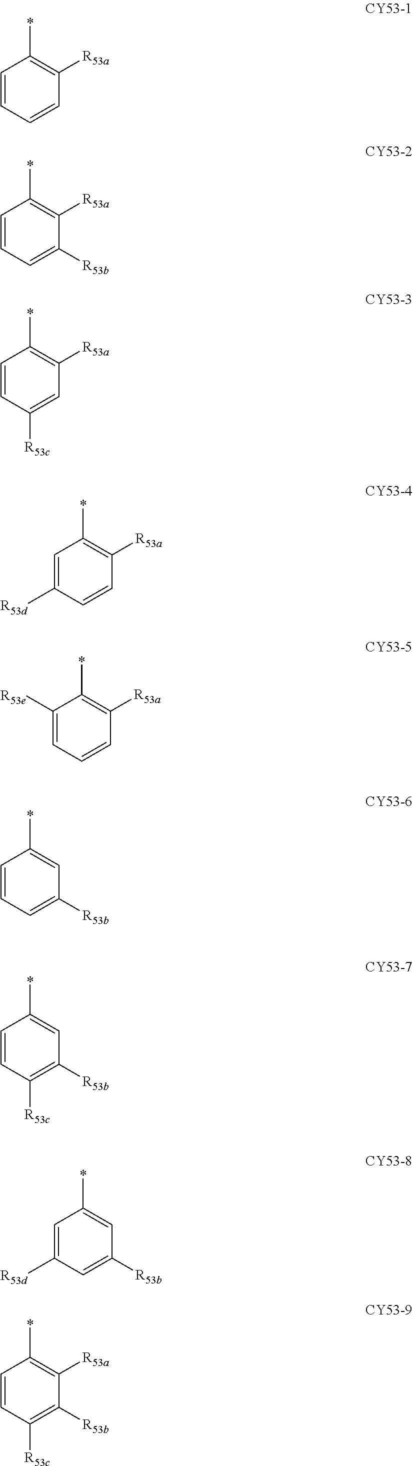

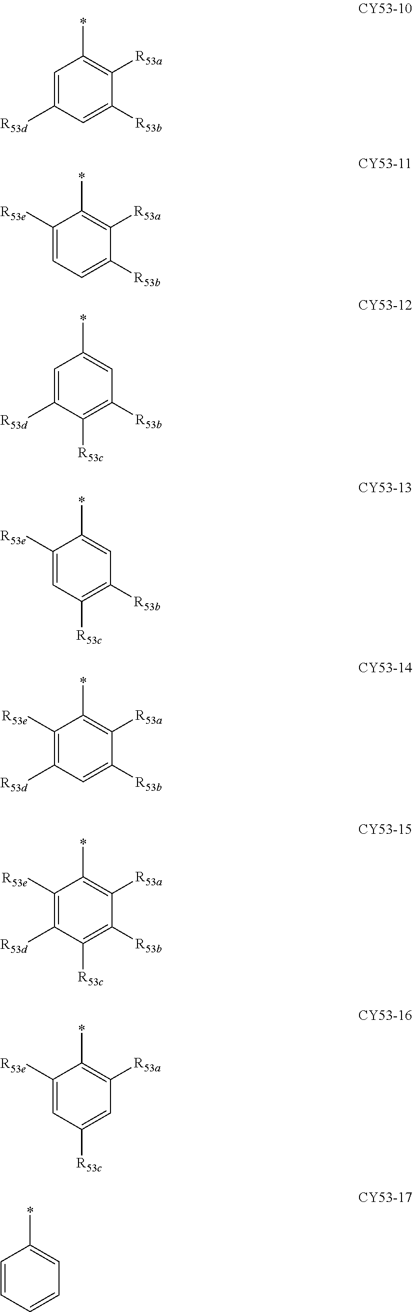

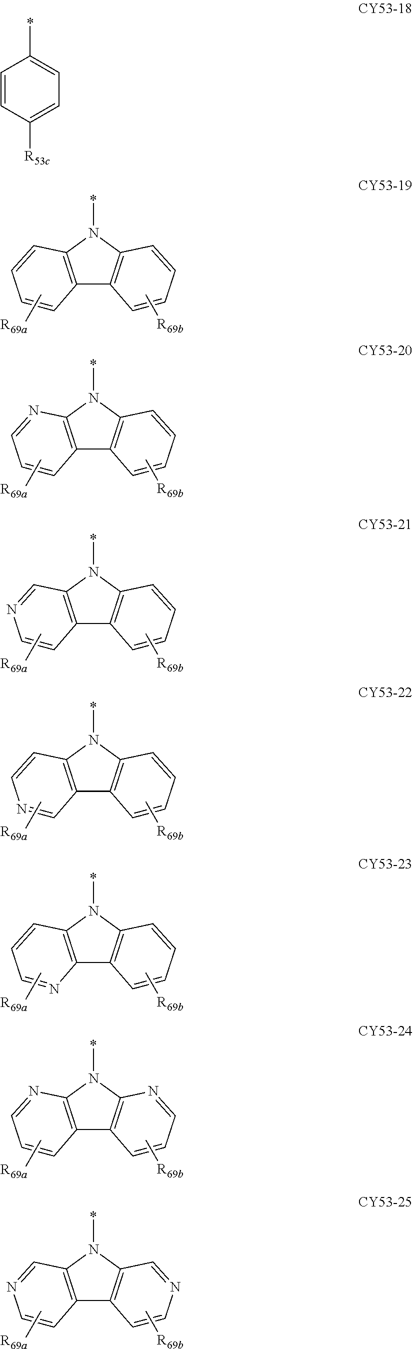

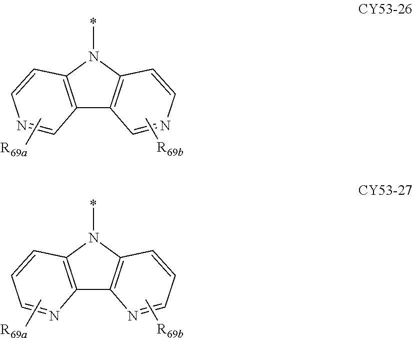

In Formulae CY51-1 to CY51-26, CY52-1 to CY52-26, and CY53-1 to CY53-27,

Y₆₃ may be a single bond, O, S, N(R₆₃), B(R₆₃), C(R₆₃ₐ)(R_{63b}), or Si(R₆₃ₐ)(R_{63b}),

Y₆₄ may be a single bond, O, S, N(R₆₄), B(R₆₄), C(R₆₄ₐ)(R_{64b}), or Si(R₆₄ₐ)(R_{64b}),

Y₆₇ may be a single bond, O, S, N(R₆₇), B(R₆₇), C(R₆₇ₐ)(R_{67b}), or Si(R₆₇ₐ)(R_{67b}),

Y₆₈ may be a single bond, O, S, N(R₆₈), B(R₆₈), C(R₆₈ₐ)(R_{68b}), or Si(R₆₈ₐ)(R_{68b}),

each of Y₆₃ and Y₆₄ in Formulae CY51-16 and CY51-17 may not be a single bond at the same time (e.g., simultaneously),

each of Y₆₇ and Y₆₈ in Formulae CY52-16 and CY52-17 may not be a single bond at the same time (e.g., simultaneously),

R₅₁ₐ to R₅₁ₑ, R₆₁ to R₆₄, R₆₃ₐ, R_{63b}, R₆₄ₐ, and R_{64b} are each the same as described in connection with R₆₁ in the present specification, wherein each of R₅₁ₐ to R₅₁ₑ may not be hydrogen,

R₅₂ₐ to R₅₂ₑ, R₆₅ to R₆₈, R₆₇ₐ, R_{67b}, R₆₈ₐ, and R_{68b} may each be the same as described in connection with R₆₂, wherein each of R₅₂ₐ to R₅₂ₑ may not be hydrogen,

R₅₃ₐ to R₅₃ₑ, R₆₉ₐ, and R_{69b} may each be the same as described in connection with R₆₃, wherein each of R₅₃ₐ to R₅₃ₑ may not be hydrogen, and

* indicates a binding site to a neighboring atom.

For example,

R₅₁ₐ to R₅₁ₑ and R₅₂ₐ to R₅₂ₑ in Formulae CY51-1 to CY51-26 and Formulae CY52-1 to 52-26 may each independently be:

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or

—C(Q₁)(Q₂)(Q₃) or —Si(Q₁)(Q₂)(Q₃), and

Q₁ to Q₃ may each independently be a phenyl group, a naphthyl group, a pyridinyl group, a pyrimidinyl group, a pyridazinyl group, a pyrazinyl group, or a triazinyl group, each independently unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof,

in Formulae CY51-16 and CY51-17, i) Y₆₃ may be O or S, and Y₆₄ may be Si(R₆₄ₐ)(R_{64b}), or ii) Y₆₃ may be Si(R₆₃ₐ)(R_{63b}), and Y₆₄ may be O or S, and

in Formulae CY52-16 and CY52-17, i) Y₆₇ may be O or S, and Yes may be Si(R₆₈ₐ)(R_{68b}), or ii) Y₆₇ may be Si(R₆₇ₐ)(R_{67b}), and Yes may be O or S.

In one or more embodiments, in Formulae 3-1 to 3-5, L₈₁ to L₈₅ may each independently be:

a single bond; or

*—C(Q₄)(Q₅)-*′ or *—Si(Q₄)(Q₅)-*′; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each independently unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof, and

Q₄, Q₅, and Q₃₁ to Q₃₃ may each independently be hydrogen, deuterium, a C₁-C₂₀₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In one or more embodiments, in Formulae 3-1 and 3-2, a group represented by

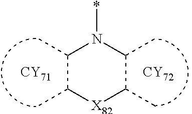

may be represented by one of Formulae CY71-1(1) to CY71-1(8), and/or

in Formulae 3-1 and 3-3, a group represented by

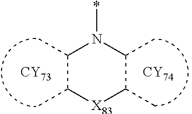

may be represented by one of Formulae CY71-2(1) to CY7-2(8), and/or

in Formulae 3-2 and 3-4, a group represented by

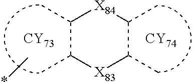

may be represented by one of Formulae CY71-3(1) to CY71-3 (32 and/or

in Formulae 3-3 to 3-5, a group represented by

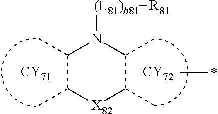

may be represented by one of Formulae CY71-4(1) to CY71-4(32), and/or

in Formula 3-5, a group represented by

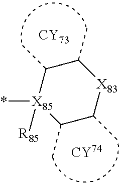

may be represented by one of Formulae CY71-5(1) to CY71-5(8):

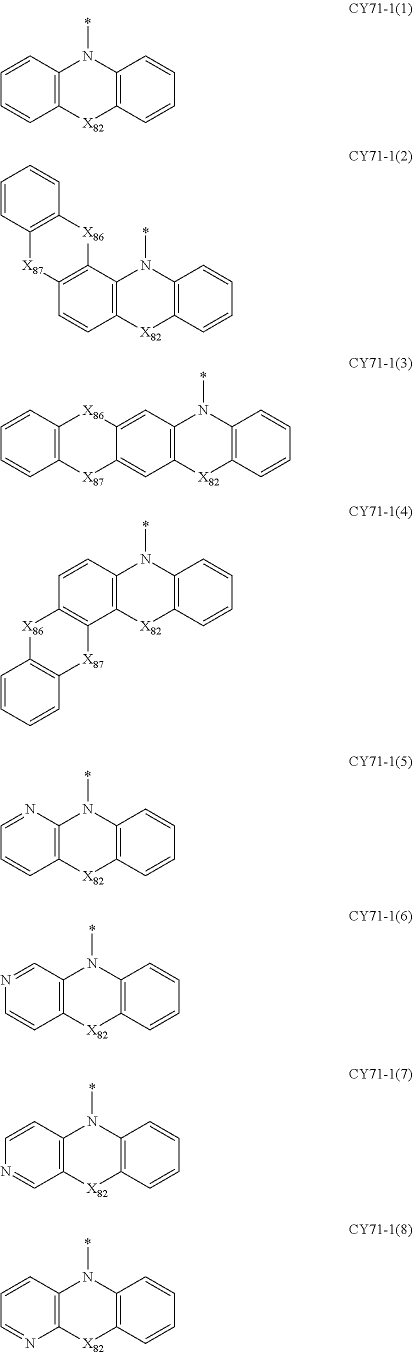

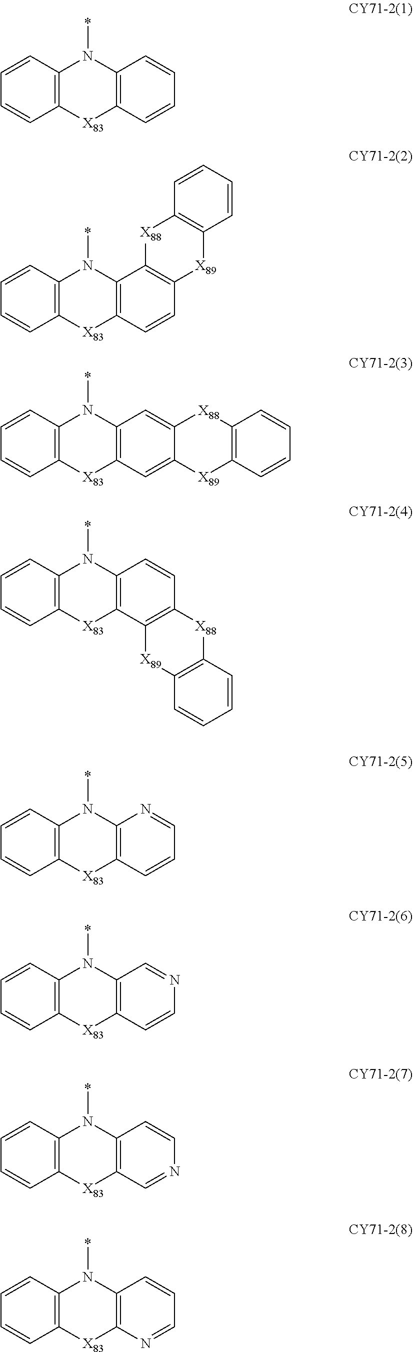

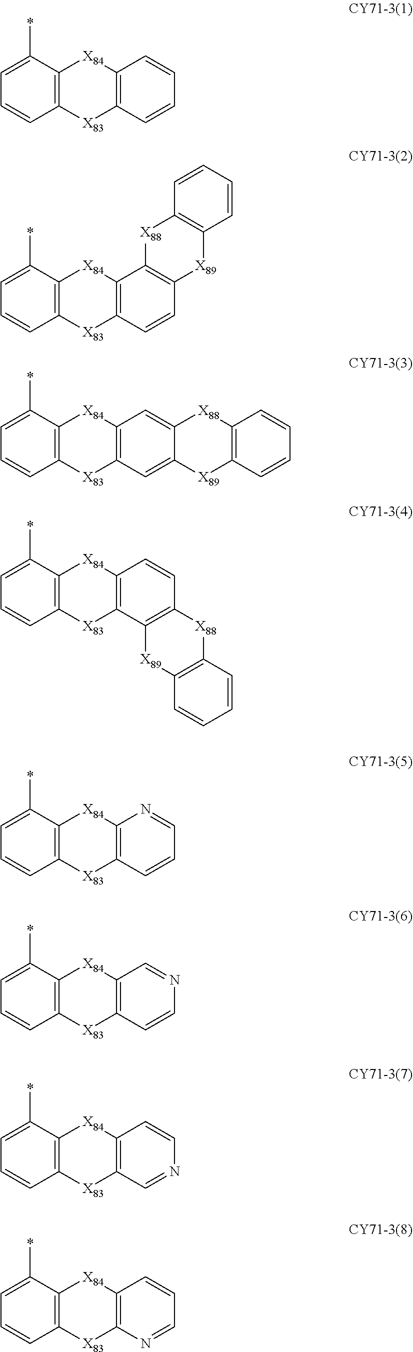

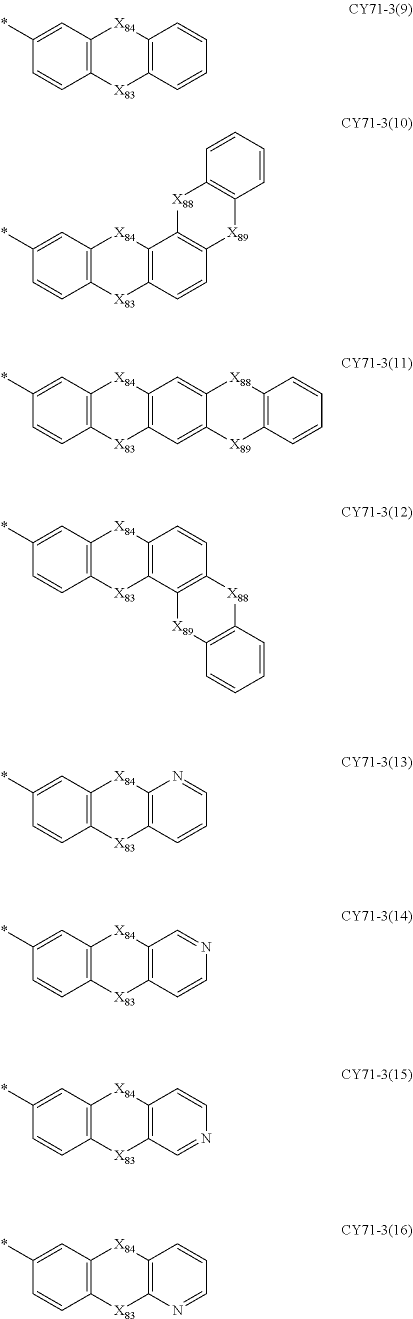

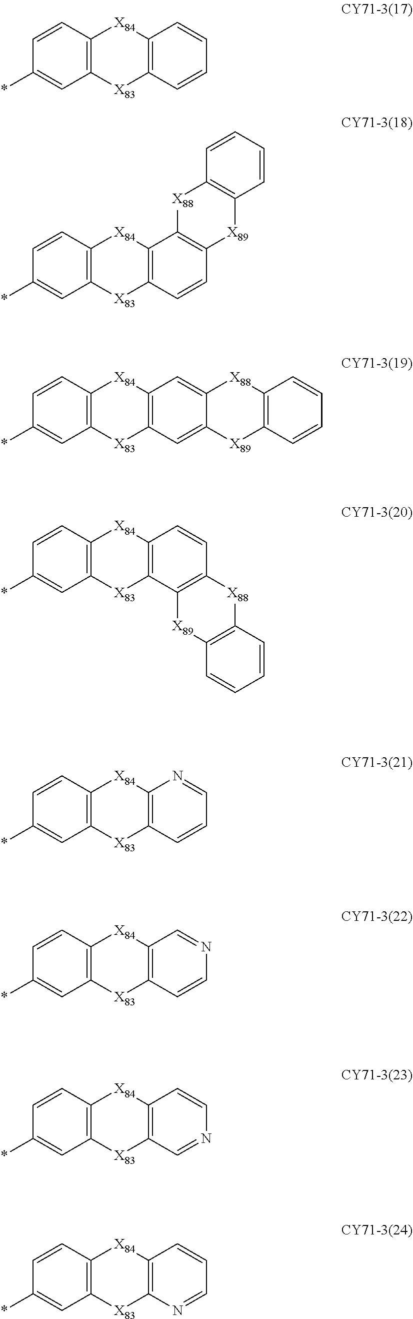

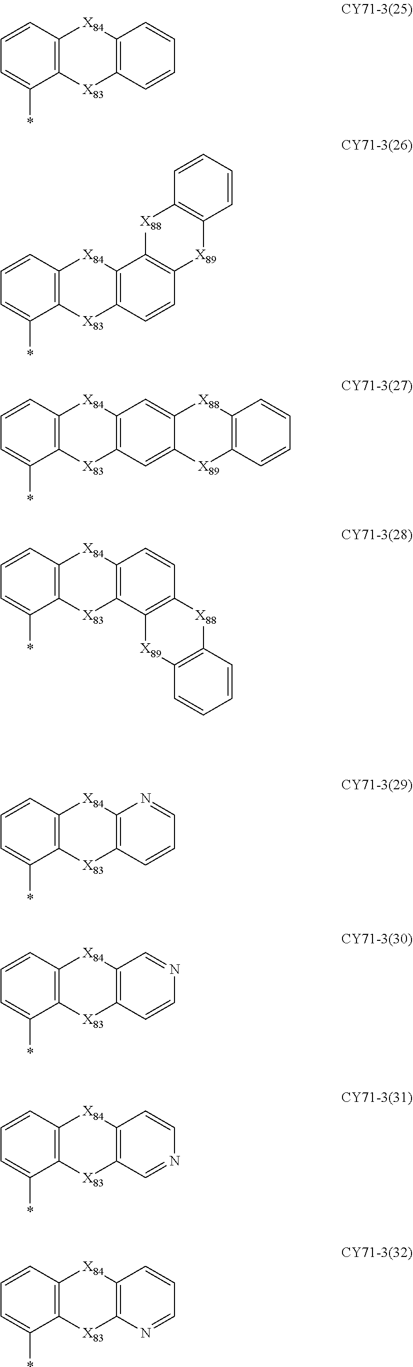

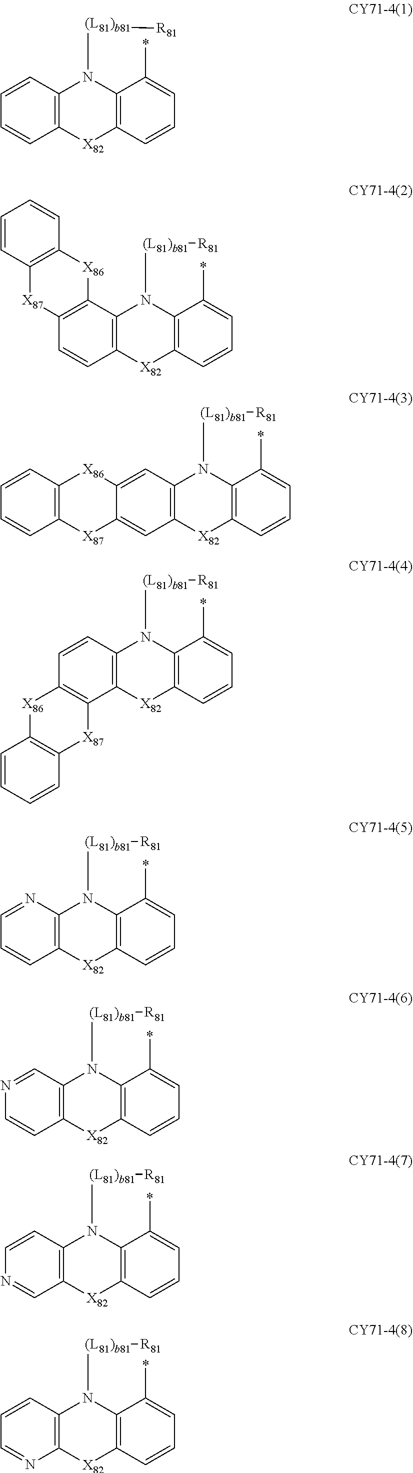

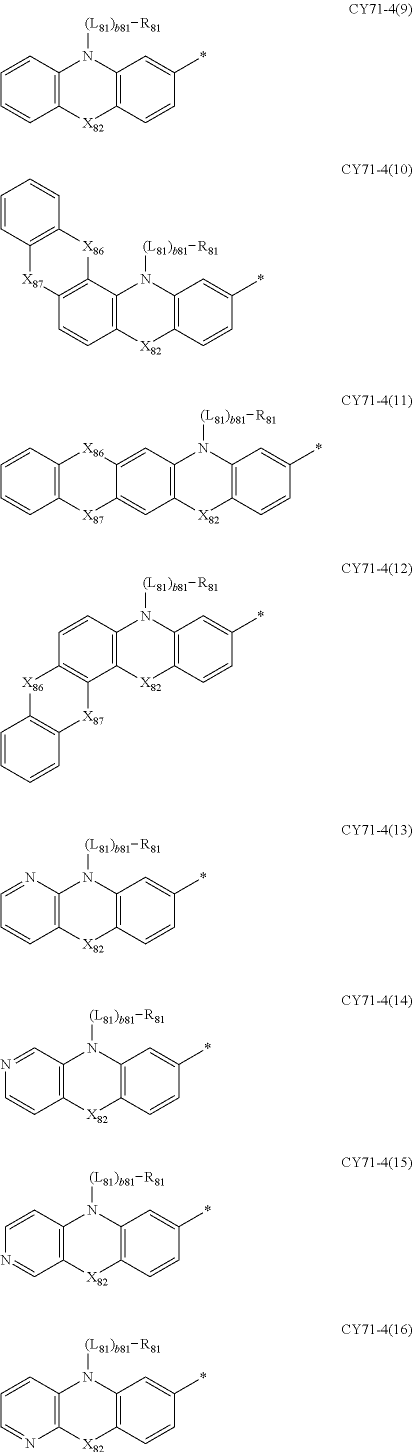

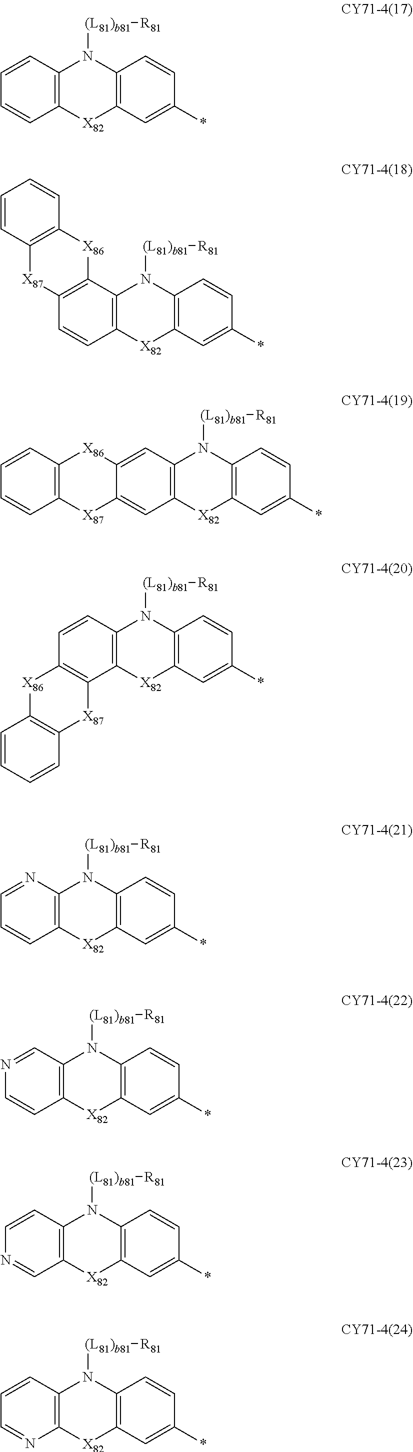

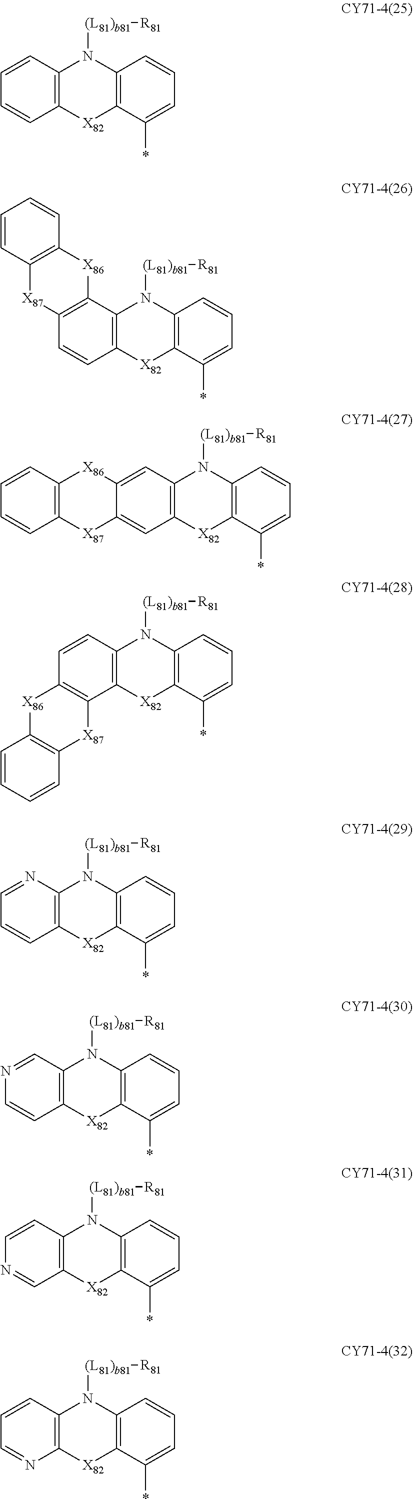

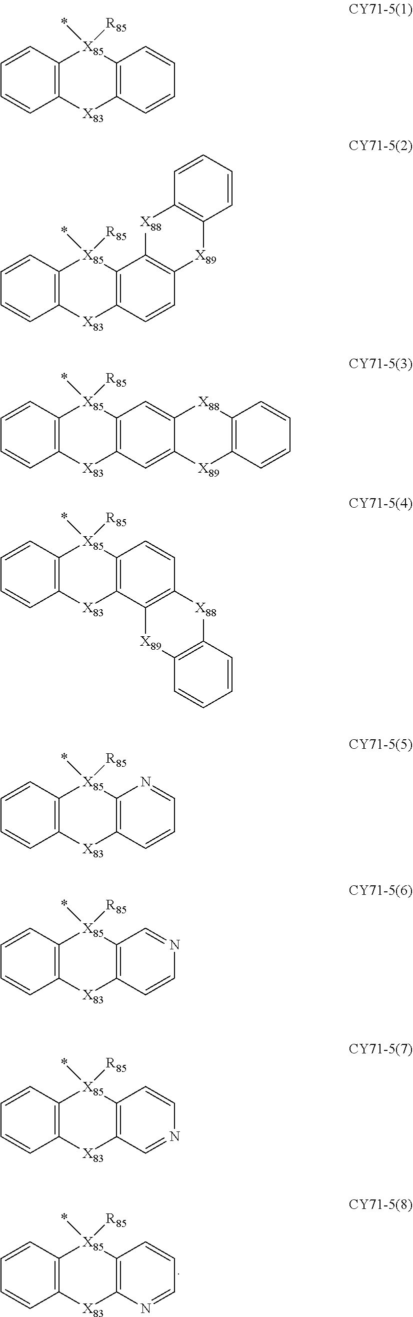

In Formulae CY71-1(1) to CY71-1(8), CY71-2(1) to CY71-2(8), CY71-3(1) to CY71-3(32), CY71-4(1) to CY71-4(32), and CY71-5(1) to CY71-5(8),

X₈₁ to X₈₅, L₈₁, b81, R₈₁, and R₈₅ may respectively be the same as described herein,

X₈₆ may be a single bond, O, S, N(R₈₆), B(R₈₆), C(R₈₆ₐ)(R_{86b}), or Si(R₈₆ₐ)(R_{86b}),

X₈₇ may be a single bond, O, S, N(R₈₇), B(R₈₇), C(R₈₇ₐ)(R_{87b}), or Si(R₈₇ₐ)(R_{87b}),

in Formulae CY71-1(1) to CY71-1(8) and CY71-4(1) to CY71-4(32), each of X₈₆ and X₈₇ may not be a single bond at the same time (e.g., simultaneously),

X₈₈ may be a single bond, O, S, N(R₈₈), B(R₈₈), C(R₈₈ₐ)(R_{86b}), or Si(R₈₈ₐ)(R_{88b}),

X₈₉ may be a single bond, O, S, N(R₈₉), B(R₈₉), C(R₈₉ₐ)(R_{89b}), or Si(R₈₉ₐ)(R_{89b}),

in Formulae CY71-2(1) to CY71-2(8), CY71-3(1) to CY71-3(32), and CY71-5(1) to CY71-5(8), each of X₈₈ and X₈₉ may not be a single bond at the same time (e.g., simultaneously), and

R₈₆ to R₈₉, R₈₆ₐ, R_{86b}, R₈₇ₐ, R_{87b}, R₈₈ₐ, R_{88b}, R₈₉ₐ, and R_{89b} may each be the same as described in connection with R₈₁.

### Examples of Second Compound, Third Compound, and Fourth Compound

In one or more embodiments, the second compound may include at least one of Compounds ETH1 to ETH85:

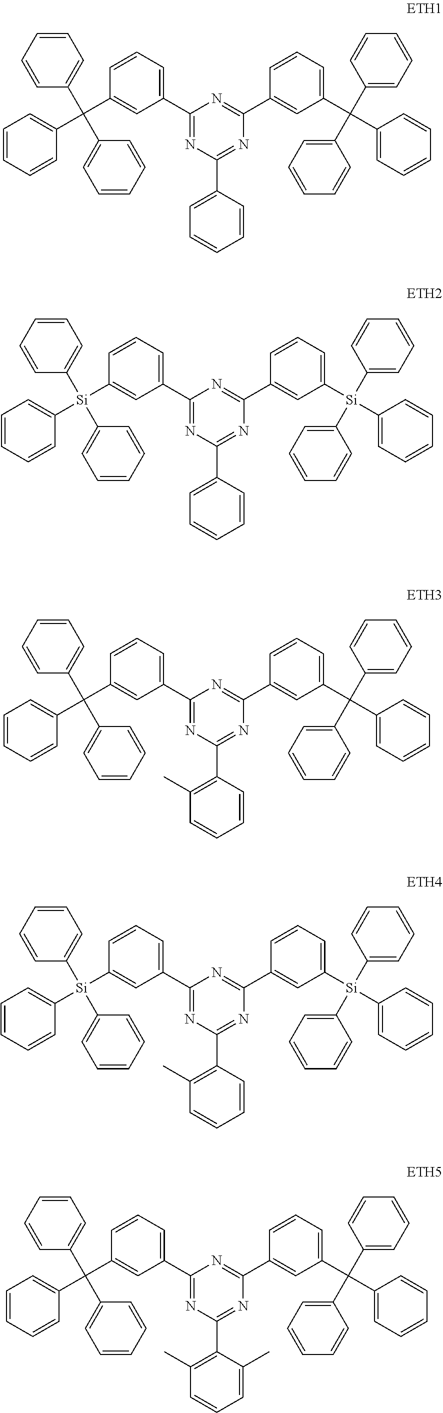

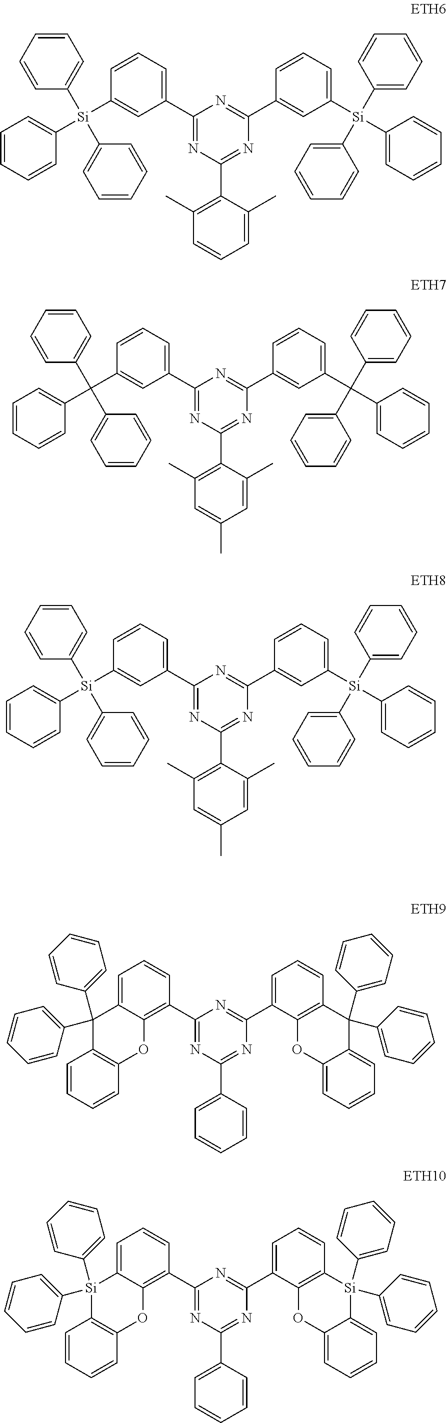

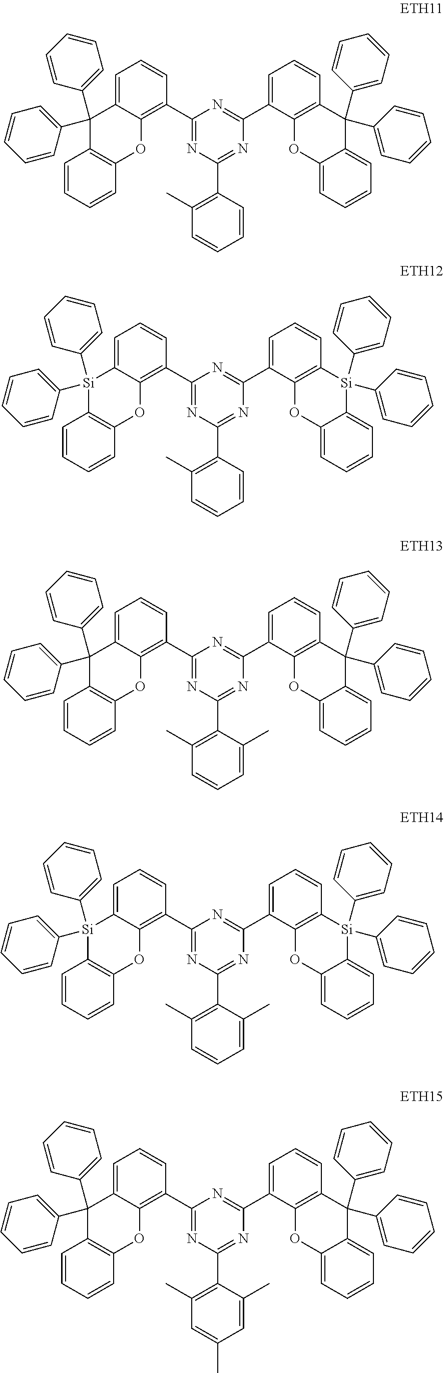

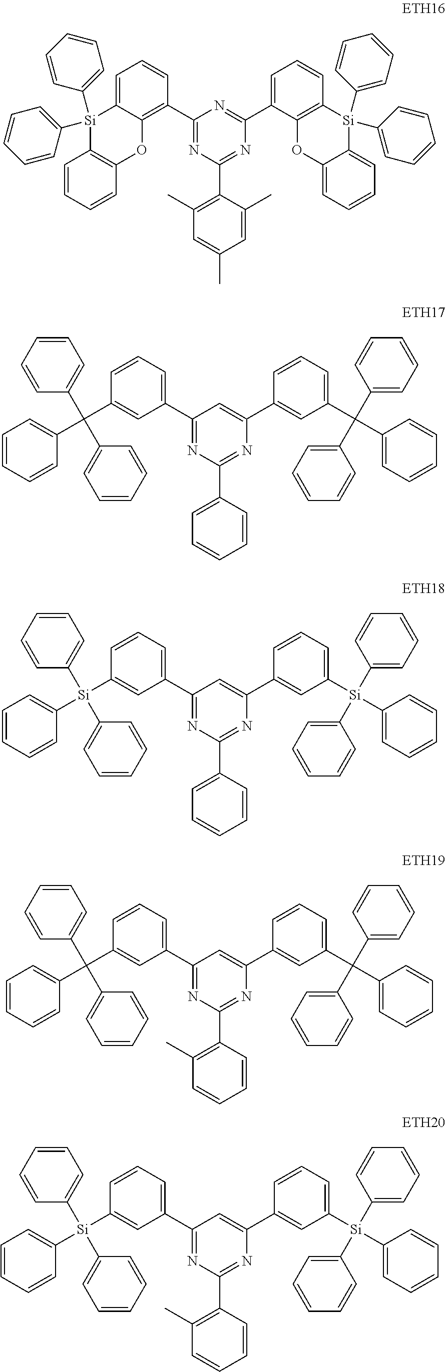

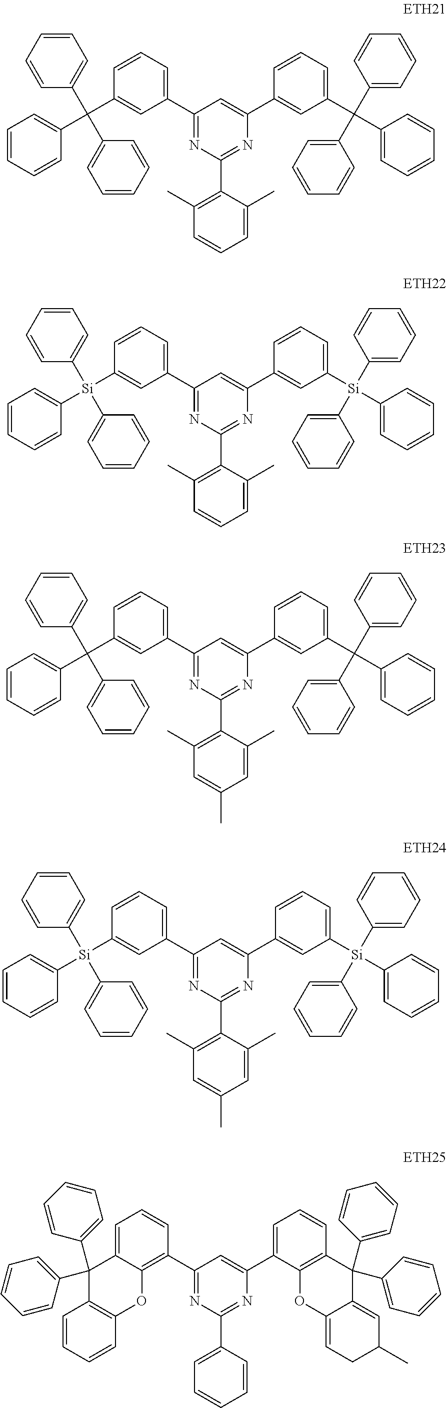

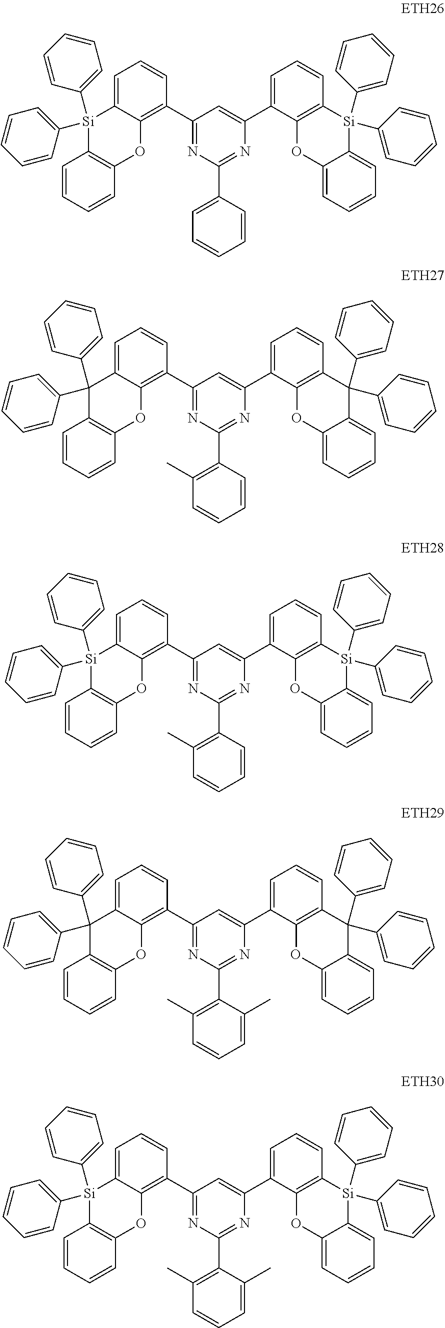

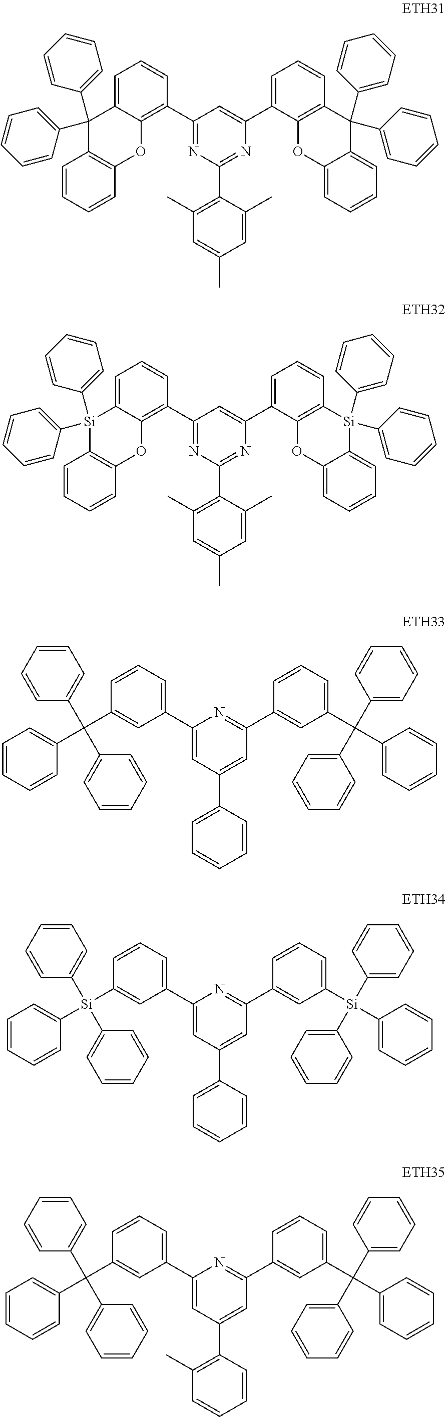

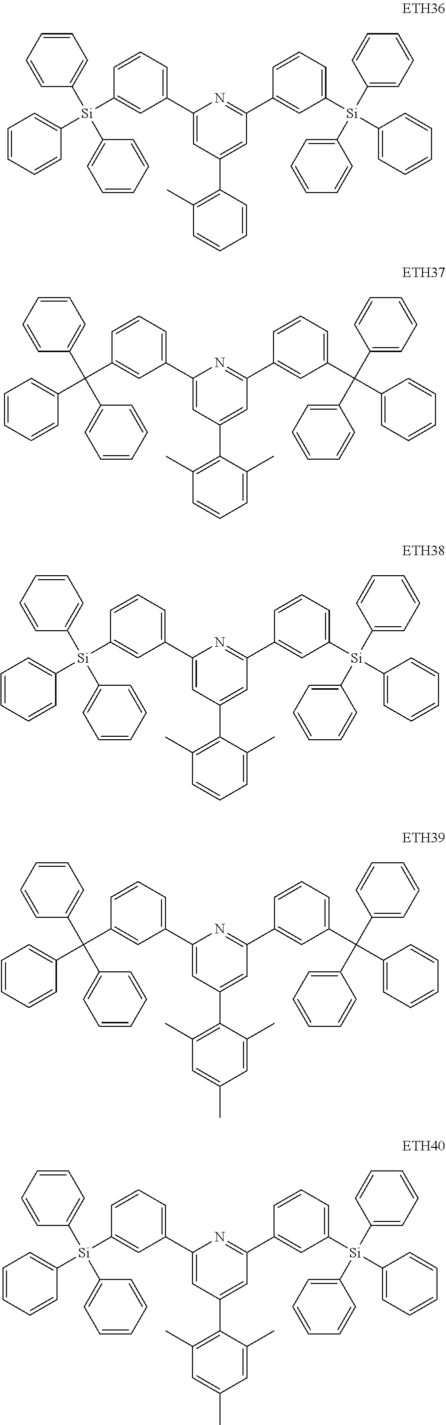

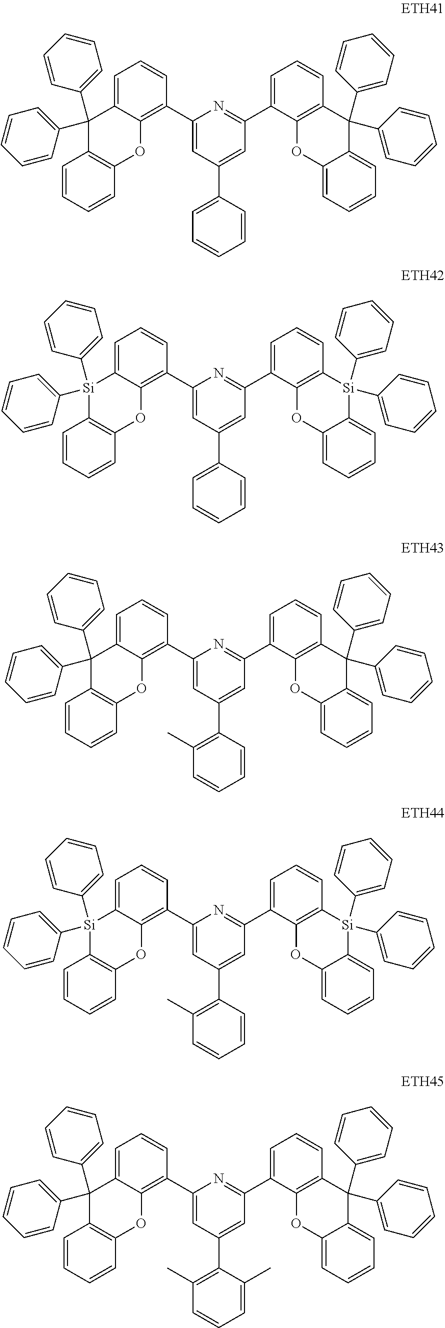

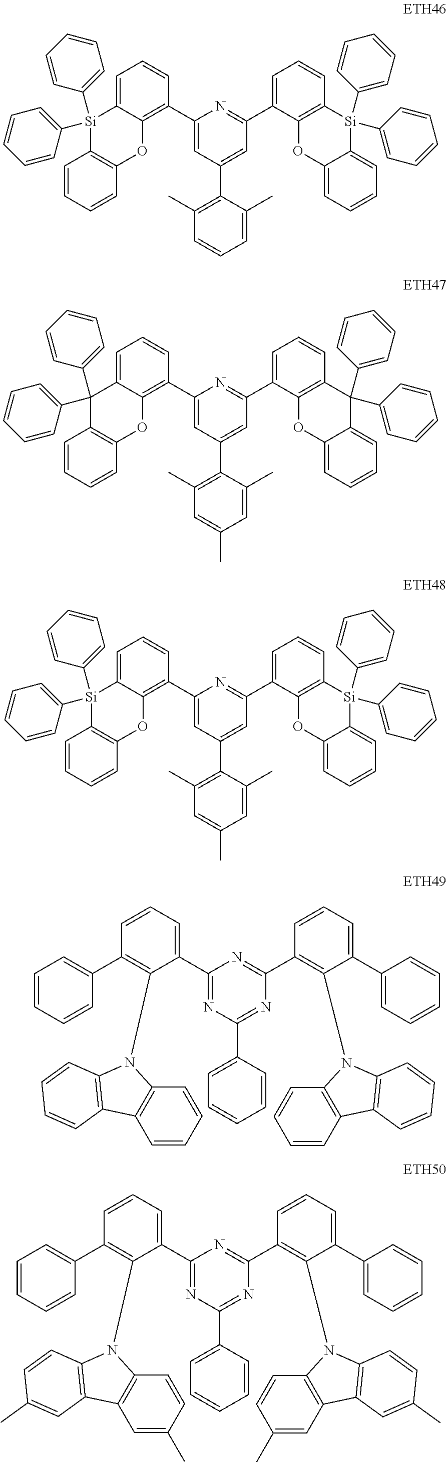

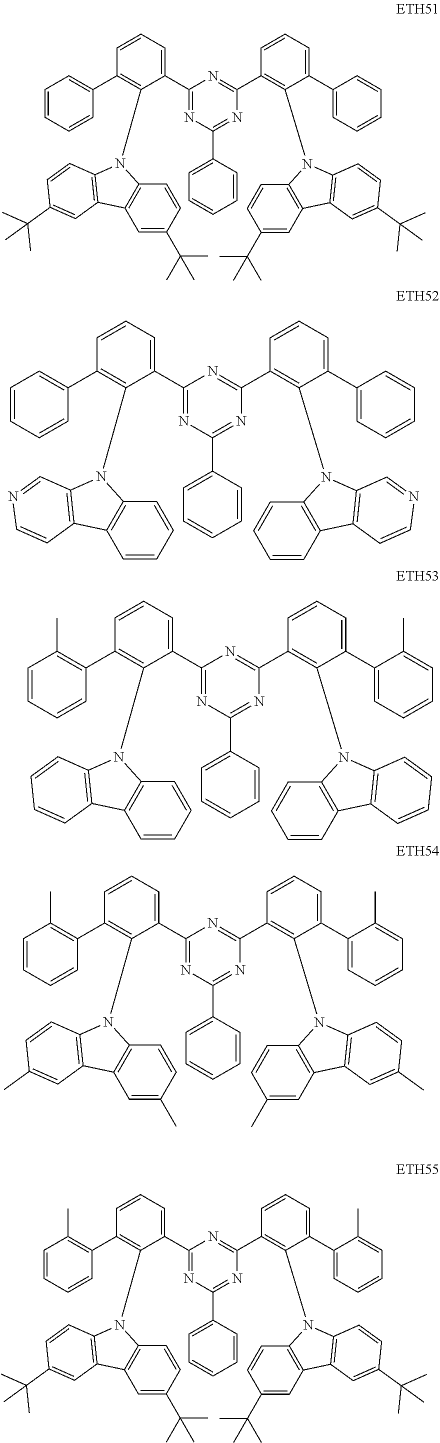

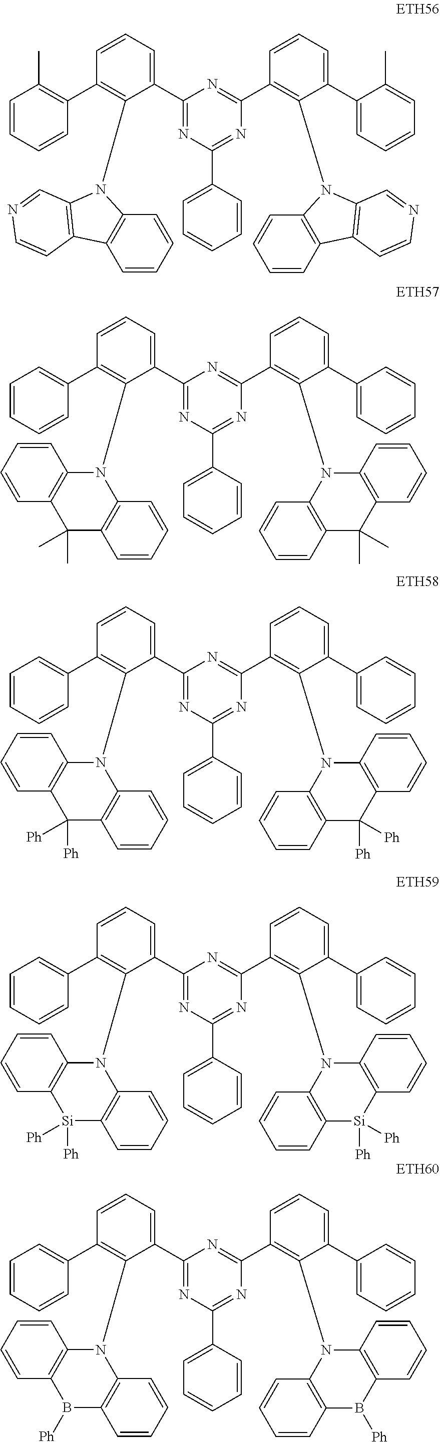

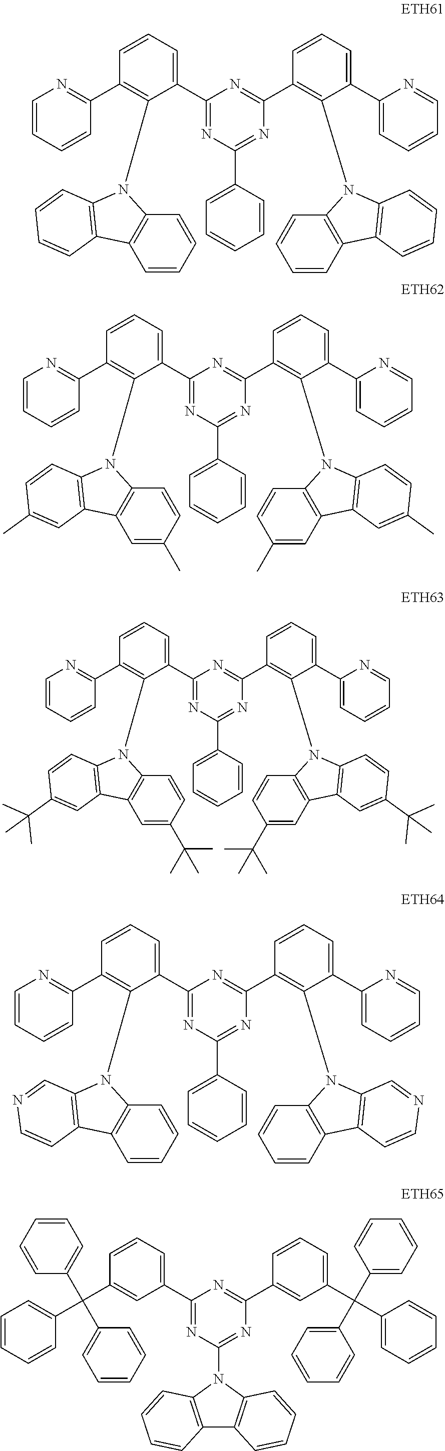

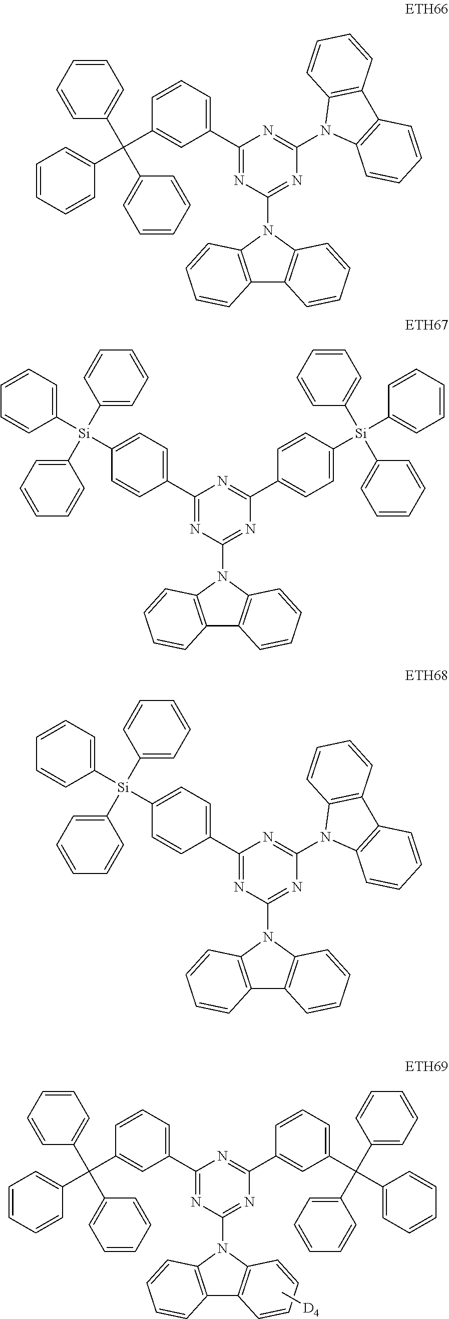

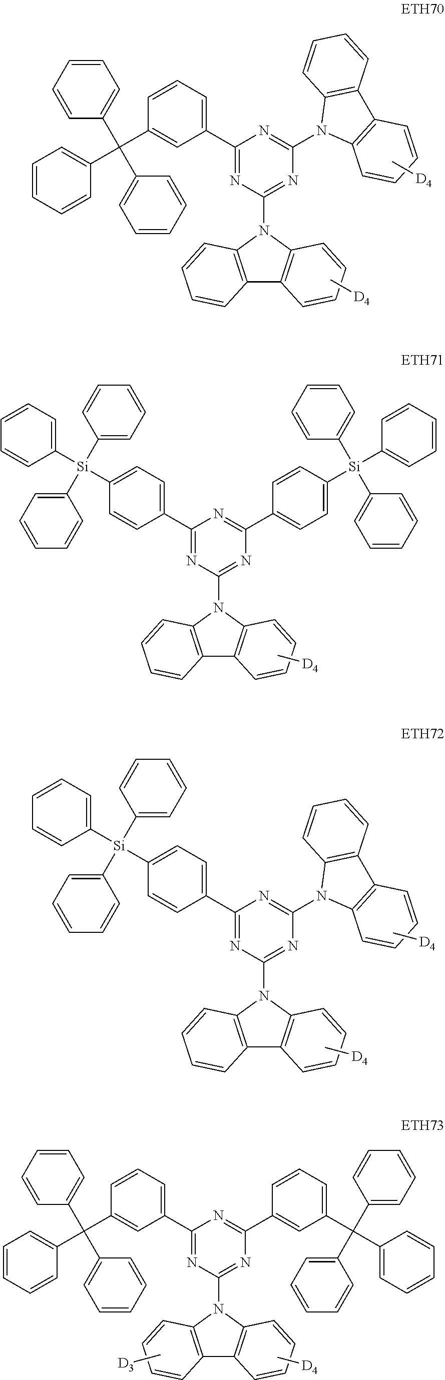

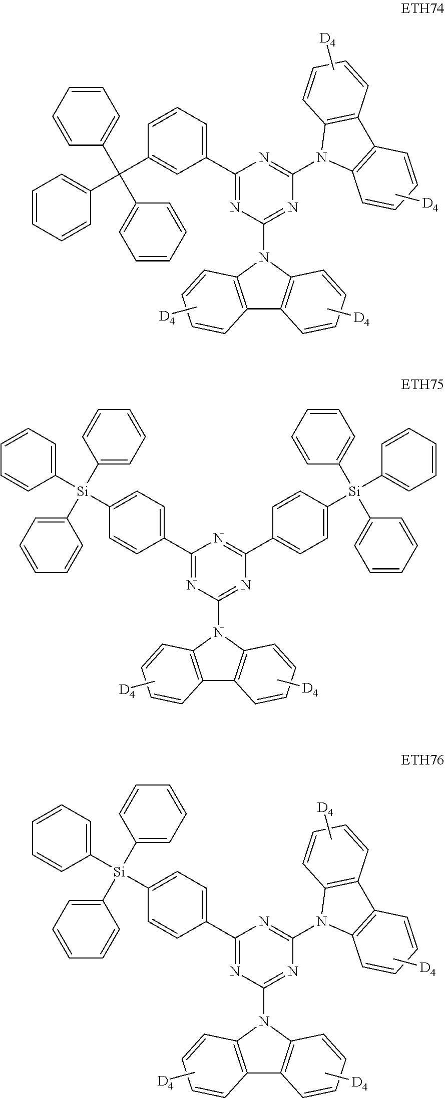

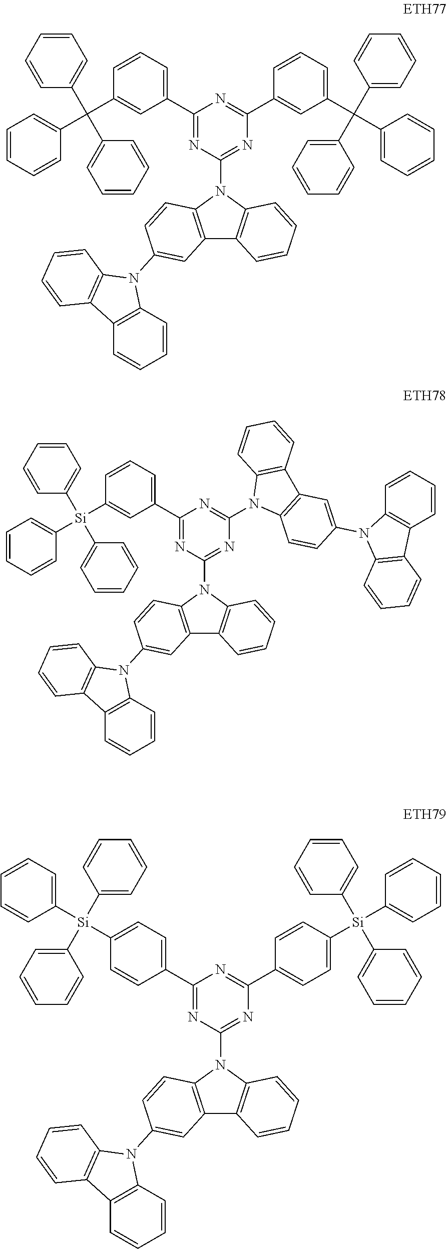 [SMILES: c1ccc(C(c2ccccc2)(c2ccccc2)c2cccc(-c3nc(-c4cccc(C(c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

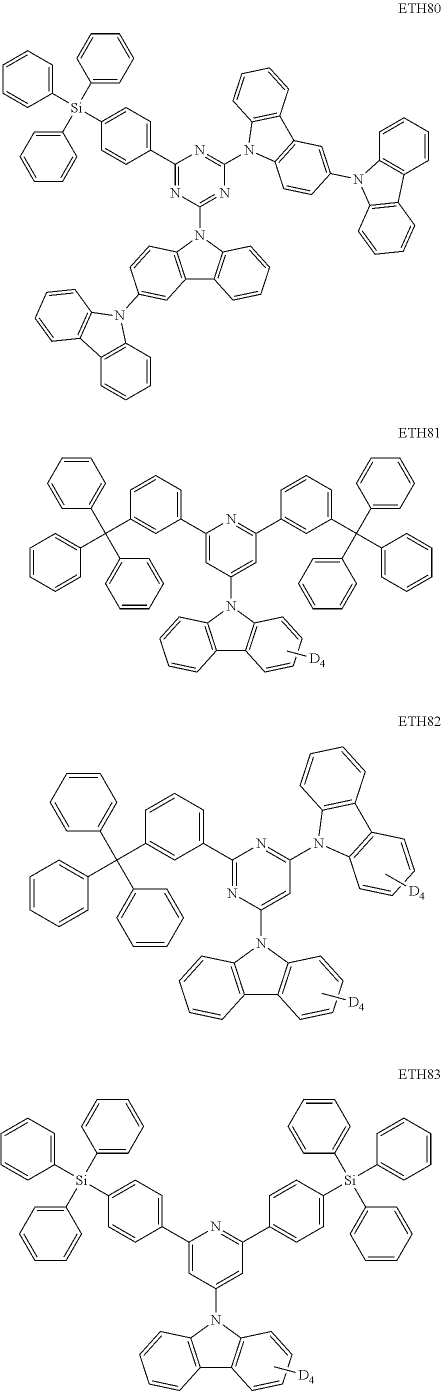

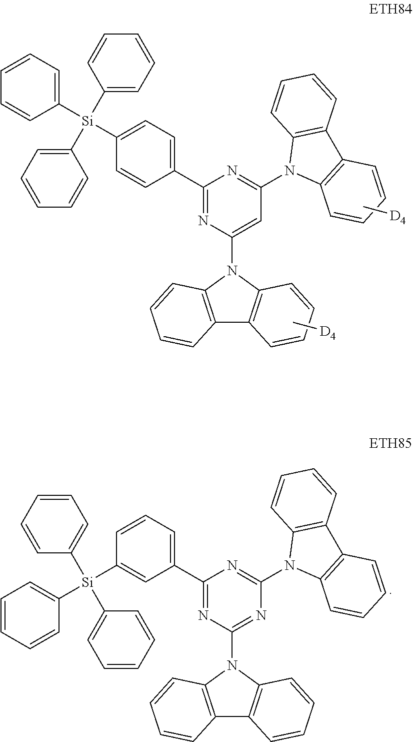

In one or more embodiments, the third compound may include at least one of Compounds HTH1 to HTH52:

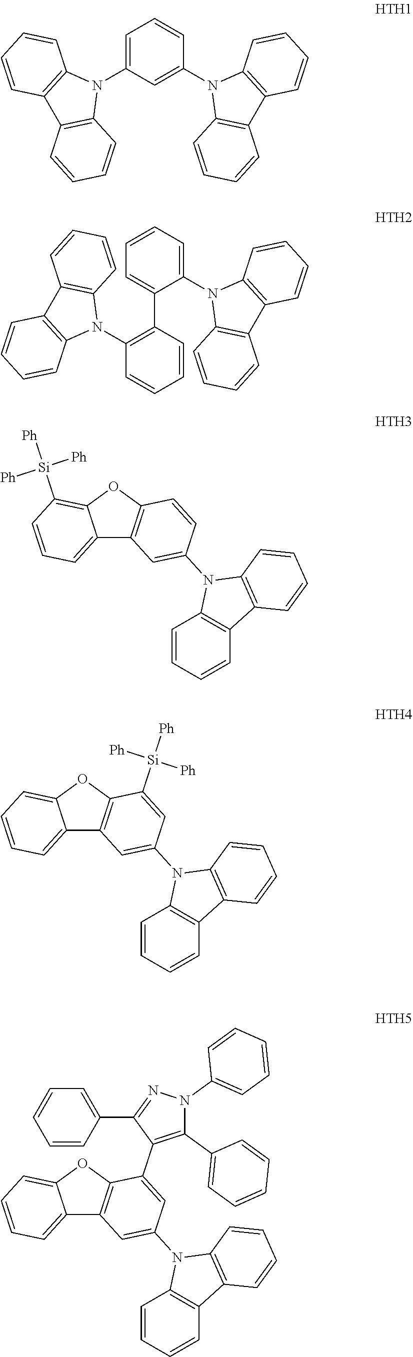 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

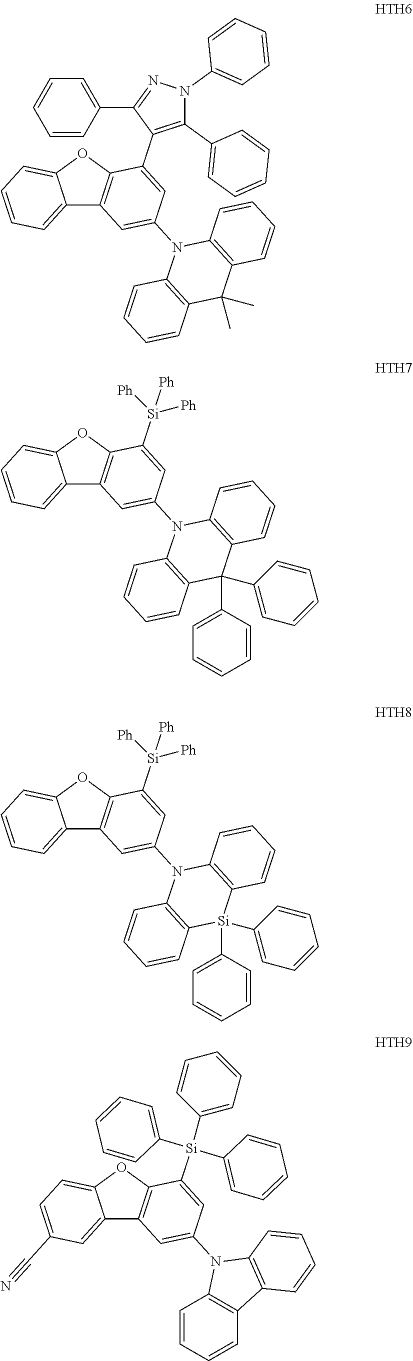

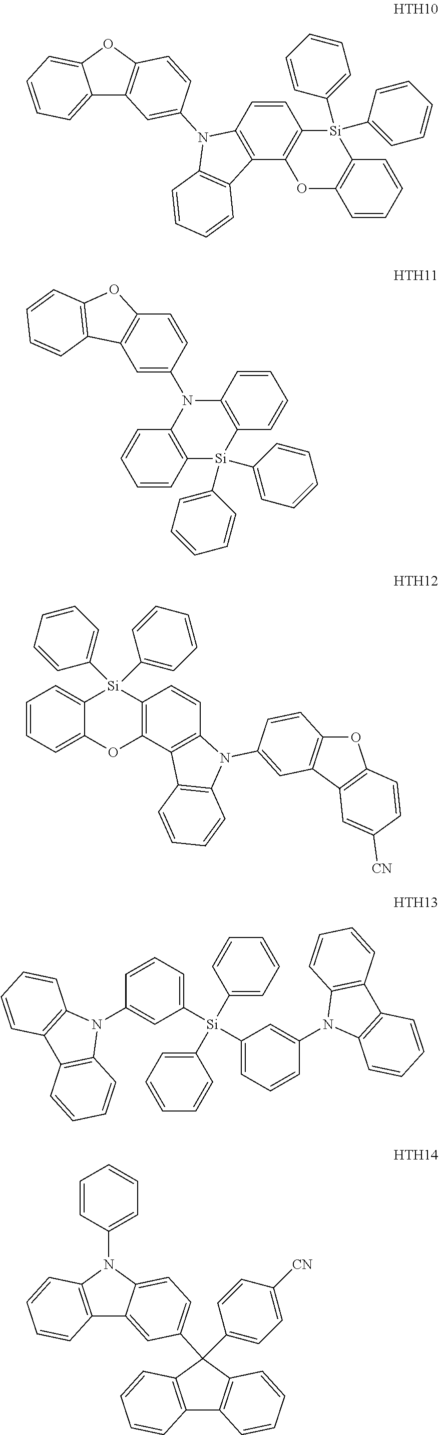 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

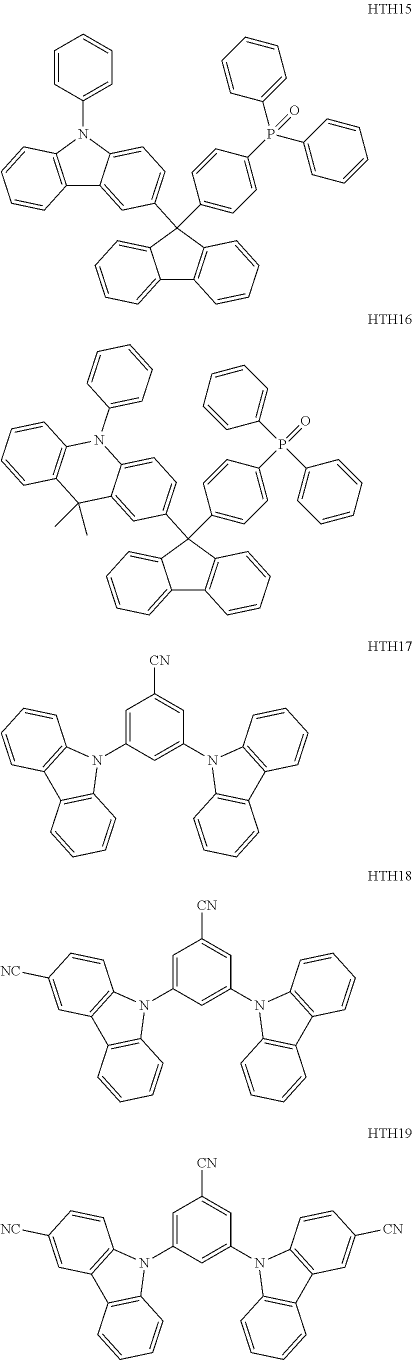

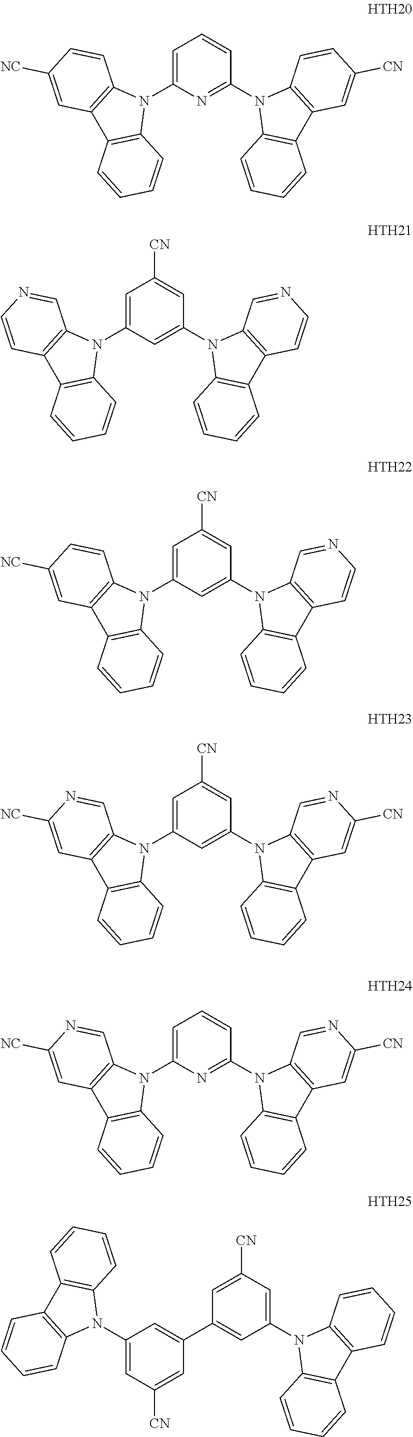 [SMILES: N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

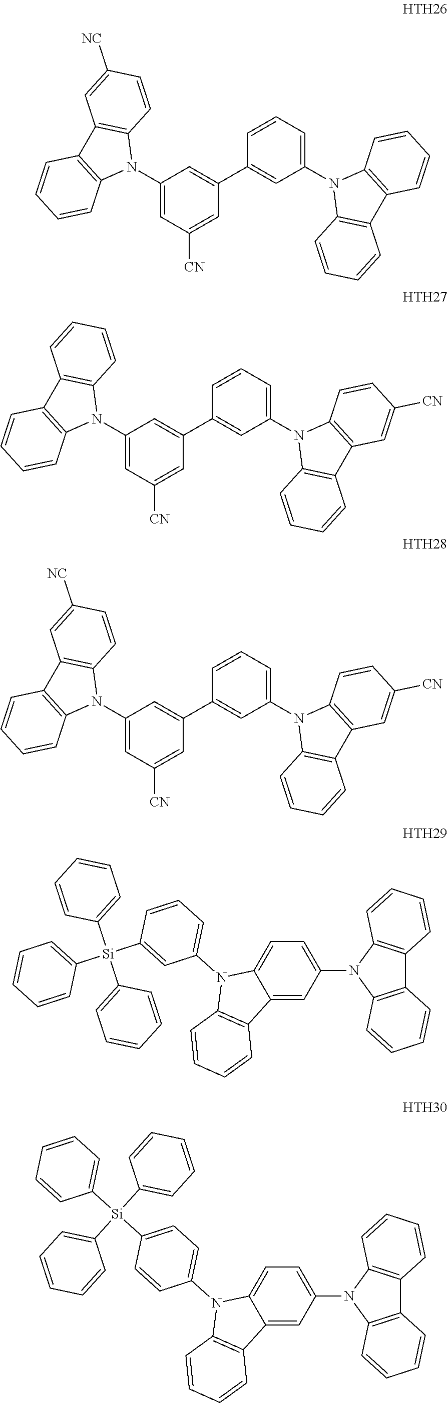 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

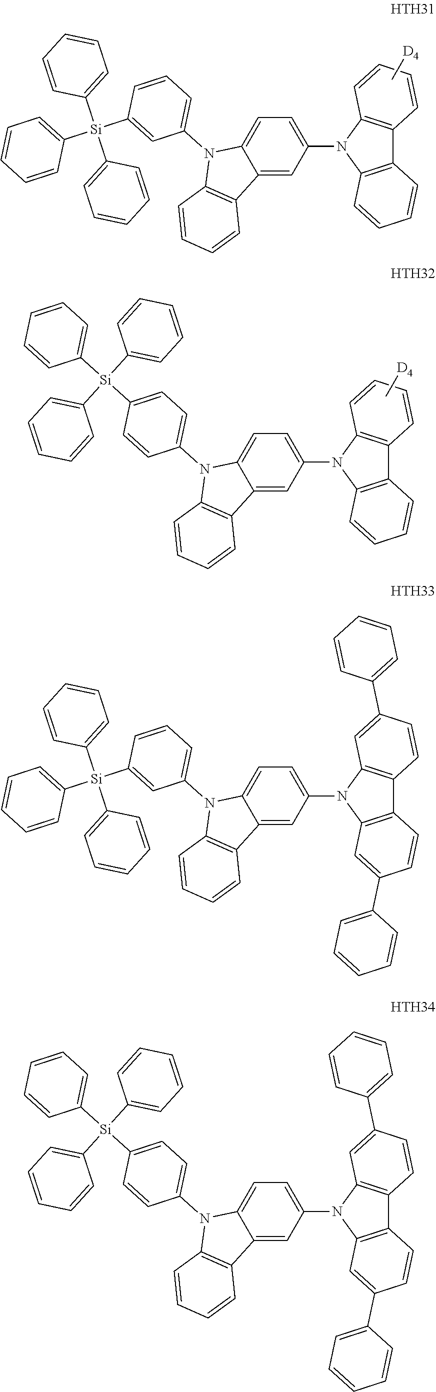

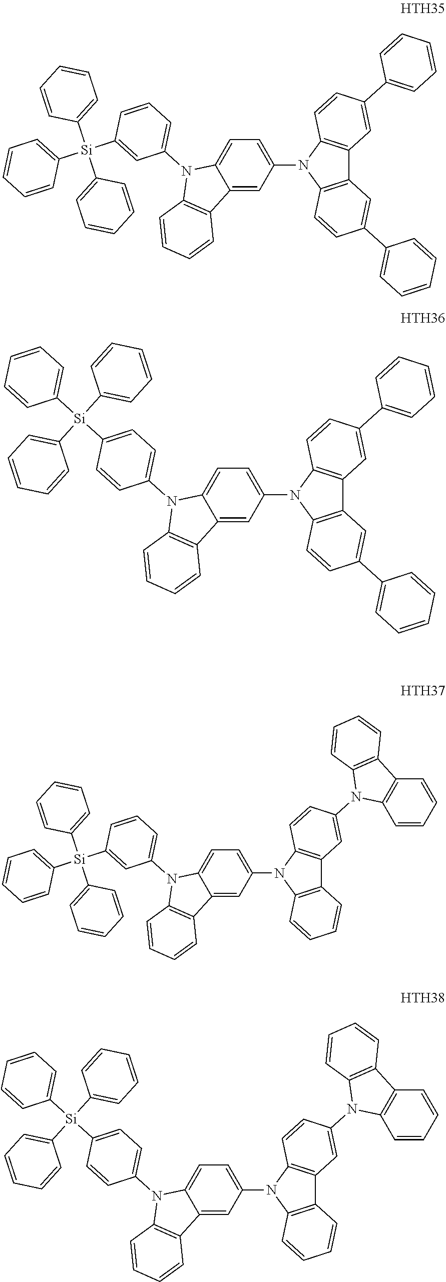 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

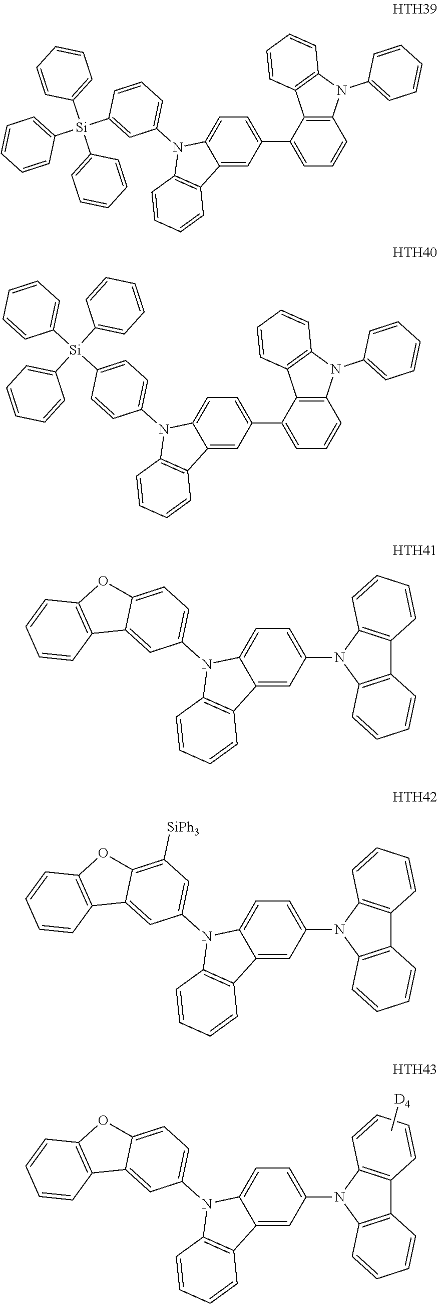

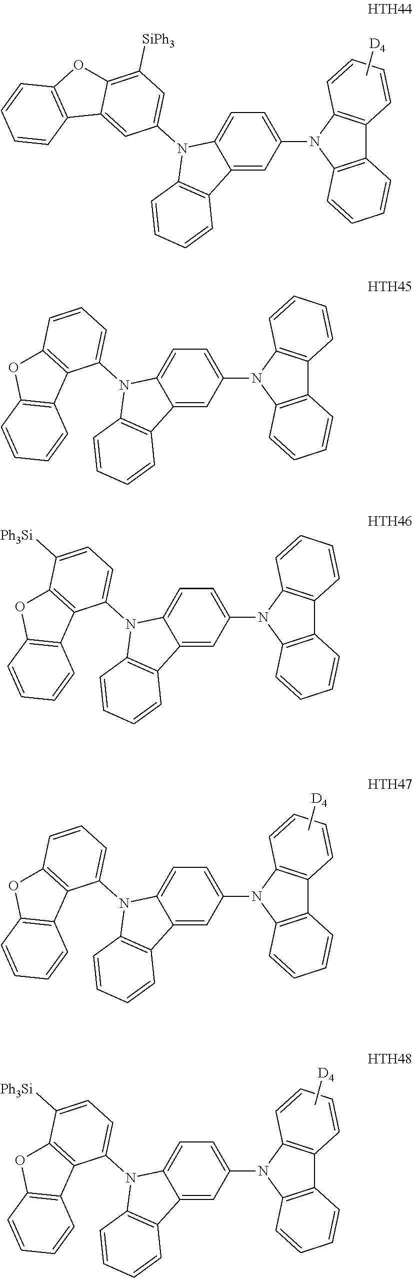

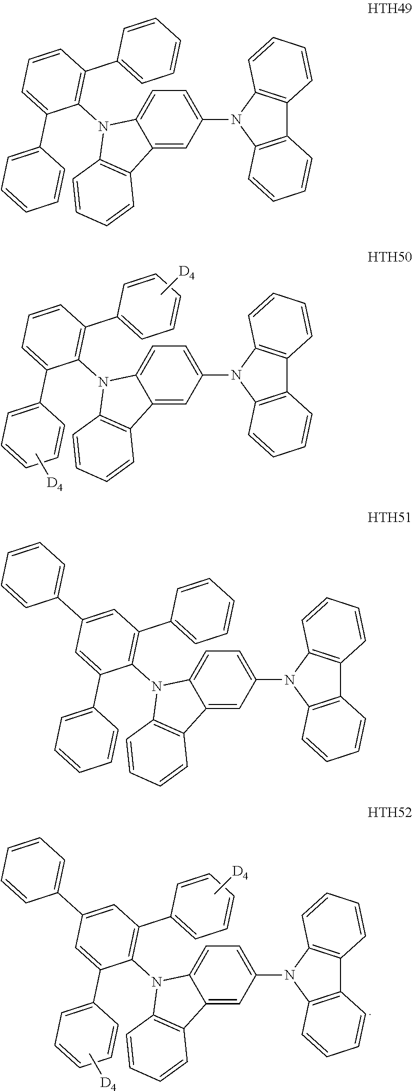

In one or more embodiments, the fourth compound may include at least one of Compounds DFD1 to DFD12:

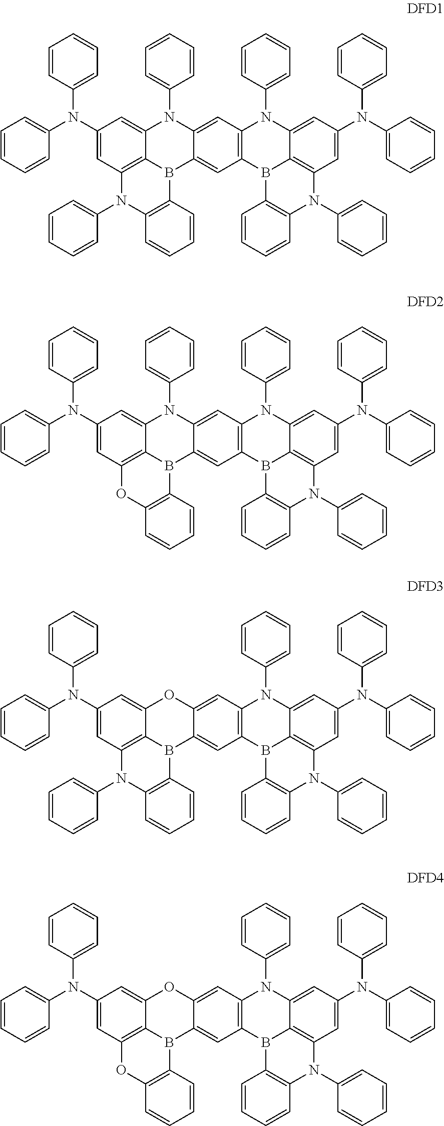

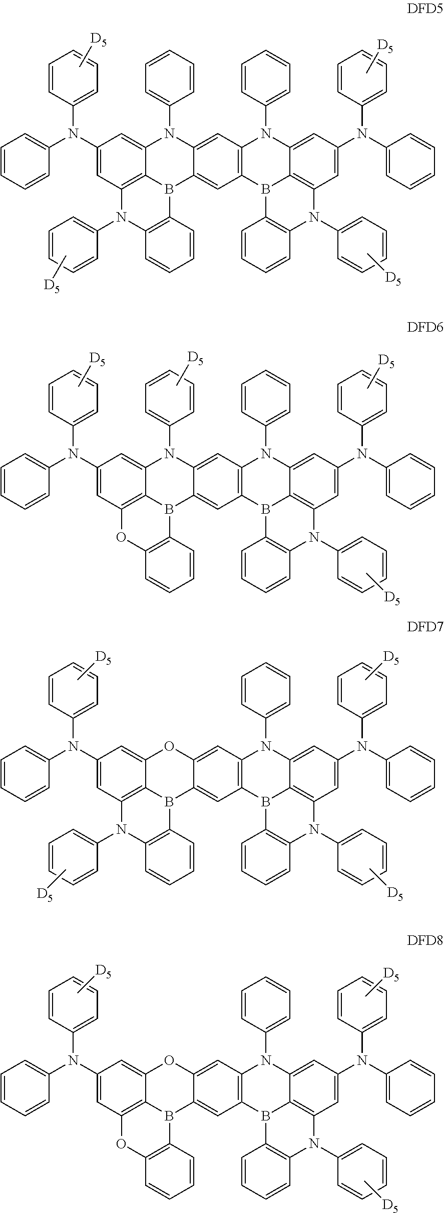

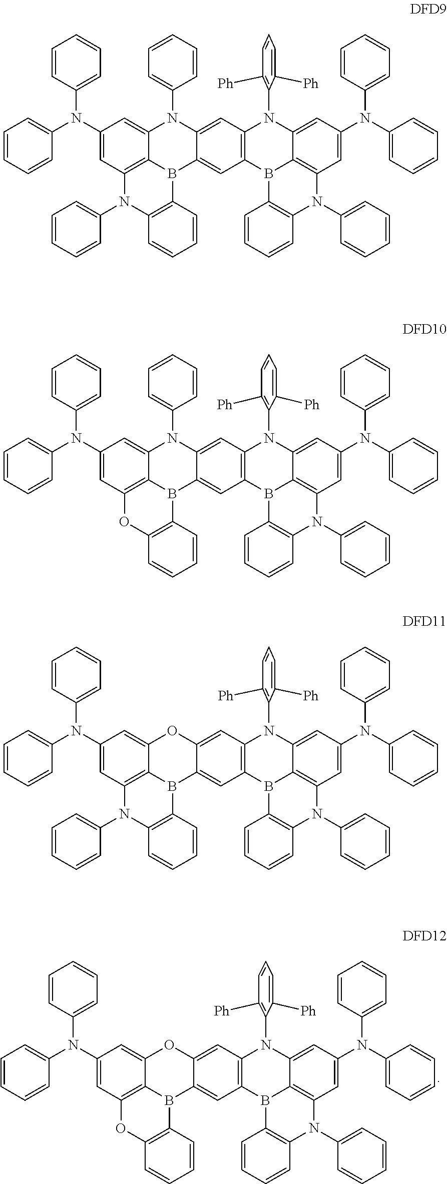

In the compounds above, “Ph” represents a phenyl group, “D5” represents substitution with five deuterium atoms, and “D4” represents substitution with four deuterium atoms. For example, a group represented by

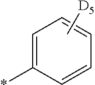

may be identical to a group represented by

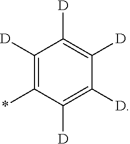

In one or more embodiments, the light-emitting device may satisfy at least one of Condition A to Condition D:

### Condition A

LUMO energy level (eV) of third compound>LUMO energy level (eV) of first compound;

### Condition B

LUMO energy level (eV) of first compound>LUMO energy level (eV) of second compound;

### Condition C

HOMO energy level (eV) of first compound>HOMO energy level (eV) of third compound; and

### Condition D

HOMO energy level (eV) of third compound>HOMO energy level (eV) of second compound.

Each of a HOMO energy level and a LUMO energy level of each of the first compound, the second compound, and the third compound may be a negative value, which is measured according to a suitable method in the art.

In one or more embodiments, an absolute value of a difference between a LUMO energy level of the first compound and a LUMO energy level of the second compound may be about 0.1 eV or higher and about 1.0 eV or lower, an absolute value of a difference between a LUMO energy level of the first compound and a LUMO energy level of the third compound may be about 0.1 eV or higher and about 1.0 eV or lower, an absolute value of a difference between a HOMO energy level of the first compound and a HOMO energy level of the second compound may be 1.25 eV or lower (for example, about 1.25 eV or lower and about 0.2 eV or higher), and an absolute value of a difference between a HOMO energy level of the first compound and a HOMO energy level of the third compound may be 1.25 eV or lower (for example, about 1.25 eV or lower and about 0.2 eV or higher).

When the relationships between the LUMO energy level and the HOMO energy level satisfy the conditions above, the balance between holes and electrons injected into the emission layer may be achieved (e.g., may be suitable).

The light-emitting device may have a structure described in First embodiment or Second embodiment:

### Description of First Embodiment

According to First embodiment, the first compound may be included in an emission layer in an interlayer of a light-emitting device, wherein the emission layer may further include a host, the first compound may be different from the host, and the emission layer may be to emit (e.g., may be configured to emit) phosphorescence or fluorescence from the first compound. For example, according to First embodiment, the first compound may be a dopant or an emitter. For example, the first compound may be a phosphorescent dopant or a phosphorescent emitter.

Phosphorescence or fluorescence emitted from the first compound may be blue light.

The emission layer may further include an auxiliary dopant. The auxiliary dopant may effectively (or suitably) transfer energy to the first compound which serves as a dopant or an emitter, so as to improve luminescence efficiency of the first compound.

The auxiliary dopant may be different from the first compound and the host.

In one or more embodiments, the auxiliary dopant may be a compound capable of emitting delayed fluorescence.

In one or more embodiments, the auxiliary dopant may be a compound including at least one cyclic group including boron (B) and nitrogen (N) as ring-forming atoms.

### Description of Second Embodiment

According to Second embodiment, the first compound may be included in an emission layer in an interlayer of a light-emitting device, wherein the emission layer may further include a host and a dopant; the first compound, the host, and the dopant may be different from one another; and the emission layer may be to emit (e.g., may be configured to emit) phosphorescence or fluorescence (for example, delayed fluorescence) from the dopant.

In one or more embodiments, the first compound in Second embodiment may serve not as a dopant, but as an auxiliary dopant that transfers energy to a dopant (or an emitter).

In one or more embodiments, the first compound in Second embodiment may serve as an emitter and also as an auxiliary dopant that transfers energy to a dopant (or an emitter).

For example, phosphorescence or fluorescence emitted from the dopant (or the emitter) in Second embodiment may be blue phosphorescence or blue fluorescence (for example, blue delayed fluorescence).

The dopant (or the emitter) in Second embodiment may be a suitable phosphorescent dopant material (for example, the organometallic compound represented by Formula 1, the organometallic compound represented by Formula 401, or any combination thereof) or any fluorescent dopant material (for example, the compound represented by Formula 501, the compound represented by Formula 502, the compound represented by Formula 503, or any combination thereof).

The blue light of First embodiment and Second embodiment may have a maximum emission wavelength in a range of about 430 nm to about 480 nm, about 430 nm to about 475 nm, about 440 nm to about 475 nm, or about 455 nm to about 470 nm.

The auxiliary dopant of First embodiment may include, for example, the fourth compound represented by Formula 502 or Formula 503.

The host of First embodiment and Second embodiment may be any suitable host material (for example, the compound represented by Formula 301, the compound represented by 301-1, the compound represented by Formula 301-2, or any combination thereof).

In one or more embodiments, the host of First embodiment and Second embodiment may be the second compound, the third compound, or any combination thereof.

According to one or more embodiments of the present disclosure, there is provided an electronic apparatus including the light-emitting device. The electronic apparatus may further include a thin-film transistor. For example, the electronic apparatus may further include a thin-film transistor including a source electrode and a drain electrode, wherein the first electrode of the light-emitting device may be electrically connected (e.g., electrically coupled) to the source electrode or the drain electrode. In one or more embodiments, the electronic apparatus may further include a color filter, a color conversion layer, a touch screen layer, a polarizing layer, or any combination thereof. More details for the electronic apparatus may be the same as described herein.

According to one or more other embodiments of the present disclosure, there is provided the organometallic compound represented by Formula 1, wherein Formula 1 is the same as described herein.

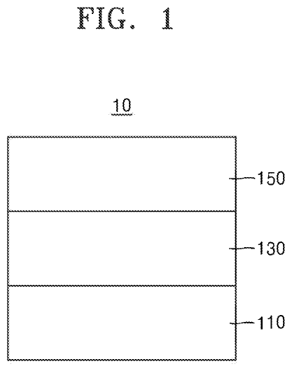

### Description of FIG. 1

FIG. 1 is a schematic cross-sectional view of a light-emitting device 10 according to one or more embodiments. The light-emitting device 10 includes a first electrode 110, an interlayer 130, and a second electrode 150.

Hereinafter, the structure of the light-emitting device 10 according to one or more embodiments and a method of manufacturing the light-emitting device 10 will be described with reference to FIG. 1.

### First Electrode 110

In FIG. 1, a substrate may be additionally arranged under the first electrode 110 or on the second electrode 150. In one or more embodiments, as the substrate, a glass substrate or a plastic substrate may be utilized. In one or more embodiments, the substrate 100 may be a flexible substrate, and for example, may include plastics with excellent or suitable heat resistance and/or durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In one or more embodiments, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layered structure including (e.g., consisting of) a single layer or a multi-layered structure including a plurality of layers. For example, the first electrode 110 may have a three-layered structure of ITO/Ag/ITO.

### Interlayer 130

The interlayer 130 is arranged on the first electrode 110. The interlayer 130 may include an emission layer.

The interlayer 130 may further include a hole transport region between the first electrode 110 and the emission layer, and an electron transport region between the emission layer and the second electrode 150.

The interlayer 130 may further include, in addition to one or more suitable organic materials, a metal-containing compound (such as an organometallic compound), an inorganic material (such as a quantum dot), and/or the like.

In one or more embodiments, the interlayer 130 may include: i) two or more emitting units sequentially stacked between the first electrode 110 and the second electrode 150; and ii) a charge generation layer arranged between the two or more emitting units. When the interlayer 130 includes two or more emitting units and the charge generation layer as described above, the light-emitting device 10 may be a tandem light-emitting device.

### Hole Transport Region in Interlayer 130

The hole transport region may have: i) a single-layered structure including (e.g., consisting of) a single layer including (e.g., consisting of) a single material; ii) a single-layered structure including (e.g., consisting of) a single layer including (e.g., consisting of) a plurality of different materials; or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein constituent layers of each structure are stacked sequentially from the first electrode 110.

The hole transport region may include a compound represented by Formula 201, a compound represented by Formula 202, or any combination thereof:

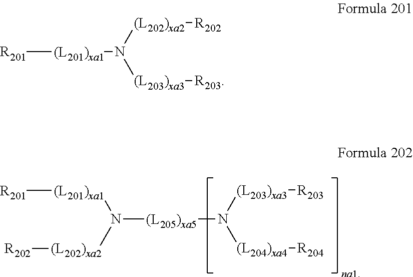

In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and 0201 may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group and/or the like) unsubstituted or substituted with at least one R₁₀ₐ(for example, Compound HT16),

R₂₀₃ and R₂₀₄ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

For example, each of Formulae 201 and 202 may include at least one of groups represented by Formulae CY201 to CY217:

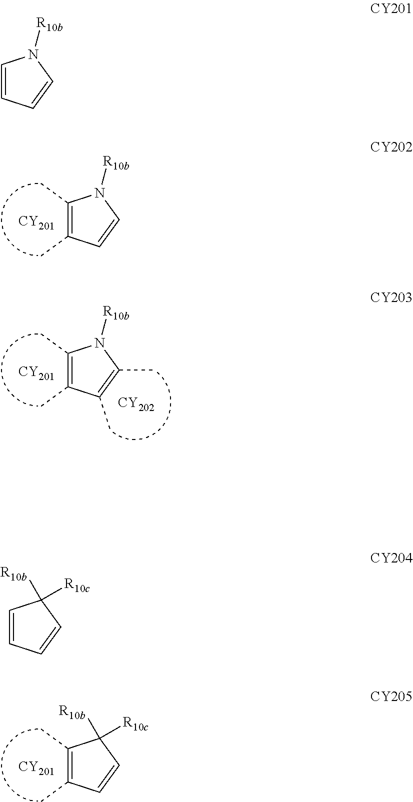

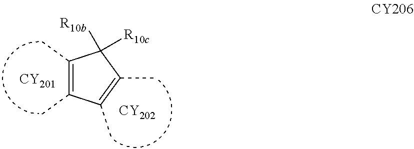

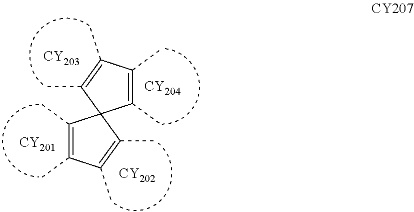

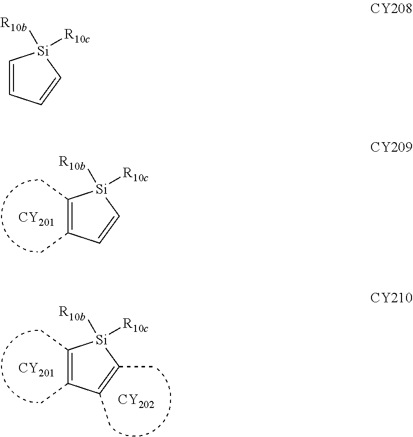

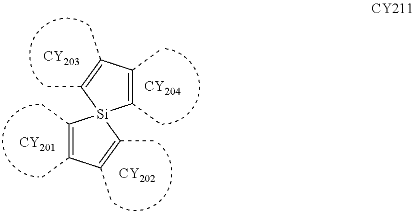

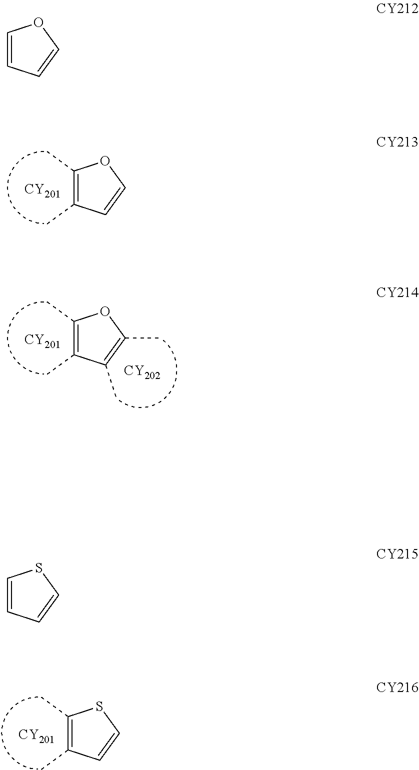

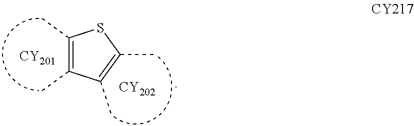

In Formulae CY201 to CY217, R_{10b} and R_{10c} may each be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In one or more embodiments, ring CY201 to ring CY204 in Formulae CY201 to CY217 may each independently be a benzene group, a naphthalene group, a phenanthrene group, or an anthracene group.

In one or more embodiments, each of Formulae 201 and 202 may include at least one of groups represented by Formulae CY201 to CY203.

In one or more embodiments, Formula 201 may include at least one of groups represented by Formulae CY201 to CY203 and at least one of groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include (e.g., may exclude) groups represented by Formulae CY201 to CY203.

In one or more embodiments, each of Formulae 201 and 202 may not include (e.g., may exclude) groups represented by Formulae CY201 to CY203, and may include at least one of groups represented by Formulae CY204 to CY217.

In one or more embodiments, each of Formulae 201 and 202 may not include (e.g., may exclude) groups represented by Formulae CY201 to CY217.

In one or more embodiments, the hole transport region may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

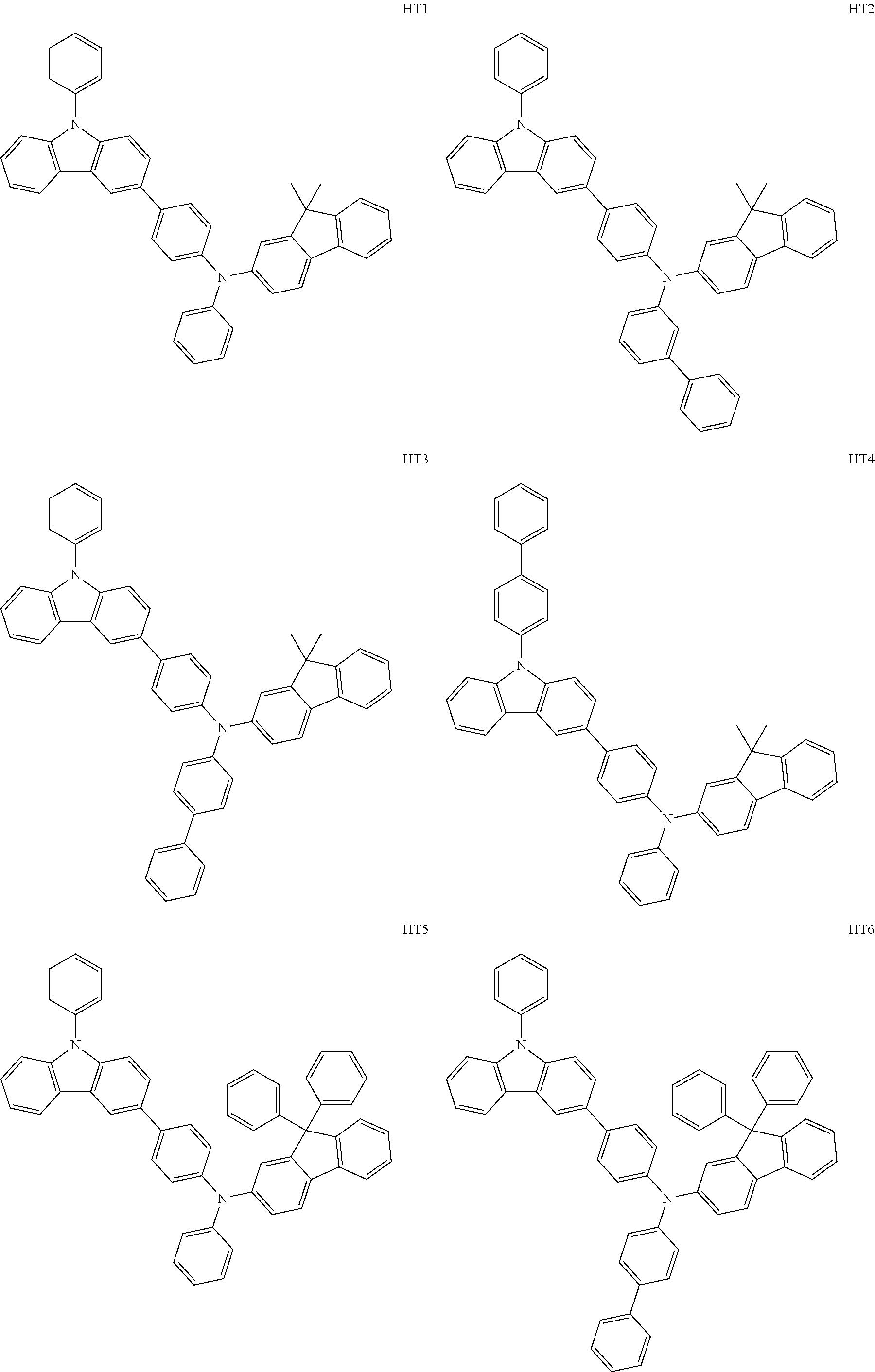

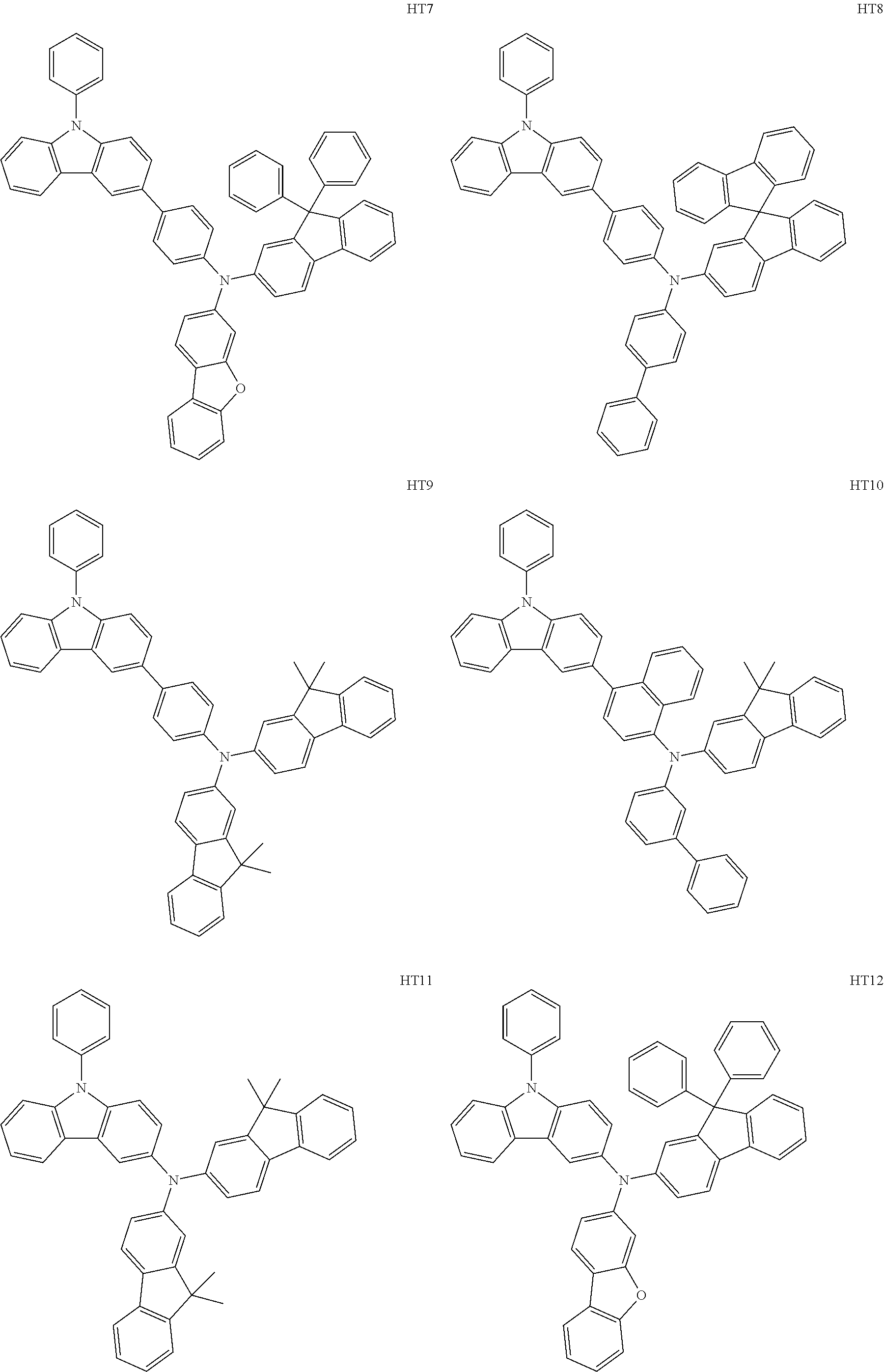

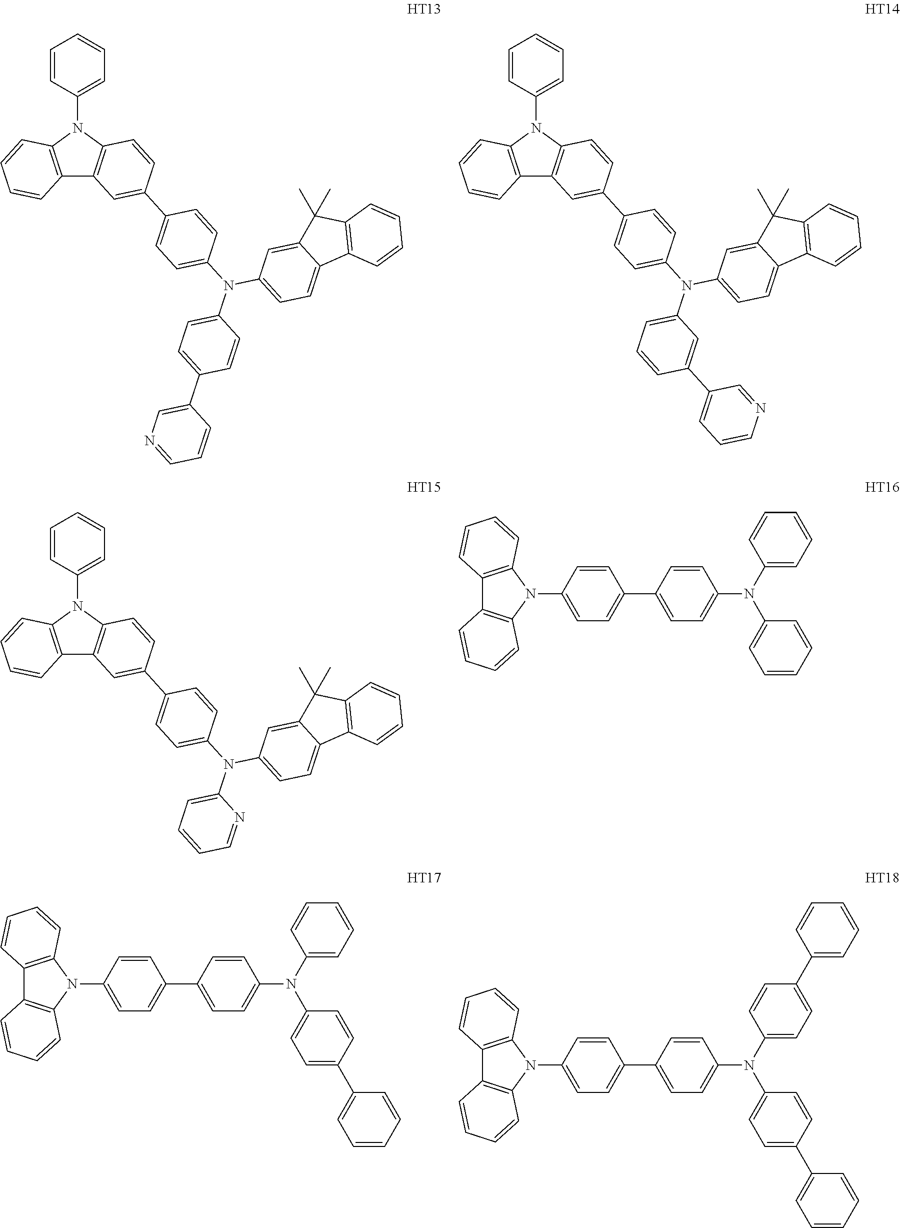 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

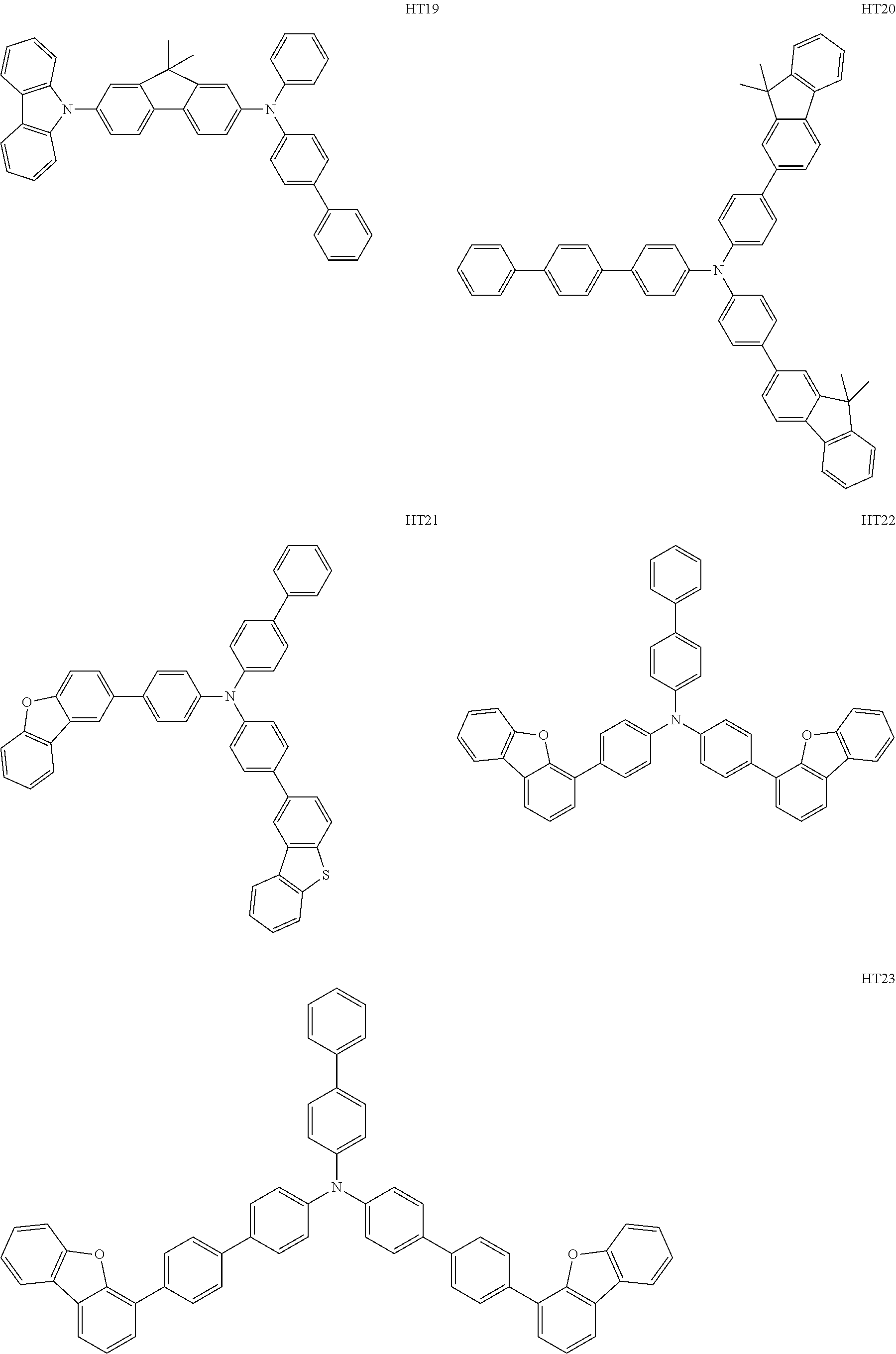 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

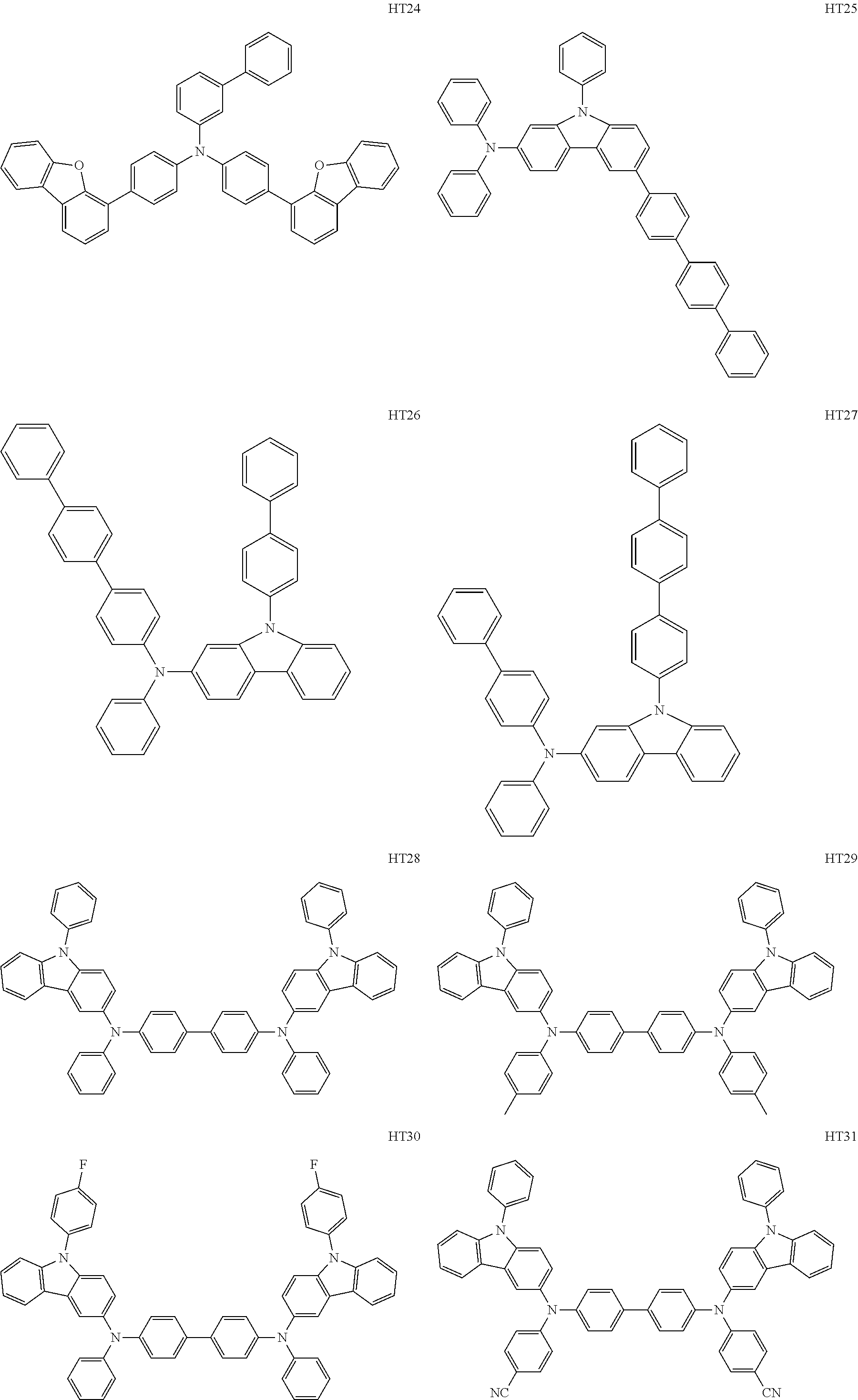

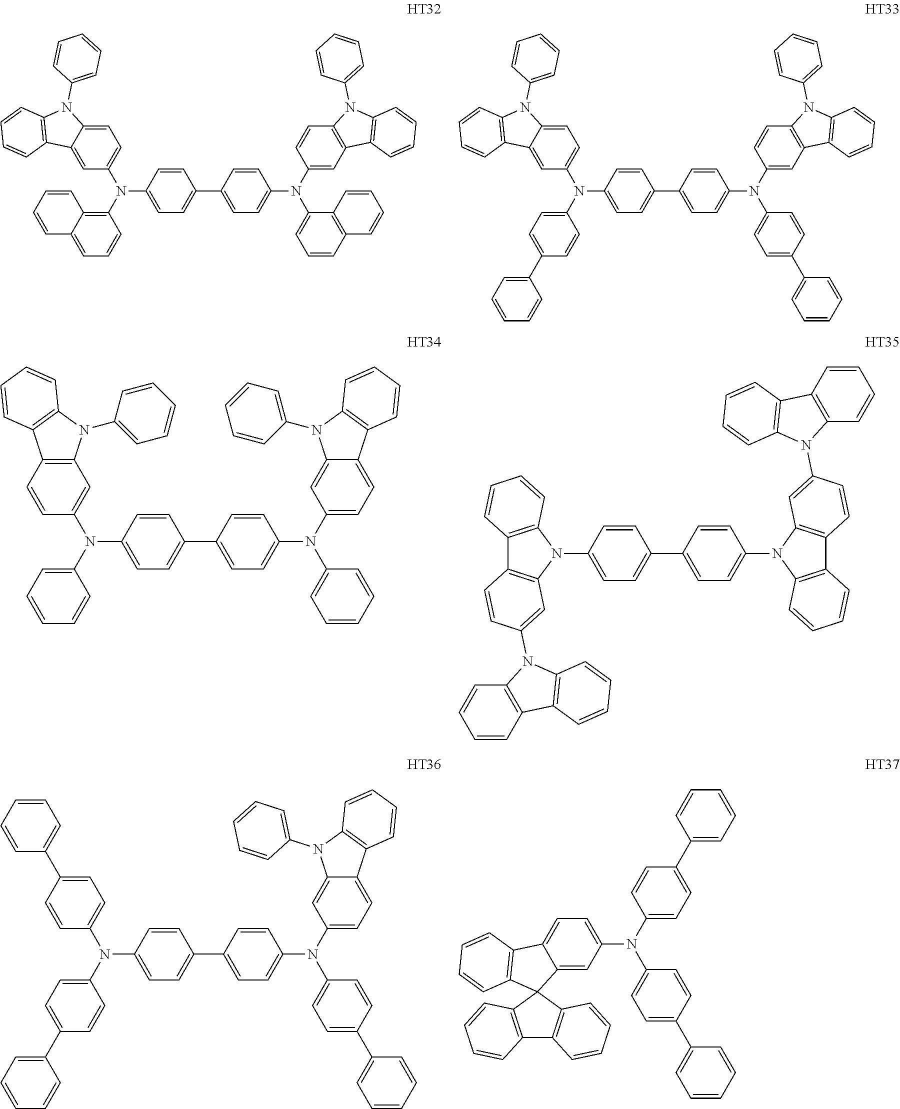

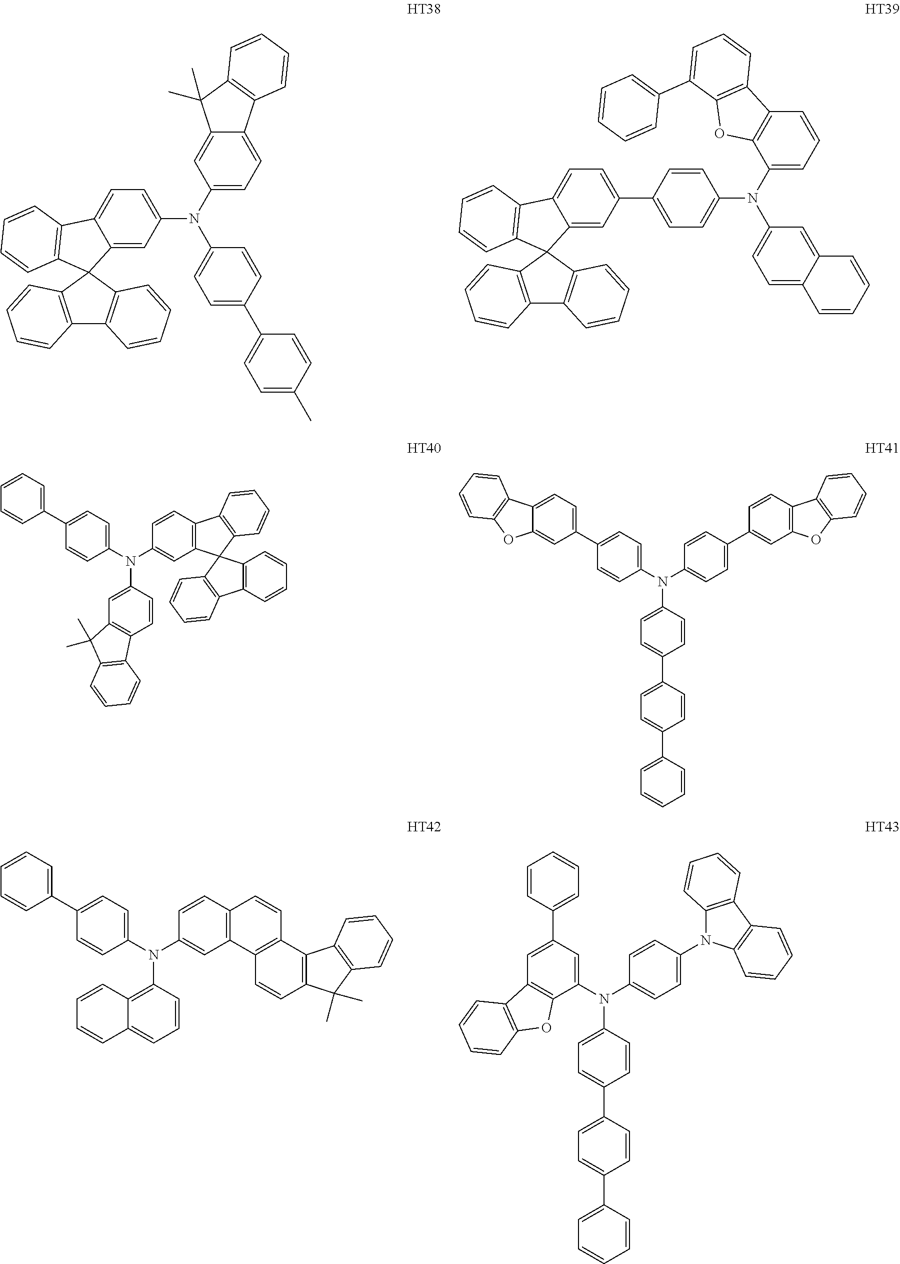

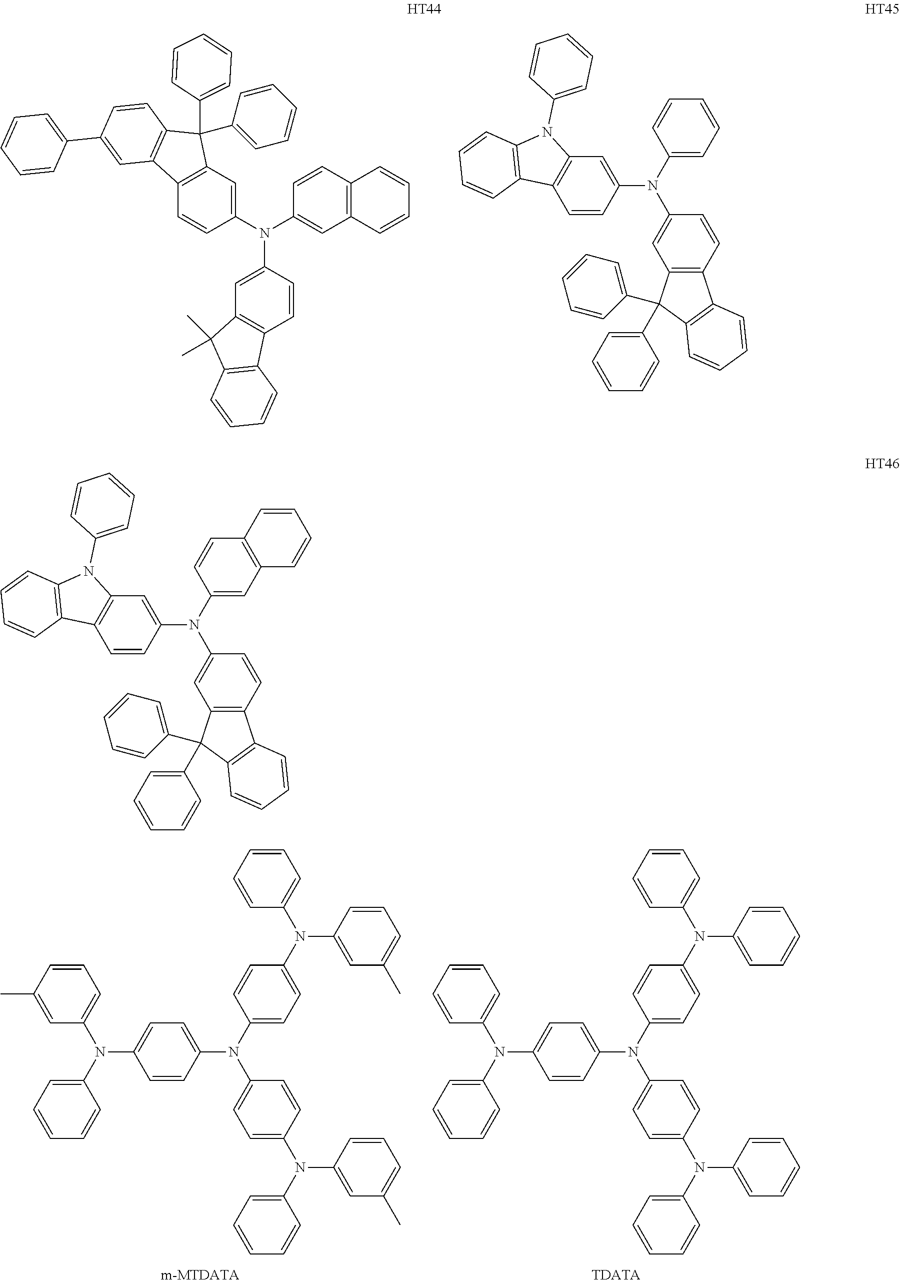

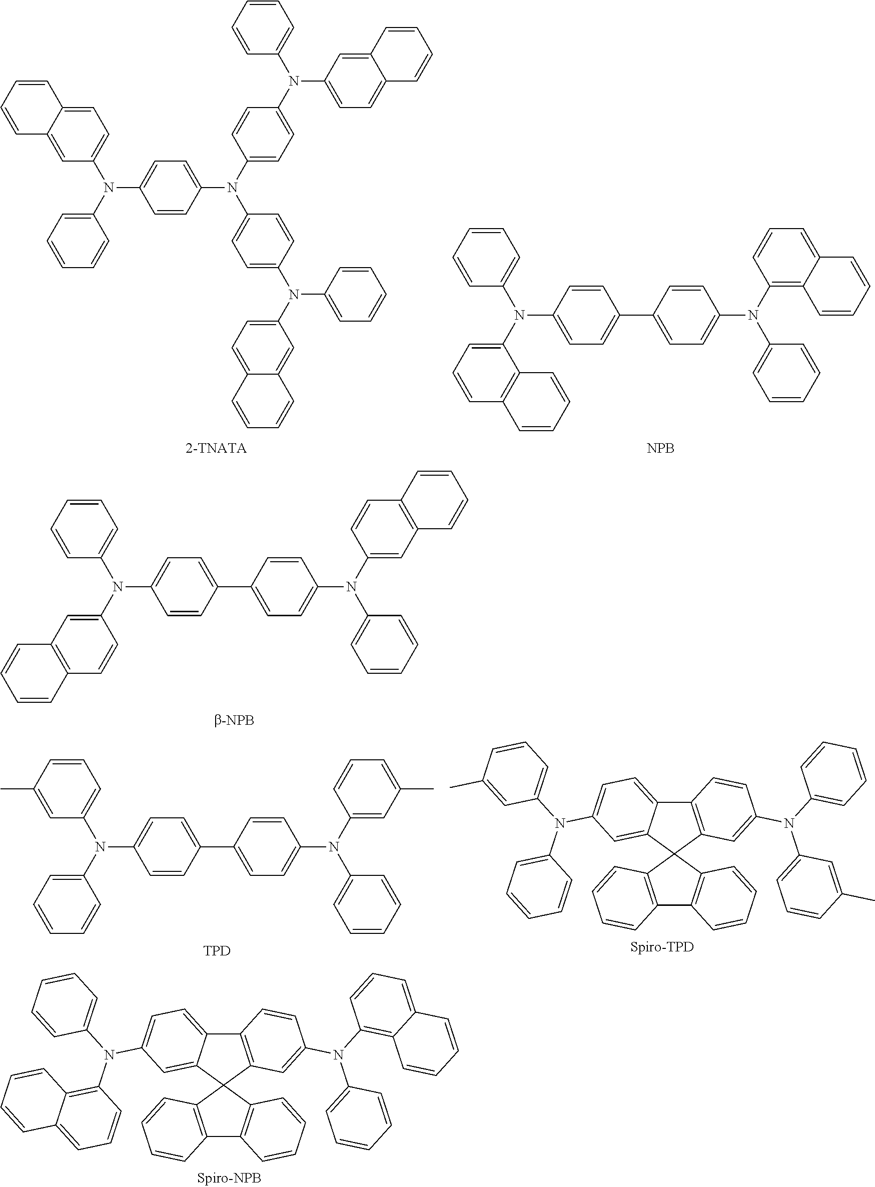

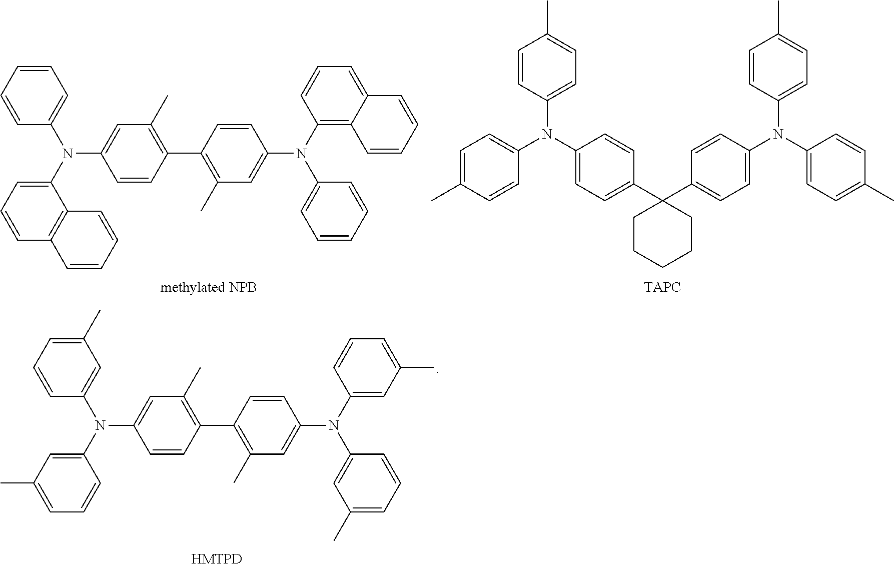

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are each independently within their respective ranges, satisfactory (or suitable) hole transporting characteristics may be obtained without a substantial increase in driving voltage.

The emission auxiliary layer may increase light-emission efficiency by compensating for an optical resonance distance according to the wavelength of light emitted by the emission layer, and the electron blocking layer may block or reduce the leakage of electrons from the emission layer to the hole transport region. Material(s) that may be included in the hole transport region may be included in the emission auxiliary layer and/or the electron-blocking layer.

p-Dopant

The hole transport region may further include, in addition to the materials described above, a charge-generation material for the improvement of conductive properties. The charge-generation material may be uniformly or non-uniformly dispersed in the hole transport region (for example, in the form of a single layer including (e.g., consisting of) a charge-generation material).

The charge-generation material may be, for example, a p-dopant.

For example, a lowest unoccupied molecular orbital (LUMO) energy level of the p-dopant may be about −3.5 eV or less.

In one or more embodiments, the p-dopant may include a quinone derivative, a cyano group-containing compound, a compound including element EL1 and element EL2, or any combination thereof.

Examples of the quinone derivative may include TCNQ, F4-TCNQ, and the like.

Examples of the cyano group-containing compound may include HAT-CN, a compound represented by Formula 221, and the like:

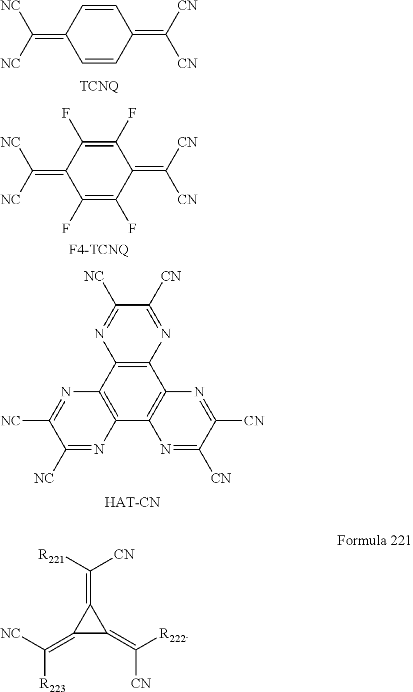

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be metal, metalloid, or any combination thereof, and element EL2 may be non-metal, metalloid, or any combination thereof.

Examples of the metal may include an alkali metal (for example, lithium (Li), sodium (Na), potassium (K), rubidium (Rb), cesium (Cs), and/or the like); alkaline earth metal (for example, beryllium (Be), magnesium (Mg), calcium (Ca), strontium (Sr), barium (Ba), and/or the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (for example, zinc (Zn), indium (In), tin (Sn), and/or the like); lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and the like.

Examples of the metalloid may include silicon (Si), antimony (Sb), tellurium (Te), and the like.

Examples of the non-metal may include oxygen (O), halogen (for example, F, Cl, Br, I, and/or the like), and the like.

Examples of the compound including element EL1 and element EL2 may include metal oxide, metal halide (for example, metal fluoride, metal chloride, metal bromide, metal iodide, and/or the like), metalloid halide (for example, metalloid fluoride, metalloid chloride, metalloid bromide, metalloid iodide, and/or the like), metal telluride, and combinations thereof.

Examples of the metal oxide may include tungsten oxide (for example, WO, W₂O₃, WO₂, WO₃, W₂O₅, and/or the like), vanadium oxide (for example, VO, V₂O₃, VO₂, V₂O₅, and/or the like), molybdenum oxide (MoO, Mo₂O₃, MoO₂, MoO₃, Mo₂O₅, and/or the like), rhenium oxide (for example, ReO₃ and/or the like), and the like.

Examples of the metal halide may include alkali metal halide, alkaline earth metal halide, transition metal halide, post-transition metal halide, lanthanide metal halide, and the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of the transition metal halide may include titanium halide (for example, TiF₄, TiCl₄, TiBr₄, TiI₄, and/or the like), zirconium halide (for example, ZrF₄, ZrCl₄, ZrBr₄, ZrI₄, and/or the like), hafnium halide (for example, HfF₄, HfCl₄, HfBr₄, HfI₄, and/or the like), vanadium halide (for example, VF₃, VCl₃, VBr₃, VI₃, and/or the like), niobium halide (for example, NbF₃, NbCl₃, NbBr₃, NbI₃, and/or the like), tantalum halide (for example, TaF₃, TaCl₃, TaBr₃, TaI₃, and/or the like), chromium halide (for example, CrF₃, CrCl₃, CrBr₃, CrI₃, and/or the like), molybdenum halide (for example, MoF₃, MoCl₃, MoBr₃, MoI₃, and/or the like), tungsten halide (for example, WF₃, WCl₃, WBr₃, WI₃, and/or the like), manganese halide (for example, MnF₂, MnCl₂, MnBr₂, MnI₂, and/or the like), technetium halide (for example, TcF₂, TcCl₂, TcBr₂, TcI₂, and/or the like), rhenium halide (for example, ReF₂, ReCl₂, ReBr₂, Re₁₂, and/or the like), iron halide (for example, FeF₂, FeCl₂, FeBr₂, Fe₁₂, and/or the like), ruthenium halide (for example, RuF₂, RuCl₂, RuBr₂, Rul₂, and/or the like), osmium halide (for example, OsF₂, OsCl₂, OsBr₂, Os₁₂, and/or the like), cobalt halide (for example, CoF₂, CoCl₂, CoBr₂, CoI₂, and/or the like), rhodium halide (for example, RhF₂, RhCl₂, RhBr₂, RhI₂, and/or the like), iridium halide (for example, IrF₂, IrCl₂, IrBr₂, IrI₂, and/or the like), nickel halide (for example, NiF₂, NiCl₂, NiBr₂, NiI₂, and/or the like), palladium halide (for example, PdF₂, PdCl₂, PdBr₂, PdI₂, and/or the like), platinum halide (for example, PtF₂, PtCl₂, PtBr₂, PtI₂, and/or the like), copper halide (for example, CuF, CuCl, CuBr, CuI, and/or the like), silver halide (for example, AgF, AgCl, AgBr, AgI, and/or the like), gold halide (for example, AuF, AuCl, AuBr, AuI, and/or the like), and the like

Examples of the post-transition metal halide may include zinc halide (for example, ZnF₂, ZnCl₂, ZnBr₂, ZnI₂, and/or the like), indium halide (for example, InI₃ and/or the like), tin halide (for example, SnI₂ and/or the like), and the like

Examples of the lanthanide metal halide may include YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, SmI₃, and the like.

Examples of the metalloid halide may include antimony halide (for example, SbCl₅ and/or the like) and the like.

Examples of the metal telluride may include alkali metal telluride (for example, Li₂Te, Na₂Te, K₂Te, Rb₂Te, Cs₂Te, and/or the like), alkaline earth metal telluride (for example, BeTe, MgTe, CaTe, SrTe, BaTe, and/or the like), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, and/or the like), post-transition metal telluride (for example, ZnTe, and/or the like), lanthanide metal telluride (for example, LaTe, CeTe, PrTe, NdTe, PmTe, EuTe, GdTe, TbTe, DyTe, HoTe, ErTe, TmTe, YbTe, LuTe, and/or the like), and the like.

### Emission Layer in Interlayer 130

When the light-emitting device 10 is a full-color light-emitting device, the emission layer may be patterned into a red emission layer, a green emission layer, and/or a blue emission layer, according to a subpixel. In one or more embodiments, the emission layer may have a stacked structure in which two or more layers among a red emission layer, a green emission layer, and a blue emission layer contact each other or are separated from each other to emit white light. In one or more embodiments, the emission layer may have a structure in which two or more materials selected from among a red light-emitting material, a green light-emitting material, and a blue light-emitting material are mixed with each other in a single layer to emit white light.

In one or more embodiments, the emission layer may include a host and a dopant. The dopant may include a phosphorescent dopant, a fluorescent dopant, or any combination thereof.

An amount of the dopant included in the emission layer may be in a range of about 0.01 part by weight to about 15 parts by weight based on 100 parts by weight of the host.

In one or more embodiments, the emission layer may include a quantum dot.

In one or more embodiments, the emission layer may include a delayed fluorescence material. The delayed fluorescence material may act as the host or the dopant in the emission layer.

A thickness of the emission layer may be in a range of about 100 Å to about 1,000 Å, for example, about 200 Å to about 600 Å. When the thickness of the emission layer is within any of these ranges, excellent or suitable luminescence characteristics may be obtained without a substantial increase in driving voltage.

### Host

The host in the emission layer may include the second compound or the third compound described in the present specification, or any combination thereof.

In one or more embodiments, the host may include a compound represented by Formula 301:

[Ar₃₀₁]_{xb11}-[(L₃₀₁)_{xb1}-R₃₀₁]_{xb21}, Formula 301

wherein, in Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ may each be the same as described in connection with Q₁.

For example, when xb11 in Formula 301 is 2 or more, two or more of Ar₃₀₁ may be bonded together via a single bond.

In one or more embodiments, the host may include a compound represented by Formula 301-1, a compound represented by Formula 301-2, or any combination thereof:

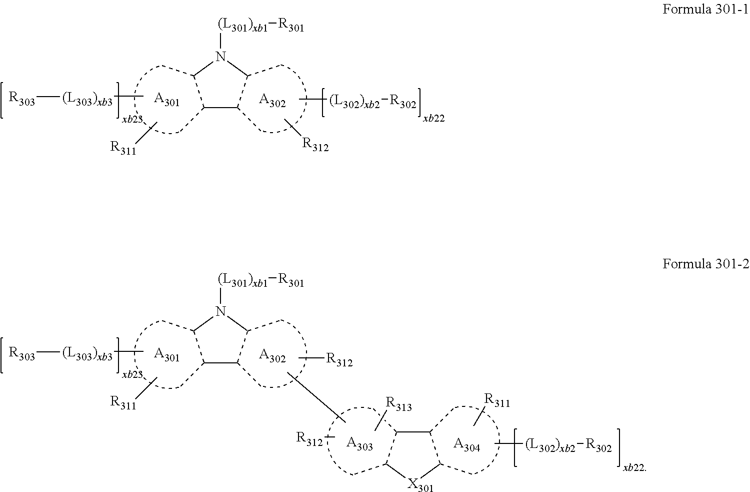

In Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄)_{xb4}-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ may each be the same as described herein,

L₃₀₂ to L₃₀₄ may each independently be the same as described in connection with L₃₀₁,

xb2 to xb4 may each independently be the same as described in connection with xb1, and

R₃₀₂ to R₃₀₅ and R₃₁₁ to R₃₁₄ may each be the same as described in connection with R₃₀₁.

In one or more embodiments, the host may include an alkali earth metal complex, a post-transition metal complex, or any combination thereof. In one or more embodiments, the host may include a Be complex (for example, Compound H55), an Mg complex, a Zn complex, or any combination thereof.

In one or more embodiments, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

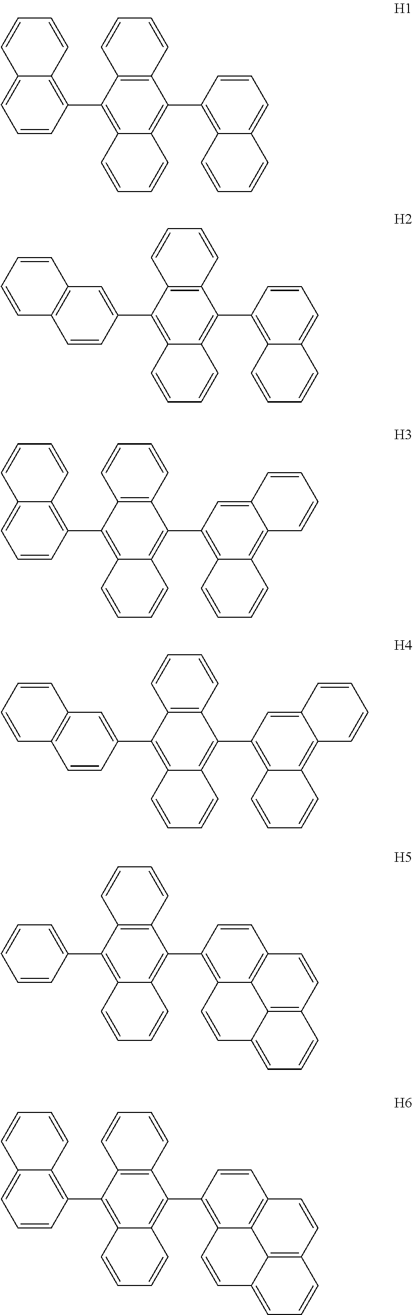

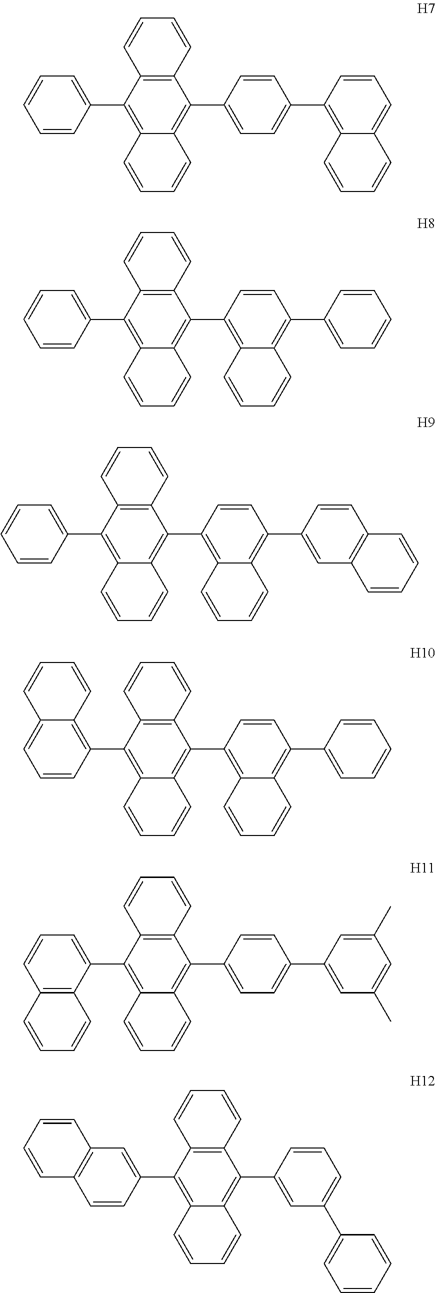

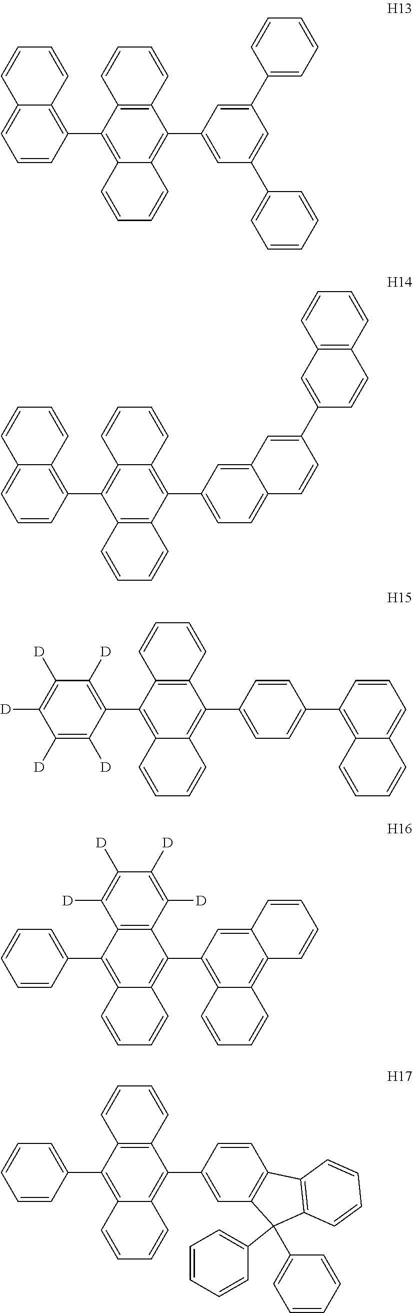

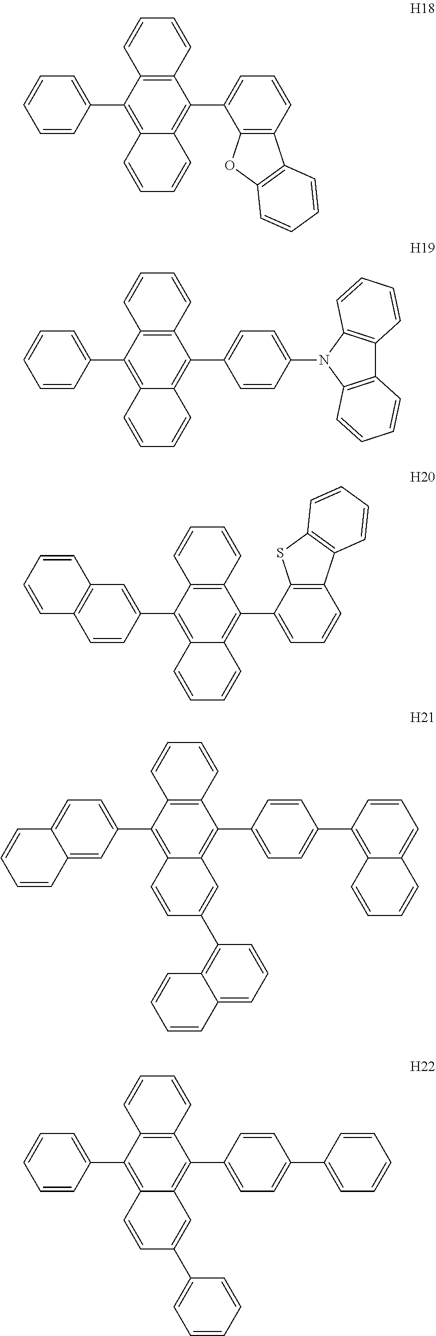

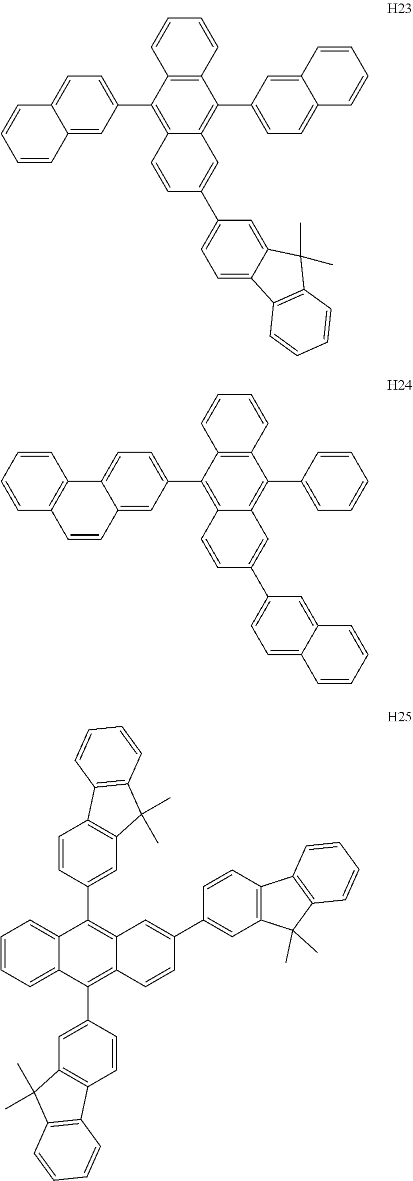

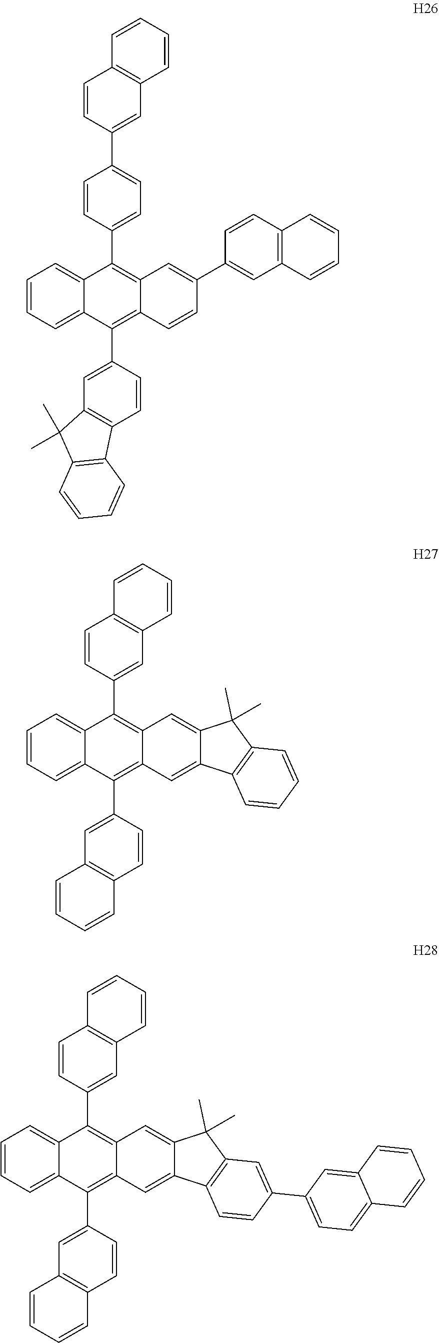

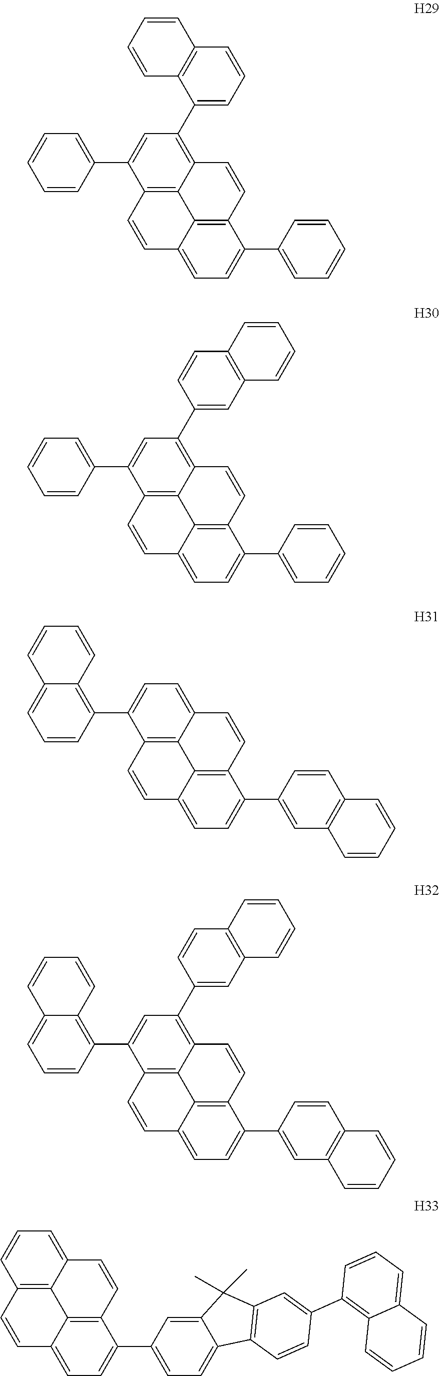

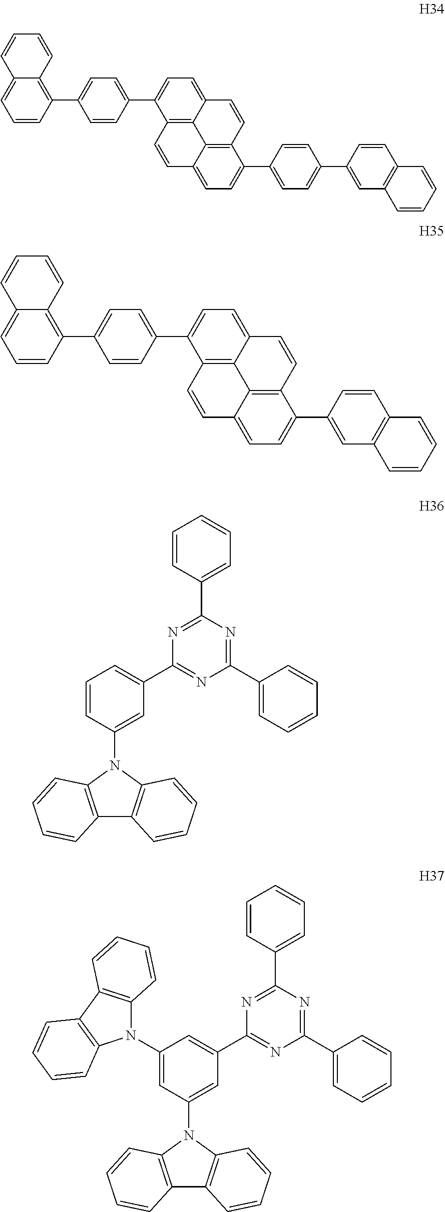

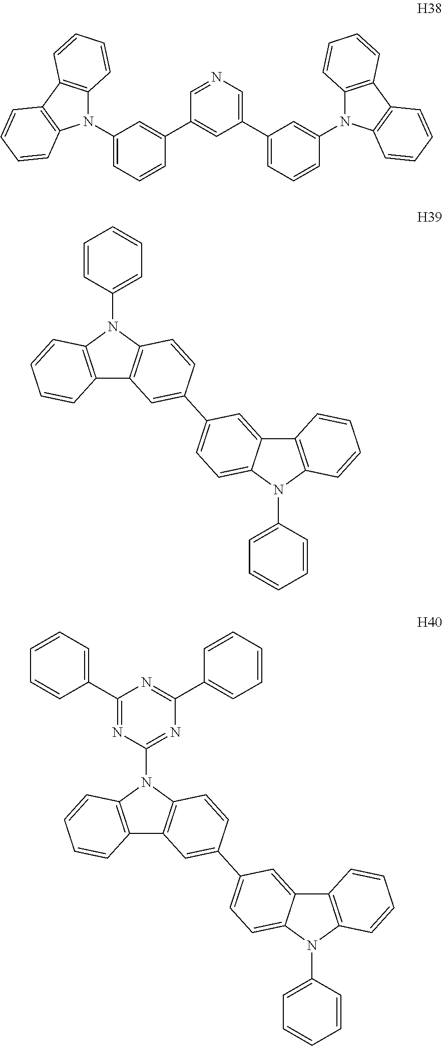 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

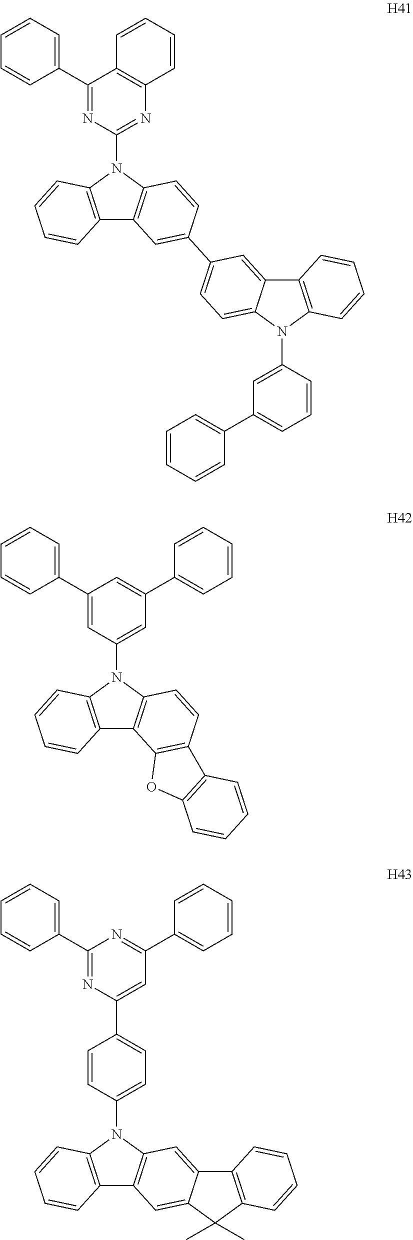 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

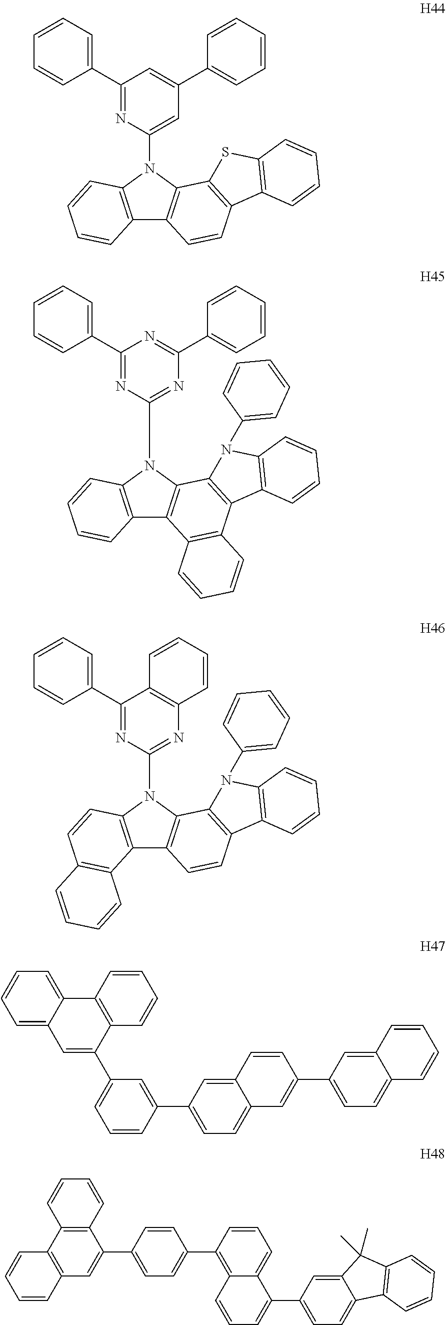

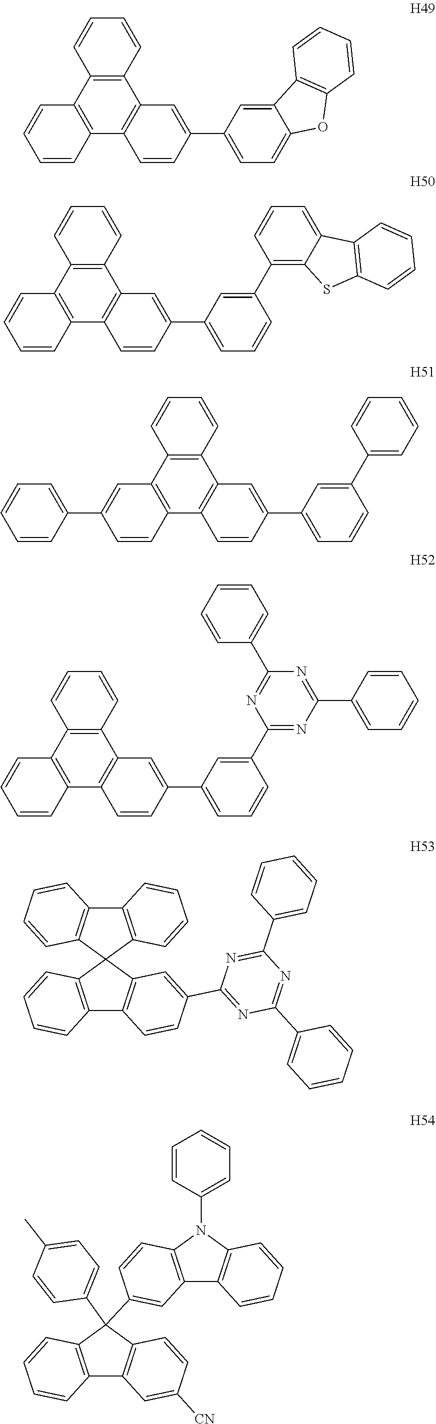

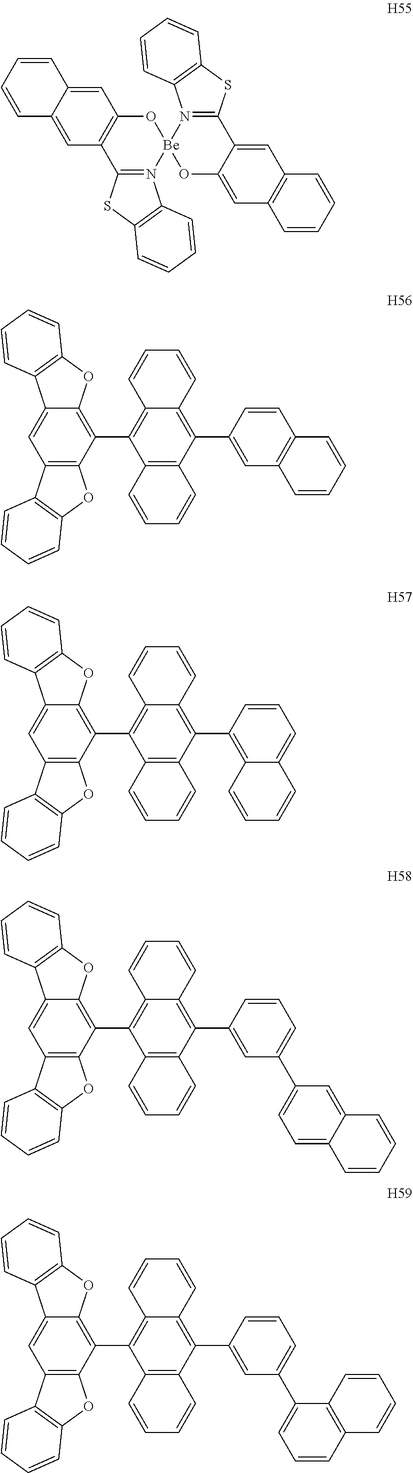

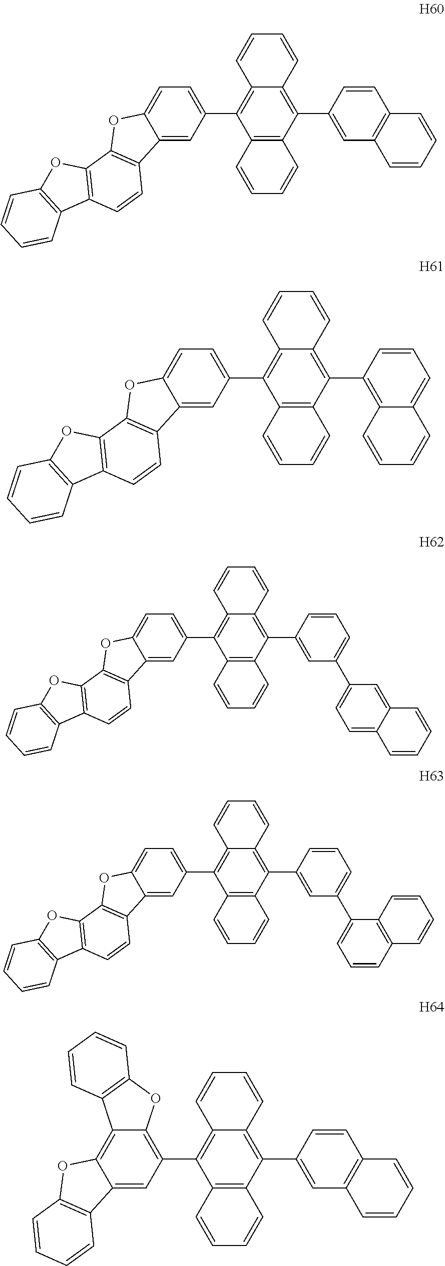 [SMILES: c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

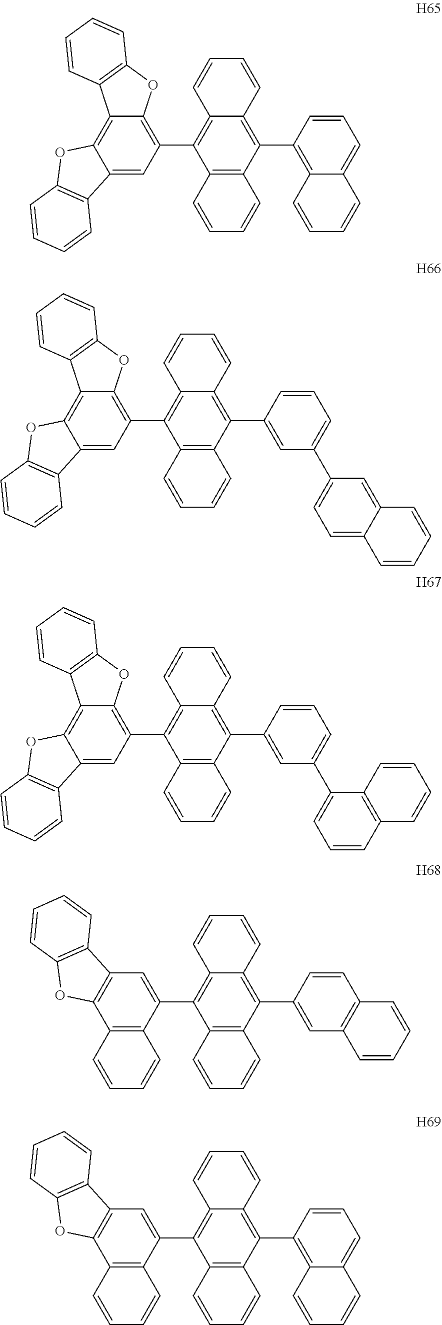

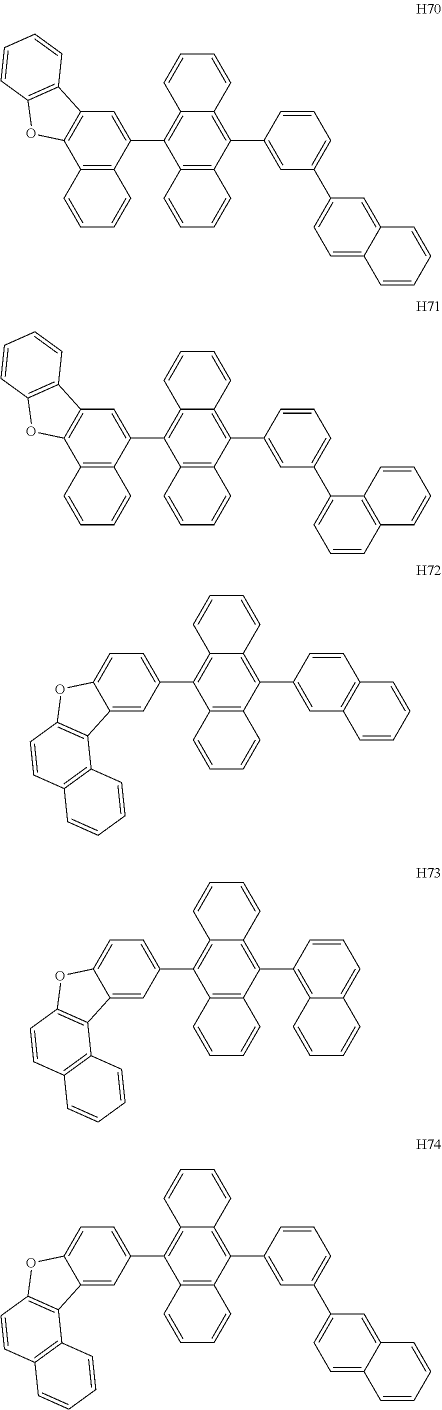 [SMILES: c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1]

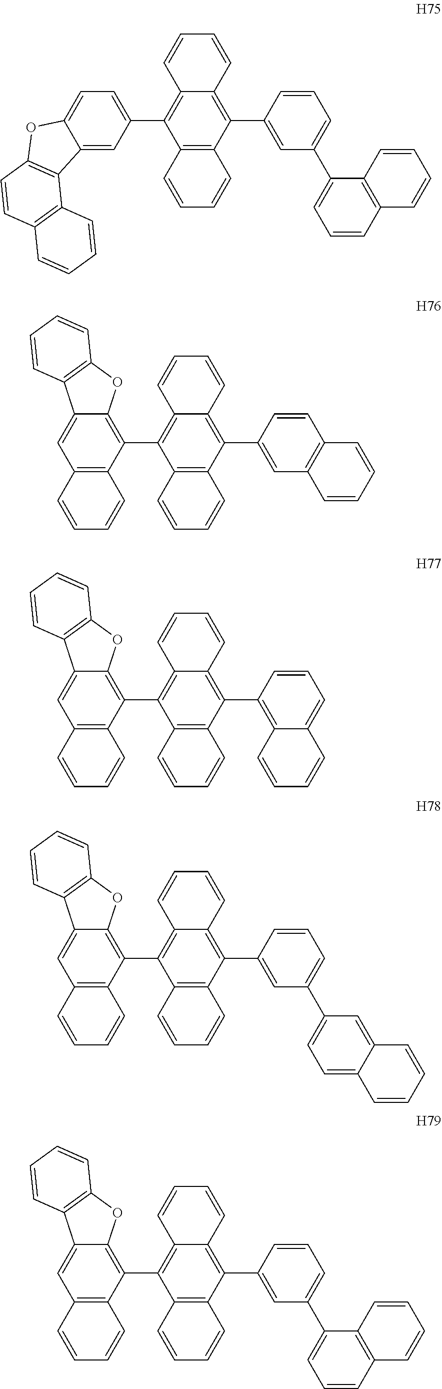

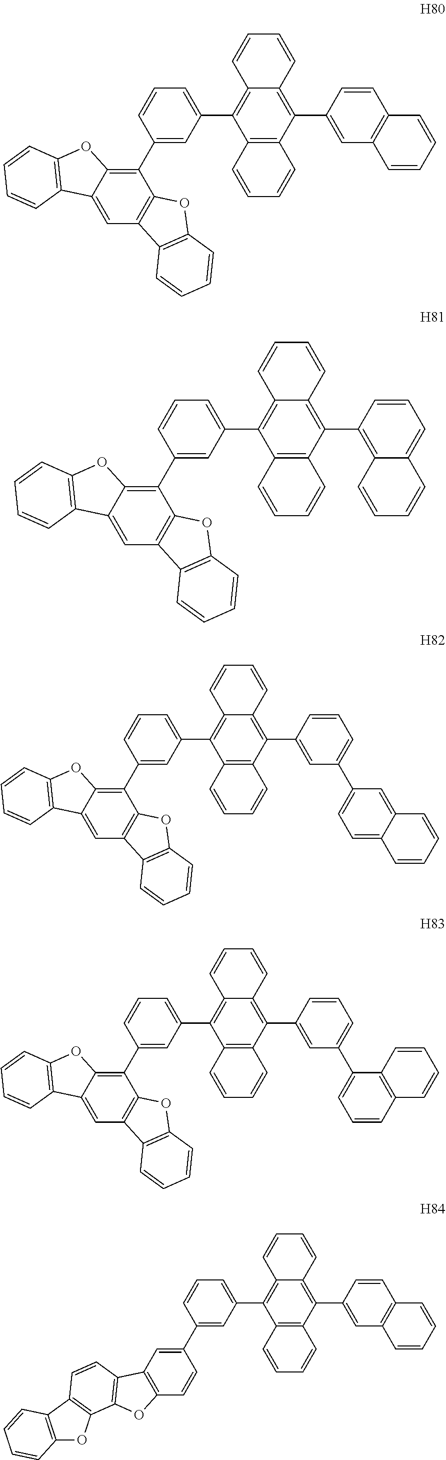 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1]

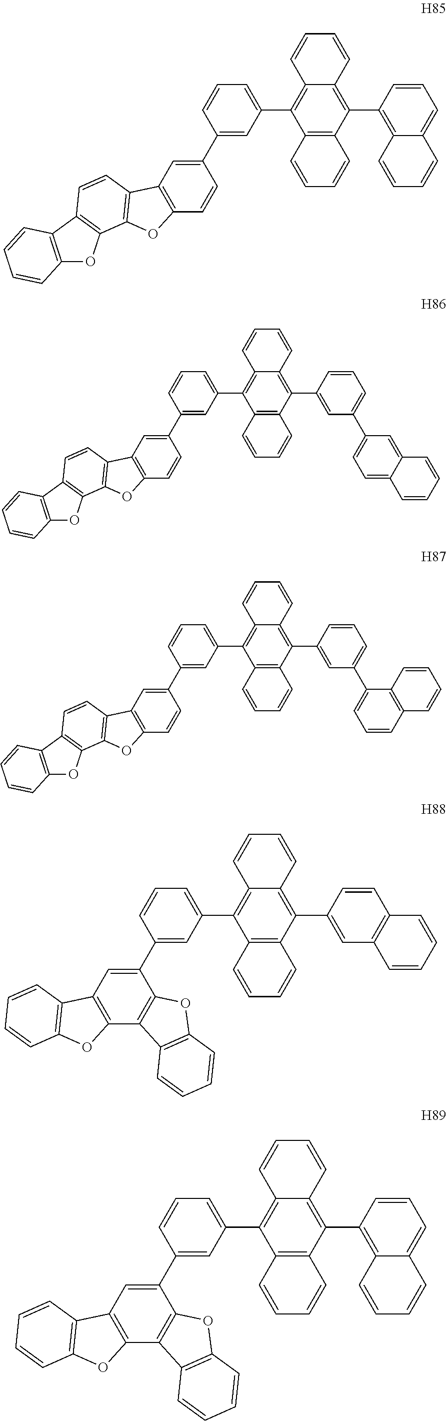 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1]

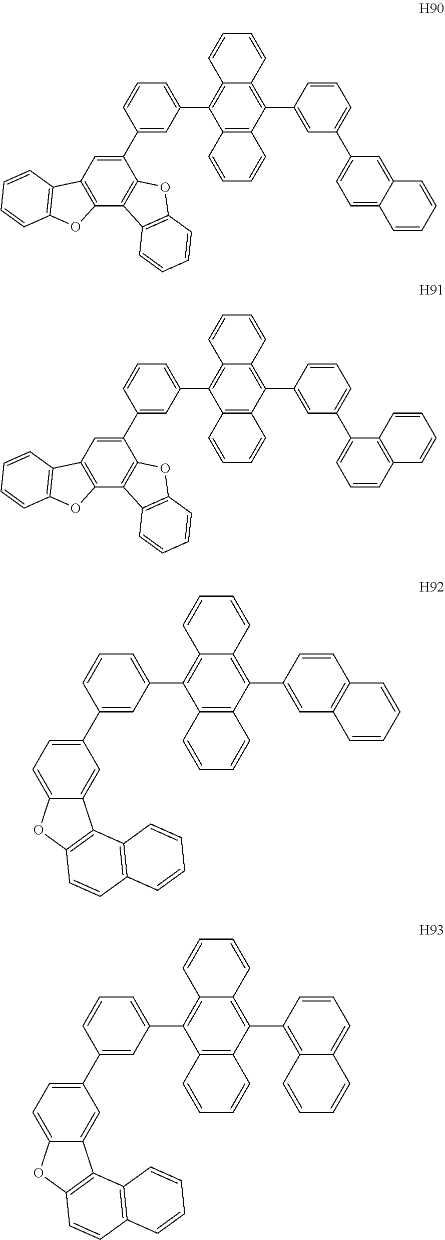 [SMILES: c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1]

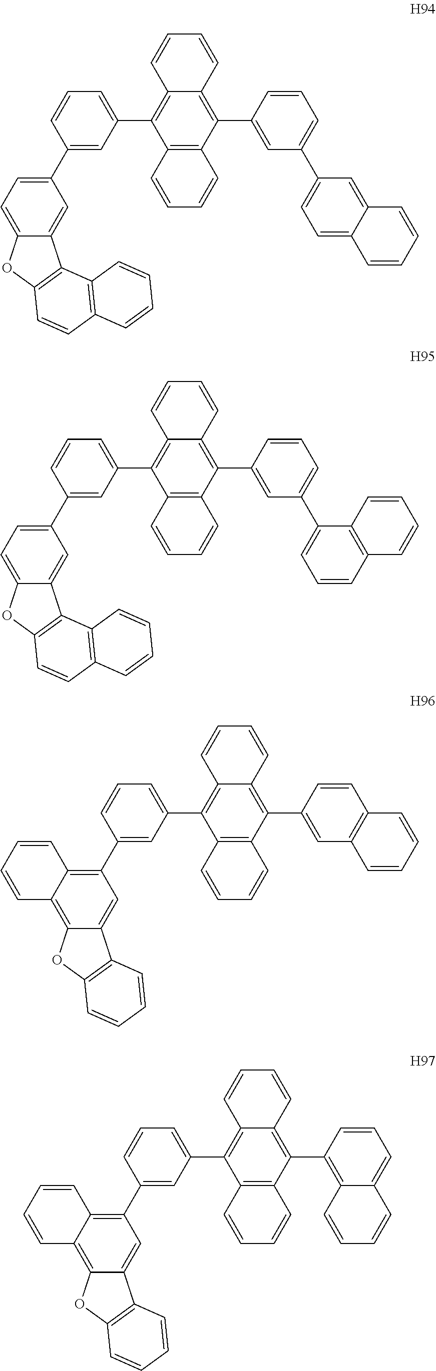 [SMILES: c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1]

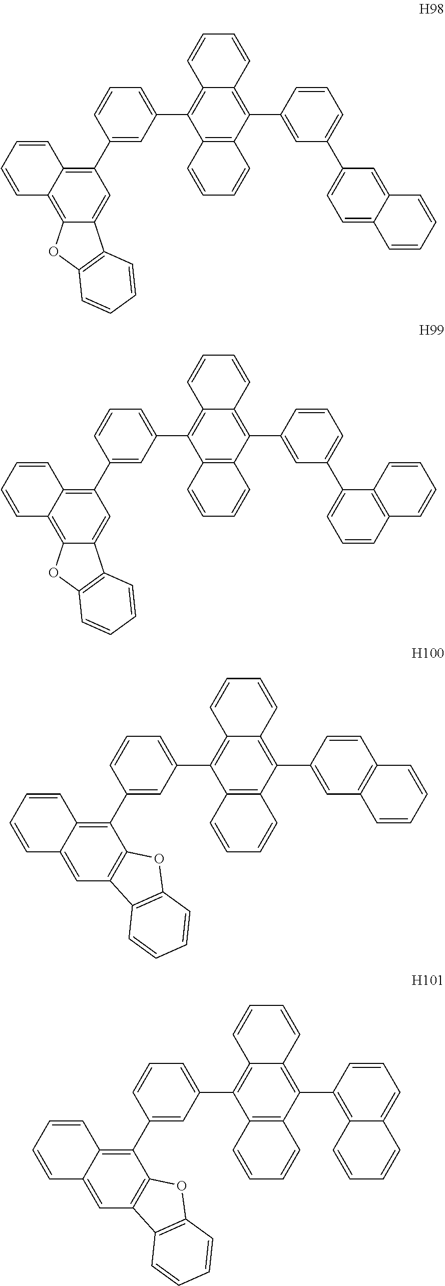 [SMILES: c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1 ; c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1]

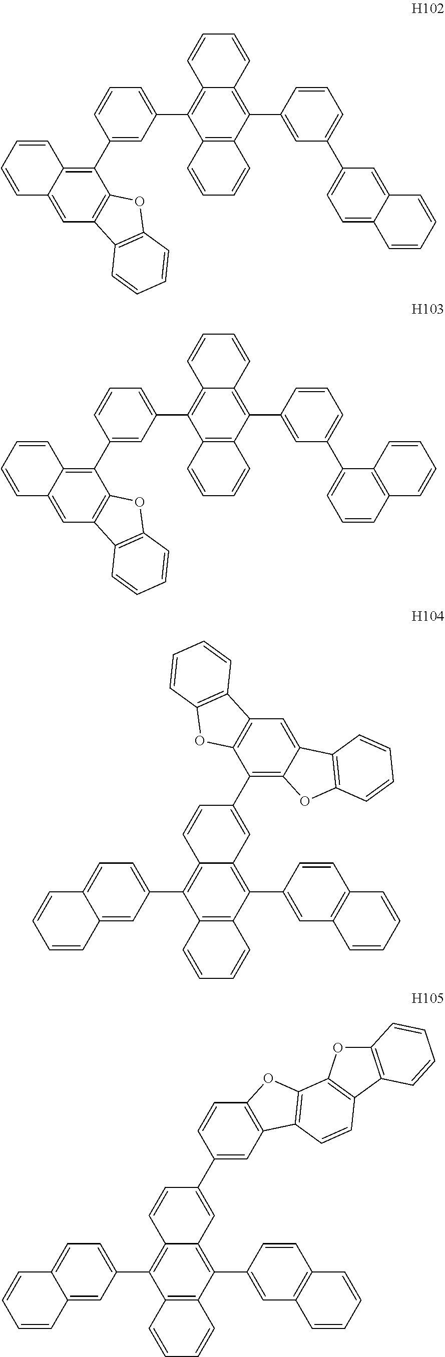 [SMILES: c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1]

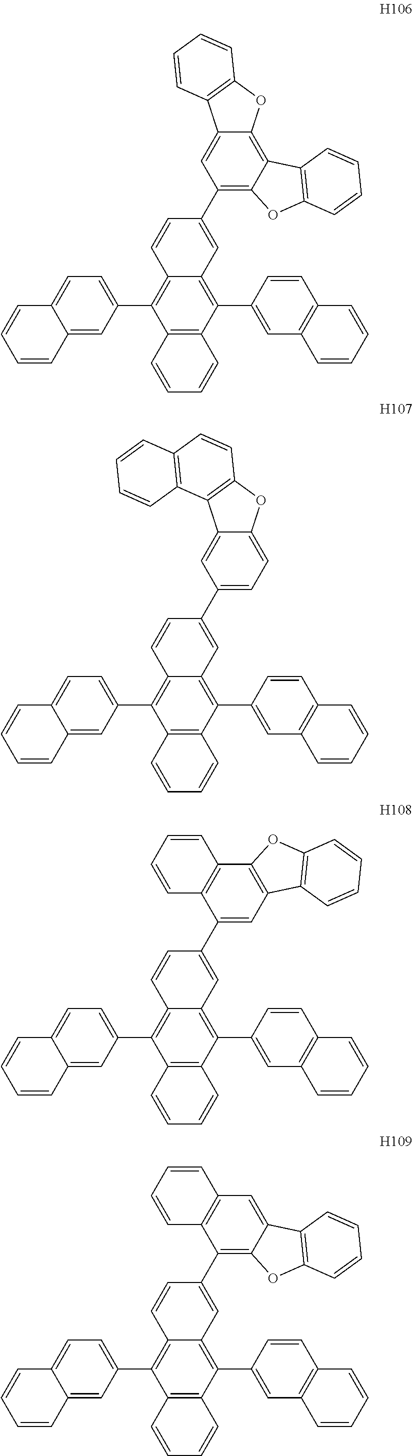

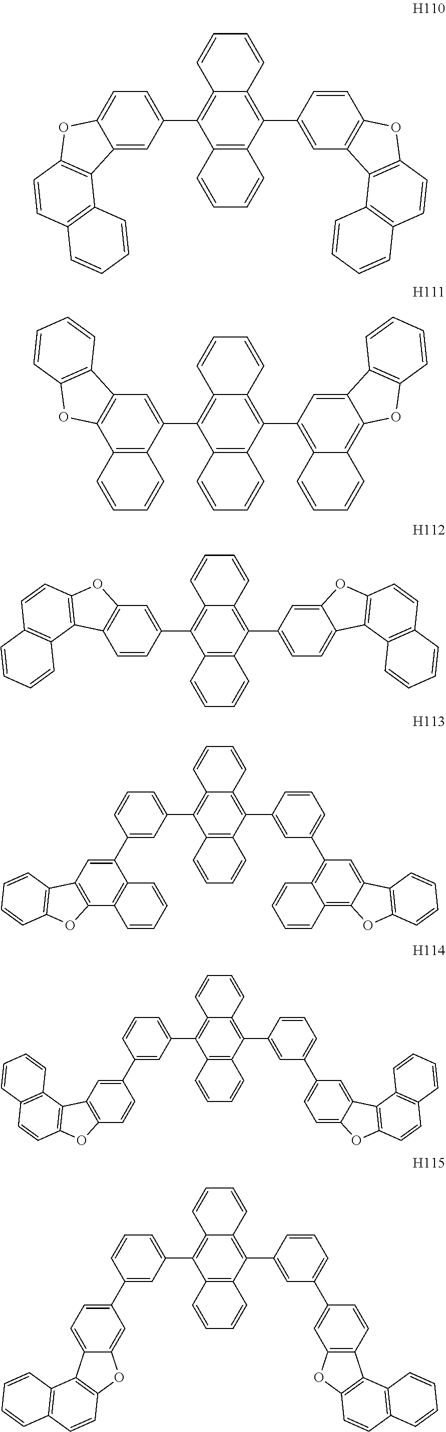

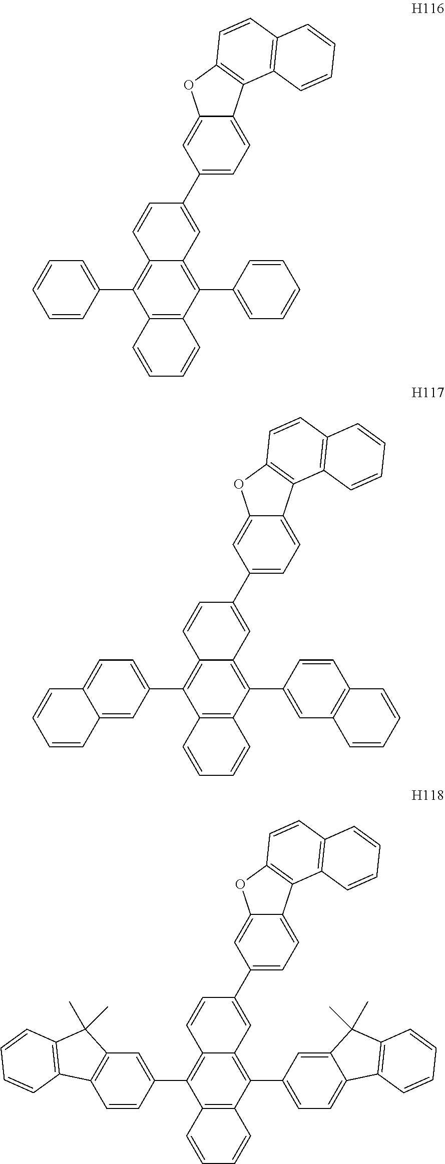 [SMILES: c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

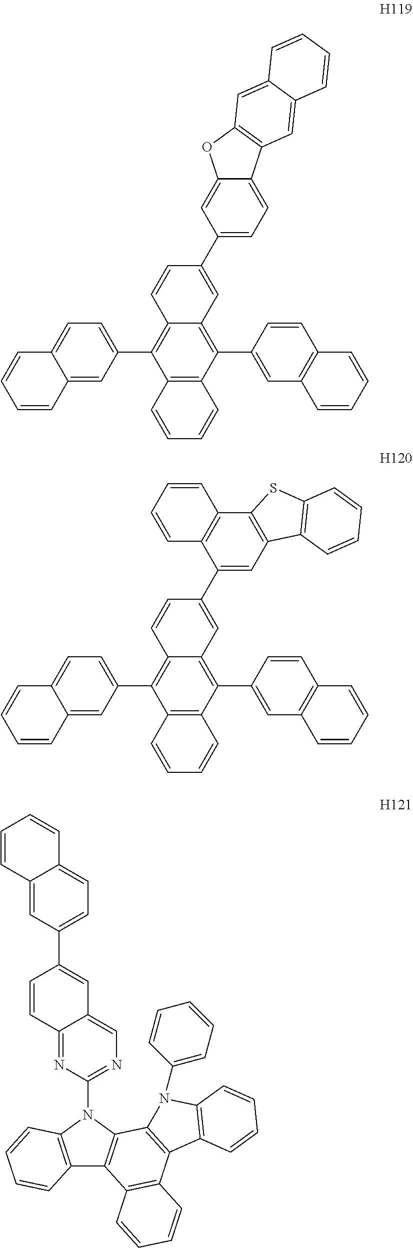

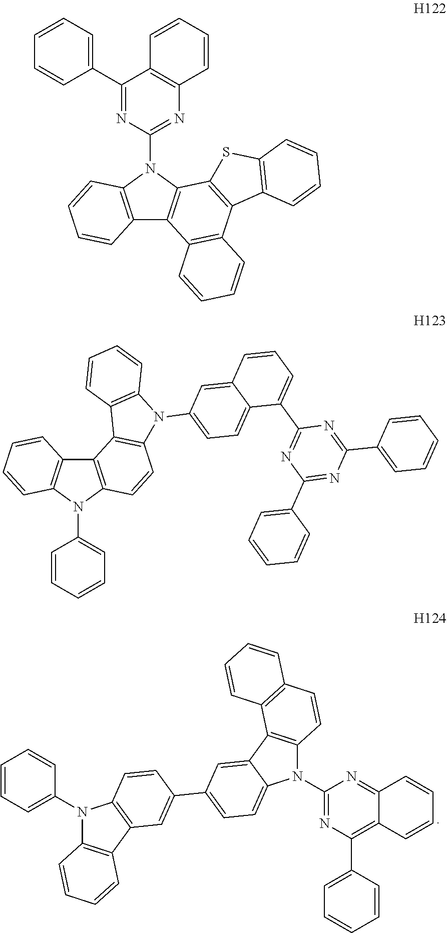 [SMILES: c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

In one or more embodiments, the host may include a silicon-containing compound, a phosphine oxide-containing compound, or any combination thereof.

The host may have one or more suitable modifications. For example, the host may include only one kind of compound, or may include two or more kinds of different compounds.

### Phosphorescent Dopant

In one or more embodiments, the emission layer may include the first compound as a phosphorescent dopant.

In one or more embodiments, when the emission layer includes the first compound and the first compound serves as an auxiliary dopant, the emission layer may further include a phosphorescent dopant different from the first compound.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, the phosphorescent dopant may include an organometallic compound represented by Formula 401:

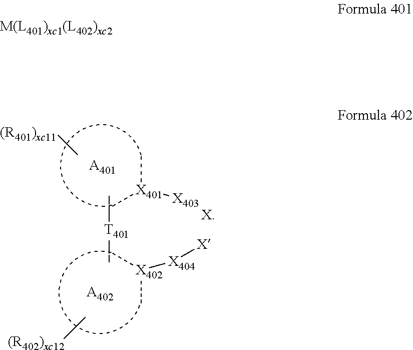

In Formulae 401 and 402,

M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), and/or thulium (Tm)),

L₄₀₁ may be a ligand represented by Formula 402, and xc1 may be 1, 2, or 3, wherein, when xc1 is 2 or more, two or more of L₄₀₁ may be identical to or different from each other,

L₄₀₂ may be an organic ligand, and xc2 may be 0, 1, 2, 3, or 4, wherein, when xc2 is 2 or more, two or more of L₄₀₂ may be identical to or different from each other,

X₄₀₁ and X₄₀₂ may each independently be nitrogen or carbon,

ring A₄₀₁ and ring A₄₀₂ may each independently be a C₃-C₆₀ carbocyclic group or a C₁-C₆₀ heterocyclic group,

T₄₀₁ may be a single bond, *—O—*′, *—S—*′, *—C(═O)—*′, *—N(Q₄₁₁)-*′, *—C(Q₄₁₁)(Q₄₁₂)*′, *—C(Q₄₁₁)=C(Q₄₁₂)-*′, *—C(Q₄₁₁)=*′, or *═C(Q₄₁₁)=*′,

X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ may each independently be the same as described in connection with Q₁,

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

Q₄₀₁ to Q₄₀₃ may each independently be the same as described in connection with Q₁,

xc11 and xc12 may each independently be an integer from 0 to 10, and

* and *′ in Formula 402 each indicate a binding site to M in Formula 401.

For example, in Formula 402, i) X₄₀₁ may be nitrogen, and X₄₀₂ may be carbon, or ii) each of X₄₀₁ and X₄₀₂ may be nitrogen.

In one or more embodiments, when xc1 in Formula 401 is 2 or more, two rings A₄₀₁ among two or more of L₄₀₁ may optionally be bonded to each other via T₄₀₂, which is a linking group, and two rings A₄₀₂ among two or more of L₄₀₁ may optionally be bonded to each other via T₄₀₃, which is a linking group (see e.g., Compounds PD1 to PD4 and PD7). T₄₀₂ and T₄₀₃ may each independently be the same as described in connection with T₄₀₁.

In Formula 401, L₄₀₂ may be an organic ligand. For example, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, and/or the like), or any combination thereof.

The phosphorescent dopant may include, for example, one of Compounds PD1 to PD39, or any combination thereof:

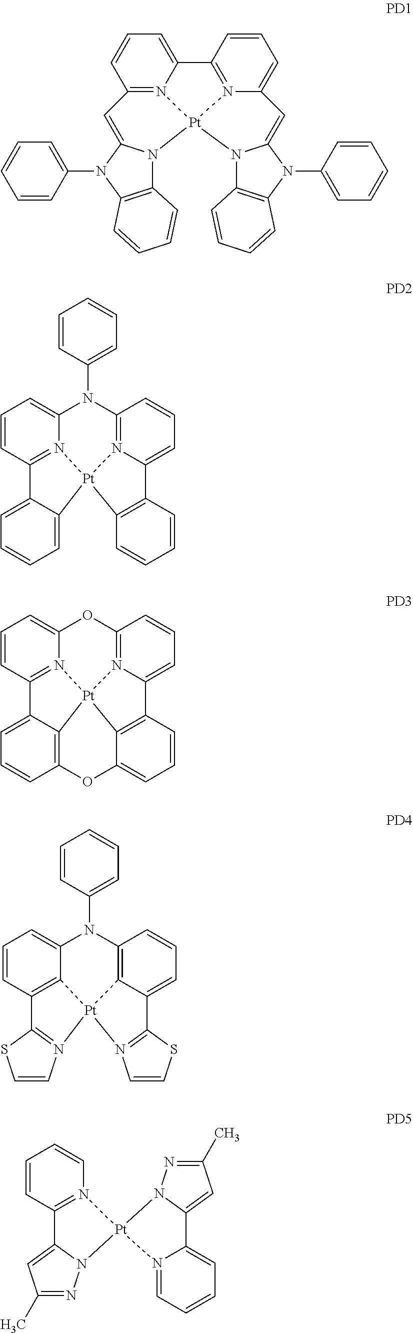

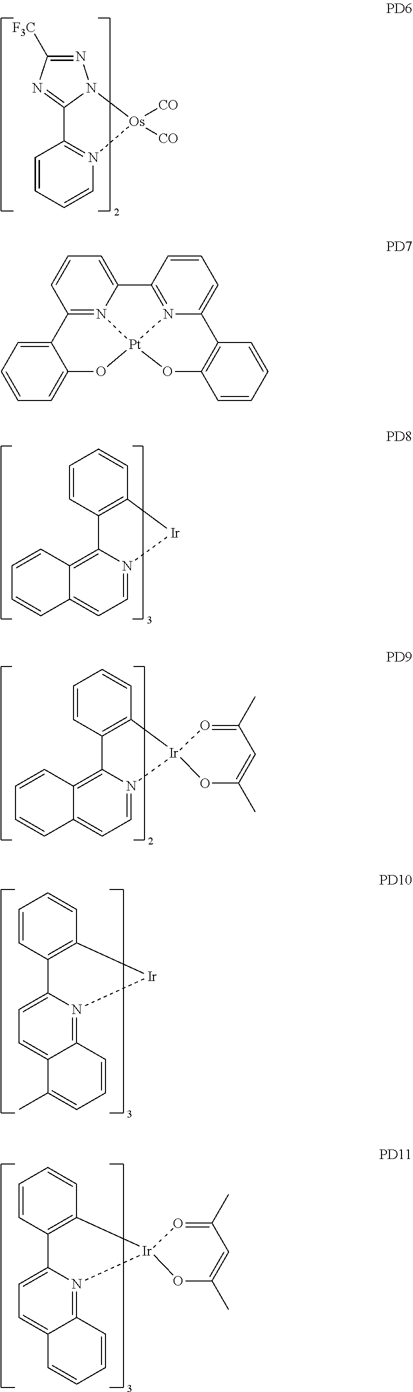

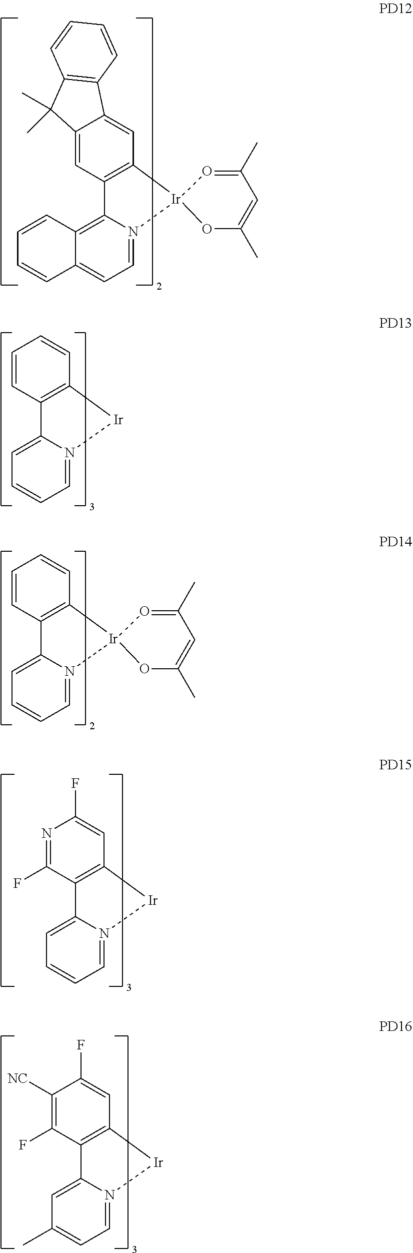

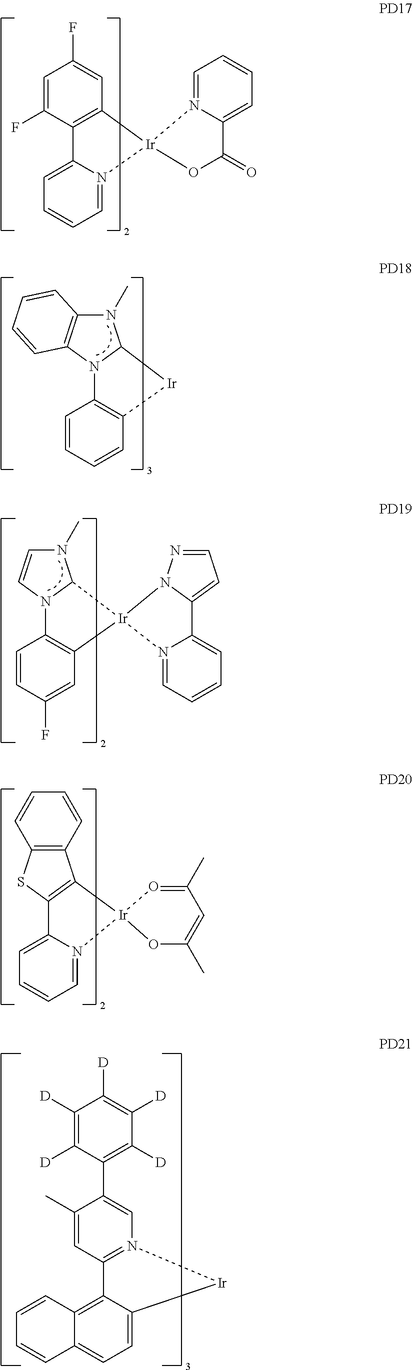

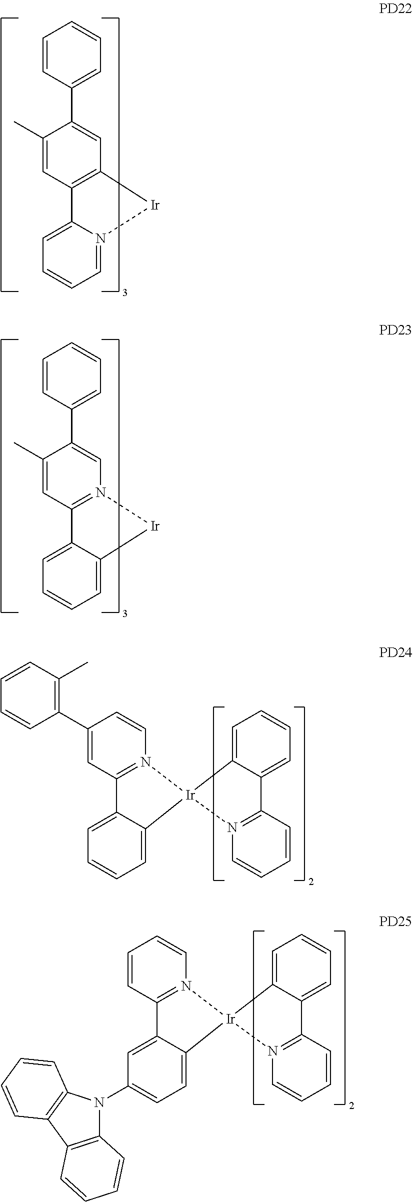

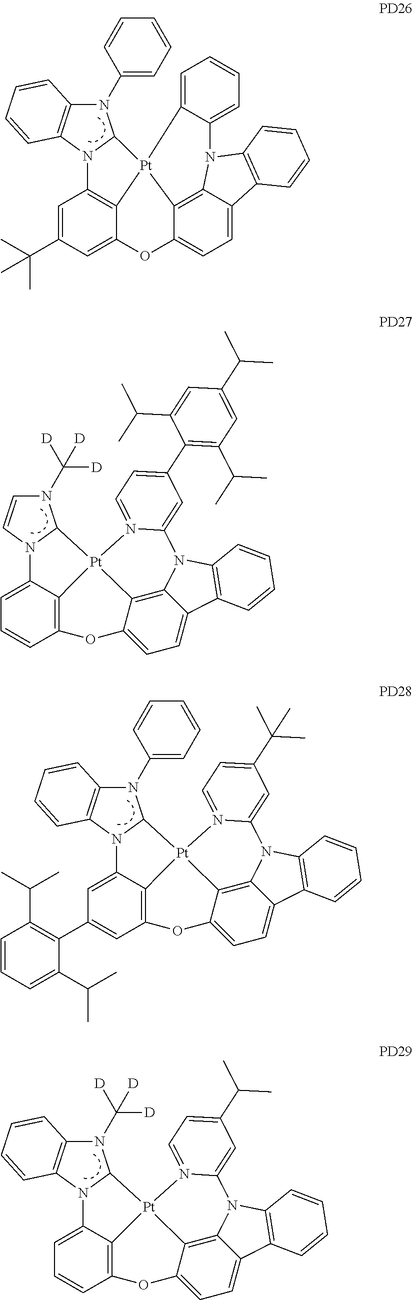

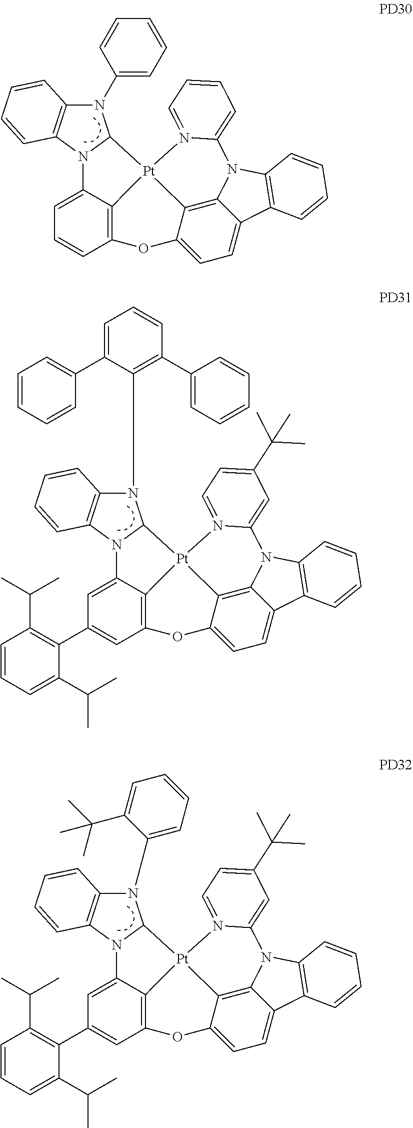

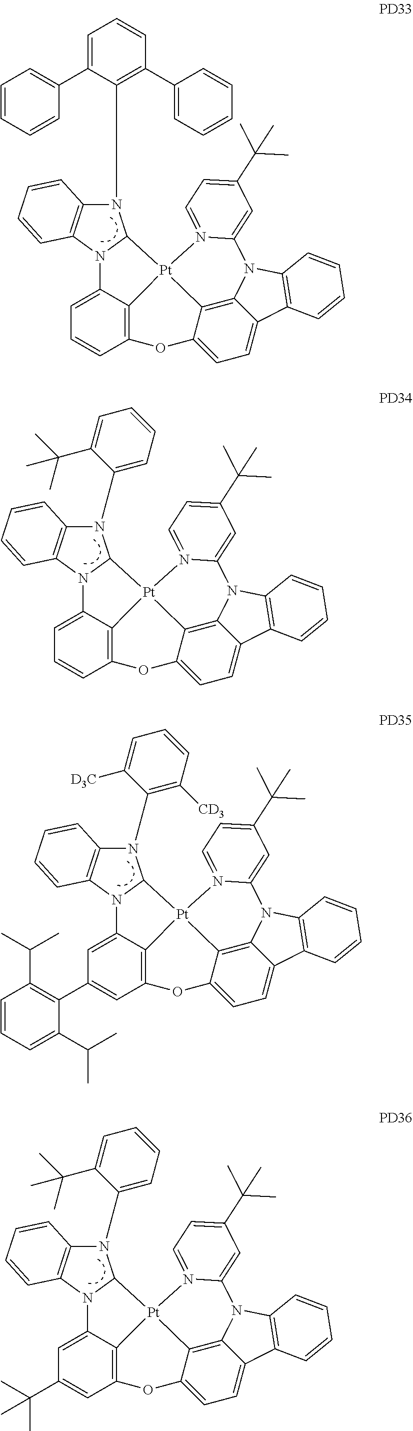

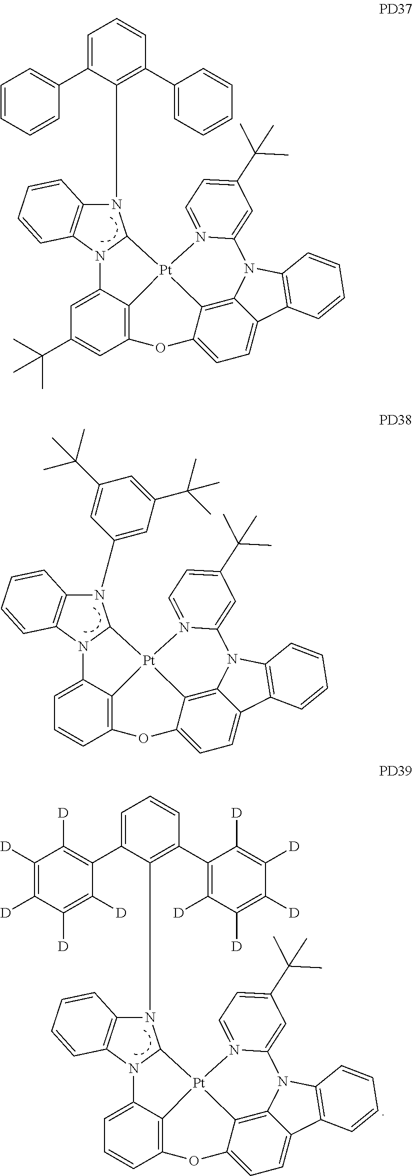

### Fluorescent Dopant

When the emission layer includes the first compound as described in the present specification and the first compound serves as an auxiliary dopant, the emission layer may further include a fluorescent dopant.

In one or more embodiments, when the emission layer includes the first compound as described in the present specification and the first compound serves as a phosphorescent dopant, the emission layer may further include an auxiliary dopant.

The fluorescent dopant and the auxiliary dopant that is not the first compound may each independently include an amine group-containing compound, a styryl group-containing compound, or any combination thereof.

In one or more embodiments, the fluorescent dopant and the auxiliary dopant may each independently include a compound represented by Formula 501:

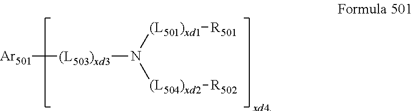

In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

For example, Ar₅₀₁ in Formula 501 may be a condensed cyclic group (for example, an anthracene group, a chrysene group, a pyrene group, and/or the like) in which three or more monocyclic groups are condensed together.

For example, xd4 in Formula 501 may be 2.

For example, the fluorescent dopant and the auxiliary dopant may each independently include one of Compounds FD1 to FD36, DPVBi, DPAVBi, or any combination thereof:

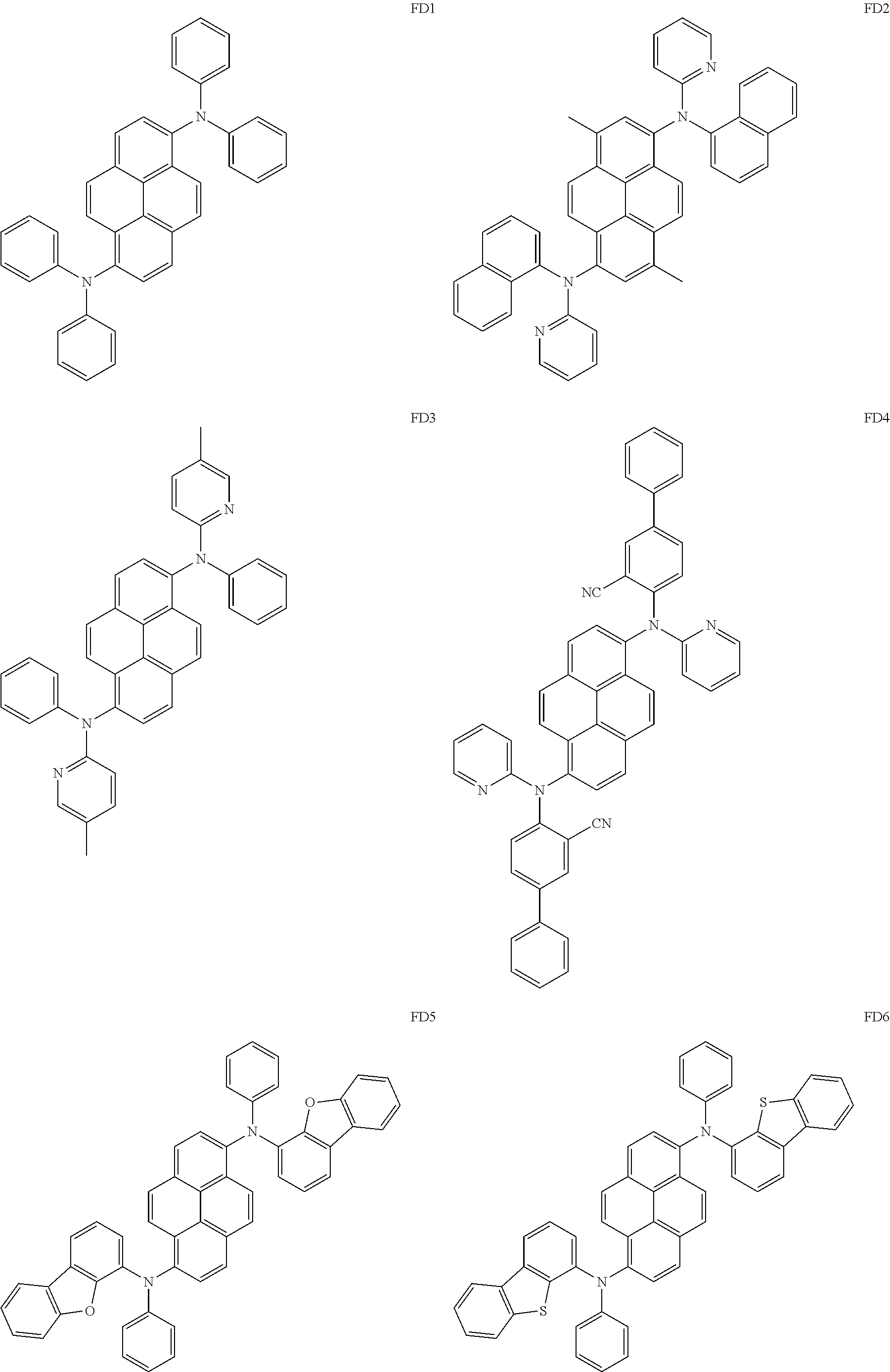

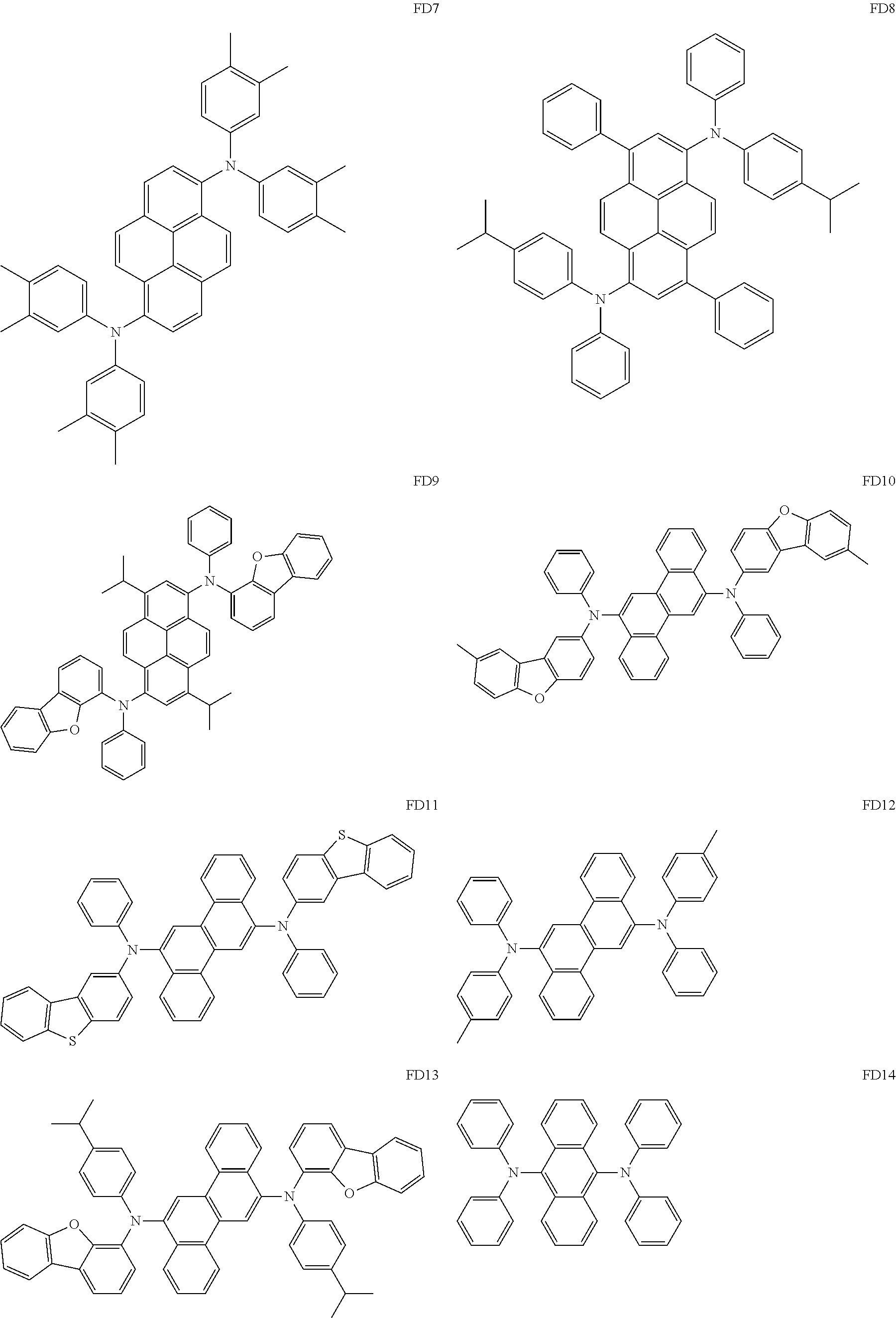

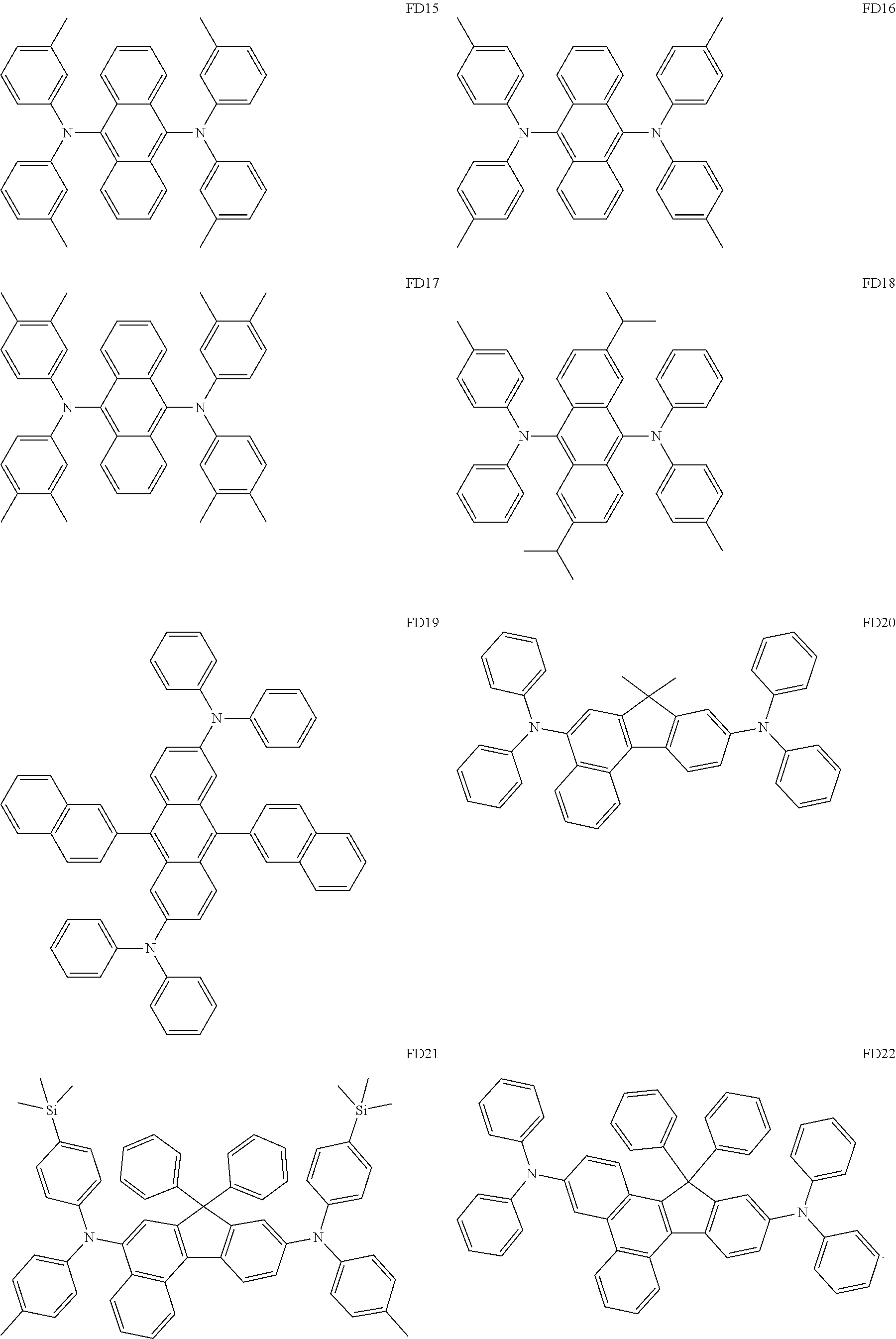

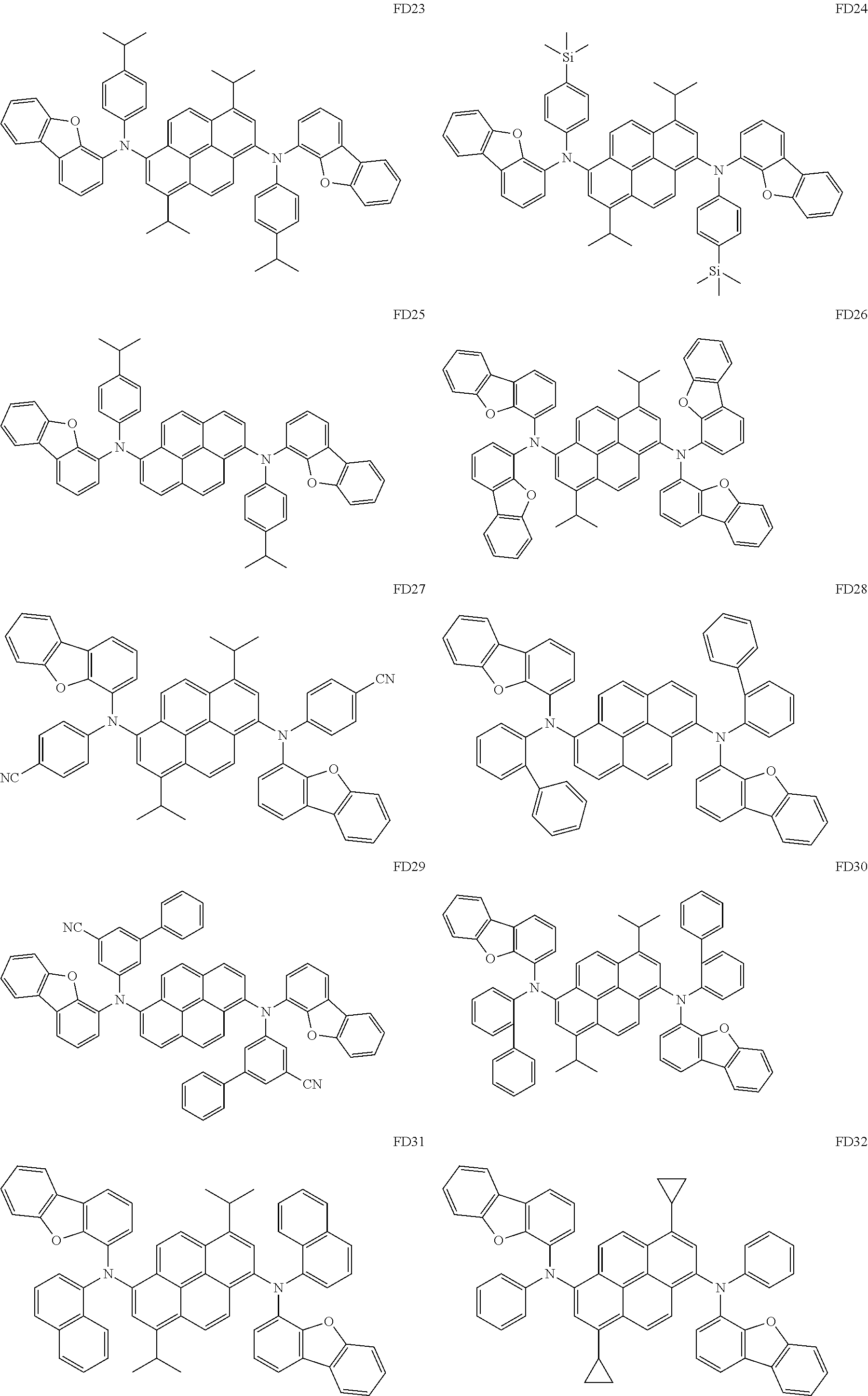

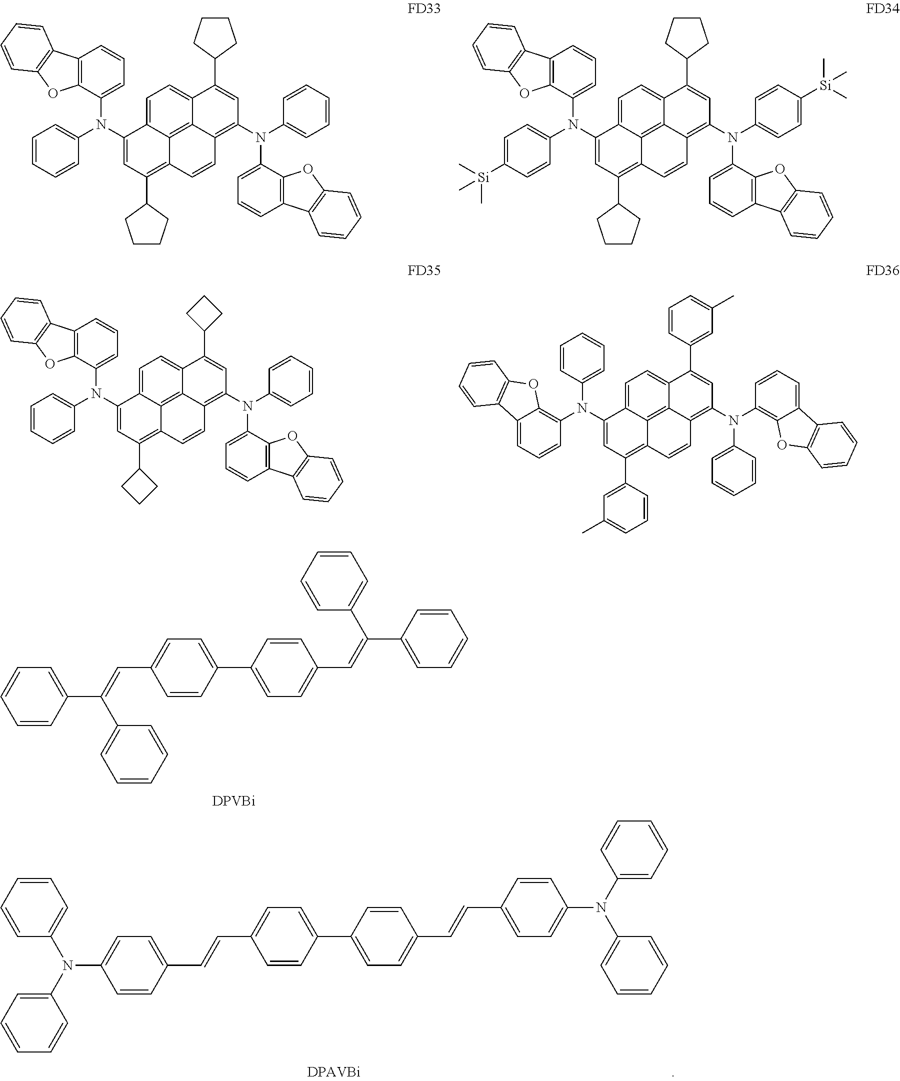

In one or more embodiments, the fluorescent dopant and the auxiliary dopant that is not the first compound may each independently include the fourth compound represented by Formula 502 or 503 as described in the present specification.

### Delayed Fluorescence Material

The emission layer may include the fourth compound as described in the present specification, as a delayed fluorescence material.

In one or more embodiments, the emission layer may include the fourth compound, and may further include a delayed fluorescence material.

In the present specification, the delayed fluorescence material may be selected from compounds capable of emitting delayed fluorescence by a delayed fluorescence emission mechanism.

The delayed fluorescence material included in the emission layer may act as a host or a dopant, depending on the type or kind of other materials included in the emission layer.

In one or more embodiments, a difference between a triplet energy level (eV) of the delayed fluorescence material and a singlet energy level (eV) of the delayed fluorescence material may be about 0 eV or more and about 0.5 eV or less. When the difference between the triplet energy level (eV) of the delayed fluorescence material and the singlet energy level (eV) of the delayed fluorescence material is satisfied within the range above, up-conversion from the triplet state to the singlet state of the delayed fluorescence materials may effectively or suitably occur, thereby improving luminescence efficiency and/or the like of the light-emitting device 10.

For example, the delayed fluorescence material may include: i) a material including at least one electron donor (for example, a π electron-rich C₃-C₆₀ cyclic group and/or the like, such as a carbazole group) and at least one electron acceptor (for example, a sulfoxide group, a cyano group, a π electron-deficient nitrogen-containing C₁-C₆₀ cyclic group, and/or the like); and ii) a material including a C₈-C₆₀ polycyclic group in which two or more cyclic groups are condensed while sharing boron (B).

Examples of the delayed fluorescence material may include at least one of Compounds DF1 to DF9:

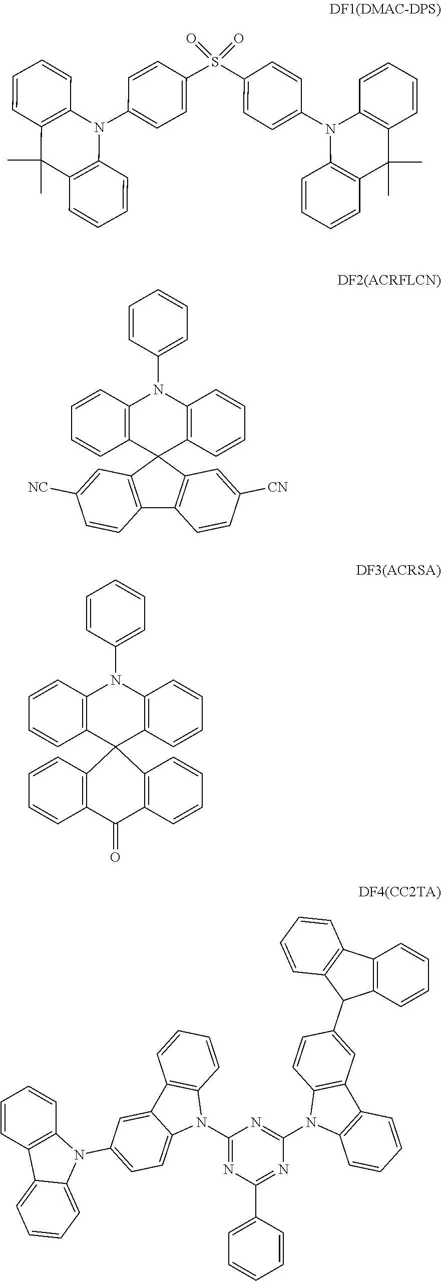

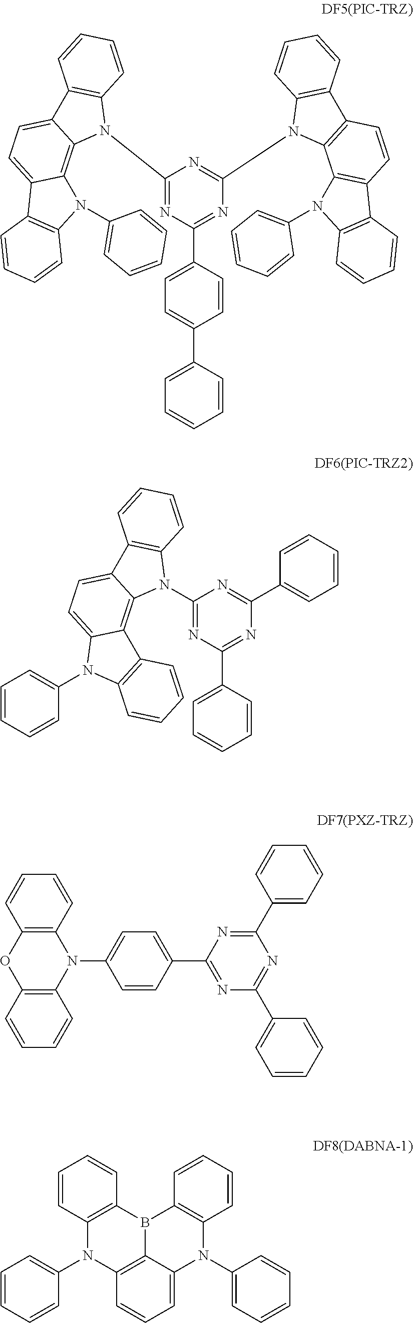 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1 ; c1ccc(N2c3ccccc3B3c4ccccc4N(c4ccccc4)c4cccc2c43)cc1]

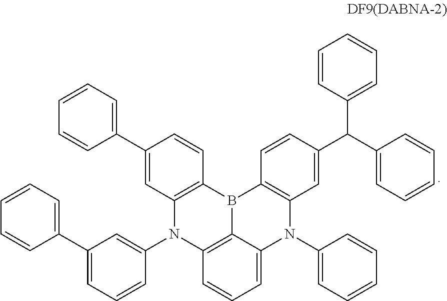 [SMILES: c1ccc(-c2cccc(N3c4cc(-c5ccccc5)ccc4B4c5ccc(C(c6ccccc6)c6ccccc6)cc5N(c5ccccc5)c5cccc3c54)c2)cc1]

### Quantum Dot

The emission layer may include a quantum dot.

The term “quantum dot” as utilized herein refers to a crystal of a semiconductor compound, and may include any material capable of emitting light of one or more suitable emission wavelengths according to the size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method including mixing a precursor material with an organic solvent and then growing a quantum dot particle crystal. When the crystal grows, the organic solvent naturally acts as a dispersant coordinated on the surface of the quantum dot crystal and controls the growth of the crystal so that the growth of quantum dot particles can be controlled or selected through a process which costs less, and is easier than vapor deposition methods, such as metal organic chemical vapor deposition (MOCVD) or molecular beam epitaxy (MBE),

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element; a Group IV compound; or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; and combinations thereof.

Examples of the Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or the like; a quaternary compound, such as GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and/or the like; and combinations thereof. The Group III-V semiconductor compound may further include a Group II element. Examples of the Group III-V semiconductor compound further including a Group II element may include InZnP, InGaZnP, InAlZnP, and the like.

Examples of the Group III-VI semiconductor compound may include: a binary compound, such as GaS, GaSe, Ga₂Se₃, GaTe, InS, InSe, In₂S₃, In₂Se₃, InTe, and/or the like; a ternary compound, such as InGaS₃, InGaSe₃, and/or the like; and combinations thereof.

Examples of the Group I-III-VI semiconductor compound may include: a ternary compound, such as AgInS, AgInS₂, CuInS, CuInS₂, CuGaO₂, AgGaO₂, AgAlO₂, and/or the like; and combinations thereof.

Examples of the Group IV-VI semiconductor compound may include: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; and combinations thereof.

The Group IV element and the Group IV compound may include: a single element compound, such as Si, Ge, and/or the like; a binary compound, such as SiC, SiGe, and/or the like; and combinations thereof.

Each element included in a multi-element compound, such as the binary compound, the ternary compound, and/or the quaternary compound, may exist in a particle form thereof at a substantially uniform concentration or a non-substantially uniform concentration.

The quantum dot may have a single structure or a dual core-shell structure. In the case of the quantum dot having a single structure, a concentration of each element included in the corresponding quantum dot may be substantially uniform. For example, a material included in the core and a material included in the shell may be different from each other.

The shell of the quantum dot may act as a protective layer that prevents or reduces chemical degeneration of the core to maintain semiconductor characteristics, and/or as a charging layer that imparts electrophoretic characteristics to the quantum dot. The shell may be a single layer or a multi-layer. The interface between the core and the shell may have a concentration gradient in which the concentration of an element existing in the shell decreases toward the center of the core.

Examples of the shell of the quantum dot may include a metal oxide, a metalloid oxide, a non-metal oxide, a semiconductor compound, and combinations thereof. Examples of the oxide of metal, metalloid, and/or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like; a ternary compound, such as MgAl₂O₄, CoFe₂O₄, NiFe₂O₄, CoMn₂O₄, and/or the like; and combinations thereof. Examples of the semiconductor compound may include: as described herein, a Group II-VI semiconductor compound; a Group III-V semiconductor compound; a Group III-VI semiconductor compound; a Group I-III-VI semiconductor compound; a Group IV-VI semiconductor compound; and combinations thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and combinations thereof.

A full width of half maximum (FWHM) of an emission wavelength spectrum of the quantum dot may be about 45 nm or less, for example, about 40 nm or less, for example, about 30 nm or less, and within any of these ranges, color purity and/or color reproducibility may be increased. In some embodiments, because the light emitted through the quantum dot is emitted in all directions, the wide viewing angle may be improved.

In some embodiments, the quantum dot may be spherical, pyramidal, multi-arm, and/or cubic nanoparticles, nanotubes, nanowires, nanofibers, and/or nanoplate particles.

Because the energy band gap may be adjusted by controlling the size of the quantum dot, light having one or more suitable wavelength bands may be obtained from the emission layer including the quantum dot. Accordingly, by utilizing quantum dot of different sizes, a light-emitting device that can emit light of one or more suitable wavelengths may be implemented. For example, the size of the quantum dot may be selected in consideration of emitting red light, green light, and/or blue light. In some embodiments, the size of the quantum dot may be configured to emit white light by combination of light of one or more suitable colors.

### Electron Transport Region in Interlayer 130

The electron transport region may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein constituent layers of each structure are sequentially stacked from the emission layer.

The electron transport region (for example, the buffer layer, the hole blocking layer, the electron control layer, and/or the electron transport layer in the electron transport region) may include a metal-free compound including at least one π electron-deficient nitrogen-containing C₁-C₆₀ cyclic group.

For example, the electron transport region may include a compound represented by Formula 601:

[Ar₆₀₁]ₓₑ₁₁-[(L₆₀₁)ₓₑ₁-R₆₀₁]ₓₑ₂₁, Formula 601

wherein, in Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each be the same as described in connection with Q₁,

xe21 may be 1, 2, 3, 4, or 5, and

at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In one or more embodiments, when xe11 in Formula 601 is 2 or more, two or more of Ar₆₀₁ may be bonded together via a single bond.

In one or more embodiments, Ar₆₀₁ in Formula 601 may be a substituted or unsubstituted anthracene group.

In one or more embodiments, the electron transport region may include a compound represented by Formula 601-1:

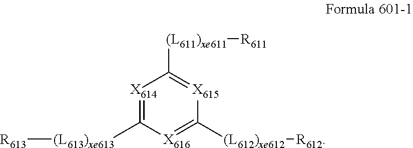

In Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each independently be the same as described in connection with L₆₀₁,

xe611 to xe613 may each independently be the same as described in connection with xe1,

R₆₁₁ to R₆₁₃ may each independently be the same as described in connection with R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

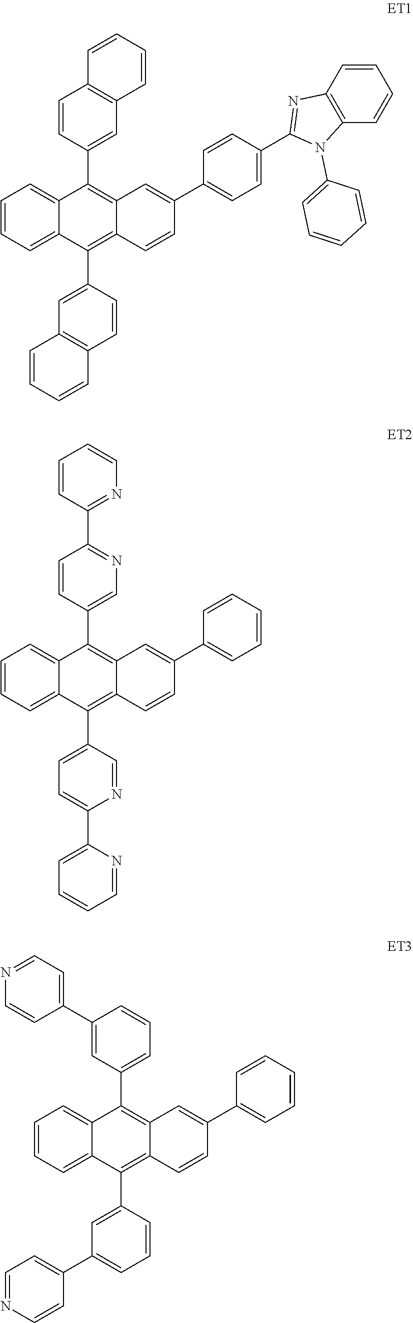 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

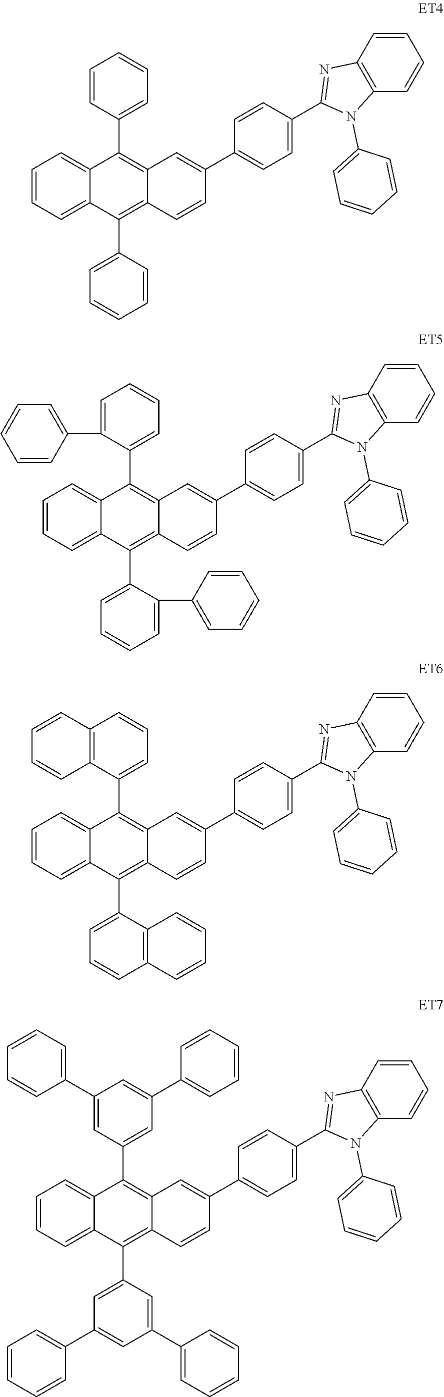 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

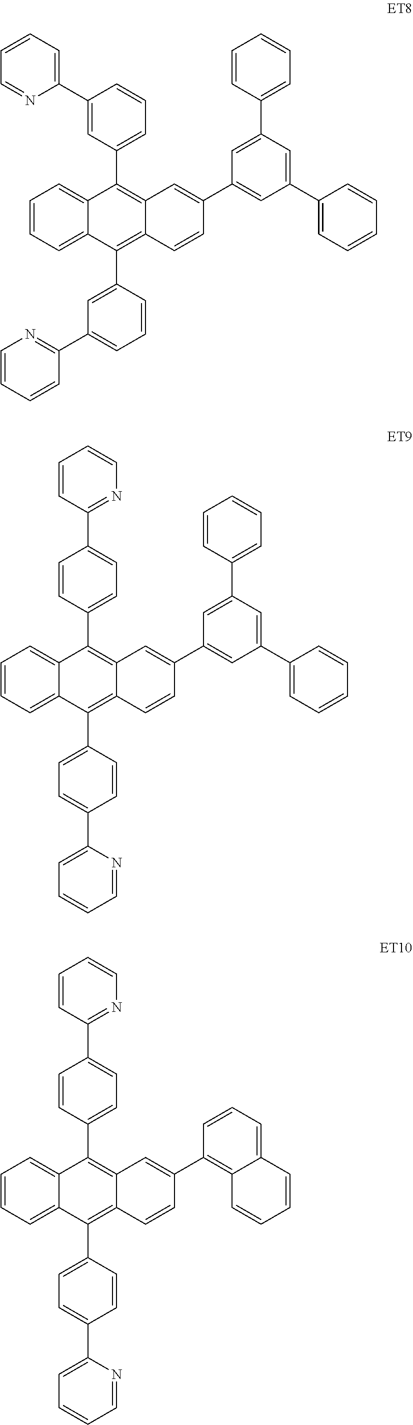

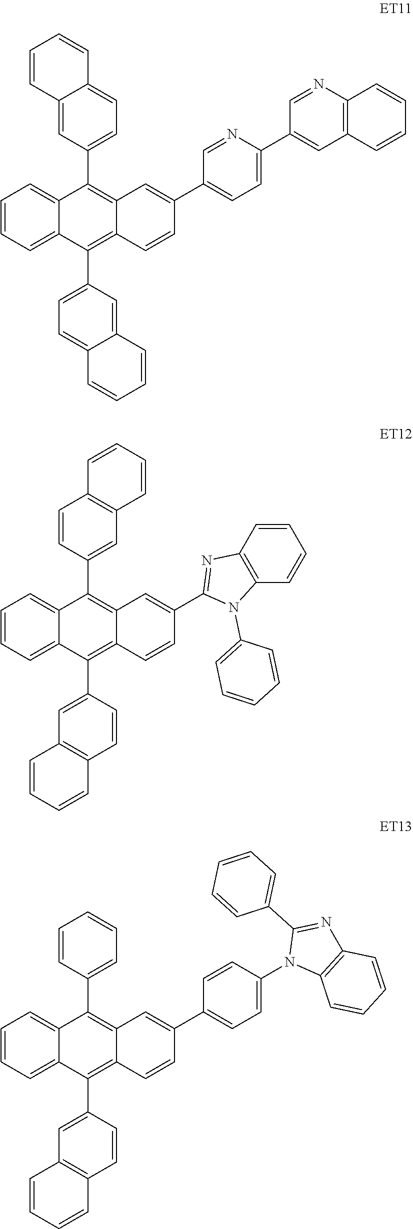

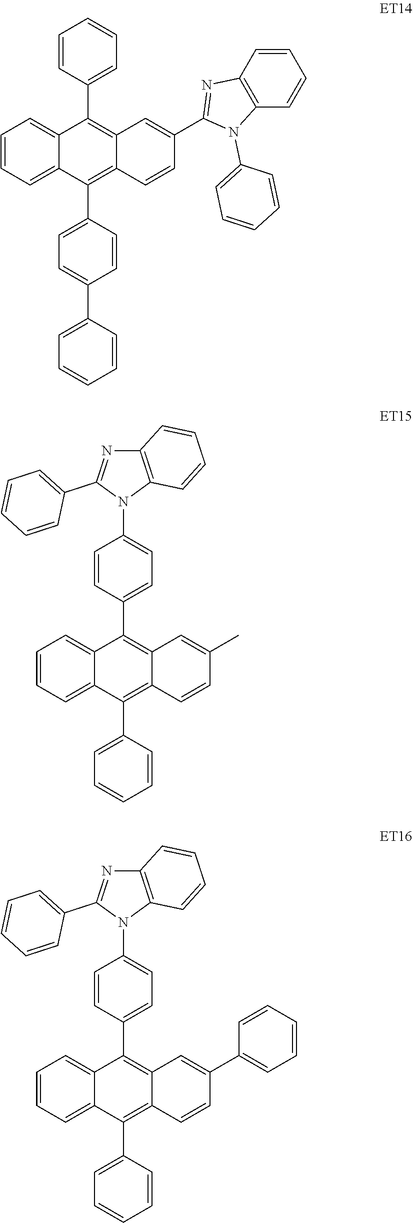 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

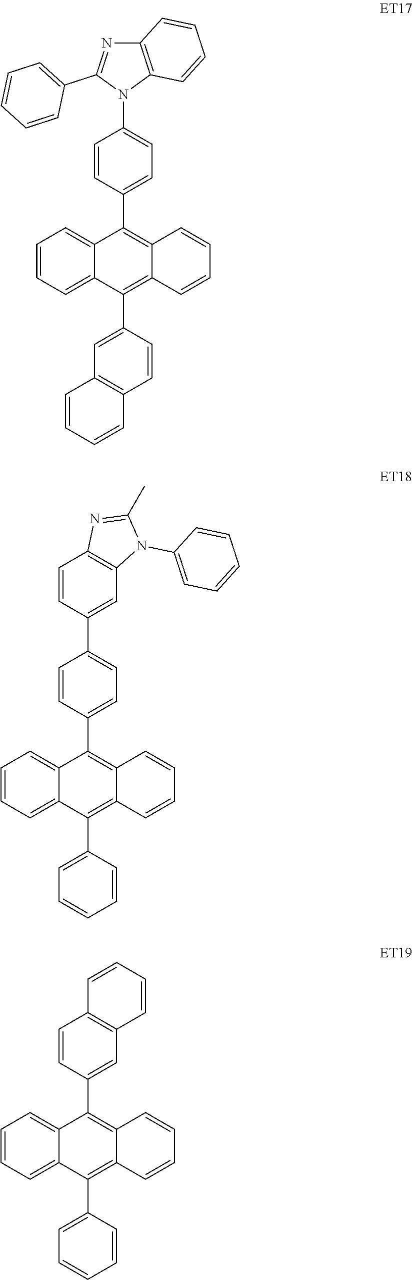

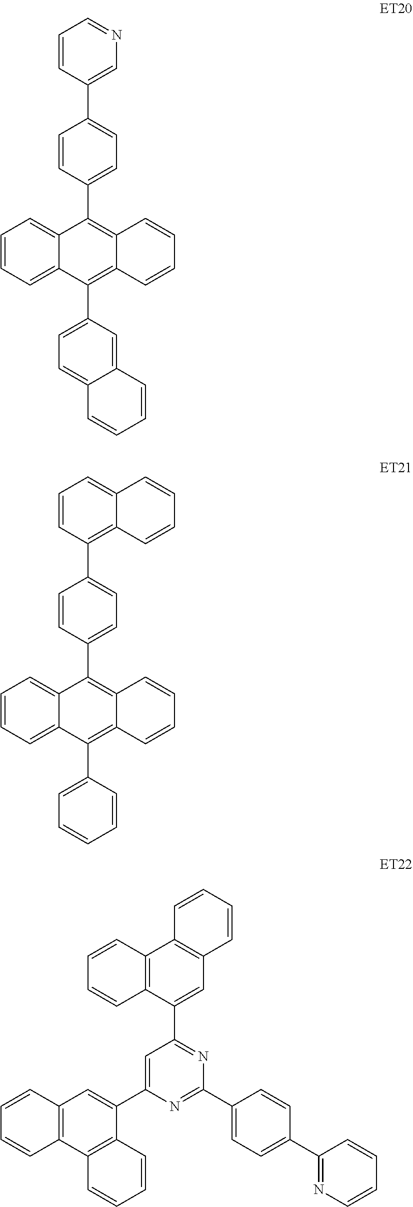

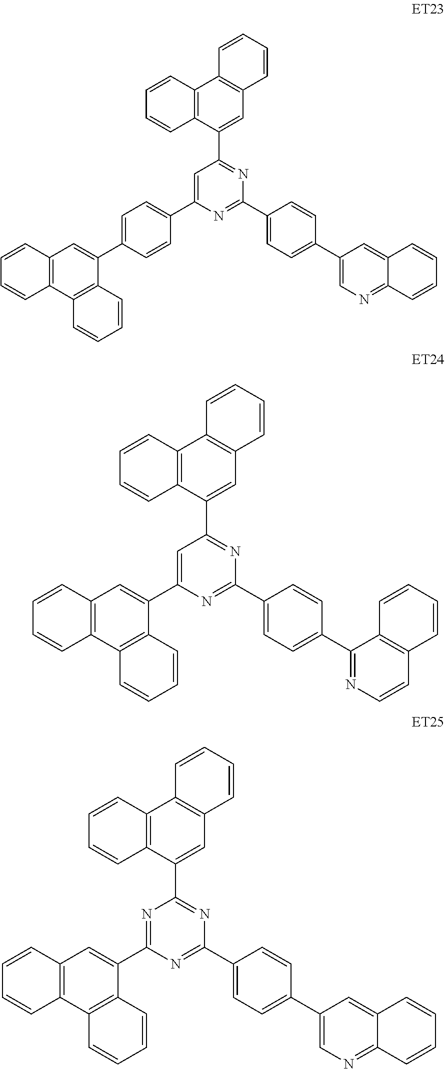 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

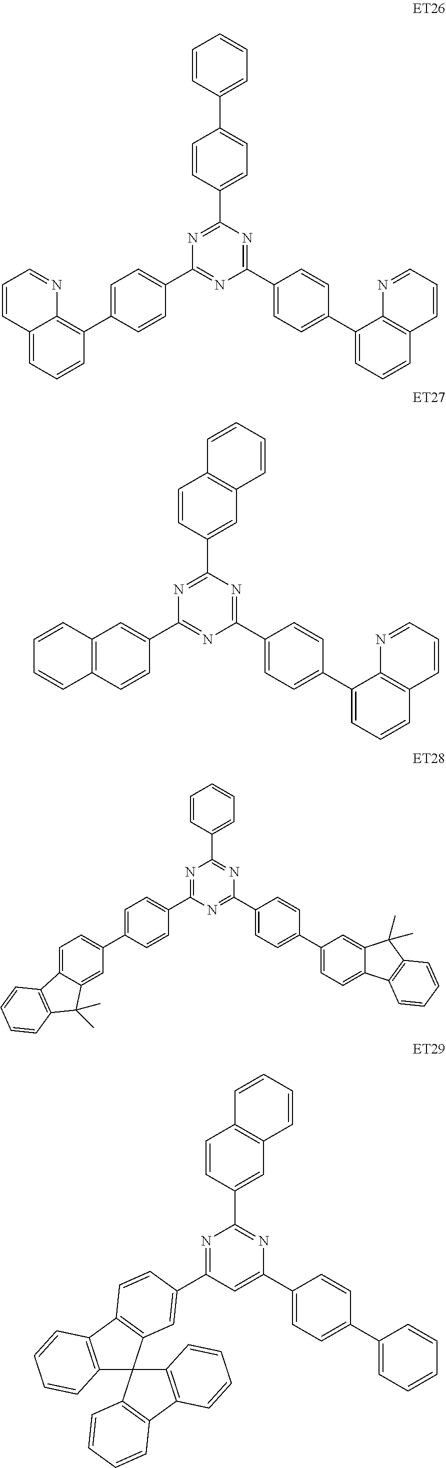 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

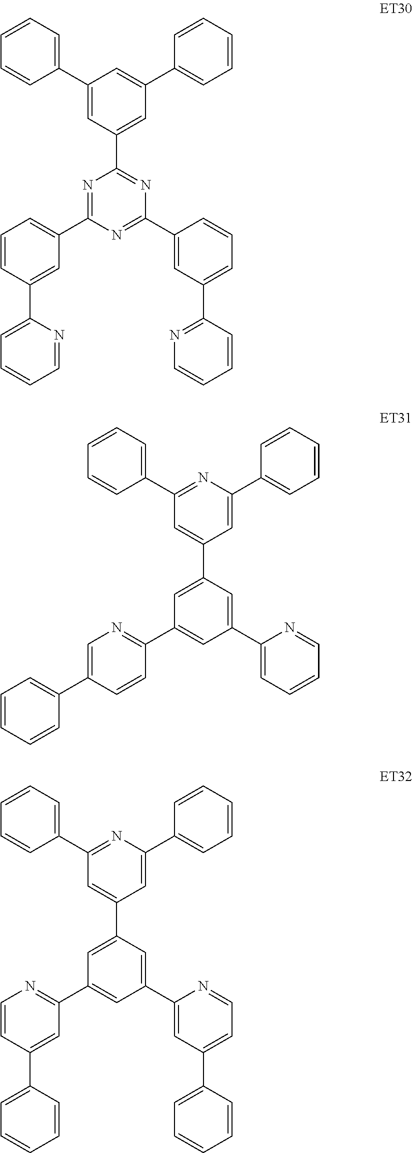

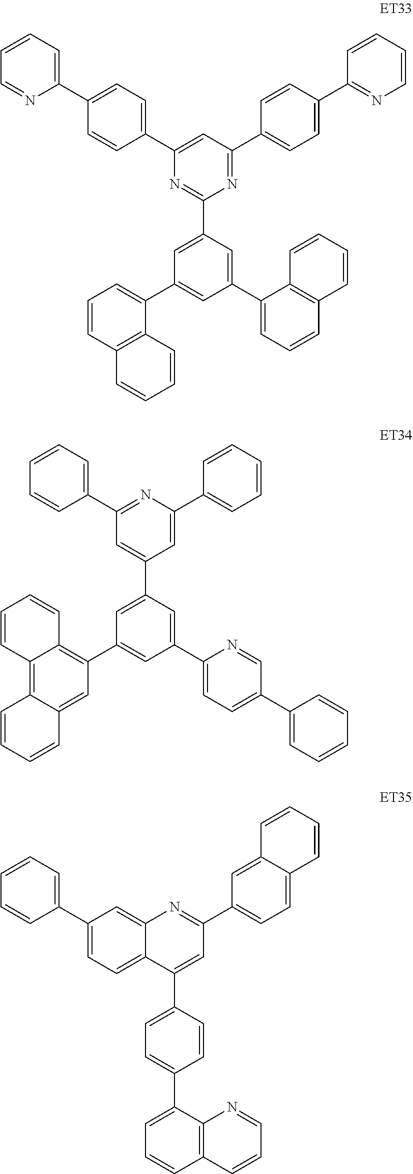 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

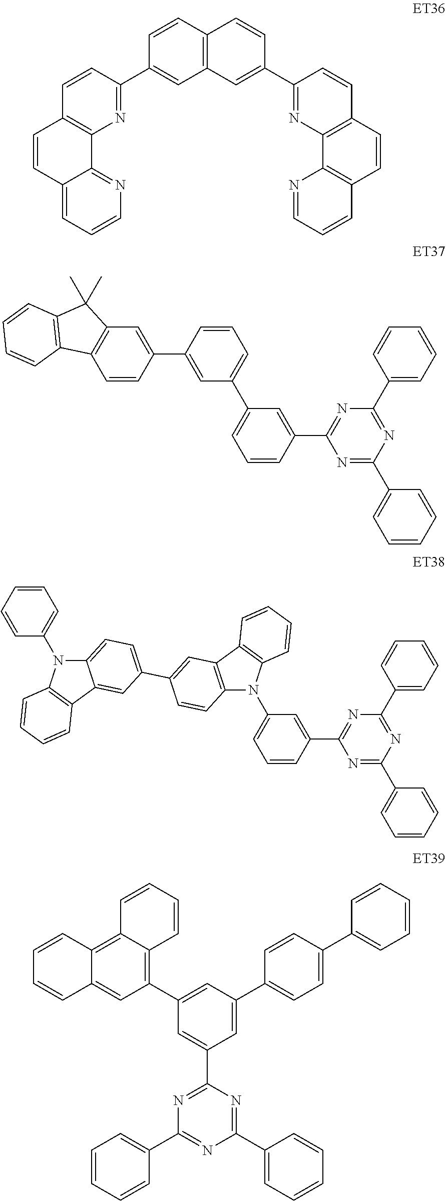

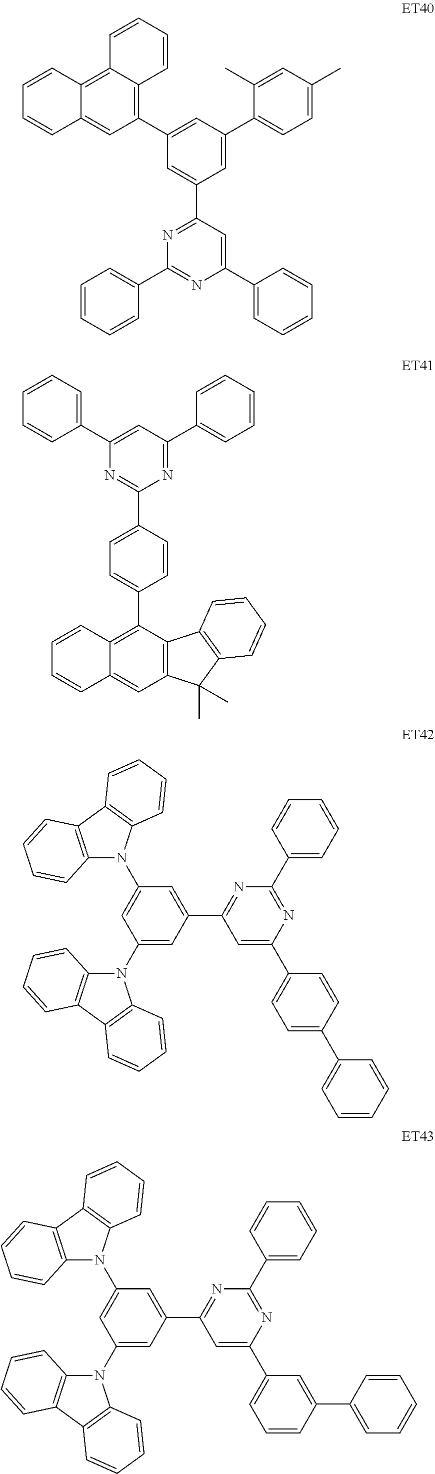 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

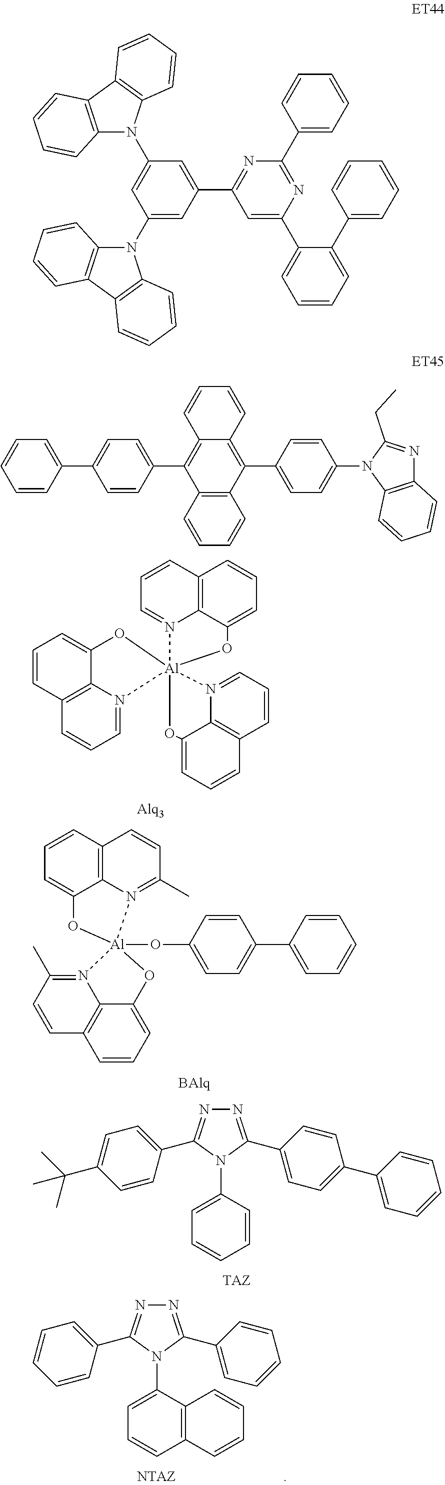

A thickness of the electron transport region may be in a range of about 100 Å to about 5,000 Å, for example, about 160 Å to about 4,000 Å. When the electron transport region includes a buffer layer, a hole blocking layer, an electron control layer, an electron transport layer, or any combination thereof, a thickness of the buffer layer, the hole blocking layer, and the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thickness of the buffer layer, the hole blocking layer, the electron control layer, the electron transport layer, and/or the electron transport region are within their respective ranges, satisfactory or suitable electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. The metal ion of an alkali metal complex may be a Li ion, a Na ion, a K ion, a Rb ion, or a Cs ion, and the metal ion of an alkaline earth metal complex may be a Be ion, a Mg ion, a Ca ion, a Sr ion, or a Ba ion. A ligand coordinated with the metal ion of the alkali metal complex and/or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, at least one of Compound ET-D1 (LiQ) or Compound ET-D2:

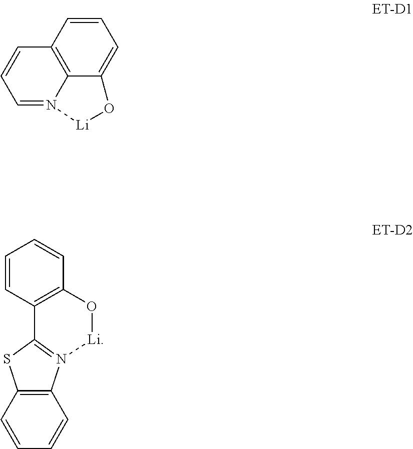

The electron transport region may include an electron injection layer that facilitates the injection of electrons from the second electrode 150. The electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron injection layer may include an alkali metal, alkaline earth metal, a rare earth metal, an alkali metal-containing compound, alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may each independently be oxides, halides (for example, fluorides, chlorides, bromides, iodides, and/or the like), or tellurides of the alkali metal, the alkaline earth metal, and the rare earth metal, respectively, or any combination thereof.

The alkali metal-containing compound may include alkali metal oxides, such as Li₂O, Cs₂O, K₂O, and/or the like; alkali metal halides, such as LiF, NaF, CsF, KF, LiI, NaI, CsI, KI, and/or the like; or any combination thereof. The alkaline earth metal-containing compound may include an alkaline earth metal compound, such as BaO, SrO, CaO, BaₓSr₁₋ₓO (wherein x is a real number satisfying the condition of 0<x<1), BaₓCa₁₋ₓO (wherein x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. For example, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include: i) one of ions of the alkali metal, the alkaline earth metal, and the rare earth metal, respectively; and ii), as a ligand bonded to the metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

In one or more embodiments, the electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In one or more embodiments, the electron injection layer may further include an organic material (for example, the compound represented by Formula 601).

In one or more embodiments, the electron injection layer may include (e.g., consist of): i) an alkali metal-containing compound (for example, an alkali metal halide); or ii) a) an alkali metal-containing compound (for example, an alkali metal halide), and b) an alkali metal, an alkaline earth metal, a rare earth metal, or any combination thereof. In one or more embodiments, the electron injection layer may be a KI:Yb co-deposited layer, an RbI:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly or non-uniformly dispersed in a matrix including the organic material.

A thickness of the electron injection layer may be in a range of about 1 Å to about 100 Å, for example, about 3 Å to about 90 Å. When the thickness of the electron injection layer is within any of these ranges, satisfactory or suitable electron injection characteristics may be obtained without a substantial increase in driving voltage.

### Second Electrode 150

The second electrode 150 is arranged on the interlayer 130 according to the present embodiments. The second electrode 150 may be a cathode, which is an electron injection electrode, and as a material for forming the second electrode 150, a metal, an alloy, an electrically conductive compound, or any combination thereof, each having a low work function, may be utilized.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multi-layered structure including a plurality of layers.

### Capping Layer

A first capping layer may be arranged outside the first electrode 110, and/or a second capping layer may be arranged outside the second electrode 150. In one or more embodiments, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In one or more embodiments, light generated in the emission layer of the interlayer 130 of the light-emitting device 10 may be extracted toward the outside through the first electrode 110, which is a semi-transmissive electrode or a transmissive electrode, and the first capping layer. In one or more embodiments, light generated in the emission layer of the interlayer 130 of the light-emitting device 10 may be extracted toward the outside through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 may be increased, so that the luminescence efficiency of the light-emitting device 10 may be also improved.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

In one or more embodiments, at least one of the first capping layer or the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each independently optionally be substituted with a substituent including O, N, S, Se, Si, F, Cl, Br, I, or any combination thereof. In one or more embodiments, at least one of the first capping layer or the second capping layer may each independently include an amine group-containing compound.

In one or more embodiments, at least one of the first capping layer or the second capping layer may each independently include a compound represented by Formula 201, a compound represented by Formula 202, or any combination thereof.

In one or more embodiments, at least one of the first capping layer or the second capping layer may each independently include one of Compounds HT28 to HT33, one of Compounds CP1 to CP6, β-NPB, or any combination thereof:

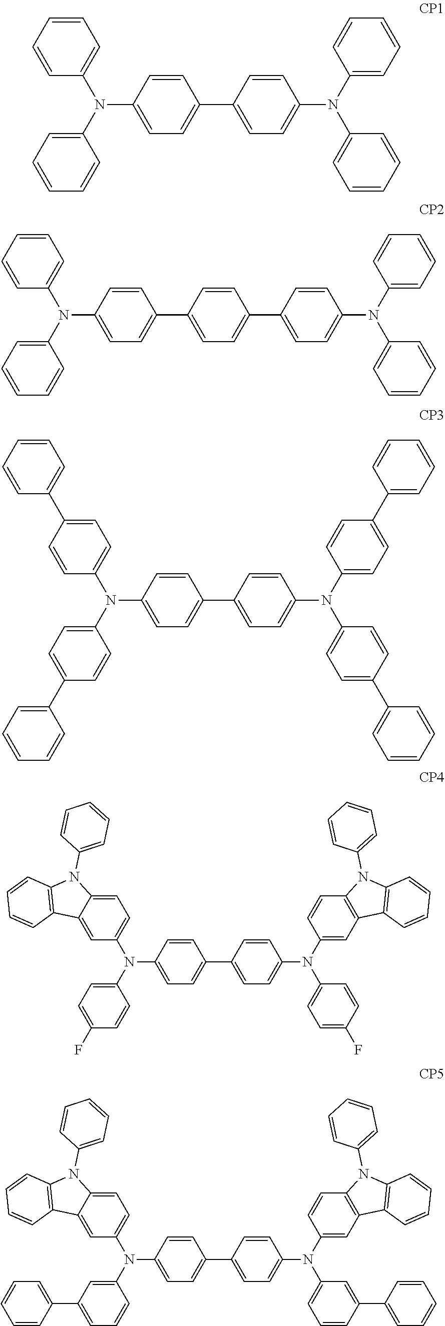 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

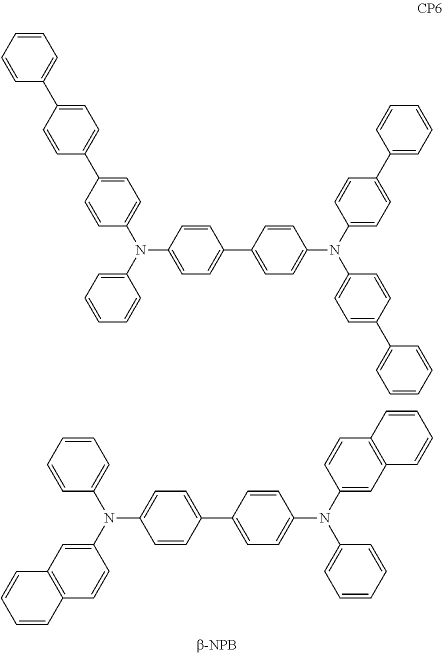

### Film

The organometallic compound represented by Formula 1 may be included in one or more suitable films. Accordingly, one or more embodiments of the present disclosure provide a film including the organometallic compound represented by Formula 1. The film may be, for example, an optical member (or a light control means) (for example, a color filter, a color conversion member, a capping layer, a light extraction efficiency enhancement layer, a selective light absorbing layer, a polarizing layer, a quantum dot-containing layer, and/or like), a light-blocking member (for example, a light reflective layer, a light absorbing layer, and/or the like), a protective member (for example, an insulating layer, a dielectric layer, and/or the like).

### Electronic Apparatus

The light-emitting device may be included in one or more suitable electronic apparatuses. For example, an electronic apparatus including the light-emitting device may be a light-emitting apparatus, an authentication apparatus, and/or the like.

The electronic apparatus (for example, a light-emitting apparatus) may further include, in addition to the light-emitting device, i) a color filter, ii) a color conversion layer, or iii) both a color filter and a color conversion layer. The color filter and/or the color conversion layer may be arranged in at least one traveling direction of light emitted from the light-emitting device. For example, light emitted from the light-emitting device may be blue light or white light. Details for the light-emitting device may be the same as described herein. In one or more embodiments, the color conversion layer may include a quantum dot. The quantum dots may be, for example, the same as described herein.

The electronic apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the plurality of subpixel areas.

A pixel-defining film may be arranged among the subpixel areas to define each of the subpixel areas.

The color filter may further include a plurality of color filter areas and light-shielding patterns arranged among the color filter areas, and the color conversion layer may further include a plurality of color conversion areas and light-shielding patterns arranged among the color conversion areas.

The plurality of color filter areas (or the plurality of color conversion areas) may include a first area emitting (e.g., to emit) first-color light, a second area emitting (e.g., to emit) second-color light, and/or a third area emitting (e.g., to emit) third-color light, wherein the first-color light, the second-color light, and/or the third-color light may have different maximum emission wavelengths from one another. For example, the first-color light may be red light, the second-color light may be green light, and the third-color light may be blue light. For example, the plurality of color filter areas (or the plurality of color conversion areas) may include quantum dots. In one or more embodiments, the first region may include red quantum dots, the second region may include green quantum dots, and the third region may not include (e.g., may exclude) quantum dots. Details for the quantum dots may be the same as described herein. The first region, the second region, and/or the third region may each independently further include a scatter.

For example, the light-emitting device may be to emit first light, the first region may be to absorb the first light and to emit first-first-color light, the second region may be to absorb the first light and to emit second-first-color light, and the third region may be to absorb the first light and to emit third-first-color light. Here, the first-first-color light, the second-first-color light, and the third-first-color light may have different maximum emission wavelengths from each other. For example, the first light may be blue light, the first-first-color light may be red light, the second-first-color light may be green light, and the third-first-color light may be blue light.

The electronic apparatus may further include a thin-film transistor in addition to the above-described light-emitting device. The thin-film transistor may include a source electrode, a drain electrode, and an activation layer, wherein any one of the source electrode or the drain electrode may be electrically connected (e.g., electrically coupled) to any one of the first electrode or the second electrode of the light-emitting device.

The thin-film transistor may further include a gate electrode, a gate insulating film, and/or the like.

The activation layer may include crystalline silicon, amorphous silicon, an organic semiconductor, an oxide semiconductor, and/or the like.

The electronic apparatus may further include a sealing portion for sealing the light-emitting device. The sealing portion may be arranged between the light-emitting device and the color conversion layer and/or color filter. The sealing portion allows light from the light-emitting device to be extracted to the outside, and concurrently (e.g., simultaneously) prevents or reduces ambient air and moisture from penetrating into the light-emitting device. The sealing portion may be a sealing substrate including a transparent glass substrate or a plastic substrate. The sealing portion may be a thin-film encapsulation layer including at least one of an organic layer and/or an inorganic layer. When the sealing portion is a thin-film encapsulation layer, the electronic apparatus may be flexible.

Various suitable functional layers may be additionally arranged on the sealing portion, in addition to the color filter and/or the color conversion layer, according to the use of the electronic apparatus. Examples of the functional layer may include a touch screen layer, a polarizing layer, and the like. The touch screen layer may be a pressure-sensitive touch screen layer, a capacitive touch screen layer, and/or an infrared touch screen layer. The authentication apparatus may be, for example, a biometric authentication apparatus that authenticates an individual by utilizing biometric information of a living body (for example, fingertips, pupils, and/or the like).

The authentication apparatus may further include, in addition to the light-emitting device as described above, a biometric information collector.

The electronic apparatus may be applied to one or more suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, one or more suitable measuring instruments, meters (for example, meters for a vehicle, an aircraft, and a vessel), projectors, and/or the like.

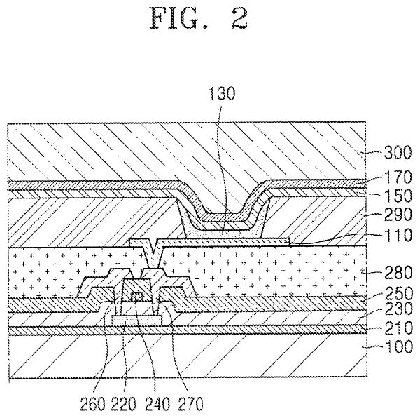

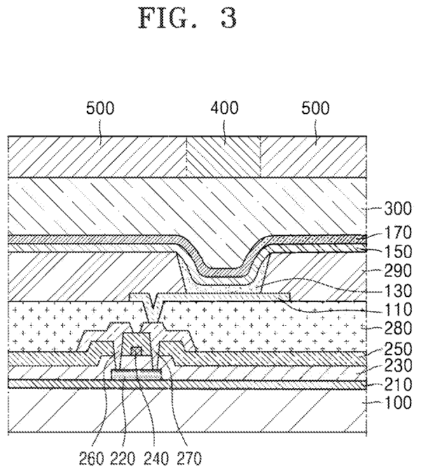

### Description of FIGS. 2 and 3

FIG. 2 is a cross-sectional view showing a light-emitting apparatus according to one or more embodiments of the present disclosure.

The light-emitting apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be arranged on the substrate 100. The buffer layer 210 may prevent or reduce penetration of impurities through the substrate 100 and may provide a flat surface on the substrate 100.

A TFT may be arranged on the buffer layer 210. The TFT may include an activation layer 220, a gate electrode 240, a source electrode 260, and a drain electrode 270.

The activation layer 220 may include an inorganic semiconductor such as silicon and/or polysilicon, an organic semiconductor, and/or an oxide semiconductor, and may include a source region, a drain region, and a channel region.

A gate insulating film 230 for insulating the activation layer 220 from the gate electrode 240 may be arranged on the activation layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate from one another.

The source electrode 260 and the drain electrode 270 may be arranged on the interlayer insulating film 250. The interlayer insulating film 250 and the gate insulating film 230 may be formed to expose the source region and the drain region of the activation layer 220, and the source electrode 260 and the drain electrode 270 may be arranged in contact with the exposed portions of the source region and the drain region of the activation layer 220.

The TFT may be electrically connected (e.g., electrically coupled) to a light-emitting device to drive the light-emitting device, and may be protected as being covered with a passivation layer 280. The passivation layer 280 may include an inorganic insulating film, an organic insulating film, or any combination thereof. A light-emitting device may be provided on the passivation layer 280. The light-emitting device may include a first electrode 110, an interlayer 130, and a second electrode 150.

The first electrode 110 may be arranged on the passivation layer 280. The passivation layer 280 may be arranged to expose a portion of the drain electrode 270, not fully covering the drain electrode 270, and the first electrode 110 may be arranged to be connected (e.g., coupled) to the exposed portion of the drain electrode 270.

A pixel defining layer 290 including an insulating material may be arranged on the first electrode 110. The pixel defining layer 290 may expose a certain region of the first electrode 110, and an interlayer 130 may be formed in the exposed region of the first electrode 110. The pixel defining layer 290 may be a polyimide-based organic film and/or a polyacrylic-based organic film. In one or more embodiments, at least some layers of the interlayer 130 may extend beyond the upper portion of the pixel defining layer 290 to be arranged in the form of a common layer.

The second electrode 150 may be arranged on the interlayer 130, and a capping layer 170 may be additionally formed on the second electrode 150. The capping layer 170 may be formed to cover the second electrode 150.

The encapsulation portion 300 may be arranged on the capping layer 170. The encapsulation portion 300 may be arranged on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and/or the like), an epoxy-based resin (for example, aliphatic glycidyl ether (AGE), and/or the like), or any combination thereof; or any combination of the inorganic films and the organic films.

FIG. 3 shows a cross-sectional view showing a light-emitting apparatus according to one or more embodiments of the present disclosure.

The light-emitting apparatus of FIG. 3 is substantially the same as the light-emitting apparatus of FIG. 2, except that a light-shielding pattern 500 and a functional region 400 are additionally arranged on the encapsulation portion 300. The functional region 400 may be i) a color filter area, ii) a color conversion area, or iii) a combination of the color filter area and the color conversion area. In one or more embodiments, the light-emitting device included in the light-emitting apparatus of FIG. 3 may be a tandem light-emitting device.

### Manufacturing Method

The layers included in the hole transport region, the emission layer, and the layers included in the electron transport region may be formed in a certain region by utilizing one or more suitable methods such as vacuum deposition, spin coating, casting, Langmuir-Blodgett (LB) deposition, ink-jet printing, laser-printing, laser-induced thermal imaging, and/or the like.

When the layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definition of Terms

The term “C₃-C₆₀ carbocyclic group” as used herein refers to a cyclic group consisting of carbon atoms only as ring-forming atoms and having 3 to 60 carbon atoms, and the term “C₁-C₆₀ heterocyclic group” as used herein refers to a cyclic group that has 1 to 60 carbon atoms and further has, in addition to carbon, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the C₁-C₆₀ heterocyclic group may have 3 to 61 ring-forming atoms.

The “cyclic group” as used herein may include the C₃-C₆₀ carbocyclic group and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

For example,

the C₃-C₆₀ carbocyclic group may be i) a T₁ group or ii) a condensed cyclic group in which two or more T₁ groups are condensed with each other (for example, the C₃-C₆₀ carbocyclic group may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, an indenoanthracene group, and/or the like),

the C₁-C₆₀ heterocyclic group may be i) a T2 group, ii) a condensed cyclic group in which two or more T2 groups are condensed with each other, or iii) a condensed cyclic group in which at least one T2 group and at least one T1 group are condensed with each other (for example, the C₁-C₆₀ heterocyclic group may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

the π electron-rich C₃-C₆₀ cyclic group may be i) a T1 group, ii) a condensed cyclic group in which two or more T1 groups are condensed with each other, iii) a T3 group, iv) a condensed cyclic group in which two or more T3 groups are condensed with each other, or v) a condensed cyclic group in which at least one T3 group and at least one T1 group are condensed with each other (for example, the π electron-rich C₃-C₆₀ cyclic group may be the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, and/or the like),

the π electron-deficient nitrogen-containing C₁-C₆₀ cyclic group may be i) a T4 group, ii) a condensed cyclic group in which two or more T4 groups are condensed with each other, iii) a condensed cyclic group in which at least one T4 group and at least one T1 group are condensed with each other, iv) a condensed cyclic group in which at least one T4 group and at least one T3 group are condensed with each other, or v) a condensed cyclic group in which at least one T4 group, at least one T1 group, and at least one T3 group are condensed with one another (for example, the π electron-deficient nitrogen-containing C₁-C₆₀ cyclic group may be a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),

the T1 group may include (e.g., be) at least one of a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,

the T2 group may include (e.g., be) at least one of a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the T3 group may include (e.g., be) at least one of a furan group, a thiophene group, a 1H-pyrrole group, a silole group, or a borole group, and

the T4 group may include (e.g., be) at least one of a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, and/or the π electron-deficient nitrogen-containing C₁-C₆₀ cyclic group” as used herein may refer to a group condensed to any cyclic group, a monovalent group, or a polyvalent group (for example, a divalent group, a trivalent group, a tetravalent group, and/or the like) according to the structure of a formula for which the corresponding term is used. In one or more embodiments, “a benzene group” may be a benzo group, a phenyl group, a phenylene group, and/or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include (e.g., be) a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the monovalent C₁-C₆₀ heterocyclic group may include (e.g., be) a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has 1 to 60 carbon atoms, and examples thereof may include (e.g., be) a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle and/or at the terminus of the C₂-C₆₀ alkyl group, and examples thereof may include (e.g., be) an ethenyl group, a propenyl group, a butenyl group, and the like. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle and/or at the terminus of the C₂-C₆₀ alkyl group, and examples thereof may include (e.g., be) an ethynyl group, a propynyl group, and the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof may include (e.g., be) a methoxy group, an ethoxy group, an isopropyloxy group, and the like.

The term “C₃-C₁₀ cycloalkyl group” as used herein refers to a monovalent saturated hydrocarbon cyclic group having 3 to 10 carbon atoms, and examples thereof may include (e.g., be) a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group of 1 to 10 carbon atoms, further including, in addition to carbon atoms, at least one heteroatom, as ring-forming atoms, and examples thereof may include (e.g., be) a 1,2,3,4-oxatriazolidinyl group, a tetrahydrofuranyl group, a tetrahydrothiophenyl group, and the like. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that has 3 to 10 carbon atoms and at least one carbon-carbon double bond in the ring thereof and no aromaticity in the molecular structure as a whole, and examples thereof may include (e.g., be) a cyclopentenyl group, a cyclohexenyl group, a cycloheptenyl group, and the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group may include (e.g., be) a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. The term “C₆-C₆₀ arylene group” as utilized herein refers to a divalent group having the same structure as the C₆-C₆₀ aryl group. When the C₆-C₆₀ aryl group and the C₆-C₆₀ arylene group each independently include two or more rings, the respective two or more rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. Examples of the C₁-C₆₀ heteroaryl group may include (e.g., be) a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. The term “C₁-C₆₀ heteroarylene group” as used herein refers to a divalent group having the same structure as the C₁-C₆₀ heteroaryl group. When the C₁-C₆₀ heteroaryl group and the C₁-C₆₀ heteroarylene group each independently include two or more rings, the respective rings may be condensed with each other.

The term “monovalent non-aromatic condensed polycyclic group” as used herein refers to a monovalent group having two or more rings condensed to each other, only carbon atoms as ring-forming atoms (for example, having 8 to 60 carbon atoms), and no aromaticity in its entire molecular structure. Examples of the monovalent non-aromatic condensed polycyclic group may include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group having two or more rings condensed to each other, further including, in addition to carbon atoms (for example, 1 to 60 carbon atoms), at least one heteroatom, as ring-forming atoms, and having no aromaticity in its entire molecular structure. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein refers to a divalent group having the same structure as the monovalent non-aromatic condensed heteropolycyclic group described above.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ arylalkyl group” used herein refers to -A₁₀₄A₁₀₅ (where A₁₀₄ is a C₁-C₅₄ alkylene group, and A₁₀₅ is a C₆-C₅₉ aryl group), and the term C₂-C₆₀ heteroarylalkyl group” as used herein refers to -A₁₀₆A₁₀₇ (where A₁₀₆ is a C₁-C₅₉ alkylene group, and A₁₀₇ is a C₁-C₅₉ heteroaryl group).

The term “R₁₀ₐ” as used herein may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each independently unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each independently unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each independently unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group.

The term “heteroatom” as used herein refers to any atom other than a carbon atom. Examples of the heteroatom are O, S, N, P, Si, B, Ge, Se, and combinations thereof.

The term “third-row transition metal” as used herein includes hafnium (Hf), tantalum (Ta), tungsten (W), rhenium (Re), osmium (Os), iridium (Ir), platinum (Pt), gold (Au), and the like.

The term “Ph” as used herein refers to a phenyl group, the term “Me” as used herein refers to a methyl group, the term “Et” as used herein refers to an ethyl group, the term “tert-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” For example, the “biphenyl group” may be a substituted phenyl group having a C₆-C₆₀ aryl group as a substituent.

The term “terphenyl group” as used herein refers to “a phenyl group substituted with a biphenyl group.” For example, the “terphenyl group” may be a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

Hereinafter, compounds according to embodiments and light-emitting devices according to embodiments will be described in more detail with reference to the following synthesis examples and examples. The wording “B was used instead of A” used in describing Synthesis Examples refers to an identical molar equivalent of B being used in place of A.

### EXAMPLES

### Synthesis Example 1: Synthesis of Compound 1

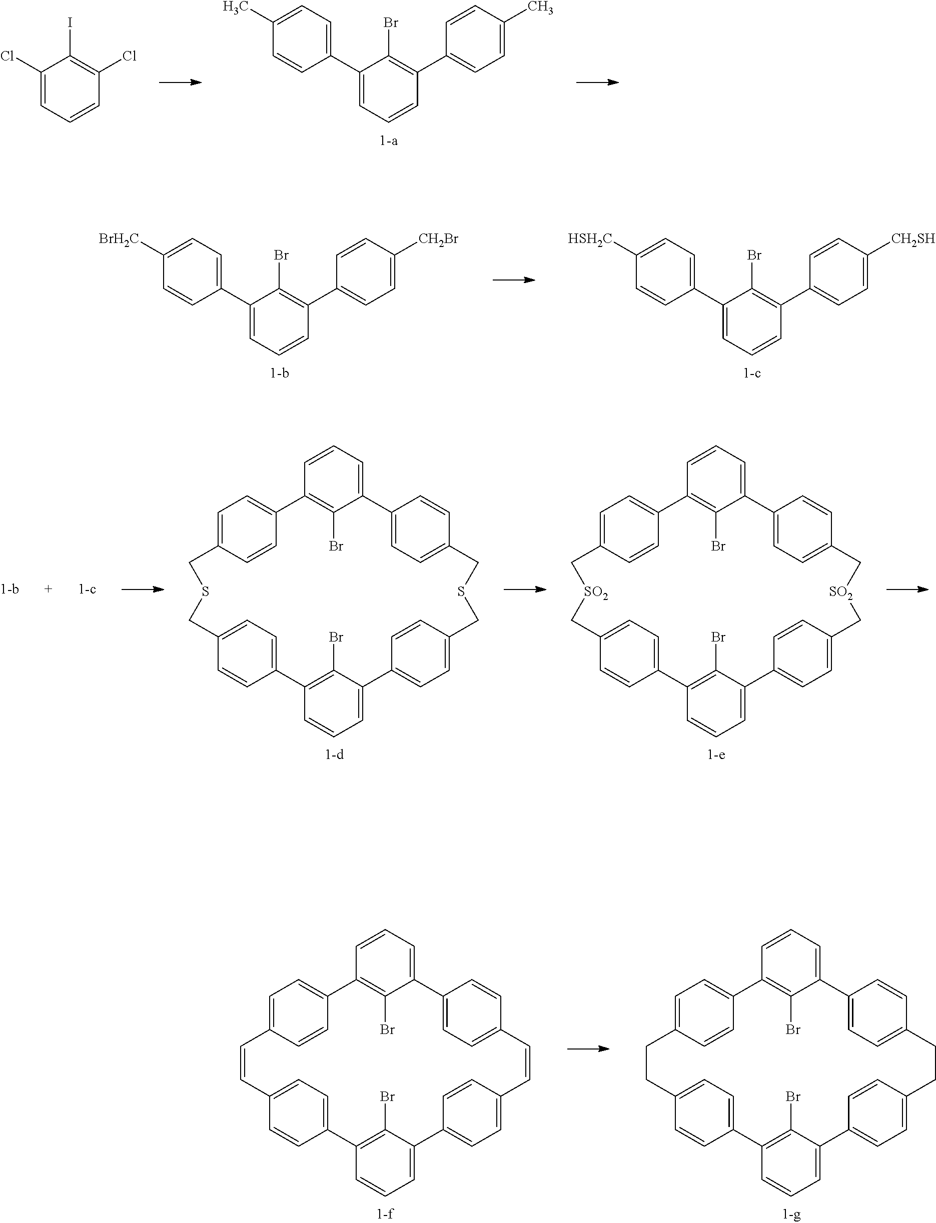

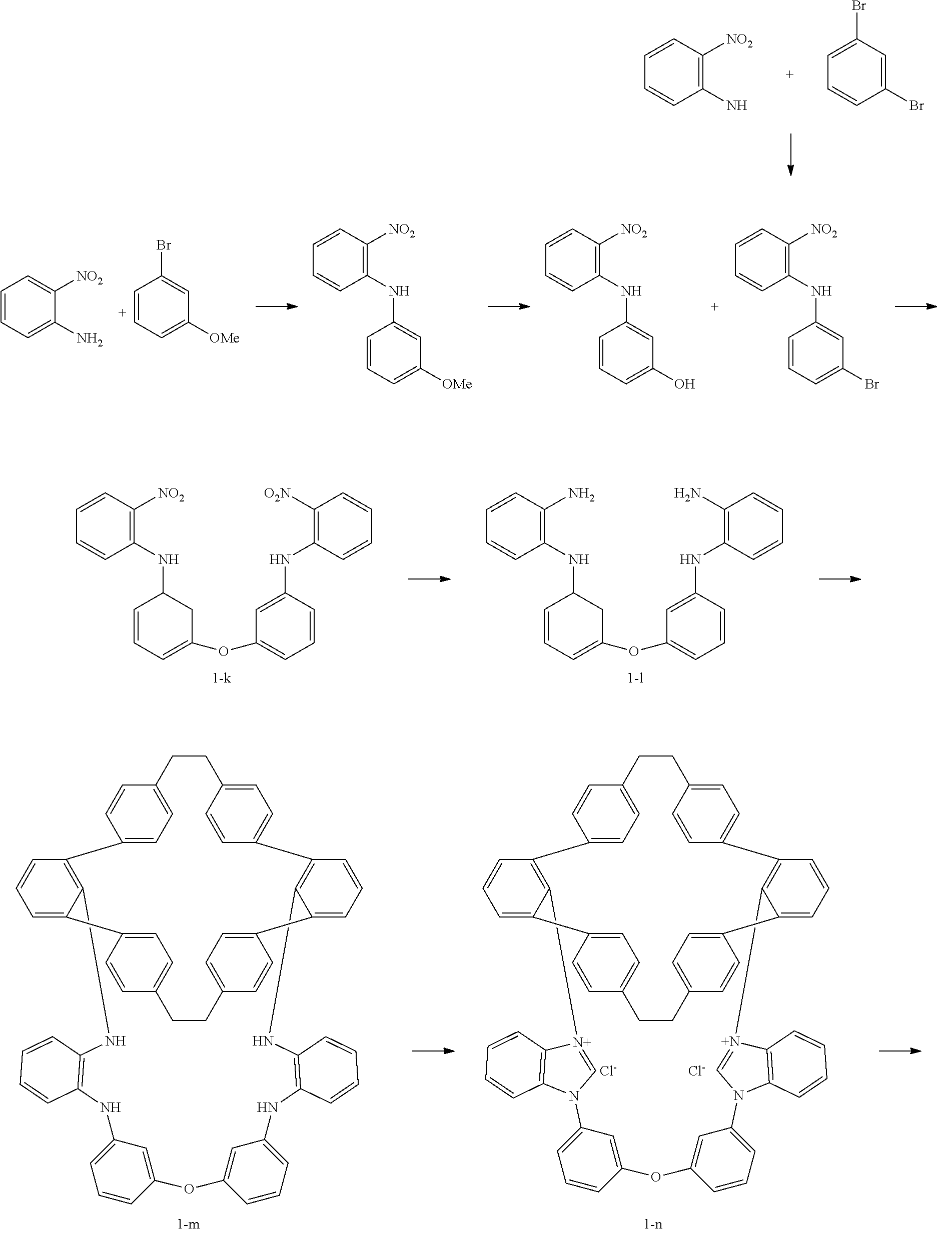

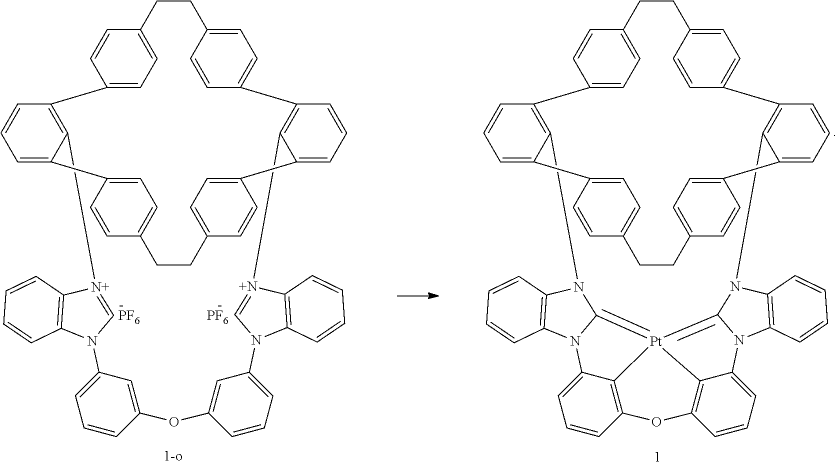

### (1) Synthesis of Intermediate Compound 1-a

2,6-dichloroiodobenzene (1.0 eq) and p-tolylmagnesium bromide (3.0 eq) were dissolved in anhydrous THF (0.1 M), and stirred at 80° C. for 1 hour. Br₂ was added to the reaction mixture, and stirred at room temperature for 15 hours. An extraction process was performed on the resultant reaction mixture three times by utilizing ethyl acetate and water to obtain an organic layer. The organic layer thus obtained was dried by utilizing magnesium sulfate, concentrated, and then subjected to column chromatography to synthesize Intermediate Compound 1-a (yield: 70%).

### (2) Synthesis of Intermediate Compound 1-b

Intermediate Compound 1-a (1.0 eq), N-bromosuccinimide (3.0 eq), and benzoyl peroxide (0.1 eq) were dissolved in acetonitrile, and stirred at 80° C. for 2 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 1-b (yield: 82%).

### (3) Synthesis of Intermediate Compound 1-c

Intermediate Compound 1-b (1.0 eq) was dissolved in ethanol (0.1 M), and thiourea (1.1 eq) was added thereto. The mixed solution was stirred at 85° C. for 6 hours. 25% NaOH aqueous solution (0.025 M) was added to the mixed solution, and then stirred again at 85° C. for 15 hours. The resultant reaction mixture was cooled at room temperature, and an extraction process was performed thereon three times by utilizing diethyl ether and water to obtain an organic layer. The organic layer thus obtained was dried by utilizing magnesium sulfate, concentrated, and then subjected to column chromatography to synthesize Intermediate Compound 1-c (yield: 61%).

### (4) Synthesis of Intermediate Compound 1-d

Intermediate Compound 1-c (1.0 eq) and NaH (2.3 eq) were dissolved in anhydrous THF (0.1 M) under nitrogen conditions, and stirred at room temperature for 1 hour. Intermediate Compound 1-b (1.0 eq) was slowly added to the reaction mixture, and stirred at room temperature for 4 hours. The resultant reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 1-d (yield: 87%).

### (5) Synthesis of Intermediate Compound 1-e

Intermediate Compound 1-d (1.0 eq) was dissolved in dichloromethane-glacial acetic acid (1:1 v/v) (0.1 M) at 0° C., and 3-chloroperbenzoic acid (m-CPBA) (10 eq) was added thereto, and stirred at room temperature for 3 days. The reaction mixture was filtered, and the filtrate was washed with CHCl₃ to synthesize Intermediate Compound 1-e (yield: 91%).

### (6) Synthesis of Intermediate Compound 1-f

Intermediate Compound 1-e (1.0 eq), CCl₄ (1.2 eq), 10% NaOH aqueous solution (0.01 M), and cetyltrimethylammonium chloride (0.5 eq) were dissolved in dichloromethane, and stirred at 50° C. for 3 days. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 1-f (yield: 34%).

### (7) Synthesis of Intermediate Compound 1-g

Intermediate Compound 1-f (1.0 eq) and Pt/C were dissolved in ethyl acetate (0.05 M), and H2 at a pressure of 40 psi was injected thereto at room temperature. After removing the catalyst and solvent from the reaction mixture, the resultant product was subjected to column chromatography to synthesize Intermediate Compound 1-g (yield: 94%).

### (8) Synthesis of Intermediate Compound 1-h

2-nitroaniline (1.1 eq), 3-bromoanisole (1.0 eq), Pd₂(dba)₃ (0.05 eq), SPhos (0.075 eq), and NaOtBu (2.0 eq) were dissolved in toluene (0.1 M), and stirred at 110° C. for 12 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 1-h (yield: 72%).

### (9) Synthesis of Intermediate Compound 1-i

Intermediate Compound 1-h (1.0 eq), HBr (0.3 M), and acetic acid (0.3 M) were stirred at 120° C. for 16 hours. The reaction mixture was cooled at room temperature, and neutralized with NaOH at 0° C. Then, an extraction process was performed thereon three times by utilizing dichloromethane and water to obtain an organic layer. The organic layer thus obtained was filtered through silica gel/celite, and the filtrate was dried by utilizing magnesium sulfate and concentrated to synthesize Intermediate Compound 1-i (yield: 93%).

### (10) Synthesis of Intermediate Compound 1-j

2-nitroaniline (1.1 eq), 1,3-dibromobenzene (1.0 eq), Pd₂(dba)₃ (0.05 eq), SPhos (0.075 eq), and NaOtBu (2.0 eq) were dissolved in toluene (0.1 M), and stirred at 110° C. for 12 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 1-j (yield: 67%).

### (11) Synthesis of Intermediate Compound 1-k

Intermediate Compound 1-i (1.0 eq), Intermediate Compound 1-j (1.2 eq), CuI (10 mol %), BPPO ligand (10 mol %), and potassium phosphate tribasic (2.0 eq) were dissolved in DMF (0.1 M), and stirred at 160° C. for 10 hours. The reaction mixture was cooled at room temperature, and DMF was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 1-k (yield: 55%).

### (12) Synthesis of Intermediate Compound 1-1

Intermediate Compound 1-k (1.0 eq), Sn (3.0 eq), and HCl (60 eq) were dissolved in ethanol, and stirred at 80° C. for 12 hours. The reaction mixture was cooled at room temperature, and neutralized with a NaOH solution. Next, an extraction process was performed thereon by utilizing dichloromethane and water to obtain an organic layer, which was then filtered through celite/silica gel. The filtrate was dried by utilizing magnesium sulfate and concentrated to synthesize Intermediate Compound 1-l (yield: 86%).

### (13) Synthesis of Intermediate Compound 1-m

Intermediate Compound 1-1 (1.2 eq), Intermediate Compound 1-g (1.2 eq), Pd₂(dba)₃ (15 mol %), SPhos (20 mol %), and sodium tert-butoxide (5.0 eq) were dissolved in toluene (0.1 M), and stirred at 110° C. for 3 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 1-m (yield: 65%).

### (14) Synthesis of Intermediate Compound 1-n

Intermediate Compound 1-m (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate, and concentrated to synthesize Intermediate Compound 1-n (yield: 86%).

### (15) Synthesis of Intermediate Compound 1-o

Intermediate Compound 1-n (1.0 eq) and ammonium hexafluorophosphate (6.0 eq) were dissolved in a solution containing methanol and H₂O (4:1 v/v) (0.5 M), and distilled water was added thereto and stirred at room temperature for 3 hours to 12 hours. After washing with distilled water and filtering to obtain a solid, an extraction process was performed thereon three times by utilizing dichloromethane and water to obtain an organic layer. The organic layer thus obtained was dried by utilizing magnesium sulfate and concentrated to synthesize Intermediate Compound 1-o (yield: 88%).

### (16) Synthesis of Compound 1

Intermediate Compound 1-o, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 1 (yield: 19%).

### Synthesis Example 2: Synthesis of Compound 2

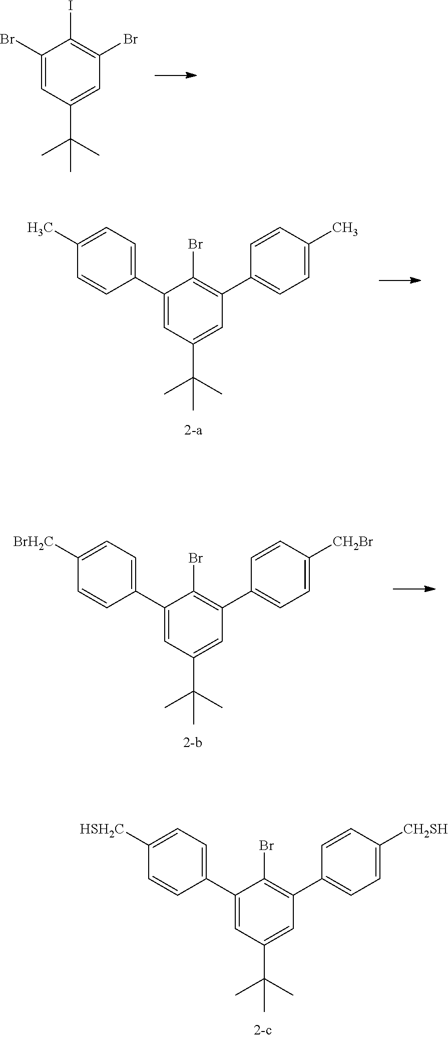

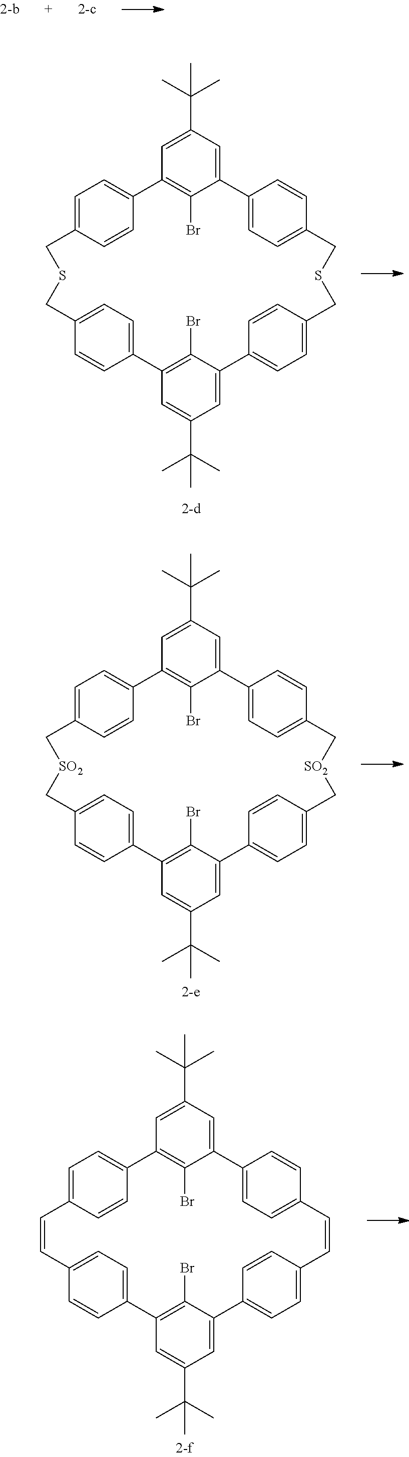 [SMILES: CC(C)(C)c1cc2c(Br)c(c1)-c1ccc(cc1)CSCc1ccc(cc1)-c1cc(C(C)(C)C)cc(c1Br)-c1ccc(cc1)CSCc1ccc-2cc1 ; CC(C)(C)c1cc2c(Br)c(c1)-c1ccc(cc1)CS(=O)(=O)Cc1ccc(cc1)-c1cc(C(C)(C)C)cc(c1Br)-c1ccc(cc1)CS(=O)(=O)Cc1ccc-2cc1 ; CC(C)(C)c1cc2c(Br)c(c1)c1ccc(ccc3ccc(cc3)c3cc(C(C)(C)C)cc(c3Br)c3ccc(ccc4ccc2cc4)cc3)cc1]

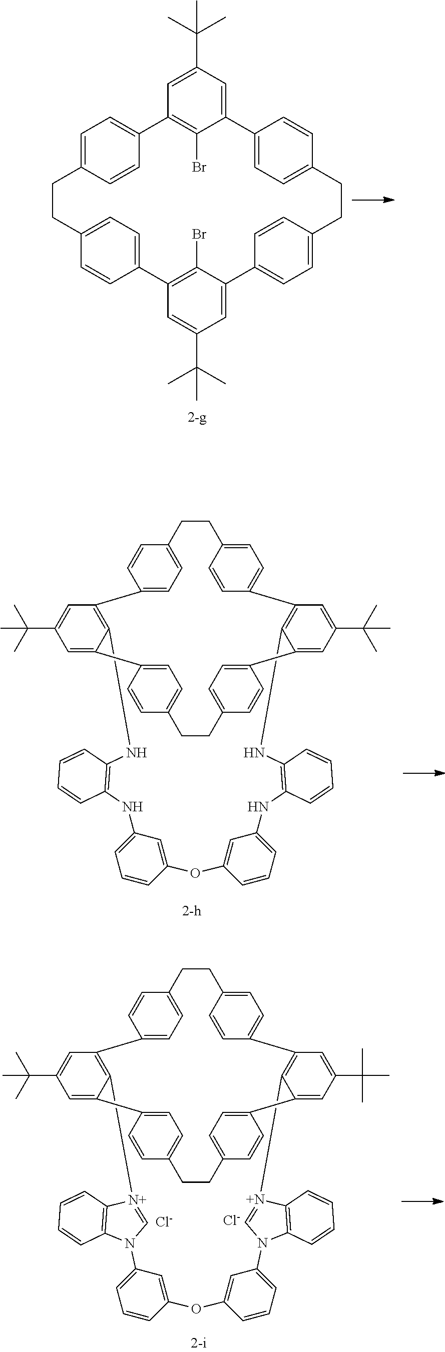

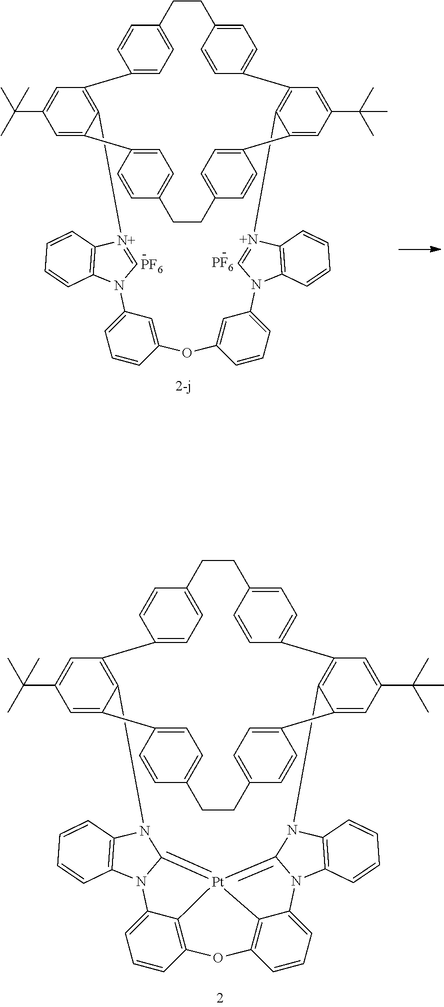

### (1) Synthesis of Intermediate Compound 2-a

1,3-dibromo-5-(tert-butyl)-2-iodobenzene (1.0 eq) and p-tolylmagnesium bromide (3.0 eq) were dissolved in anhydrous THF (0.1 M), and stirred at 80° C. for 1 hour. Br₂ was added to the reaction mixture, and stirred at room temperature for 15 hours. An extraction process was performed on the resultant reaction mixture three times by utilizing ethyl acetate and water to obtain an organic layer. The organic layer thus obtained was dried by utilizing magnesium sulfate, concentrated, and then subjected to column chromatography to synthesize Intermediate Compound 2-a (yield: 75%).

### (2) Synthesis of Intermediate Compound 2-b

Intermediate Compound 2-a (1.0 eq), N-bromosuccinimide (3.0 eq), and benzoyl peroxide (0.1 eq) were dissolved in acetonitrile, and stirred at 80° C. for 1 hour. The reaction mixture was cooled at room temperature, and an extraction process was performed thereon three times by utilizing ethyl acetate and water to obtain an organic layer. The organic layer thus obtained was dried by utilizing sodium sulfate, concentrated, and then subjected to column chromatography to synthesize Intermediate Compound 2-b (yield: 81%).

### (3) Synthesis of Intermediate Compound 2-c

Intermediate Compound 2-b (1.0 eq) was dissolved in ethanol (0.1 M), and thiourea (1.1 eq) was added thereto. The mixed solution was stirred at 85° C. for 6 hours. A 25% NaOH aqueous solution (0.025 M) was added to the mixed solution, and then stirred again at 85° C. for 15 hours. The resultant reaction mixture was cooled at room temperature, and an extraction process was performed thereon three times by utilizing diethyl ether and water to obtain an organic layer. The organic layer thus obtained was dried by utilizing magnesium sulfate, concentrated, and then subjected to column chromatography to synthesize Intermediate Compound 2-c (yield: 55%).

### (4) Synthesis of Intermediate Compound 2-d

Intermediate Compound 2-c (1.0 eq) and NaH (2.3 eq) were dissolved in anhydrous THF (0.1 M) under nitrogen conditions, and stirred at room temperature for 1 hour. Intermediate Compound 2-b (1.0 eq) was slowly added to the reaction mixture, and stirred at room temperature for 4 hours. The resultant reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 2-d (yield: 83%).

### (5) Synthesis of Intermediate Compound 2-e

Intermediate Compound 2-d (1.0 eq) was dissolved in dichloromethane (0.1 M) at 0° C., and 3-chloroperbenzoic acid (m-CPBA) (10 eq) in glacial acetic acid (0.1 M) was added thereto, and stirred at room temperature for 3 days. The reaction mixture was filtered, and the filtrate was washed with CHCl₃ to synthesize Intermediate Compound 2-e (yield: 90%).

### (6) Synthesis of Intermediate Compound 2-f

Intermediate Compound 2-e (1.0 eq), CCl₄ (1.2 eq), 10% NaOH aqueous solution (0.01 M), and cetyltrimethylammonium chloride (0.5 eq) were dissolved in dichloromethane, and stirred at 50° C. for 3 days. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 2-f (yield: 30%).

### (7) Synthesis of Intermediate Compound 2-g

Intermediate Compound 2-f (1.0 eq) and Pt/C (20 mol %) were dissolved in ethyl acetate (0.05 M), and H2 at a pressure of 40 psi was injected thereto at room temperature. After removing the catalyst and solvent from the reaction mixture, the resultant product was subjected to column chromatography to synthesize Intermediate Compound 2-g (yield: 95%).

### (8) Synthesis of Intermediate Compound 2-h

Intermediate Compound 1-1 (1.2 eq), Intermediate Compound 2-g (1.0 eq), Pd₂(dba)₃ (15 mol %), SPhos (20 mol %), and sodium tert-butoxide (5.0 eq) were dissolved in toluene (0.1 M), and stirred at 110° C. for 2.5 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 2-h (yield: 67%).

### (9) Synthesis of Intermediate Compound 2-i

Intermediate Compound 2-h (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate and concentrated to synthesize Intermediate Compound 2-i (yield: 80%).

### (10) Synthesis of Intermediate Compound 2-j

Intermediate Compound 2-i (1.0 eq) and ammonium hexafluorophosphate (6.0 eq) were dissolved in a solution containing methanol and H₂O (4:1 v/v) (0.5 M), and distilled water was added thereto and stirred at room temperature for 2 hours. After washing with distilled water and filtering to obtain a solid, an extraction process was performed thereon three times by utilizing dichloromethane and water to obtain an organic layer. The organic layer thus obtained was dried by utilizing magnesium sulfate, and then subjected to column chromatography to synthesize Intermediate Compound 2-j (yield: 95%).

### (11) Synthesis of Compound 2

Intermediate Compound 2-j, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 2 (yield: 15%).

### Synthesis Example 3: Synthesis of Compound 6

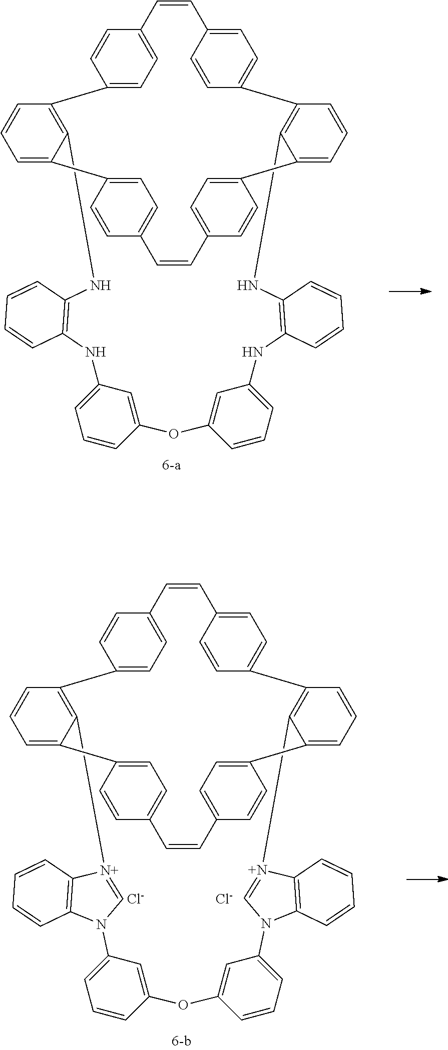 [SMILES: c1cc2cc(c1)Oc1cccc(c1)Nc1ccccc1Nc1c3cccc1c1ccc(ccc4ccc(cc4)c4cccc(c4Nc4ccccc4N2)c2ccc(ccc4ccc3cc4)cc2)cc1 ; c1cc2cc(c1)-n1c[n+](c3ccccc31)-c1c3cccc1c1ccc(ccc4ccc(cc4)c4cccc(c4-[n+]4cn(c5ccccc54)-c4cccc(c4)O2)c2ccc(ccc4ccc3cc4)cc2)cc1 ; [Cl-] ; [Cl-]]

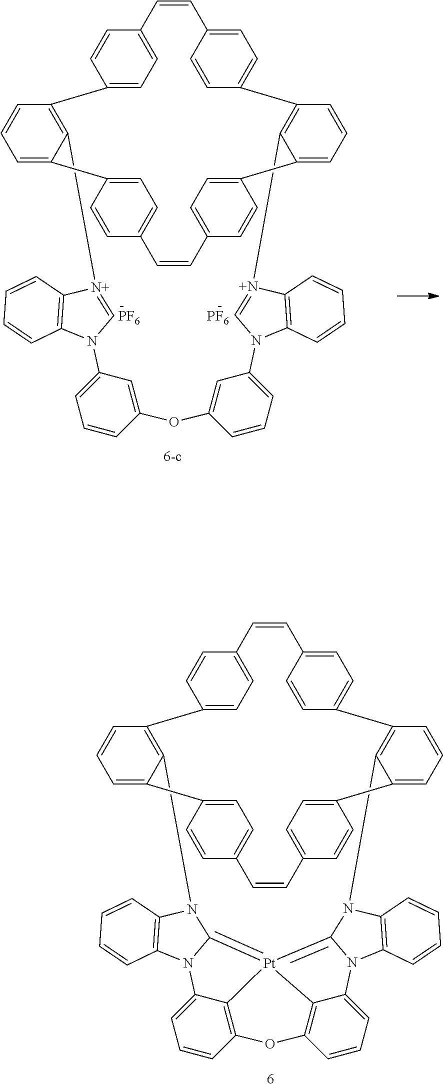

### (1) Synthesis of Intermediate Compound 6-a

Intermediate Compound 1-l (1.2 eq), Intermediate Compound 1-f (1.0 eq), Pd₂(dba)₃ (15 mol %), SPhos (20 mol %), and sodium tert-butoxide (5.0 eq) were dissolved in toluene (0.1 M), and stirred at 110° C. for 2.5 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 6-a (yield: 70%).

### (2) Synthesis of Intermediate Compound 6-b

Intermediate Compound 6-a (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate, and concentrated to synthesize Intermediate Compound 6-b (yield: 80%).

### (3) Synthesis of Intermediate Compound 6-c

Intermediate Compound 6-b (1.0 eq) and ammonium hexafluorophosphate (6.0 eq) were dissolved in a solution containing methanol and H₂O (4:1 v/v) (0.5 M), and distilled water was added thereto and stirred at room temperature for 2 hours. After washing with distilled water and filtering to obtain a solid, an extraction process was performed thereon three times by utilizing dichloromethane and water to obtain an organic layer. The organic layer thus obtained was dried by utilizing magnesium sulfate, and concentrated to synthesize Intermediate Compound 6-c (yield: 92%).

### (4) Synthesis of Compound 6

Intermediate Compound 6-c, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 6 (yield: 20%).

### Synthesis Example 4: Synthesis of Compound 11

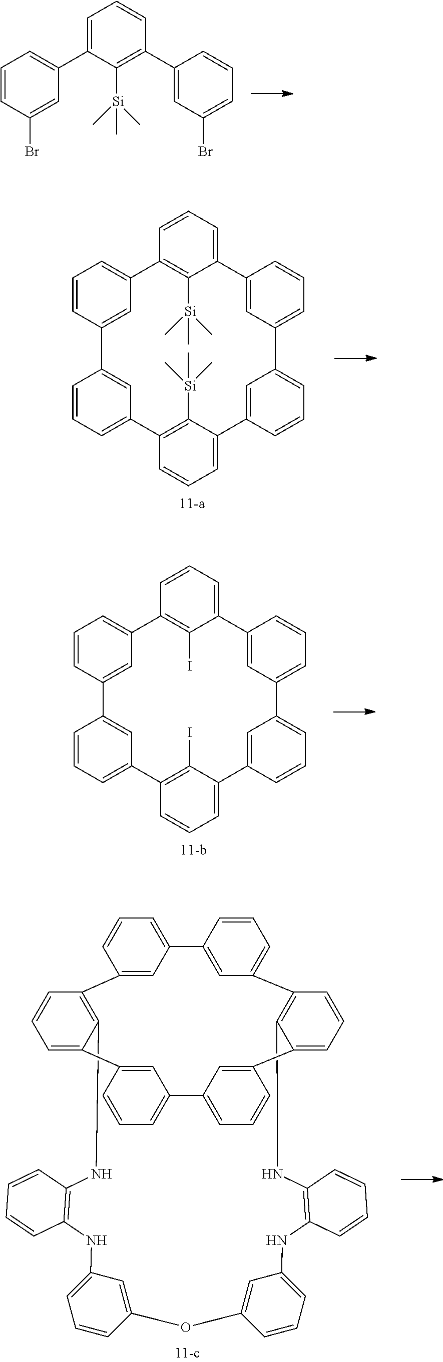 [SMILES: C[Si](C)(C)c1c(-c2cccc(Br)c2)cccc1-c1cccc(Br)c1 ; C[Si](C)(C)c1c2cccc1c1cccc(c1)c1cccc(c1)c1cccc(c1[Si](C)(C)C)c1cccc(c1)c1cccc2c1 ; Ic1c2cccc1c1cccc(c1)c1cccc(c1)c1cccc(c1I)c1cccc(c1)c1cccc2c1 ; c1cc2cc(c1)Oc1cccc(c1)Nc1ccccc1Nc1c3cccc1c1cccc(c1)c1cccc(c1)c1cccc(c1Nc1ccccc1N2)c1cccc(c1)c1cccc3c1]

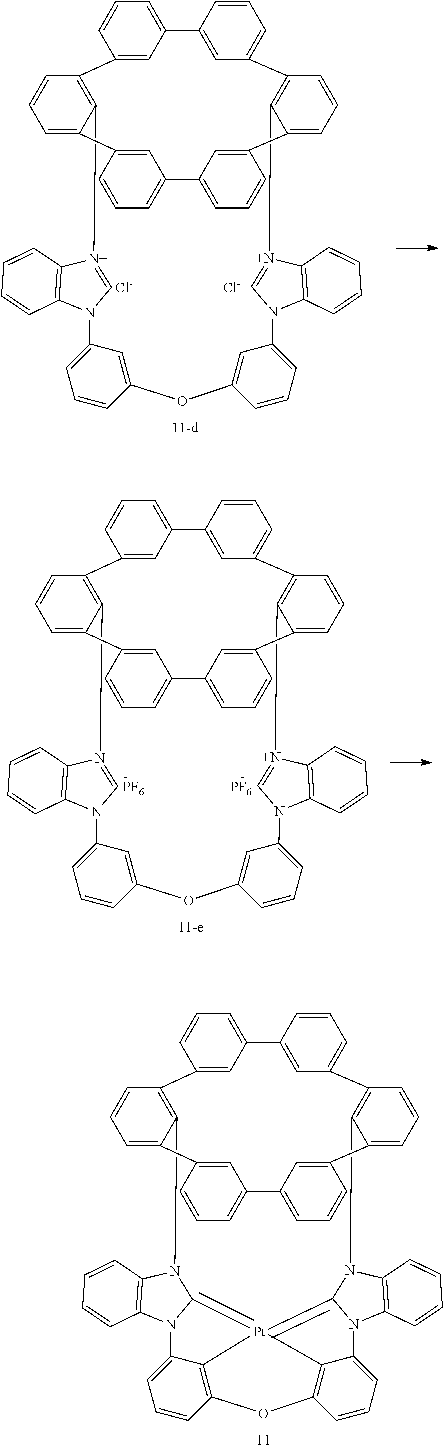

### (1) Synthesis of Intermediate Compound 11-a

(3,3″-dibromo-[1,1′:3′,1″-terphenyl]-2′-yl)trimethylsilane (1.0 eq), 2,2′-bipyridine (2.0 eq), 1,5-cyclooctadiene (cod) (2.0 eq), and [Ni(cod)₂] (1.9 eq) were dissolved in anhydrous DMF (0.1 M), and stirred at 80° C. for 3 days. After cooling the reaction mixture at room temperature, the reaction was terminated by adding 10% HCl thereto. Then, an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 11-a (yield: 60%).

### (2) Synthesis of Intermediate Compound 11-b

Intermediate Compound 11-a (1.0 eq) and iodine monochloride (2.0 eq) were dissolved in dichloromethane (0.1 M), and stirred at room temperature for 8 hours. The reaction mixture was filtered, and the filtrate was washed with THF and H₂O, and then dried to synthesize Intermediate Compound 11-b (yield: 80%).

### (3) Synthesis of Intermediate Compound 11-c

Intermediate Compound 1-1 (1.2 eq), Intermediate Compound 11-b (1.0 eq), Pd₂(dba)₃ (15 mol %), SPhos (20 mol %), and sodium tert-butoxide (5.0 eq) were dissolved in toluene (0.1 M), and stirred at 110° C. for 4 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 11-c (yield: 74%).

### (4) Synthesis of Intermediate Compound 11-d

Intermediate Compound 11-c (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate, and concentrated to synthesize Intermediate Compound 11-d (yield: 71%).

### (5) Synthesis of Intermediate Compound 11-e

Intermediate Compound 11-d (1.0 eq) and ammonium hexafluorophosphate (6.0 eq) were dissolved in a solution containing methanol and H₂O (4:1 v/v) (0.5 M), and distilled water was added thereto and stirred at room temperature for 3 hours. After washing with distilled water and filtering to obtain a solid, an extraction process was performed thereon three times by utilizing dichloromethane and water to obtain an organic layer. The organic layer thus obtained was dried by utilizing magnesium sulfate and concentrated to synthesize Intermediate Compound 11-e (yield: 90%).

### (6) Synthesis of Compound 11

Intermediate Compound 11-e, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 11 (yield: 22%).

### Synthesis Example 5: Synthesis of Compound 16

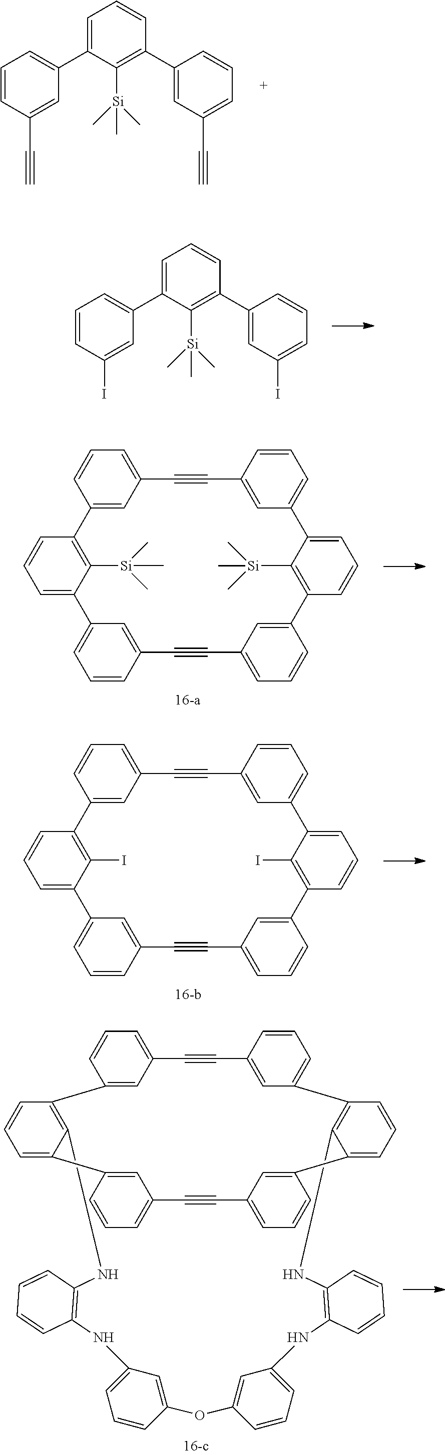 [SMILES: C#Cc1cccc(-c2cccc(-c3cccc(C#C)c3)c2[Si](C)(C)C)c1 ; C[Si](C)(C)c1c(-c2cccc(I)c2)cccc1-c1cccc(I)c1 ; C[Si](C)(C)c1c2cccc1c1cccc(c#cc3cccc(c3)c3cccc(c3[Si](C)(C)C)c3cccc(c#cc4cccc2c4)c3)c1 ; Ic1c2cccc1c1cccc(c#cc3cccc(c3)c3cccc(c3I)c3cccc(c#cc4cccc2c4)c3)c1 ; c1c2cccc(c2)c2cccc3c2Nc2ccccc2Nc2cccc(c2)Oc2cccc(c2)Nc2ccccc2Nc2c(cccc2c2cccc(c#cc4cccc3c4)c2)c2cccc(c#1)c2]

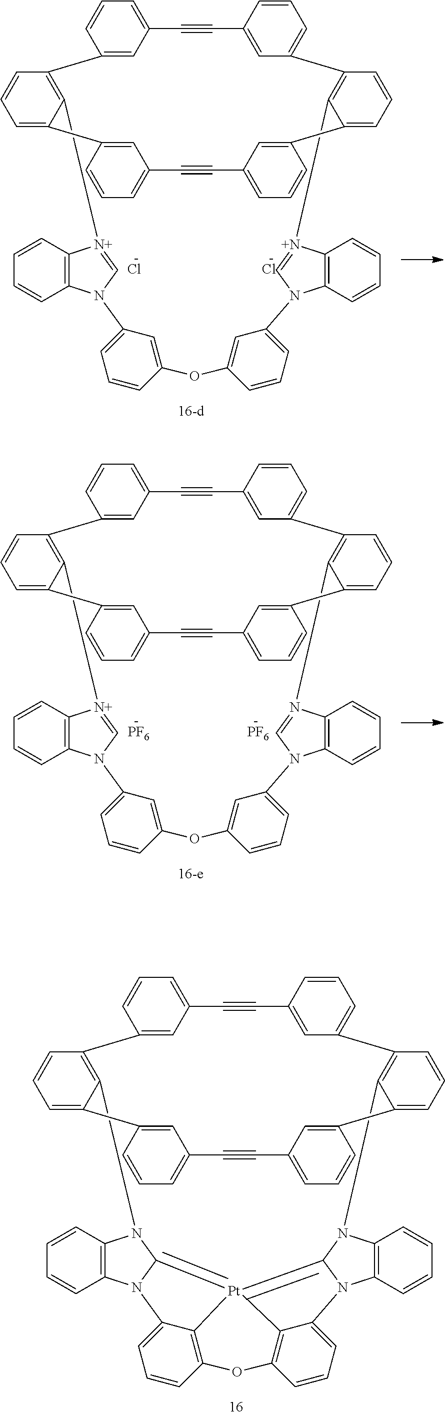

### (1) Synthesis of Intermediate Compound 16-a

(3,3″-diethynyl-[1,1′:3′,1″-terphenyl]-2′-yl)trimethylsilane (1.05 eq), (3,3″-diiodo-[1,1′: 3,1″-terphenyl]-2′-yl)trimethylsilane (1.0 eq), PdCl₂(PPh₃)₄ (2 mol %), CuI (4 mol %), and triethylamine (2.5 eq) were dissolved in THF (0.1 M), and stirred at 80° C. for 12 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 16-a (yield: 68%).

### (2) Synthesis of Intermediate Compound 16-b

Intermediate Compound 16-a (1.0 eq) and iodine monochloride (2.0 eq) were dissolved in dichloromethane (0.1 M), and stirred at room temperature for 8 hours. The reaction mixture was filtered, and the filtrate was washed with THF and H₂O, and then dried to synthesize Intermediate Compound 16-b (yield: 82%).

### (3) Synthesis of Intermediate Compound 16-c

Intermediate Compound 1-1 (1.2 eq), Intermediate Compound 16-b (1.0 eq), Pd₂(dba)₃ (15 mol %), SPhos (20 mol %), and sodium tert-butoxide (5.0 eq) were dissolved in toluene (0.1 M), and stirred at 110° C. for 3 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 16-c (yield: 61%).

### (4) Synthesis of Intermediate Compound 16-d

Intermediate Compound 16-c (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography (5 vol % MeOH:MC) to synthesize Intermediate Compound 16-d (yield: 83%).

### (5) Synthesis of Intermediate Compound 16-e

Intermediate Compound 16-d (1.0 eq) and ammonium hexafluorophosphate (6.0 eq) were dissolved in a solution containing methanol and H₂O (4:1 v/v) (0.5 M), and distilled water was added thereto and stirred at room temperature for 3 hours to 12 hours. After washing with distilled water and filtering to obtain a solid, an extraction process was performed thereon three times by utilizing dichloromethane and water to obtain an organic layer. The organic layer thus obtained was dried by utilizing magnesium sulfate and concentrated to synthesize Intermediate Compound 16-e (yield: 90%).

### (6) Synthesis of Compound 16

Intermediate Compound 16-e, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 16 (yield: 17%).

### Synthesis Example 6: Synthesis of Compound 36

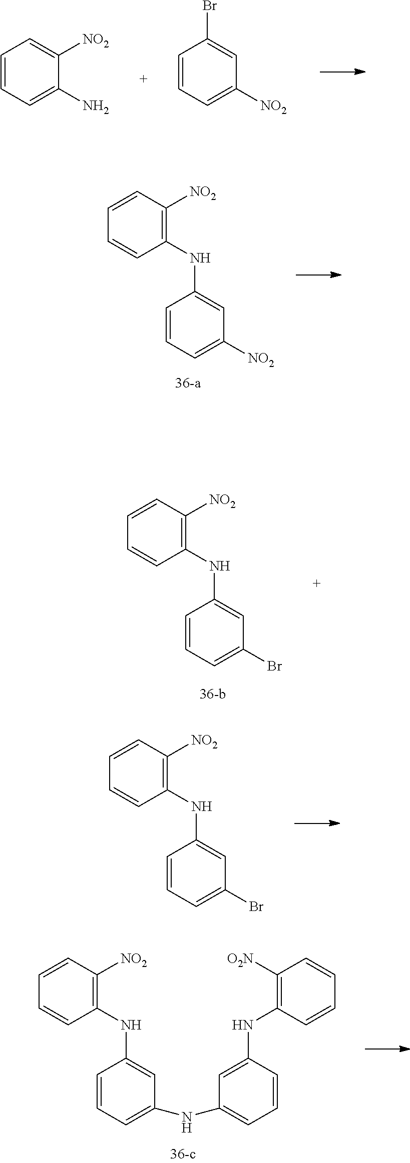 [SMILES: Nc1ccccc1[N+](=O)[O-] ; O=[N+]([O-])c1cccc(Br)c1 ; O=[N+]([O-])c1cccc(Nc2ccccc2[N+](=O)[O-])c1 ; O=[N+]([O-])c1ccccc1Nc1cccc(Br)c1 ; O=[N+]([O-])c1ccccc1Nc1cccc(Br)c1 ; O=[N+]([O-])c1ccccc1Nc1cccc(Nc2cccc(Nc3ccccc3[N+](=O)[O-])c2)c1]

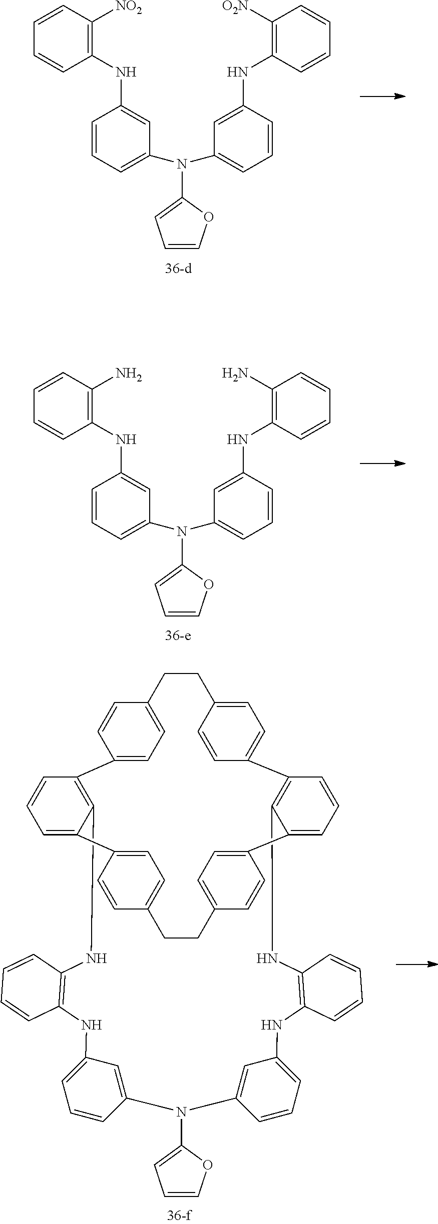 [SMILES: O=[N+]([O-])c1ccccc1Nc1cccc(N(c2cccc(Nc3ccccc3[N+](=O)[O-])c2)c2ccco2)c1 ; Nc1ccccc1Nc1cccc(N(c2cccc(Nc3ccccc3N)c2)c2ccco2)c1 ; c1cc2cc(c1)N(c1ccco1)c1cccc(c1)Nc1ccccc1Nc1c3cccc1-c1ccc(cc1)CCc1ccc(cc1)-c1cccc(c1Nc1ccccc1N2)-c1ccc(cc1)CCc1ccc-3cc1]

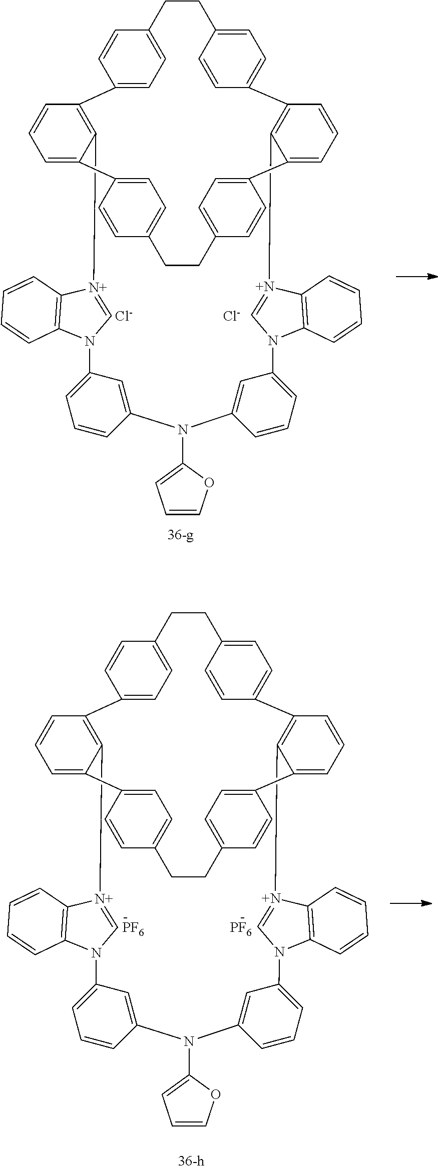

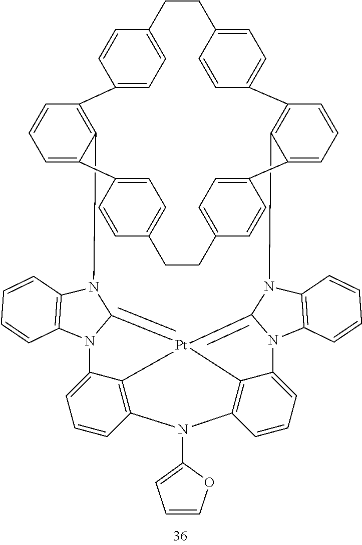

### (1) Synthesis of Intermediate Compound 36-a

2-nitroaniline (1.1 eq), 1-bromo-3-nitrobenzene (1.0 eq), Pd₂(dba)₃ (0.05 eq), SPhos (0.075 eq), and NaOtBu (2.0 eq) were dissolved in toluene (0.1 M), and stirred at 110° C. for 12 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 36-a (yield: 65%).

### (2) Synthesis of Intermediate Compound 36-b

Intermediate Compound 36-a (1.0 eq), Sn (1.5 eq), and HCl (30 eq) were dissolved in ethanol and stirred at 80° C. for 12 hours. After the reaction mixture was cooled at room temperature, the reaction mixture was neutralized with a NaOH solution. Next, an extraction process was performed thereon by utilizing dichloromethane and water to obtain an organic layer, which was then filtered through celite/silica gel. The filtrate was dried by utilizing magnesium sulfate and concentrated to synthesize Intermediate Compound 36-b (yield: 86%).

### (3) Synthesis of Intermediate Compound 36-c

Intermediate Compound 36-b (1.1 eq), N-(3-bromophenyl)-2-nitroaniline (1.0 eq), Pd₂(dba)₃ (0.05 eq), SPhos (0.075 eq), and NaOtBu (2.0 eq) were dissolved in toluene (0.1 M), and stirred at 110° C. for 12 hours. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 36-c (yield: 54%).

### (4) Synthesis of Intermediate Compound 36-d

Intermediate Compound 36-c (1.1 eq), 2-bromofuran (1.0 eq), PtBu₃ (5 mol %), Pd₂(dba)₃ (0.05 eq), and NaOtBu (2.0 eq) were dissolved in toluene (0.1 M), and stirred at 100° C. for 16 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 36-d (yield: 78%).

### (5) Synthesis of Intermediate Compound 36-e

Intermediate Compound 36-d (1.0 eq), Sn (3.0 eq), and HCl (60 eq) were dissolved in ethanol, and stirred at 80° C. for 20 hours. After the reaction mixture was cooled at room temperature, the reaction mixture was neutralized with a NaOH solution. Next, an extraction process was performed thereon by utilizing dichloromethane and water to obtain an organic layer, which was then filtered through celite/silica gel. The filtrate was dried by utilizing magnesium sulfate and concentrated to synthesize Intermediate Compound 36-e (yield: 91%).

### (6) Synthesis of Intermediate Compound 36-f

Intermediate Compound 36-e (1.2 eq), Intermediate Compound 1-g (1.0 eq), Pd₂(dba)₃ (5 mol %), SPhos (10 mol %), and sodium tert-butoxide (5.0 eq) were dissolved in toluene (0.1 M), and stirred at 110° C. for 3 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 36-f (yield: 62%).

### (7) Synthesis of Intermediate Compound 36-g

Intermediate Compound 36-f (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate and concentrated to synthesize Intermediate Compound 36-g (yield: 84%).

### (8) Synthesis of Intermediate Compound 36-h

Intermediate Compound 36-g (1.0 eq) and ammonium hexafluorophosphate (6.0 eq) were dissolved in a solution containing methanol and H₂O (4:1 v/v) (0.5 M), and distilled water was added thereto and stirred at room temperature for 3 hours to 12 hours. After washing with distilled water and filtering to obtain a solid, an extraction process was performed thereon three times by utilizing dichloromethane and water to obtain an organic layer. The organic layer thus obtained was dried by utilizing magnesium sulfate, and concentrated to synthesize Intermediate compound 36-h (yield: 92%).

### (9) Synthesis of Compound 36

Intermediate Compound 36-h, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 36 (yield: 14%).

### Synthesis Example 7: Synthesis of Compound 41

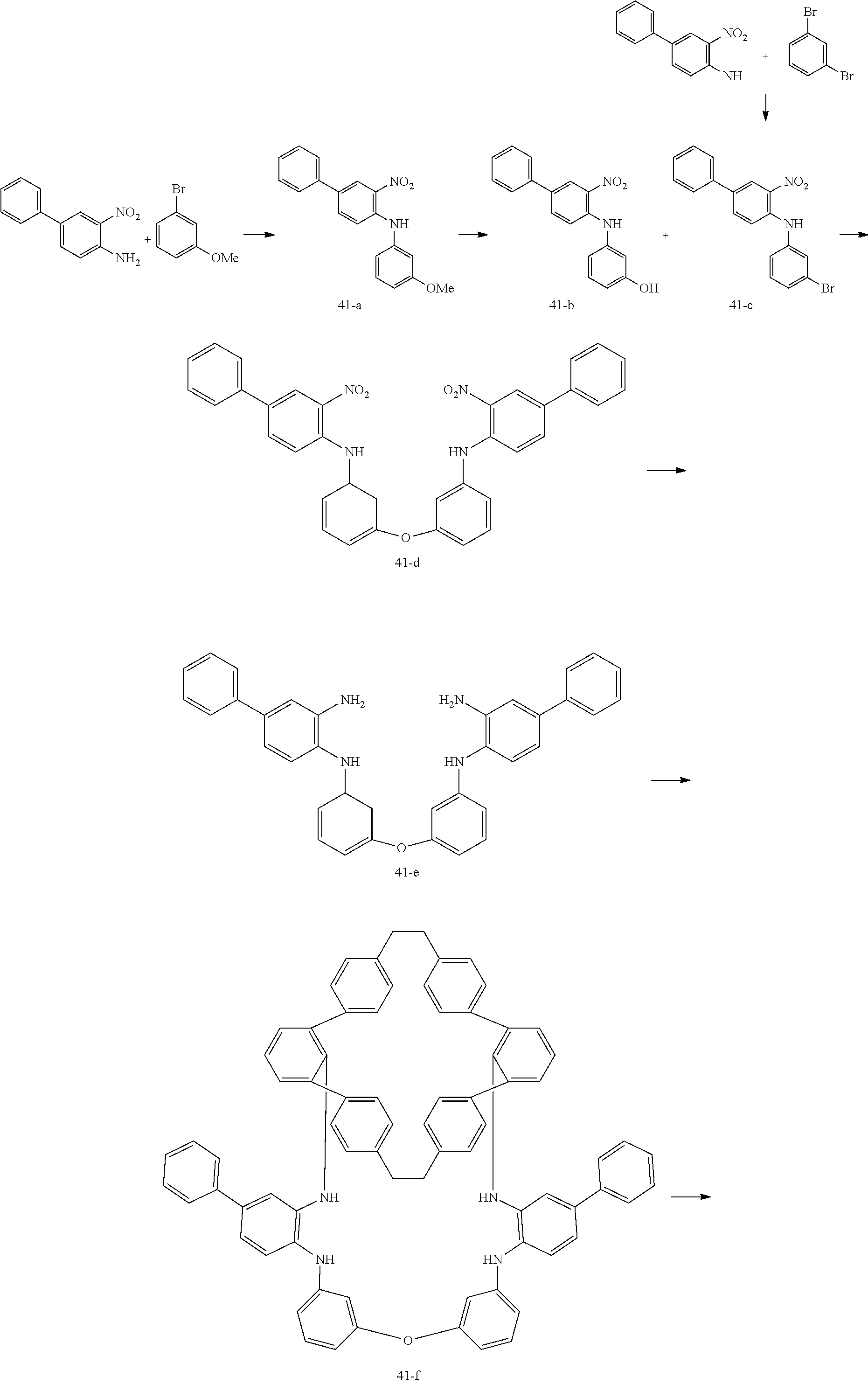

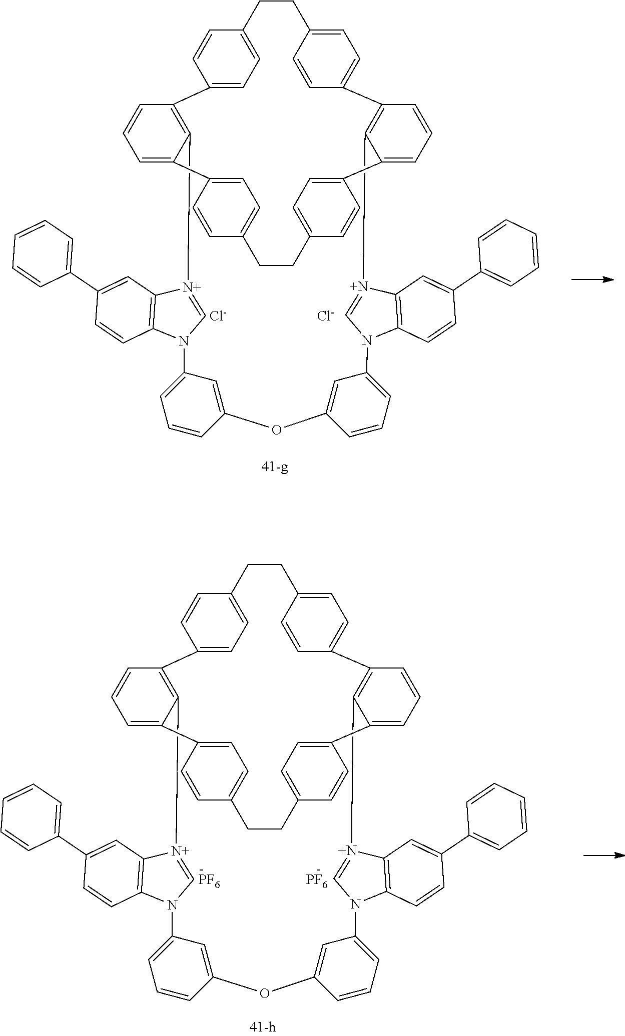

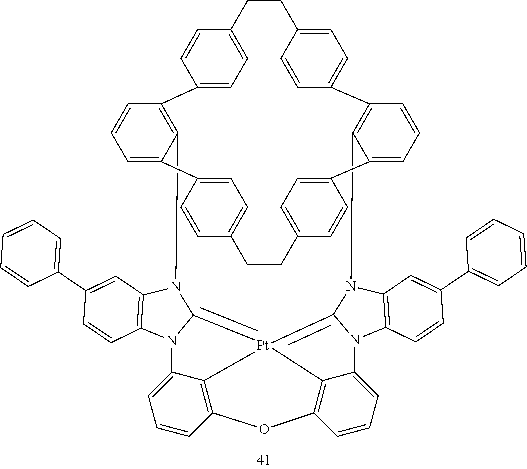

### (1) Synthesis of Intermediate Compound 41-a

3-nitro-[1,1′-biphenyl]-4-amine (1.2 eq), 3-bromoanisole (1.0 eq), Pd₂(dba)₃ (0.05 eq), SPhos (0.075 eq), and NaOtBu (2.0 eq) were dissolved in toluene (0.1 M), and stirred at 110° C. for 12 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 41-a (yield: 60%).

### (2) Synthesis of Intermediate Compound 41-b

Intermediate Compound 41-a (1.0 eq), HBr (0.3 M), and acetic acid (0.3 M) were stirred at 120° C. for 16 hours. The reaction mixture was cooled at room temperature, and neutralized with NaOH at 0° C. Then, an extraction process was performed thereon three times by utilizing dichloromethane and water to obtain an organic layer. The organic layer thus obtained was filtered through silica gel/celite, and the filtrate was dried by utilizing magnesium sulfate and concentrated to synthesize Intermediate Compound 41-b (yield: 91%).

### (3) Synthesis of Intermediate Compound 41-c

3-nitro-[1,1′-biphenyl]-4-amine (1.5 eq), 1,3-dibromobenzene (1.0 eq), Pd₂(dba)₃ (0.05 eq), SPhos (0.075 eq), and NaOtBu (2.0 eq) were dissolved in toluene (0.1 M), and stirred at 110° C. for 8 hours. The reaction mixture was cooled at room temperature, and an extraction process was performed thereon three times by utilizing ethyl acetate and water to obtain an organic layer. The organic layer thus obtained was dried by utilizing magnesium sulfate, concentrated, and then subjected to column chromatography to synthesize Intermediate Compound 41-c (yield: 65%).

### (4) Synthesis of Intermediate Compound 41-d

Intermediate Compound 41-b (1.0 eq), Intermediate Compound 41-c (1.2 eq), CuI (10 mol %), BPPO ligand (10 mol %), and potassium phosphate tribasic (2.0 eq) were dissolved in DMF (0.1 M), and stirred at 160° C. for 10 hours. The reaction mixture was cooled at room temperature, and DMF was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 41-d (yield: 54%).

### (5) Synthesis of Intermediate Compound 41-e

Intermediate Compound 41-d (1.0 eq), Sn (3.0 eq), and HCl (60 eq) were dissolved in ethanol, and stirred at 80° C. for 12 hours. After the reaction mixture was cooled at room temperature, the reaction mixture was neutralized with a NaOH solution. Next, an extraction process was performed thereon by utilizing dichloromethane and water to obtain an organic layer, which was then filtered through celite/silica gel. The filtrate was dried by utilizing magnesium sulfate and concentrated to synthesize Intermediate compound 41-e (yield: 86%).

### (6) Synthesis of Intermediate Compound 41-f

Intermediate Compound 41-e (1.0 eq), Intermediate Compound 1-g (1.2 eq), Pd₂(dba)₃ (15 mol %), SPhos (20 mol %), and sodium tert-butoxide (3.0 eq) were dissolved in toluene (0.1 M), and stirred at 110° C. for 3 hours. The reaction mixture was cooled at room temperature, and toluene was removed under reduced pressure. Then, an extraction process was performed thereon three times by utilizing dichloromethane and water to obtain an organic layer. The organic layer thus obtained was dried by utilizing magnesium sulfate, concentrated, and then subjected to column chromatography to synthesize Intermediate Compound 41-f (yield: 66%).

### (7) Synthesis of Intermediate Compound 41-g

Intermediate Compound 41-f (1.0 eq) was dissolved in triethyl orthoformate (60 eq), and 37% HCl (3.5 eq) was added thereto and stirred at 80° C. for 12 hours. The reaction mixture was cooled at room temperature, and triethyl orthoformate was removed under reduced pressure. Then, an extraction process was performed thereon three times by utilizing dichloromethane and water to obtain an organic layer. The organic layer thus obtained was dried by utilizing magnesium sulfate and concentrated to synthesize Intermediate Compound 41-g (yield: 86%).

### (8) Synthesis of Intermediate Compound 41-h

Intermediate Compound 41-g (1.0 eq) and ammonium hexafluorophosphate (6.0 eq) were dissolved in a solution containing methanol and H₂O (4:1 v/v) (0.5 M), and distilled water was added thereto and stirred at room temperature for 3 hours to 12 hours. After washing with distilled water and filtering to obtain a solid, an extraction process was performed thereon three times by utilizing dichloromethane and water to obtain an organic layer. The organic layer thus obtained was dried by utilizing magnesium sulfate and concentrated to synthesize Intermediate Compound 41-h (yield: 85%).

### (9) Synthesis of Compound 41

Intermediate Compound 41-h, dichloro(1,5-cyclooctadiene)platinum (II) (1.1 eq), and sodium acetate (5.0 eq) were dissolved in anhydrous 1,4-dioxane (0.05 M), and stirred under nitrogen conditions at 120° C. for 3 days. The reaction mixture was cooled at room temperature, and an extraction process was performed thereon three times by utilizing dichloromethane and water to obtain an organic layer. The organic layer thus obtained was dried by utilizing magnesium sulfate, concentrated, and then subjected to column chromatography (30 vol % MC:hexane) to synthesize Compound 41 (yield: 13%).

¹H NMR and MALDI-TOF MS of the compounds synthesized according to Synthesis Examples 1 to 7 are shown in Table 1. Synthesis methods of compounds other than the compounds of Synthesis Examples 1 to 7 may be easily recognized by those skilled in the art by referring to the synthesis paths and source materials.

TABLE 1

| | | MALDI-TOF | |
|---|---|---|---|
| | | MS [M⁺] | |
| Compound | ¹H NMR (CDCl₃, 500 MHz) | found | calc. |
| 1 | 7.76 (4H, m), 7.67 (2H, m), 7.43 (4H, dd), 7.38 | 1104.05 | 1104.19 |
| | (8H, m), 7.32 (8H, m), 7.17 (2H, t), 7.08 (2H, d), | | |
| | 6.92 (2H, d), 6.71 (2H, t), 6.66 (2H, dd), 2.88 (8H, s) | | |
| 2 | 7.81 (4H, m), 7.61 (2H, m), 7.39 (4H, dd), 7.38 | 1216.36 | 1216.41 |
| | (8H, m), 7.32 (8H, m), 7.17 (2H, t), 7.08 (2H, d), | | |
| | 6.92 (2H, d), 6.71 (2H, t), 6.57 (2H, dd), 2.88 (8H, s), | | |
| | 1.33 (18H, s) | | |
| 6 | 7.82 (4H, m), 7.65 (2H, m), 7.43 (4H, dd), 7.38 | 1100.11 | 1100.16 |
| | (8H, m), 7.32 (8H, m), 7.17 (2H, t), 7.08 (2H, d), | | |
| | 6.92 (2H, d), 6.71 (2H, t), 6.66 (2H, dd), 6.56 (4H, s) | | |
| 11 | 7.94 (4H, s), 7.73-7.72 (6H, m), 7.64 (4H, m), 7.43 | 1048.21 | 1048.08 |
| | (4H, t), 7.61 (8H, m), 7.17 (2H, t), 7.08 (2H, d), | | |
| | 6.90 (2H, d), 6.71 (2H, t), 6.66 (2H, dd) | | |
| 16 | 7.80 (4H, m), 7.72 (2H, dd), 7.67 (4H, m), 7.64 | 1113.07 | 1113.18 |
| | (4H, m), 7.50 (4H, m), 7.44 (4H, m)7.35 (2H, m), | | |
| | 7.22 (2H, m), 7.17 (2H, d), 7.03 (2H, m), 6.75 (2H, s), | | |
| | 6.43 (2H, m) | | |
| 36 | 7.88 (1H, dd), 7.73 (2H, s), 7.62 (8H, m), 7.61 (4H, m), | 1169.20 | 1169.26 |
| | 7.32 (8H, dd), 7.29 (2H, m), 7.27 (2H, m), 7.17 | | |
| | (2H, d), 7.03 (2H, m), 7.00 (1H, s), 6.86 (2H, s), | | |
| | 6.74 (2H, m), 6.68 (1H, s), 2.88 (4H, s) | | |
| 41 | 7.75 (4H, m), 7.73 (2H, s), 7.62 (8H, m), 7.61 (4H, m), | 1256.22 | 1256.39 |
| | 7.49 (4H, m), 7.41 (2H, m), 7.35 (2H, m), 7.32 | | |
| | (8H, dd), 7.22 (2H, m), 7.17 (2H, d), 7.03 (2H, m), | | |
| | 6.43 (2H, m), 2.88 (4H, s) | | |

### Evaluation Example 1

HOMO energy, LUMO energy, ³MLCT (%), simulation maximum emission wavelength (Δₘₐₓ^{sim}), experimental maximum emission wavelength (Δₘₐₓ^{exp}), and ³MC energy of compounds utilized in Synthesis Examples 1 to 7 and Comparative Examples were measured, and results thereof are shown in Table 2.

Characteristics of Compounds 1, 2, 6, 11, 16, 36, and 41 and Compounds BD1 and BD2 as comparative compounds were evaluated, and the HOMO energy and the LUMO energy of the compounds were measured according to differential pulse voltammetry. Here, a bandgap value was an absolute value of a difference between the LUMO energy level and the HOMO energy level. The ³MC state energy level value was evaluated utilizing B3LYP functional. The ³MLCT (%) value was measured by structural optimization at the level of B3LYP, 6-31 G(d,p) utilizing a density functional theory (DFT) calculation method of the Gaussian program.

TABLE 2

| | | HOMO | LUMO | | | ³MC | |
|---|---|---|---|---|---|---|---|
| | Compound | (eV) | (eV) | λₘₐₓ^{sim}(nm) | λₘₐₓ^{exp}(nm) | (kcal/mol) | ³MLCT(%) |
| Synthesis | 1 | −5.05 | −1.33 | 469 | 460 | 1.30 | 12.08 |
| Example 1 | | | | | | | |
| Synthesis | 2 | −5.03 | −1.31 | 469 | 461 | 1.33 | 12.11 |
| Example 2 | | | | | | | |
| Synthesis | 6 | −5.03 | −1.34 | 469 | 460 | 1.31 | 12.11 |
| Example 3 | | | | | | | |
| Synthesis | 11 | −5.08 | −1.33 | 469 | 461 | 1.26 | 12.11 |
| Example 4 | | | | | | | |
| Synthesis | 16 | −5.08 | −1.32 | 469 | 461 | 1.22 | 12.30 |
| Example 5 | | | | | | | |
| Synthesis | 36 | −5.07 | −1.32 | 468 | 461 | 1.29 | 12.11 |
| Example 6 | | | | | | | |
| Synthesis | 41 | −5.08 | −1.31 | 469 | 460 | 1.32 | 12.30 |
| Example 7 | | | | | | | |
| Comparative | BD1 | −5.20 | −1.27 | 465 | 453 | 0.81 | 9.80 |
| Examples 1 | | | | | | | |
| and 3 | | | | | | | |
| Comparative | BD2 | −5.19 | −1.28 | 464 | 457 | 0.81 | 9.77 |
| Example 2 | | | | | | | |

### Example 1

As a substrate also serving as an anode, a glass substrate with 15 Ω/cm² (1,200 Å) ITO (manufactured by Corning. Inc.) formed thereon was cut to a size of 50 mm×50 mm×0.7 mm, and sonicated with isopropyl alcohol and pure water, each for 5 minutes. Then, ultraviolet light was irradiated for 30 minutes thereto, and ozone was exposed thereto for cleaning. Subsequently, the resultant glass substrate was mounted on a vacuum deposition apparatus.

On the anode, 2-TNATA was vacuum-deposited to form a hole injection layer having a thickness of 600 Å, and 4,4′-bis[N-(1-naphthyl)-N-phenylamino]biphenyl (hereinafter, referred as “NPB”) was vacuum-deposited on the hole injection layer to form a hole transport layer having a thickness of 300 Å.

Compound 1 (as the first compound), Compound ETH85 (as the second compound), and Compound HTH29 (as the third compound) were vacuum-deposited on the hole transport layer to form an emission layer having a thickness of 400 Å. Here, an amount of Compound 1 was 10 wt % based on a total weight (100 wt %) of the emission layer, and a weight ratio of Compound ETH85 to Compound HTH29 was adjusted to 3:7.

Compound ETH2 was vacuum-deposited on the emission layer to form a hole blocking layer having a thickness of 50 Å, Alq₃ was vacuum-deposited on the hole blocking layer to form an electron transport layer having a thickness of 300 Å, LiF was vacuum-deposited on the electron transport layer to form an electron injection layer having a thickness of 10 Å, and then A₁ was vacuum-deposited thereon to form a cathode having a thickness of 3,000 Å, thereby completing manufacture of an organic light-emitting device.

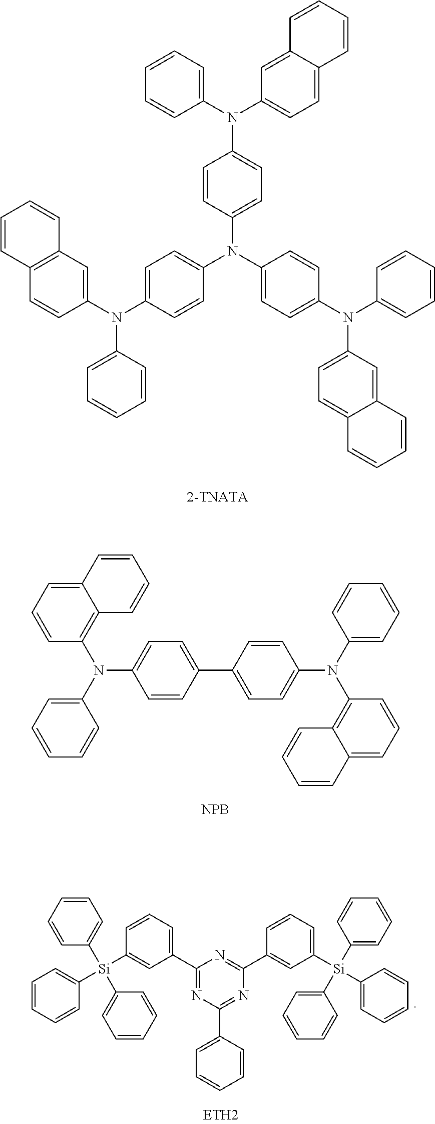 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

### Examples 2 to 7 and Comparative Examples 1 and 2

Organic light-emitting devices were manufactured in substantially the same manner as in Example 1, except that, in forming an emission layer, compounds shown in Table 3 were utilized as the first compound, the second compound, and the third compound.

### Example 8 and Comparative Example 3

Organic light-emitting device were manufactured in substantially the same manner as in Example 1, except that, in forming an emission layer, Compound 1 or BD1, respectively (as the first compound), Compound ETH85 (as the second compound), Compound HTH29 (as the third compound), and Compound DFD1 (as the fourth compound) were vacuum-deposited on the hole transport layer, instead of Compound 1 (as the first compound), Compound ETH85 (as the second compound), and Compound HTH29 (as the third compound). Here, an amount of Compound 1 or BD1 was 10 wt % based on a total weight of the emission layer (100 wt %), an amount of Compound DFD1 was 0.5 wt % based on a total weight of the emission layer (100 wt %), and a weight ratio of Compound ETH85 to Compound HTH29 was adjusted to 3:7.

### Evaluation Example 2

Driving voltage (V) at 1,000 cd/m², luminescence efficiency (cd/A), color conversion efficiency (cd/A/y), maximum emission wavelength (nm), and lifespan (T₉₀) of the organic light-emitting devices manufactured in Examples 1 to 8 and Comparative Examples 1 to 3 were each measured by utilizing Keithley SMU 236 and luminance meter PR650, and results thereof are shown in Tables 3 and 4. In Table 4, the lifespan (T₉₀) is a measure of the time (hr) taken for the luminance to reach 90% of the initial luminance.

TABLE 3

| | | | | Auxiliary | | | |
|---|---|---|---|---|---|---|---|
| | Dopant | Host | | dopant | | Driving | Luminescence |
| | First | Second | Third | Fourth | Luminance | voltage | efficiency |
| No. | compound | compound | compound | compound | (cd/m²) | (V) | (cd/A) |
| Example 1 | 1 | ETH85 | HTH29 | — | 1000 | 4.8 | 42.1 |
| Example 2 | 2 | ETH85 | HTH29 | — | 1000 | 4.8 | 39.5 |
| Example 3 | 6 | ETH85 | HTH41 | — | 1000 | 4.7 | 35.1 |
| Example 4 | 11 | ETH85 | HTH29 | — | 1000 | 4.7 | 32.2 |
| Example 5 | 16 | ETH85 | HTH29 | — | 1000 | 4.8 | 36.7 |
| Example 6 | 36 | ETH85 | HTH29 | — | 1000 | 4.7 | 40.0 |
| Example 7 | 41 | ETH85 | HTH29 | — | 1000 | 4.8 | 33.6 |
| Example 8 | 1 | ETH85 | HTH29 | DFD1 | 1000 | 4.7 | 75.5 |
| Comparative | BD1 | ETH85 | HTH29 | — | 1000 | 4.9 | 20.1 |
| Example 1 | | | | | | | |
| Comparative | BD2 | ETH85 | HTH29 | — | 1000 | 4.7 | 17.2 |
| Example 2 | | | | | | | |
| Comparative | BD1 | ETH85 | HTH29 | DFD1 | 1000 | 5.0 | 37.0 |
| Example 3 | | | | | | | |

TABLE 4

| | | | | Auxiliary | Color | Maximum | |
|---|---|---|---|---|---|---|---|
| | Dopant | Host | | dopant | conversion | emission | Lifespan |
| | First | Second | Third | Fourth | efficiency | wavelength | (T₉₀) |
| No. | compound | compound | compound | compound | (cd/A/y) | (nm) | (hr) |
| Example | 1 | ETH85 | HTH29 | — | 278 | 460 | 35 |
| 1 | | | | | | | |
| Example | 2 | ETH85 | HTH29 | — | 280 | 461 | 35 |
| 2 | | | | | | | |
| Example | 6 | ETH85 | HTH41 | — | 281 | 460 | 34 |
| 3 | | | | | | | |
| Example | 11 | ETH85 | HTH29 | — | 277 | 461 | 39 |
| 4 | | | | | | | |
| Example | 16 | ETH85 | HTH29 | — | 275 | 461 | 31 |
| 5 | | | | | | | |
| Example | 36 | ETH85 | HTH29 | — | 278 | 461 | 29 |
| 6 | | | | | | | |
| Example | 41 | ETH85 | HTH29 | — | 278 | 460 | 30 |
| 7 | | | | | | | |
| Example | 1 | ETH85 | HTH29 | DFD1 | 310 | 460 | 68 |
| 8 | | | | | | | |
| Comparative | BD1 | ETH85 | HTH29 | — | 151 | 453 | 7 |
| Example | | | | | | | |
| 1 | | | | | | | |
| Comparative | BD2 | ETH85 | HTH29 | — | 122 | 457 | 3 |
| Example | | | | | | | |
| 2 | | | | | | | |
| Comparative | BD1 | ETH85 | HTH29 | DFD1 | 160 | 454 | 16 |
| Example | | | | | | | |
| 3 | | | | | | | |

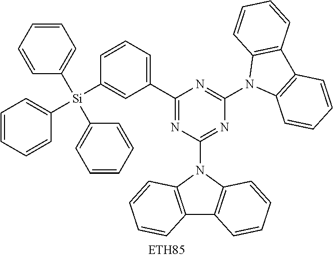 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

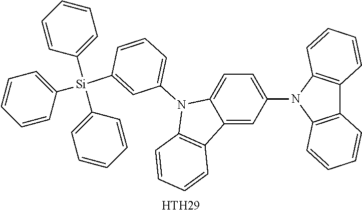

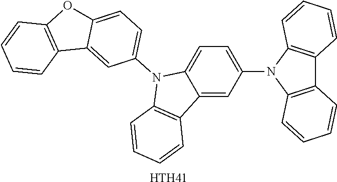

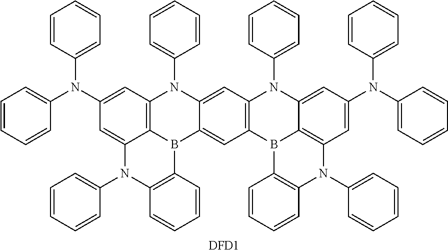

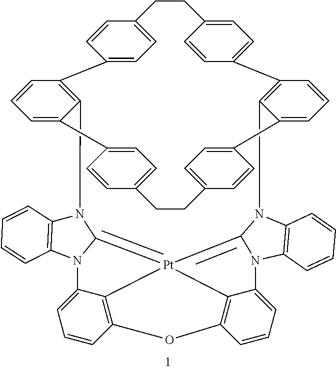

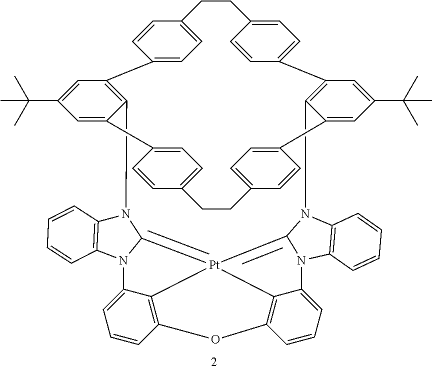

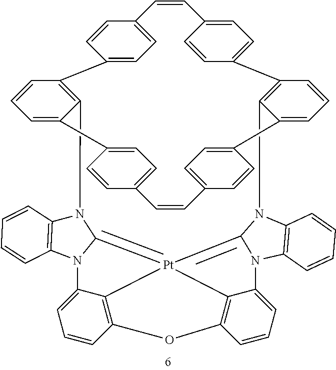

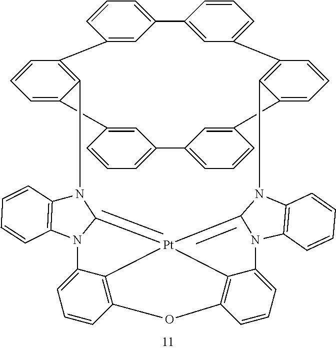

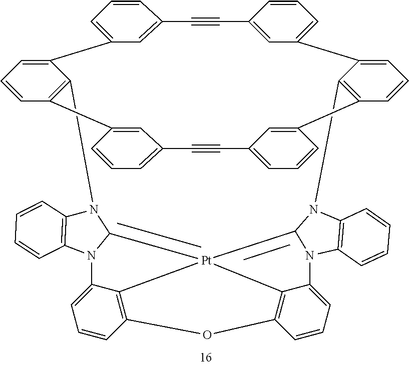

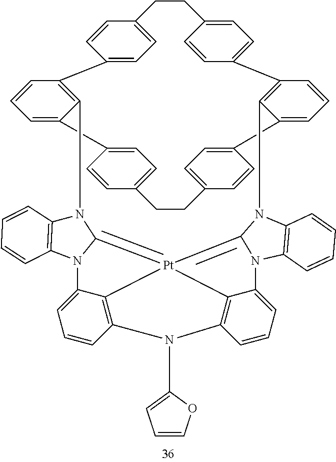

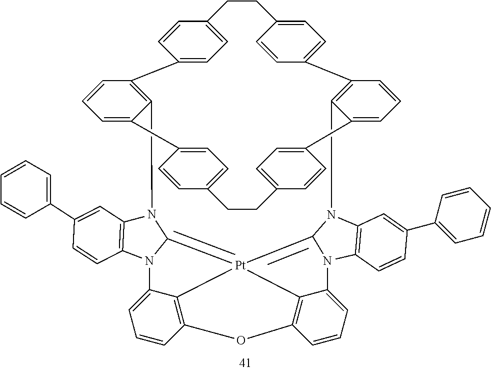

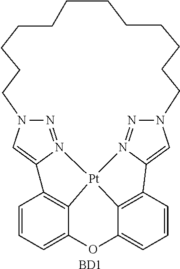

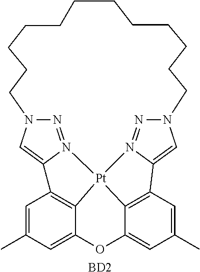

Referring to Tables 3 and 4, it was confirmed that the organic light-emitting devices of Examples 1 to 8 emitted deep blue light and had excellent or improved driving voltage, luminescence efficiency, color conversion efficiency, and lifespan characteristics.

As described above, according to the one or more embodiments, a light-emitting device including an organometallic compound represented by Formula 1 may have excellent or improved characteristics in terms of luminescence efficiency, color conversion efficiency, and lifespan, without a significant increase in driving voltage. Accordingly, the light-emitting device may provide for a high-quality electronic apparatus.

It should be understood that embodiments described herein should be considered in a descriptive sense only and not for purposes of limitation. Descriptions of features or aspects within each embodiment should typically be considered as available for other similar features or aspects In one or more embodiments. While one or more embodiments have been described with reference to the drawings, it will be understood by those of ordinary skill in the art that one or more suitable changes in form and details may be made therein without departing from the spirit and scope of the present disclosure as defined by the following claims and equivalents thereof.

What is claimed is:

1. A light-emitting device comprising:
a first electrode;
a second electrode facing the first electrode; and
an interlayer between the first electrode and the second electrode, the interlayer comprising an emission layer,
wherein the emission layer comprises an organometallic compound represented by Formula 1: 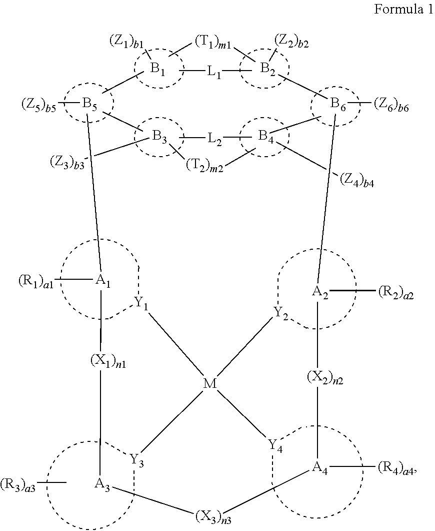
and wherein, in Formula 1,
M is iridium (Ir), platinum (Pt), palladium (Pd), copper (Cu), silver (Ag), gold (Au), rhodium (Rh), ruthenium (Ru), rhenium (Re), osmium (Os), titanium (Ti), zirconium (Zr), hafnium (Hf), europium (Eu), terbium (Tb), or thulium (Tm),
X₁ to X₃ are each independently a single bond, *—C(R₅)(R₆)—*′, *—C(R₅)═*′, *═C(R₅)—*′, *—C(R₅)═C(R₆)—*′, *—C(═O)—*′, *—C(═S)—*′, *—C≡C—*′, *—B(R₅)—*′, *—N(R₅)—*′, *—O—*′, *—P(R₅)—*′, *—Si(R₅)(R₆)—*′, *—P(═O)(R₅)—*′, *—S—*′, *—S(═O)—*′, *—S(═O)₂—*′, or *—Ge(R₅)(R₆)*′,
n1 to n3 are each independently 1, 2, or 3,
L₁ and L₂ are each independently a single bond, a C₁-C₂₀ alkylene group unsubstituted or substituted with at least one R₁₀ₐ, a C₂-C₆₀ alkenylene group unsubstituted or substituted with at least one R₁₀ₐ, or a C₂-C₆₀ alkynylene group unsubstituted or substituted with at least one R₁₀ₐ,
T₁ is *—C(Z₇)(Z₈)—*′, *—C(Z₇)═*′, *═C(Z₇)—*′, *—C(Z₇)═C(Z₈)—*′, *—C(═O)—*′, *—C(═S)—*′, *—C≡C—*′, *—B(Z₇)—*′, *—N(Z₇)—*′, *—O—*′, *—P(Z₇)—*′, *—Si(Z₇)(Z₈)—*′, *—P(═O)(Z₇)—*′, *—S—*′, *—S(═O)*′, *—S(═O)₂—*′, or *—Ge(Z₇)(Z₈)*′,
T₂ is *—C(Z₉)(Z₁₀)*′, *—C(Z₉)═*′, *═C(Z₉)—*′, *—C(Z₉)═C(Z₁₀)—*′, *—C(═O)—*′, *—C(═S)—*′, *—CC C*′, *—B(Z₉)—*′, *—N(Z₉)—*′, *—O—*′, *—P(Z₉)—*′, *—Si(Z₉)(Z₁₀)—*′, *—P(═O)(Z₉)—*′, *—S—*′, *—S(═O)*′, *—S(═O)₂*′, or *—Ge(Z₉)(Z₁₀)*′,
m1 and m2 are each independently 0, 1, 2, or 3, and i) when m1 is 0, T₁ is not present, and ii) when m2 is 0, T₂ is not present,
Y₁ to Y₄ are each independently C or N,
ring A₁ to ring A₄ and ring B₁ to ring B₆ are each independently a C₃-C₆₀ carbocyclic group or a C₁-C₆₀ heterocyclic group,
R₁ to R₆ and Z₁ to Z₁₀ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkoxy group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
two or more of R₁ to R₆ and Z₁ to Z₁₀ are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
a1 to a4 are each independently an integer from 0 to 10,
b1 to b6 are each independently an integer from 0 to 10,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each independently unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each independently unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each independently unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein
the first electrode is an anode,
the second electrode is a cathode,
the interlayer further comprises a hole transport region between the first electrode and the emission layer, and an electron transport region between the emission layer and the second electrode,
the hole transport region comprises a hole injection layer, a hole transport layer, an emission auxiliary layer, an electron blocking layer, or any combination thereof, and
the electron transport region comprises a hole blocking layer, an electron transport layer, an electron injection layer, or any combination thereof.

3. The light-emitting device of claim 1, wherein the emission layer is configured to emit blue light having a maximum emission wavelength in a range of about 430 nm to about 500 nm.

4. The light-emitting device of claim 1, wherein the emission layer comprises a host and a dopant, and
the dopant comprises the organometallic compound represented by Formula 1.

5. An electronic apparatus comprising the light-emitting device of claim 1.

6. The electronic apparatus of claim 5, further comprising a thin-film transistor,
wherein the thin-film transistor comprises a source electrode and a drain electrode, and
the first electrode of the light-emitting device is electrically coupled to one of the source electrode or the drain electrode of the thin-film transistor.

7. The electronic apparatus of claim 6, further comprising a color filter, a color conversion layer, a touch screen layer, a polarizing layer, or any combination thereof.

8. An organometallic compound represented by Formula 1: 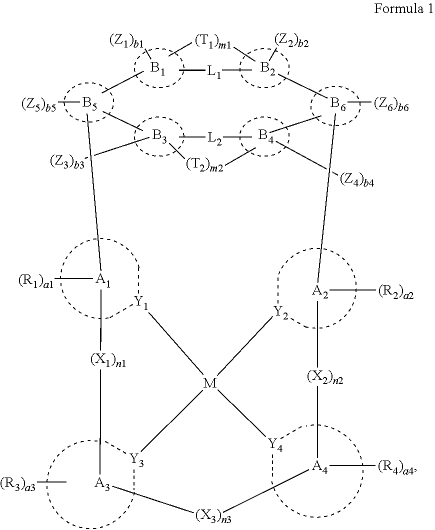
wherein, in Formula 1,
M is iridium (Ir), platinum (Pt), palladium (Pd), copper (Cu), silver (Ag), gold (Au), rhodium (Rh), ruthenium (Ru), rhenium (Re), osmium (Os), titanium (Ti), zirconium (Zr), hafnium (Hf), europium (Eu), terbium (Tb), or thulium (Tm),
X₁ to X₃ are each independently a single bond, *—C(R₅)(R₆)—*′, *—C(R₅)═*′, *═C(R₅) *′, *—C(R₅)═C(R₆)—*′, *—C(═O)—*′, *—C(═S)—*′, *—C≡C—*′, *—B(R₅) *′, *—N(R₅)—*′, *—O—*′, *—P(R₅)—*′, *—Si(R₅)(R₆)—*′, *—P(═O)(R₅)—*′, *—S—*′, *—S(═O)—*′, *—S(═O)₂—*′, or *—Ge(R₅)(R₆)*′,
n1 to n3 are each independently 1, 2, or 3,
L₁ and L₂ are each independently a single bond, a C₁-C₂₀ alkylene group unsubstituted or substituted with at least one R₁₀ₐ, a C₂-C₆₀ alkenylene group unsubstituted or substituted with at least one R₁₀ₐ, or a C₂-C₆₀ alkynylene group unsubstituted or substituted with at least one R₁₀ₐ,
T₁ is *—C(Z₇)(Z₈)—*′, *—C(Z₇)═*′, *═C(Z₇)—*′, *—C(Z₇)═C(Z₈)—*′, *—C(═O)—*′, *—C((═S)—*′ *—C≡C—*′, *—B(Z₇)*′, *—N(Z₇)*′, *—O—*′, *—P(Z₇)—*′, *—Si(Z₇)(Z₈)—*′, *—P(═O)(Z₇)—*′, *—S—*′, *—S(═O)*′, *—S(═O)₂—*′, or *—Ge(Z₇)(Z₈)*′,
T₂ is *—C(Z₉)(Z₁₀)*′, *—C(Z₉)═*′, *═C(Z₉)—*′, *—C(Z₉)═C(Z₁₀)*′, *—C(═O)—*′, *—C(═S)—*′, *—C *′, *—B(Z₉)—*′, *—N(Z₉)—*′, *—O—*′, *—P(Z₉)—*′, *—Si(Z₉)(Z₁₀)—*′, *—P(═O)(Z₉)—*′, *—S—*′, *—S(═O)—*′, *—S(═O)₂*′, or *—Ge(Z₉)(Z₁₀)*′,
m1 and m2 are each independently 0, 1, 2, or 3, and i) when m1 is 0, T₁ is not present, and ii) when m2 is 0, T₂ is not present,
Y₁ to Y₄ are each independently C or N,
ring A₁ to ring A₄ and ring B₁ to ring B₆ are each independently a C₃-C₆₀ carbocyclic group or a C₁-C₆₀ heterocyclic group,
R₁ to R₆ and Z₁ to Z₁₀ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkoxy group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
two or more of R₁ to R₆ and Z₁ to Z₁₀ are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
a1 to a4 are each independently an integer from 0 to 10,
b1 to b6 are each independently an integer from 0 to 10,
* and *′ each indicate a binding site to a neighboring atom,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each independently unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each independently unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each independently unsubstituted or substituted with deuterium, —F, a cyano group, a C₁-C₆₀ alkyl group, a C₁-C₆₀ alkoxy group, a phenyl group, a biphenyl group, or any combination thereof.

9. The organometallic compound of claim 8, wherein M is Pt, Pd, or Au.

10. The organometallic compound of claim 8, wherein X₁ and X₂ are each independently a single bond, *—C(R₅)(R₆)—*′, *—B(R₅)—*′, *—N(R₅)—*′, *—O—*′, *—P(R₅)—*′, *—Si(R₅)(R₆)—*′, or *—S—*′, and
X₃ is *—C(R₅)(R₆)—*′, *—B(R₅)*′, *—N(R₅)—*′, *—0*′, *—P(R₅)—*′, *—Si(R₅)(R₆)—*′, or *—S—*′.

11. The organometallic compound of claim 8, wherein n1 to n3 are each 1.

12. The organometallic compound of claim 8, wherein L₁ and L₂ are each independently a single bond, a C₁-C₅ alkylene group unsubstituted or substituted with at least one R₁₀ₐ, a C₂-C₅ alkenylene group unsubstituted or substituted with at least one R₁₀ₐ, or a C₂-C₅ alkynylene group unsubstituted or substituted with at least one R₁₀ₐ.

13. The organometallic compound of claim 8, wherein T₁ is *—C(Z₇)(Z₈)—*′, *—B(Z₇)*′, *—N(Z₇)*′, *—O—*′, *—Si(Z₇)(Z₈)—*′, or *—S—*′, and
T₂ is *—C(Z₉)(Z₁₀)*′, *—B(Z₉)*′, *—N(Z₉)*′, *—O—*′, *—Si(Z₉)(Z₁₀)—*′, or *—S*′.

14. The organometallic compound of claim 8, wherein m1 and m2 are each independently 0 or 1.

15. The organometallic compound of claim 8, wherein each of Y₁ to Y₄ is C.

16. The organometallic compound of claim 8, wherein a bond between Y₁ and M and a bond between Y₂ and M are each a coordinate bond, and
a bond between Y₃ and M and a bond between Y₄ and M are each a covalent bond.

17. The organometallic compound of claim 8, wherein
ring A₁ and ring A₂ are each independently:
a pyrazole group, an imidazole group, a triazole group, an oxazole group, an isoxazole group, an oxadiazole group, a thiazole group, an isothiazole group, or a thiadiazole group; or
a pyrazole group, an imidazole group, a triazole group, an oxazole group, an isoxazole group, an oxadiazole group, a thiazole group, an isothiazole group, or a thiadiazole group, each independently condensed with a benzene group, a pyridine group, a pyrimidine group, a pyrazine group, a pyridazine group, or any combination thereof.

18. The organometallic compound of claim 8, wherein
ring A₃, ring A₄, and ring B₁ to ring B₆ are each independently:
a benzene group, a pyridine group, a pyrimidine group, a pyrazine group, a pyridazine group, or a triazine group; or
a benzene group, a pyridine group, a pyrimidine group, a pyrazine group, a pyridazine group, or a triazine group, each independently condensed with a benzene group, a pyridine group, a pyrimidine group, a pyrazine group, a pyridazine group, a cyclohexane group, a cyclohexene group, an adamantane group, norbornane group, or any combination thereof.

19. The organometallic compound of claim 8, wherein the organometallic compound satisfies at least one of Condition 1 to Condition 4:
Condition 1
a group represented by 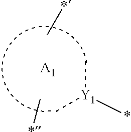
in Formula 1 is represented by one of Formulae A₁-1 to A₁-8: 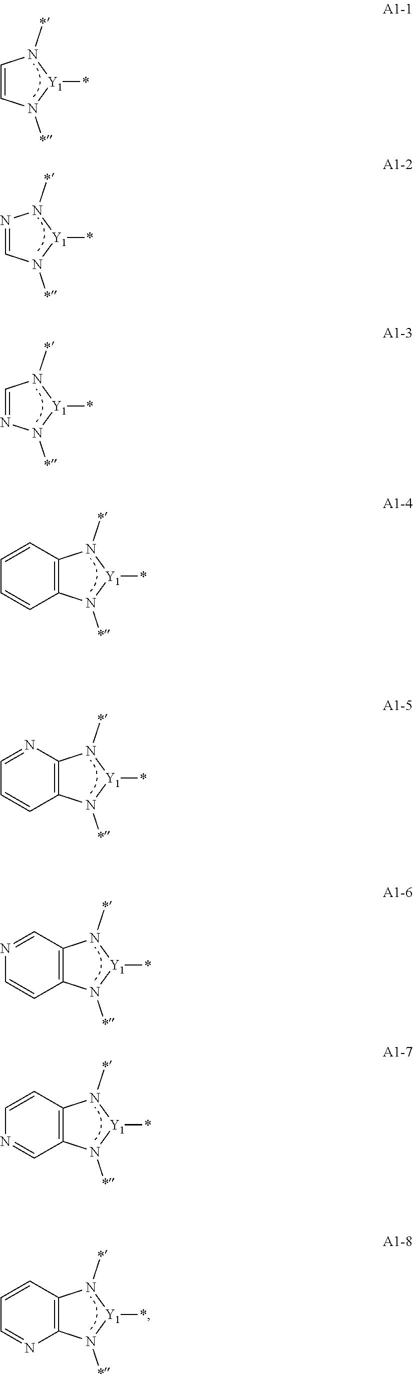
wherein, in Formulae A₁-1 to A₁-8,
Y₁ is C,
*′ indicates a binding site to ring B₅,
* indicates a binding site to M in Formula 1, and
*′ indicates a binding site to X₁ in Formula 1,
Condition 2
a group represented by 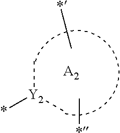
in Formula 1 is represented by one of Formulae A₂-1 to A₂-8: 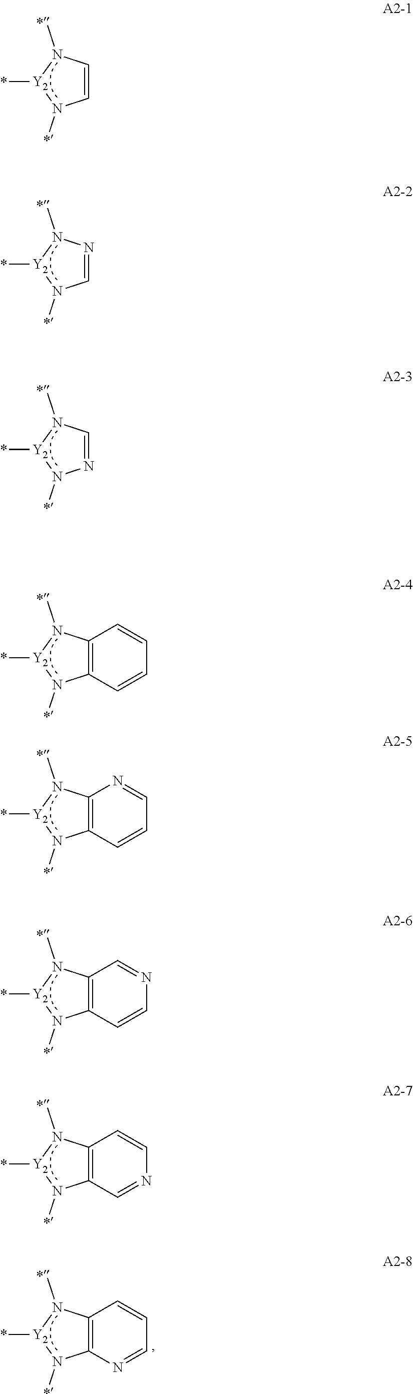
wherein, in Formulae A₂-1 to A₂-8,
Y₂ is C,
*″ indicates a binding site to ring B₆,
* indicates a binding site to M in Formula 1, and
*′ indicates a binding site to X₂ in Formula 1,
Condition 3
a group represented by 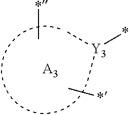
in Formula 1 is represented by one of Formulae A₃-1 to A₃-6: 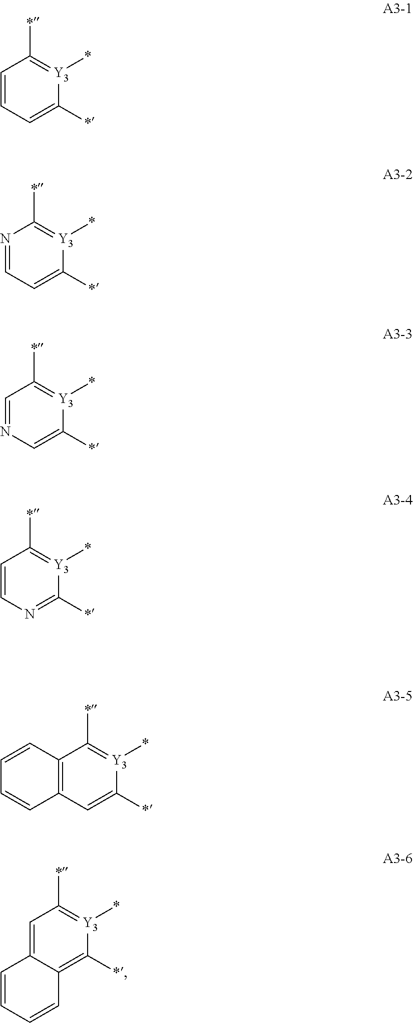
wherein, in Formulae A₃-1 to A₃-6,
Y₃ is C,
*″ indicates a binding site to X₁ in Formula 1,
* indicates a binding site to M in Formula 1, and
* is a binding site to X₃ in Formula 1; and
Condition 4
a group represented by 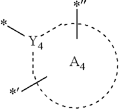
in Formula 1 is represented by one of Formulae A₄-1 to A₄-6: 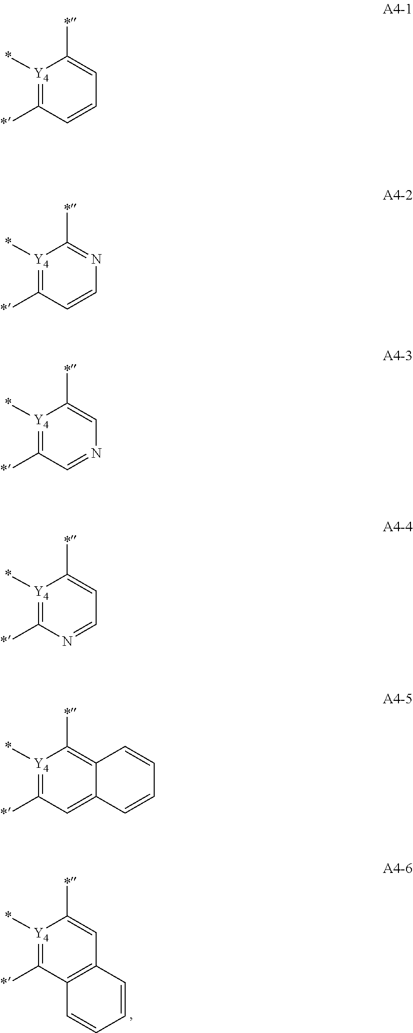
and
wherein, in Formulae A₄-1 to A₄-6,
Y₄ is C,
*″ indicates a binding site to X₂ in Formula 1,
* indicates a binding site to M in Formula 1, and
*′ is a binding site to X₃ in Formula 1.

20. The organometallic compound of claim 8, wherein a group represented by 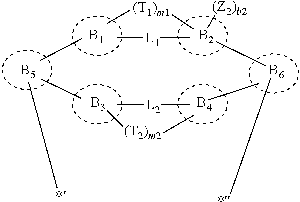
in Formula 1 is a group represented by one of Formulae B1-1 to B1-3: 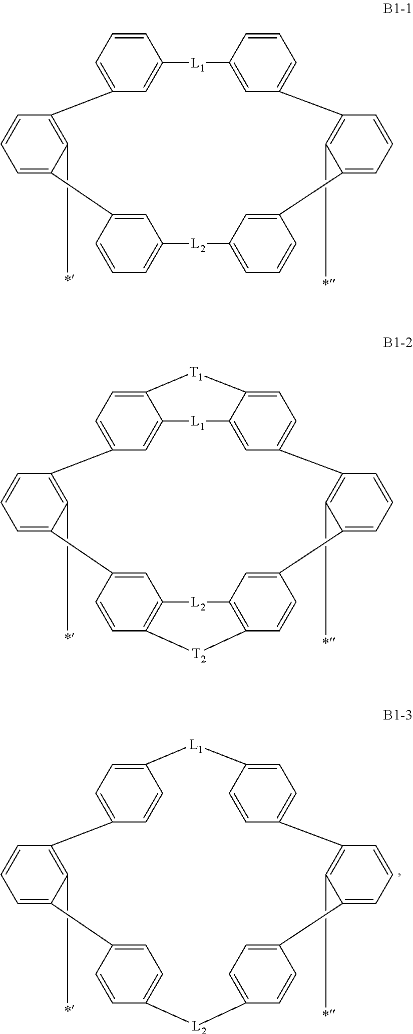
and
wherein, in Formulae B1-1 to B1-3,
L₁, L₂, T₁, and T₂ are respectively as described in Formula 1,
*′ indicates a binding site to ring A₁ in Formula 1, and
*″ indicates a binding site to ring A₂ in Formula 1.

21. The organometallic compound of claim 8, wherein
R₁ to R₆ are each independently:
hydrogen, deuterium, —F, a hydroxyl group, a cyano group, or a nitro group;
a C₁-C₂₀ alkyl group unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkoxy group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a biphenyl group, a naphthyl group, a pyridinyl group, a pyrimidinyl group, or any combination thereof,
a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, an indenyl group, a fluorenyl group, a pyrrolyl group, a thiophenyl group, a furanyl group, an indolyl group, a benzoindolyl group, a naphthoindolyl group, an isoindolyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzoxazolyl group, a benzothiazolyl group, a benzoxadiazolyl group, or a benzothiadiazolyl group, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a C₁-C₂₀ alkoxy group, a cyclopropyl group, a cyclobutyl group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, an indenyl group, a fluorenyl group, a pyrrolyl group, a thiophenyl group, a furanyl group, an indolyl group, a benzoindolyl group, a naphthoindolyl group, an isoindolyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzoxazolyl group, a benzothiazolyl group, a benzoxadiazolyl group, a benzothiadiazolyl group, —Si(Q₃₁)(Q₃₂)(Q₃₃), —B(Q₃₁)(Q₃₂), or any combination thereof; or
—Si(Q₁)(Q₂)(Q₃), —N(Q₁)(Q₂), or —B(Q₁)(Q₂), and
Q₁ to Q₃ and Q₃₁ to Q₃₃ are respectively as described in Formula 1.

22. The organometallic compound of claim 8, wherein
Z₁ to Z₁₀ are each independently:
hydrogen, deuterium, —F, a hydroxyl group, a cyano group, or a nitro group;
a C₁-C₂₀ alkyl group or a C₁-C₂₀ alkoxy group, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkoxy group, a cyclopentyl group, a cyclohexyl group, a cycloheptyl group, a cyclooctyl group, an adamantanyl group, a norbornanyl group, a cyclopentenyl group, a cyclohexenyl group, a cycloheptenyl group, a phenyl group, a biphenyl group, a naphthyl group, a pyridinyl group, a pyrimidinyl group, or any combination thereof;
a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, an indenyl group, a fluorenyl group, a pyrrolyl group, a thiophenyl group, a furanyl group, an indolyl group, a benzoindolyl group, a naphthoindolyl group, an isoindolyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzoimidazolyl group, a benzoxazolyl group, a benzothiazolyl group, a benzoxadiazolyl group, or a benzothiadiazolyl group, each independently unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a C₁-C₂₀ alkoxy group, —Si(Q₃₁)(Q₃₂)(Q₃₃), —B(Q₃₁)(Q₃₂), or any combination thereof; or
—Si(Q₁)(Q₂)(Q₃), —N(Q₁)(Q₂), or —B(Q₁)(Q₂), and
Q₁ to Q₃ and Q₃₁ to Q₃₃ are respectively as described in Formula 1.

23. The organometallic compound of claim 8, wherein a1 to a4 are each independently an integer from 0 to 5.

24. The organometallic compound of claim 8, wherein b1 to b6 are each independently an integer from 0 to 5.

25. The organometallic compound of claim 8, wherein the organometallic compound is configured to emit blue light having a maximum emission wavelength of about 430 nm or more and about 500 nm or less.
